(19) United States
(12) Patent Application Publication
(10) Pub. No.: US 2023/0200206 A1
(43) Pub. Date: Jun. 22, 2023

(54) CONDENSED CYCLIC COMPOUND AND ORGANIC ELECTROLUMINESCENT DEVICE INCLUDING THE SAME

(71) Applicant: Samsung Electronics Co., Ltd., Suwon-si (KR)

(72) Inventors: Katsunori SHIBATA, Kanagawa-ken (JP); Eigo MIYAZAKI, Kanagawa-ken (JP); Tomoya HIROSE, Kanagawa-ken (JP); Atsushi IMAMURA, Kanagawa-ken (JP)

(21) Appl. No.: 18/069,381

(22) Filed: Dec. 21, 2022

(30) Foreign Application Priority Data
Dec. 21, 2021 (JP) 2021-206802
Oct. 19, 2022 (JP) 2022-167426

(51) Int. Cl. H10K 85/30; C07F 5/02; C09K 11/06

(52) U.S. Cl. CPC H01L 51/008; C07F 5/025; C09K 11/06; H01L 51/5012

(57) ABSTRACT

Provided are a condensed cyclic compound represented by Formula 1 and an organic electroluminescent device including the cyclic compound:

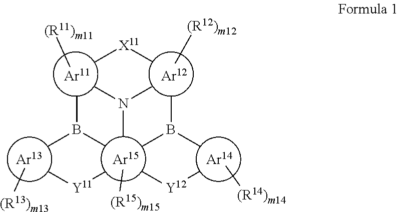

wherein, the substituents in Formula 1 are the same as described in the detailed description.

### CROSS-REFERENCE TO RELATED APPLICATIONS

This application is based on and claims priority under 35 U.S.C. § 119 to Japanese Patent Application Nos. 2021-206802, filed on Dec. 21, 2021, and 2022-167426, filed on Oct. 19, 2022, in the Japanese Patent Office, the disclosures of which are incorporated by reference herein in their entirety.

### BACKGROUND

### 1. Field

The disclosure relates to a condensed cyclic compound and an organic electroluminescent device including the same.

### 2. Description of the Related Art

Organic light-emitting devices are self-emissive devices that, as compared with devices of the related art, have wide viewing angles, high contrast ratios, short response times, and excellent characteristics in terms of luminance, driving voltage, and response speed, and produce full-color images.

An organic light-emitting device includes an anode, a cathode, and an organic layer that includes an emission layer and is arranged between the anode and the cathode. A hole transport region may be arranged between the anode and the emission layer, and an electron transport region may be arranged between the emission layer and the cathode. Holes provided from the anode move toward the emission layer through the hole transport region, and electrons provided from the cathode move toward the emission layer through the electron transport region. The holes and the electrons recombine in the emission layer to produce excitons. These excitons transition from an excited state to a ground state to thereby generate light that is then emitted from the device.

### SUMMARY

Provided are a condensed cyclic compound and an organic electroluminescent device including the condensed cyclic compound. In detail, provided is a novel condensed cyclic compound that has a narrow emission spectrum and high color purity and emits blue light.

Additional aspects will be set forth in part in the description which follows and, in part, will be apparent from the description, or may be learned by practice of the presented embodiments of the disclosure.

According to an aspect of the disclosure, provided is a condensed cyclic compound represented by Formula 1

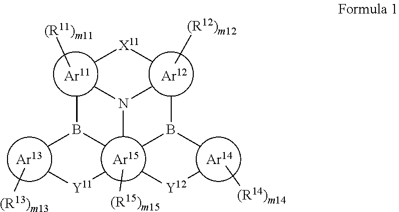

wherein, in Formula 1,

Ar¹¹, Ar¹², Ar¹³, and Ar¹⁴ may each independently be a group derived from an aromatic hydrocarbon ring having 6 to 18 ring-forming atoms or a group derived from a heteroaromatic ring having 5 to 18 ring-forming atoms,

Ar¹⁵ may be a group derived from a benzene ring or a group derived from a heteroaromatic ring having 5 or 6 ring-forming atoms,

X¹¹ may be —O—, —S—, —Se—, —Te—, —NR^{X11}—, or a single bond,

R^{X11} may be a hydrogen atom, a substituted or unsubstituted alkyl group, a substituted or unsubstituted aryl group, a substituted or unsubstituted heteroaryl group, a substituted or unsubstituted alkylsilyl group, a substituted or unsubstituted arylsilyl group, a substituted or unsubstituted alkylamino group, a substituted or unsubstituted arylamino group, a substituted or unsubstituted alkenyl group, a substituted or unsubstituted alkynyl group, or a substituted or unsubstituted arylalkyl group, wherein R^{X11} is optionally bonded to at least one of adjacent rings Ar¹¹ or Ar¹² via a linking group,

Y¹¹ and Y¹² may each independently be —O—, —S—, —Se—, —Te—, —NR^{Y11}—, —CR^{Y12}R^{Y13}— or —SiR^{Y14}R^{Y15}—, R^{Y11}, R^{Y12}, R^{Y13}, R^{Y14}, and R^{Y15} may each independently be a hydrogen atom, a substituted or unsubstituted alkyl group, a substituted or unsubstituted aryl group, a substituted or unsubstituted heteroaryl group, a substituted or unsubstituted alkylsilyl group, a substituted or unsubstituted arylsilyl group, a substituted or unsubstituted alkylamino group, a substituted or unsubstituted arylamino group, a substituted or unsubstituted alkenyl group, a substituted or unsubstituted alkynyl group, or a substituted or unsubstituted arylalkyl group, wherein at least one of R^{Y11}, R^{Y12}, R^{Y13}, R^{Y14}, or R^{Y15} are independently optionally bonded to adjacent ring Ar¹⁵ via a linking group, at least one of R^{Y11}, R^{Y13} or R^{Y15} are independently optionally bonded to Ar¹³ via a single bond, and/or at least one of R^{Y11}, R^{Y12} or R^{Y15} are independently optionally bonded to Ar¹⁴ via a single bond,

R¹¹, R¹², R¹³, R¹⁴, and R¹⁵ may each independently be a hydrogen atom, deuterium atom, a halogen atom, a cyano group, a substituted or unsubstituted alkyl group, a substituted or unsubstituted aryl group, a substituted or unsubstituted heteroaryl group, a substituted or unsubstituted diarylamino group, a substituted or unsubstituted diheteroarylamino group, a substituted or unsubstituted arylheteroarylamino group, a substituted or unsubstituted alkylsilyl group, a substituted or unsubstituted arylsilyl group, a substituted or unsubstituted alkylamino group, a substituted or unsubstituted arylamino group, a substituted or unsubstituted aryloxy group, a substituted or unsubstituted heteroaryloxy group, a substituted or unsubstituted arylthio group, a substituted or unsubstituted heteroarylthio group, a substituted or unsubstituted alkenyl group, a substituted or unsubstituted alkynyl group, or a substituted or unsubstituted arylalkyl group,

m11 and m12 may each independently be 0, 1, 2, or 3,

m13 and m14 may each independently be 0, 1, 2, 3, or 4, and

m15 may be 0 or 1.

According to another aspect of the disclosure, an organic electroluminescent device includes a first electrode, a second electrode, and an organic layer including an emission layer between the first electrode and the second electrode, wherein the organic layer includes the condensed cyclic compound described herein.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic cross-sectional view of an organic electroluminescent device according to an embodiment;

FIG. 2 is a schematic cross-sectional view of an organic electroluminescent device according to another embodiment;

FIG. 3 is a schematic cross-sectional view of an organic electroluminescent device according to another embodiment;

FIG. 4 is a diagram qualitatively illustrating each energy relationship; and

FIG. 5 is a graph of full width at half maximum (FWHM) of emission in photoluminescence (PL) measured in Condensed Cyclic Compounds R1 to R3 known in the art versus reorganization energy (eV) calculated by density functional theory (DFT).

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects.

It will be understood that when an element is referred to as being “on” another element, it can be directly on the other element or intervening elements may be present therebetween. In contrast, when an element is referred to as being “directly on” another element, there are no intervening elements present.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. As used herein, the term “and/or” includes any and all combinations of one or more of the associated listed items.

Expressions such as “at least one of,” when preceding a list of elements, modify the entire list of elements and do not modify the individual elements of the list. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. In addition, the dimension ratio of the drawings may be exaggerated for convenience of explanation, and thus may differ from the actual ratio.

Moreover, sharp angles that are illustrated may be rounded. Thus, the regions illustrated in the figures are schematic in nature and their shapes are not intended to illustrate the precise shape of a region and are not intended to limit the scope of the present claims.

In addition, unless otherwise specified, measurements of operation and physical properties are performed at room temperature (20° C. or more and 25° C. or less) and at relative humidity of 40% RH or more and 50% RH or less.

As used herein, the term “X and Y may each independently be” may be understood that X and Y may be identical to or different from each other.

In addition, as used herein, the term “group derived from a ring” refers to a group obtained by removing one or more hydrogens bonded to one or more ring-forming atoms in a ring structure.

In addition, as used herein, the term “X to Y” representing a range may include X and Y, and may be understood as “X or more and Y or less”.

### Condensed Cyclic Compound

As used herein, a condensed cyclic compound according to the disclosure may be simply referred to as a “condensed cyclic compound,” “condensed cyclic compound of the disclosure,” or “compound of the disclosure.” In addition, an organic electroluminescent device may be simply referred to as an “organic electroluminescent (EL) device.”

As used herein, the term “number of ring-forming atoms” refers to the number of atoms constituting the ring itself of a compound (e.g., a monocyclic compound, a condensed cyclic compound, a cross-linked compound, a carbocyclic compound, and a heterocyclic compound) having a structure (e.g., a monocyclic ring, a condensed ring, and a ring assembly) in which atoms are bonded in a ring-like manner. Atoms not constituting the ring or, when the ring is substituted by a substituent, atoms included in the substituent are not included in the number of ring-forming atoms. Unless otherwise specified, the number of ring-forming atoms described below may be understood in the same way.

For example, a benzene ring has 6 ring-forming atoms, a naphthalene ring has 10 ring-forming atoms, a pyridine ring has 6 ring-forming atoms one of which is a nitrogen, and a furan ring has 5 ring-forming atoms on of which is oxygen.

When a benzene ring is substituted with, for example, an alkyl group as a substituent, the number of carbon atoms of the alkyl group is not included in the number of ring-forming atoms in the benzene ring. Accordingly, a benzene ring substituted with an alkyl group has 6 ring-forming atoms. In addition, when a naphthalene ring is substituted with, for example, an alkyl group as a substituent, the number of atoms of the alkyl group is not included in the number of ring-forming atoms in the naphthalene ring. Accordingly, a naphthalene ring substituted with an alkyl group has 10 ring-forming atoms.

For example, the number of hydrogen atoms bonded to a pyridine ring or the number of atoms constituting a substituent is not included in the number of ring-forming atoms in the pyridine ring. Accordingly, a pyridine ring to which hydrogen atoms or a substituent is bonded has 6 ring-forming atoms. In addition, the number of hydrogen atoms bonded to a furan ring or the number of atoms constituting a substituent is not included in the number of ring-forming atoms in the furan ring. Accordingly, a furan ring to which hydrogen atoms or a substituent is bonded has 5 ring-forming atoms.

The condensed cyclic compound according to the disclosure may have a narrow emission spectrum and exhibit high color purity.

A mechanism for resolving issues according to a configuration of the disclosure is speculated as follows.

The condensed cyclic compound according to the disclosure has an electron-donating nitrogen atom (N) and an electron-accepting boron atom (B), and includes within a conjugated system having a specific structure are properly arranged. In a molecular structure with such multiple resonance structures, the highest occupied molecular orbital (HOMO) and the lowest unoccupied molecular orbital (LUMO) may be alternately localized on adjacent carbon atoms of a ring. Accordingly, a change in the molecular structure (bond length, bond angle, etc.) between the ground singlet state (S₀) and the first excited singlet state (S₁) may be suppressed, and thus, a solid condensed ring structure may be maintained. Accordingly, high-purity light emission with a narrow spectrum width, particularly blue light emission, may be exhibited.

The above stated electronic characteristics is based on theory, particular theory associated with extended conjugated aromatic ring systems and does not affect the technical scope of the disclosure. This applies to other mechanistic or chemical/electronic speculations of the disclosure.

The condensed cyclic compound may be represented by Formula 1:

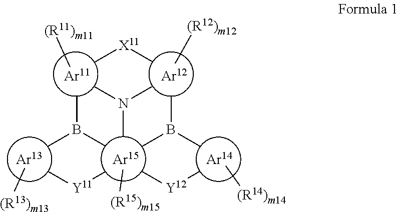

wherein, in Formula 1,

Ar¹¹, Ar¹², Ar¹³, and Ar¹⁴ may each independently be a group derived from an aromatic hydrocarbon ring having 6 to 18 ring-forming atoms or a group derived from a heteroaromatic ring having 5 to 18 ring-forming atoms.

The aromatic hydrocarbon rings of Ar¹¹, Ar¹², Ar¹³, and Ar¹⁴ may each independently be a single ring or a condensed ring. The number of ring-forming atoms in the aromatic hydrocarbon ring of Ar¹¹, Ar¹², Ar¹³, and Ar¹⁴ may each independently be 6 or more and 18 or less, for example, 6 or more and 14 or less, for example, 6 or more and 10 or less, or for example, about 6. Examples of the aromatic hydrocarbon ring of Ar¹¹, Ar¹², Ar¹³, and Ar¹⁴ may each independently have 6 to 18 ring-forming atoms may include, but are not particularly limited to, a benzene ring, a pentalene ring, an indene ring, a naphthalene ring, an anthracene ring, an azulene ring, a heptalene ring, an acenaphthylene ring, a phenalene ring, a fluorene ring, a phenanthrene ring, a biphenyl ring, a terphenyl ring, a triphenylene ring, a pyrene ring, a chrysene ring, a tetraphene ring, or the like. Among the above examples, a benzene ring, a naphthalene ring, or a phenanthrene ring, for example, a benzene ring, may be preferred.

The heteroaromatic ring of Ar¹¹, Ar¹², Ar¹³, and Ar¹⁴ may each independently be a single ring or a condensed ring. The number of ring-forming atoms in the heteroaromatic ring of Ar¹¹, Ar¹², Ar¹³, and Ar¹⁴ may be 5 or more and 18 or less, for example, 5 or more and 14 or less, for example, 5 or more and 10 or less, or for example, about 6.

As used herein, the term “heteroaromatic ring” may have one or more heteroatoms (e.g., nitrogen atoms (N), oxygen atoms (O), phosphorus atoms (P), sulfur atoms (S), silicon atoms (Si) or a combination thereof) as ring-forming atoms, and the remaining ring-forming atoms may be carbon atoms (C). Examples of the heteroaromatic ring having 5 to 18 ring-forming atoms may include, but are not particularly limited to, a pyridine ring, a pyrazine ring, a pyridazine ring, a pyrimidine ring, a triazine ring, a quinoline ring, an isoquinoline ring, a quinoxaline ring, a quinazoline ring, a naphthyridine ring, an acridine ring, a phenazine ring, a benzoquinoline ring, a benzoisoquinoline ring, a phenanthridine ring, a phenanthroline ring, a benzoquinone ring, a coumarin ring, an anthraquinone ring, a fluorenone ring, a furan ring, a thiophene ring, a benzofuran ring, a benzothiophene ring, a dibenzofuran ring, a dibenzothiophene ring, a pyrrole ring, an indole ring, a carbazole ring, an imidazole ring, a benzimidazole ring, a pyrazole ring, an indazole ring, an oxazole ring, an isoxazole ring, a benzoxazole ring, a benzoisoxide ring, a thiazole ring, an isothiazole ring, a benzothiazole ring, a benzoisothiazole ring, an imidazolinone ring, a benzimidazolinone ring, an imidazopyridine ring, an imidazopyrimidine ring, an imidazolephenanthridine ring, an azadibenzofuran ring, an azacarbazole ring, a diazadibenzofuran ring, a diazacarbazole ring, a diazadibenzothiophene ring, a xanthone ring, a thioxanthone ring, or the like. Among the above examples, a pyridine ring may be preferred.

According to an embodiment, a condensed cyclic compound represented by Formula 1, Ar¹⁵ may be a group derived from a benzene ring or a group derived from a heteroaromatic ring having 5 or 6 ring-forming atoms.

Examples of the heteroaromatic ring having ring 5 or 6 ring-forming atoms may include, but are not particularly limited to, a pyridine ring, a pyrazine ring, a pyridazine ring, a pyrimidine ring, a triazine ring, a furan ring, a thiophene ring, a pyrrole ring, a pyrazole ring, a thiazole ring, an isothiazole ring, an imidazolinone ring, and the like.

According to an embodiment, a condensed cyclic compound represented by Formula 1, X¹¹ may be —O—, —S—, —Se—, —Te—, —NR^{X11}—, or a single bond. For example, X¹¹ may be —O— or —NR^{X11}— (wherein R^{X11} is a phenyl group), for example, X¹¹ may be —O—, —S—, —Se—, or —Te—, or for example, X¹¹ may be —O—.

According to an embodiment, a condensed cyclic compound represented by Formula 1, R^{X11} may be a hydrogen atom, a substituted or unsubstituted alkyl group, a substituted or unsubstituted aryl group, a substituted or unsubstituted heteroaryl group, a substituted or unsubstituted alkylsilyl group, a substituted or unsubstituted arylsilyl group, a substituted or unsubstituted alkylamino group, a substituted or unsubstituted arylamino group, a substituted or unsubstituted alkenyl group, a substituted or unsubstituted alkynyl group, or a substituted or unsubstituted arylalkyl group, wherein R^{X11} may be optionally bonded to at least one of adjacent rings Ar¹¹ or Ar¹² via a linking group.

Examples of the alkyl group may include, but are not particularly limited to, a methyl group, an ethyl group, an n-propyl group, an isopropyl group, an n-butyl group, an s-butyl group, a tert-butyl group, an i-butyl group, a 2-ethylbutyl group, a 3,3-dimethylbutyl group, an n-pentyl group, an i-pentyl group, a neopentyl group, a tert-pentyl group (a t-pentyl group), a cyclopentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, a cyclohexyl group, a 4-methylcyclohexyl group, a 4-tert-butylcyclohexyl group (a 4-t-butylcyclohexyl group), an n-heptyl group, a 1-methylpeptyl group, a 2,2-dimethylheptyl group, a 2-ethylheptyl group, a 2-butylheptyl group, an n-octyl group, a tert-octyl group (a t-octyl group), a 2-ethyloctyl group, a 2-butyloctyl group, a 2-hexyloctyl group, a 3,7-dimethyloctyl group, a cyclooctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldodecyl group, a 2-octyldecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-icosyl group, a 2-ethylicosyl group, a 2-butylicosyl group, a 2-hexylicosyl group, a 2-octylicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, and the like.

The aryl group may be, but is not particularly limited to, a monovalent group derived from a hydrocarbon ring including one or more aromatic rings. In addition, the hydrocarbon ring constituting the aryl group may be a condensed ring. In addition, when the aryl group includes two or more aromatic rings, the two or more aromatic rings may be linked to each other via a single bond or may be condensed with each other. In addition, when the aryl group includes two or more partially or fully aromatic rings, a plurality of aromatic rings may share one atom. The number of ring-forming atoms in the aryl group may be, but is not particularly limited to, 6 or more and 18 or less, for example, 6 or more and 14 or less, for example, 6 or more and 10 or less, or for example, about 6. Examples of the aryl group may include, but are not particularly limited to, a phenyl group, a naphthyl group, a phenanthryl group, a biphenylenyl group, an anthryl group, a fluorenyl group, an azulenyl group, an acenaphthenyl group, and the like.

The heteroaryl group may be, but is not particularly limited to, a monovalent group derived from a ring including one or more heteroaromatic rings having one or more heteroatoms (e.g., nitrogen atoms (N), oxygen atoms (O), phosphorus atoms (P), sulfur atoms (S), silicon atoms (Si)) as ring-forming atoms, or a combination thereof, wherein the remaining ring-forming atoms may be carbon atoms (C). When the heteroaryl group includes two or more heteroatoms, the two or more heteroatoms may be identical to or different from each other. In addition, a ring constituting the heteroaryl group may be a condensed ring. In addition, when the heteroaryl group includes two or more heteroaromatic rings, the two or more heteroaromatic rings may be linked to each other via a single bond or may be condensed with each other. In addition, when the heteroaryl group includes two or more heteroaromatic rings, a plurality of hetero rings may share one atom.

As such, the heteroaryl group may be a monocyclic heteroaryl group or a polycyclic heteroaryl group. The number of ring-forming atoms in the heteroaryl group may be, but is not particularly limited to, 5 or more and 18 or less, for example, 5 or more and 14 or less, for example, 5 or more and 10 or less, or for example, about 6.

Examples of the heteroaryl group may include, but are not particularly limited to, a thienyl group, a furanyl group, a pyrrolyl group, an imidazolyl group, a thiazolyl group, an oxazolyl group, an oxadiazolyl group, a triazolyl group, a pyridyl group, a bipyridyl group, a pyrimidyl group, a triazinyl group, an acridinyl group, a pyridazinyl group, a pyridinyl group, a quinolinyl group, a quinazolinyl group, a quinoxalinyl group, a phenoxazinyl group, a phthalazinyl group, a pyridopyrimidinyl group, a pyridopyrazinyl group, a pyrazinopyrazinyl group, an isoquinolinyl group, an indolyl group, a benzoxazolyl group, a benzimidazolyl group, a benzothiazolyl group, a benzocarbazolyl group, a benzothiophenyl group, a dibenzothienyl group, a thienothienyl group, a benzofuranyl group, a phenanthrolinyl group, an isoxazolyl group, an oxadiazolyl group, a thiadiazolyl group, a dibenzosilolyl group, a dibenzofuranyl group, and a group consisting of a combination thereof.

The alkylsilyl group may be a monoalkylsilyl group represented by a —SiH2(alkyl) group, a dialkylsilyl group represented by —SiH(alkyl)(alkyl) group, or a trialkylsilyl group represented by a —Si(alkyl)(alkyl)(alkyl) group. In this regard, the alkyl groups may each independently be the same as the alkyl group described above.

The arylsilyl group may be a monoarylsilyl group represented by a —SiH2(aryl) group, a diarylsilyl group represented by a —SiH(aryl)(aryl) group, or a triarylsilyl group represented by a —Si(aryl)(aryl)(aryl) group. In this regard, the aryl groups may each independently be the same as the aryl group described above.

The alkylamino group may be a monoalkylamino group represented by a —NH(alkyl) group or a dialkylamino group represented by a —N(alkyl)(alkyl) group. In this regard, the alkyl groups may each independently be the same as the alkyl group described above.

The arylamino group may be a monoarylamino group represented by a —NH(aryl) group or a diarylamino group represented by a —N(aryl)(aryl) group. In this regard, the aryl groups may each independently be the same as the aryl group described above.

The alkenyl group may be linear, branched, or cyclic, for example, may be linear. The number of carbon atoms in the alkenyl group may be, but is not particularly limited to, 2 or more and 20 or less, for example, 2 or more and 10 or less, or for example, 2 or more and 4 or less. Examples of the alkenyl group may include, but are not particularly limited to, a vinyl group, a 2-prophenyl group, a 2-butenyl group, a 3-butenyl group, a 1-methyl-2-prophenyl group, a 2-methyl-2-prophenyl group, a 2-pentenyl group, a 3-pentenyl group, a 4-pentenyl group, a 1-methyl-2-butenyl group, a 2-methyl-2-butenyl group, a 3-methyl-2-butenyl group, a 1-methyl-3-butenyl group, a 2-methyl-3-butenyl group, a 3-methyl-3-butenyl group, a 1,1-dimethyl-2-prophenyl group, a 1,2-dimethyl-2-prophenyl group, a 1-ethyl-2-prophenyl group, and the like.

The alkynyl group may be linear, branched, or cyclic, for example, may be linear. The number of carbon atoms in the alkynyl group may be, but is not particularly limited to, 2 or more and 20 or less, for example, 2 or more and 10 or less, or for example, 2 or more and 4 or less. Examples of the alkenyl group may include, but are not particularly limited to, a 2-butynyl group, a 3-pentynyl group, a hexynyl group, a heptynyl group, an octynyl group, a decynyl group, and the like.

The number of carbon atoms in the arylalkyl group may be, but is not particularly limited to, 7 or more and 20 or less. Examples of the arylalkyl group may include, but are not particularly limited to, a benzyl group, a phenethyl group, and a diphenylmethyl group.

At least one hydrogen atom of the alkyl group, the aryl group, the heteroaryl group, the alkylsilyl group, the arylsilyl group, the alkylamino group, the arylamino group, the alkenyl group, the alkynyl group, or the arylalkyl group may be substituted. In this case, the type of a substituent may be, but is not limited to, a deuterium atom, a halogen atom, a substituted or unsubstituted alkyl group, a substituted or unsubstituted aryl group, a substituted or unsubstituted heteroaryl group, a substituted or unsubstituted alkoxy group, a substituted or unsubstituted aryloxy group, a substituted or unsubstituted heteroaryloxy group, a substituted or unsubstituted diarylamino group, a substituted or unsubstituted diheteroarylamino group, or a substituted or unsubstituted arylheteroarylamino group. When two or more hydrogen atoms are substituted, the types of substituents may be identical to or different from each other. In addition, the substituent does not substitute a group of the same type. For example, a substituent substituting an alkyl group does not include an alkyl group.

When X¹¹ is —NR^{X11}—, R^{X11} may be optionally bonded to at least one of adjacent rings Ar¹¹ or Ar¹² via a linking group. In an embodiment, R^{X11} may be bonded to at least one ring-forming atom of Ar¹¹ or Ar¹² via a linking group to form a ring. In this regard, the linking group may be, but is not particularly limited to, —O—, —S—, —NR—, —CR′R″—, or a single bond. When the linking group is —NR— or —CR′R″—, R, R′, and R″ may each independently be a hydrogen atom, a deuterium atom, a halogen atom, a substituted or unsubstituted alkyl group, a substituted or unsubstituted aryl group, a substituted or unsubstituted heteroaryl group, a substituted or unsubstituted silyl group, a substituted or unsubstituted alkoxy group, a substituted or unsubstituted alkylthio group, a substituted or unsubstituted aryloxy group, a substituted or unsubstituted heteroaryloxy group, a substituted or unsubstituted arylthio group, a substituted or unsubstituted heteroarylthio group, or a substituted or unsubstituted amino group, wherein R′ and R″ may be identical to or different from each other.

According to an embodiment, a condensed cyclic compound represented by Formula 1, Y¹¹ and Y¹² may each independently be —O—, —S—, —Se—, —Te—, —NR^{Y11}—, —CR^{Y12}R^{Y13}— or —SiR^{Y14}R^{Y15}—. In an embodiment, Y¹¹ and Y¹² may each independently be —O—, —S—, —NR^{Y11}—, —CR^{Y12}R^{Y13}—, or —SiR^{Y14}R^{Y15}— (wherein R^{Y11}, R^{Y12}, R^{Y13}, R^{Y1}, and R^{Y15} are each independently a phenyl group, a biphenyl group, a tert-butylphenyl group, or a naphthyl group), for example, may each independently be —NR^{Y11}— (wherein R^{Y11} is a phenyl group or a tert-butylphenyl group).

According to an embodiment, a condensed cyclic compound represented by Formula 1, R^{Y11}, R^{Y12}, R^{Y13}, R^{Y14}, and R^{Y15} may each independently be hydrogen, a substituted or unsubstituted alkyl group, a substituted or unsubstituted aryl group, a substituted or unsubstituted heteroaryl group, a substituted or unsubstituted alkylsilyl group, a substituted or unsubstituted arylsilyl group, a substituted or unsubstituted alkylamino group, a substituted or unsubstituted arylamino group, a substituted or unsubstituted alkenyl group, a substituted or unsubstituted alkynyl group, or a substituted or unsubstituted arylalkyl group, wherein at least one of R^{Y11}, R^{Y12}, R^{Y13}, R^{Y14}, or R^{Y15} may independently be optionally bonded to adjacent ring Ar¹⁵ via a linking group, at least one of R^{Y11}, R^{Y13} or R^{Y15} may independently be optionally bonded to adjacent ring Ar¹³ via a single bond, and/or at least one of R^{Y11}, R^{Y12} or R^{Y14} are independently optionally bonded to adjacent ring Ar¹⁴ via a single bond.

In an embodiment, at least one of R^{Y11}, R^{Y12}, R^{Y13}, R^{Y14}, and R^{Y15} and at least one ring-forming atom of Ar¹⁵ may form a ring via a linking group, at least one of R^{Y11} or R^{Y15} and at least one ring-forming atom of Ar¹³ may form a ring via a single bond, and/or at least one of R^{Y12} or R^{Y14} and at least one ring-forming atom of Ar¹⁴ may form a ring via a single bond. In this regard, the linking group may be the same as described above.

In this regard, examples of the substituted or unsubstituted alkyl group, the substituted or unsubstituted aryl group, the substituted or unsubstituted heteroaryl group, the substituted or unsubstituted alkylsilyl group, the substituted or unsubstituted arylsilyl group, the substituted or unsubstituted alkylamino group, the substituted or unsubstituted arylamino group, the substituted or unsubstituted alkenyl group, the substituted or unsubstituted alkynyl group, or the substituted or unsubstituted arylalkyl group may be the same as described in connection with R^{X11}.

According to an embodiment, a condensed cyclic compound represented by Formula 1, R¹¹, R¹², R¹³, R¹⁴, and R¹⁵ may each independently be a hydrogen atom, deuterium atom, a halogen atom, a cyano group, a substituted or unsubstituted alkyl group, a substituted or unsubstituted aryl group, a substituted or unsubstituted heteroaryl group, a substituted or unsubstituted diarylamino group, a substituted or unsubstituted diheteroarylamino group, a substituted or unsubstituted arylheteroarylamino group, a substituted or unsubstituted alkylsilyl group, a substituted or unsubstituted arylsilyl group, a substituted or unsubstituted alkylamino group, a substituted or unsubstituted arylamino group, a substituted or unsubstituted aryloxy group, a substituted or unsubstituted heteroaryloxy group, a substituted or unsubstituted arylthio group, a substituted or unsubstituted heteroarylthio group, a substituted or unsubstituted alkenyl group, a substituted or unsubstituted alkynyl group, or a substituted or unsubstituted arylalkyl group.

In an embodiment, R¹¹, R¹², R¹³, R¹⁴, and R¹⁵ may each independently be a hydrogen atom, a halogen atom, a substituted or unsubstituted alkyl group, a substituted or unsubstituted aryl group, or a substituted or unsubstituted diarylamino group, for example, may each independently be a hydrogen atom, a halogen atom, an unsubstituted alkyl group, an unsubstituted aryl group, or an unsubstituted diarylamino group. In an embodiment, R¹¹, R¹², R¹³, R¹⁴, and R¹⁵ may each independently be a hydrogen atom, a chlorine (Cl), a tert-butyl group, a phenyl group, or a diphenylamino group.

Examples of the halogen atom may include a fluorine (F), a chlorine (Cl), a bromine (Br), an iodine (I), and the like.

Examples of the alkyl group, the aryl group, and the heteroaryl group may be the same as described in connection with R^{X11}.

The diarylamino group may have a structure of a —N(aryl)(aryl) group, wherein the aryl groups may each independently be the same as an aryl group described above.

The diheteroarylamino group may have a structure of a —N(heteroaryl)(heteroaryl) group, wherein the heteroaryl groups may each independently be the same as a heteroaryl group described above.

The arylheteroarylamino group may have a structure of a —N(aryl(heteroaryl) group, wherein the aryl group and the heteroaryl group may respectively be the same as a aryl group and a heteroaryl group described above.

The aryloxy group may have a structure of a —O(aryl) group, wherein the aryl group may be the same as an aryl group described above.

The heteroaryloxy group may have a structure of a —O(heteroaryl) group, wherein the heteroaryl group may be the same as a heteroaryl group described above.

The arylthio group may have a structure of a —S(aryl) group, wherein the aryl group may be the same as the aryl group described above.

In any of the above aromatic groups, at least one hydrogen atom of the alkyl group, the aryl group, the heteroaryl group, the diarylamino group, the diheteroarylamino group, the arylheteroarylamino group, the aryloxy group, the heteroaryloxy group, the arylthio group, or the heteroarylthio group may be substituted. In this regard, the type of a substituent may be the same as described above. When two or more hydrogen are substituted, the types of substituents may be identical to or different from each other. In addition, the substituent does not substitute a group of the same type. For example, a substituent substituting an alkyl group does not include an alkyl group.

According to an embodiment, a condensed cyclic compound represented by Formula 1, m11 and m12 may indicate the number of substituents (R¹¹ and R¹²) present in Ar¹¹ and Ar¹², respectively, and may each independently be 0, 1, 2, or 3. In this regard, m11 and m12 may be identical to or different from each other, for example, m11 and m12 may be identical to each other. In an embodiment, m11 and m12 may each independently be 0 or 1, for example, m11 and m12 may each be 0.

According to an embodiment, a condensed cyclic compound represented by Formula 1, m13 and m14 may indicate the number of substituents (R¹³ and R¹⁴) present in Ar¹³ and Ar¹⁴, respectively, and may each independently be 0, 1, 2, or 3. In this regard, m13 and m14 may be identical to or different from each other, for example, m13 and m14 may be identical to each other. In an embodiment, m13 and m14 may each independently be 0 or 1, for example, m13 and m14 may each be 1.

According to an embodiment, a condensed cyclic compound represented by Formula 1, m15 may be 0 or 1, for example, m15 may be 1.

According to an embodiment, the condensed cyclic compound represented by Formula 1 may be represented by Formula 2:

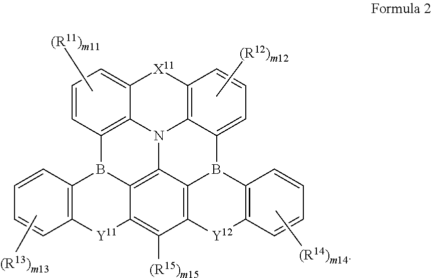

The condensed cyclic compound represented by Formula 2 may be a condensed cyclic compound in which Ar¹¹, Ar¹², Ar¹³, Ar¹⁴, and Ar¹⁵ in Formula 1 are each a benzene ring.

In Formula 2, X¹¹ may be —O—, —S—, —Se—, or —Te—, for example, may be —O—.

In Formula 2, Y¹¹ and Y¹² may be the same as defined in Formula 1, and R¹¹, R¹², R¹³, R¹⁴, R¹⁵, m11, m12, m13, m14, and m15 may be the same as defined in Formula 1.

In an embodiment, a specific compound of the condensed cyclic compound may be represented by one of Formulae 1-1 to 1-53:

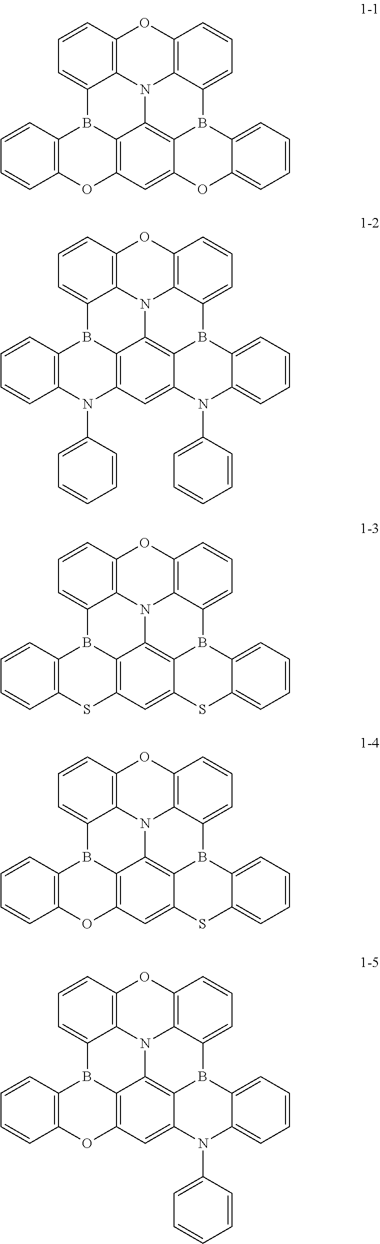

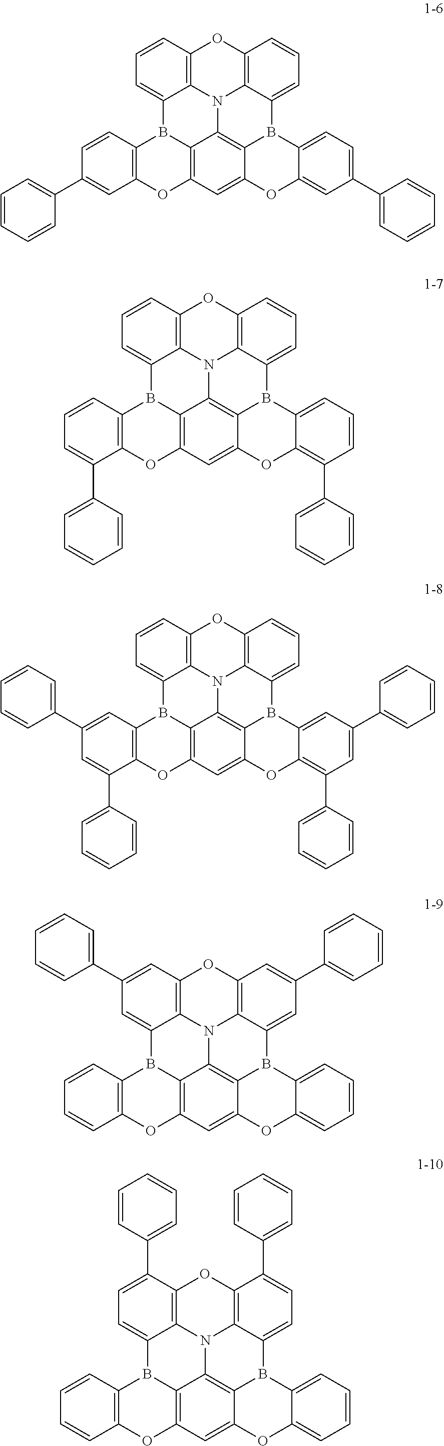

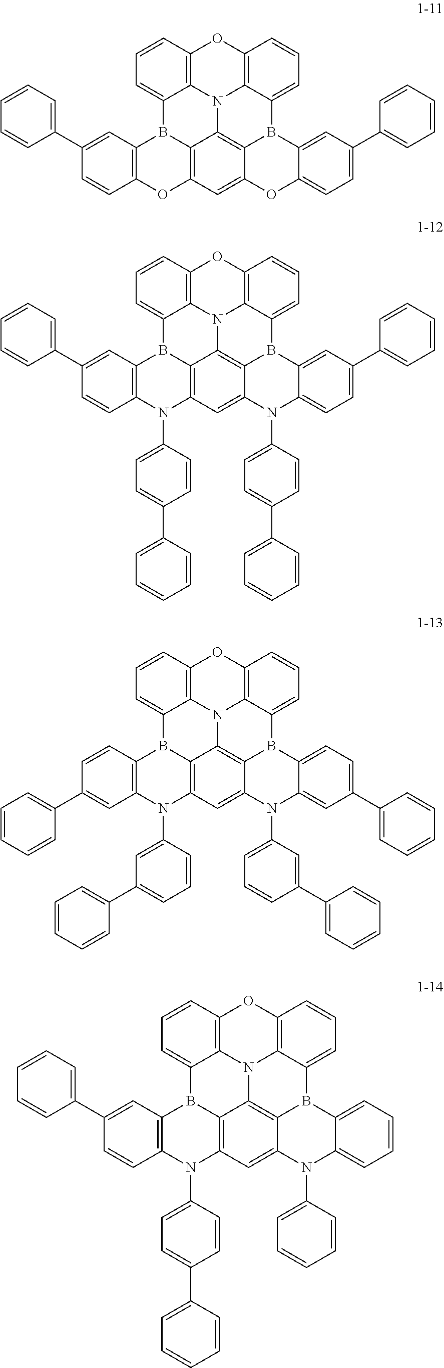 [SMILES: c1ccc(-c2ccc3c(c2)B2c4cccc5c4N4c6c(cccc6B6c7cc(-c8ccccc8)ccc7Oc7cc(c2c4c76)O3)O5)cc1 ; c1ccc(-c2ccc(N3c4ccc(-c5ccccc5)cc4B4c5cccc6c5N5c7c(cccc7B7c8cc(-c9ccccc9)ccc8N(c8ccc(-c9ccccc9)cc8)c8cc3c4c5c87)O6)cc2)cc1 ; c1ccc(-c2cccc(N3c4cc(-c5ccccc5)ccc4B4c5cccc6c5N5c7c(cccc7B7c8ccc(-c9ccccc9)cc8N(c8cccc(-c9ccccc9)c8)c8cc3c4c5c87)O6)c2)cc1 ; c1ccc(-c2ccc(N3c4ccc(-c5ccccc5)cc4B4c5cccc6c5N5c7c(cccc7B7c8ccccc8N(c8ccccc8)c8cc3c4c5c87)O6)cc2)cc1]

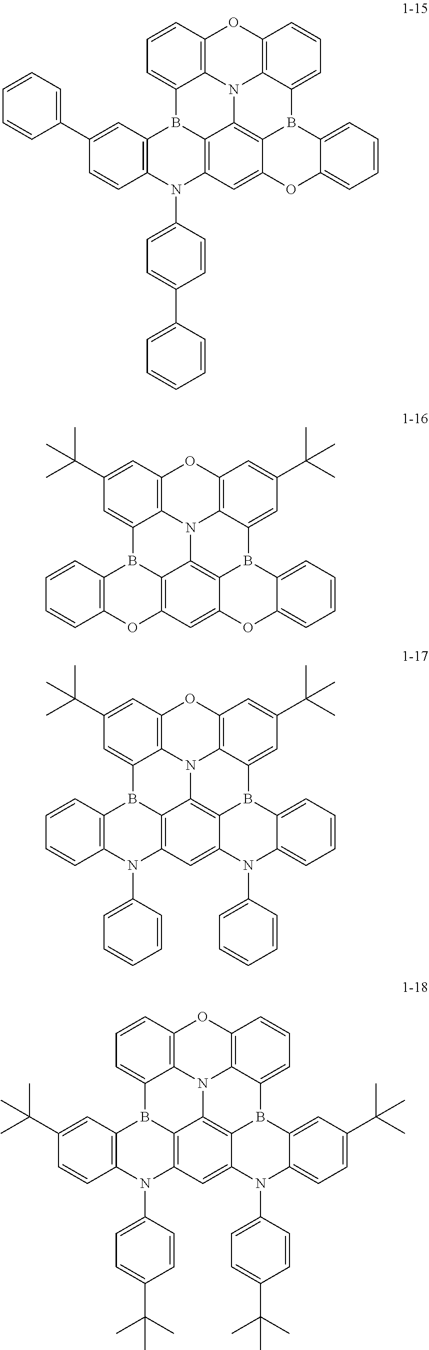

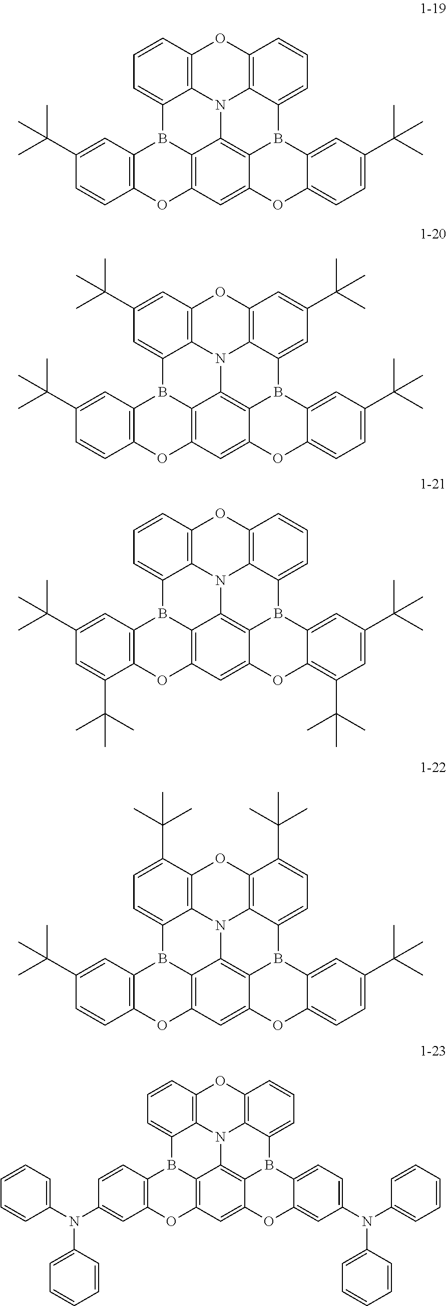

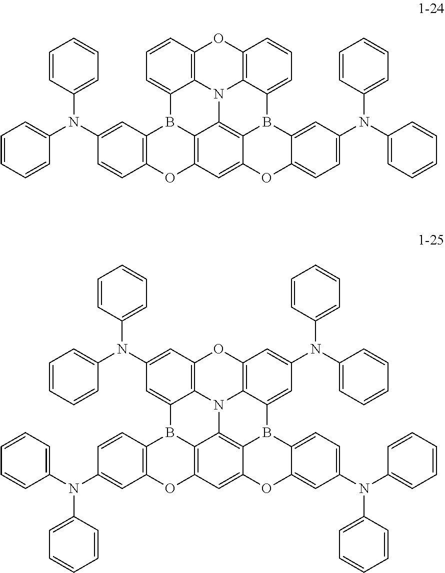 [SMILES: c1ccc(N(c2ccccc2)c2ccc3c(c2)B2c4cccc5c4N4c6c(cccc6B6c7cc(N(c8ccccc8)c8ccccc8)ccc7Oc7cc(c2c4c76)O3)O5)cc1 ; c1ccc(N(c2ccccc2)c2ccc3c(c2)Oc2cc4c5c6c2B3c2cc(N(c3ccccc3)c3ccccc3)cc3c2N6c2c(cc(N(c6ccccc6)c6ccccc6)cc2B5c2ccc(N(c5ccccc5)c5ccccc5)cc2O4)O3)cc1]

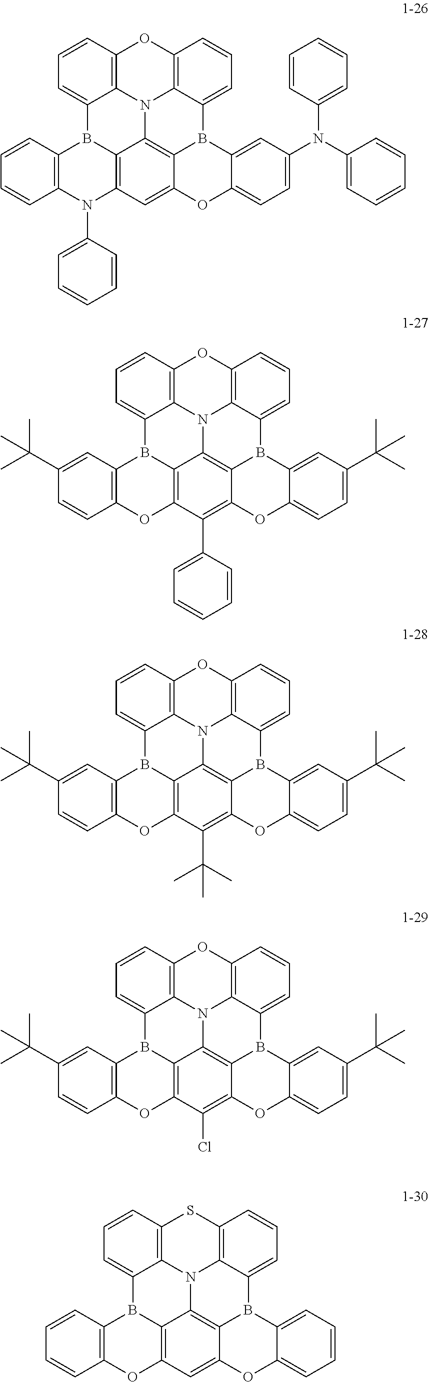

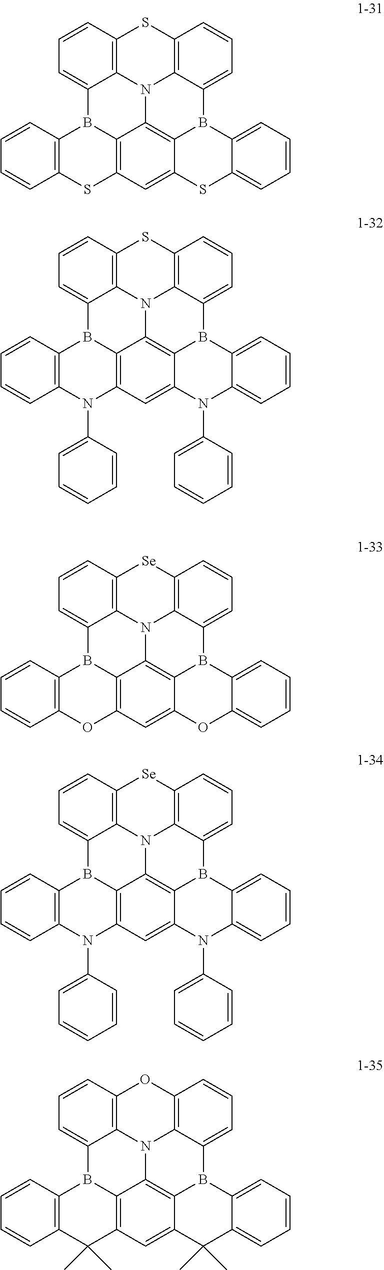

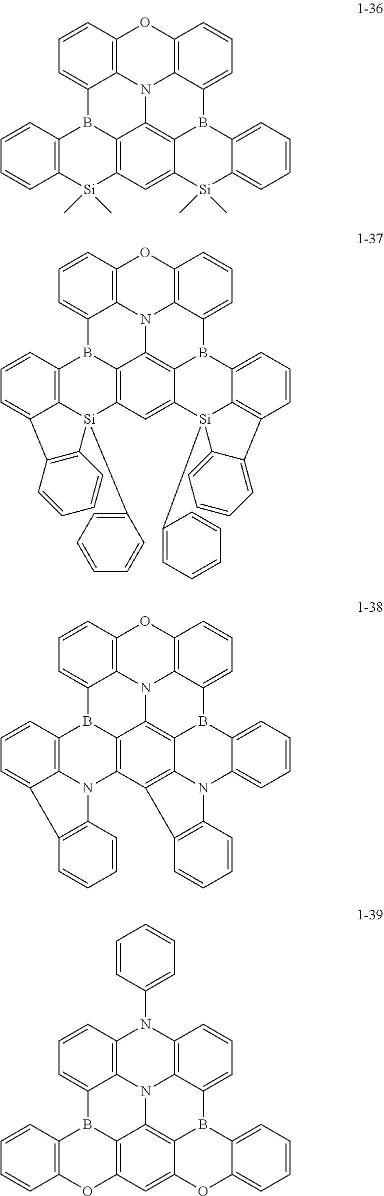

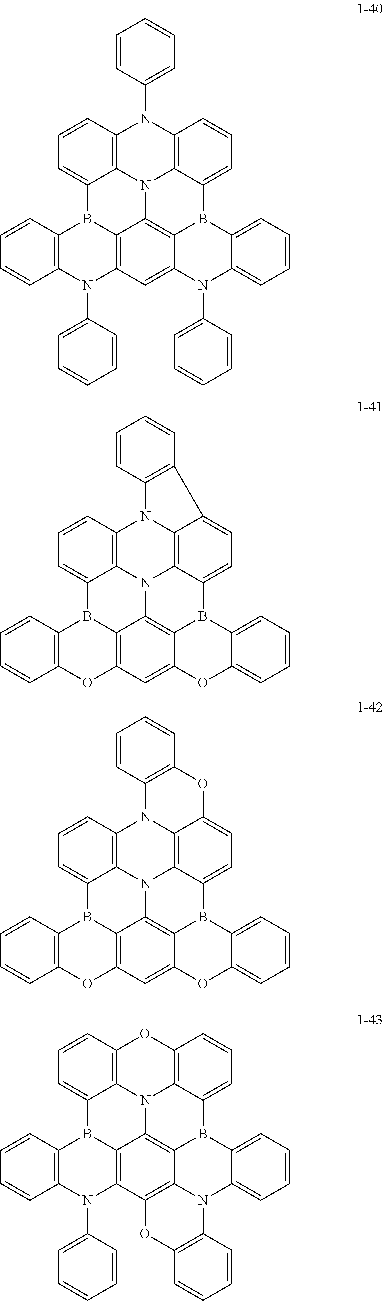

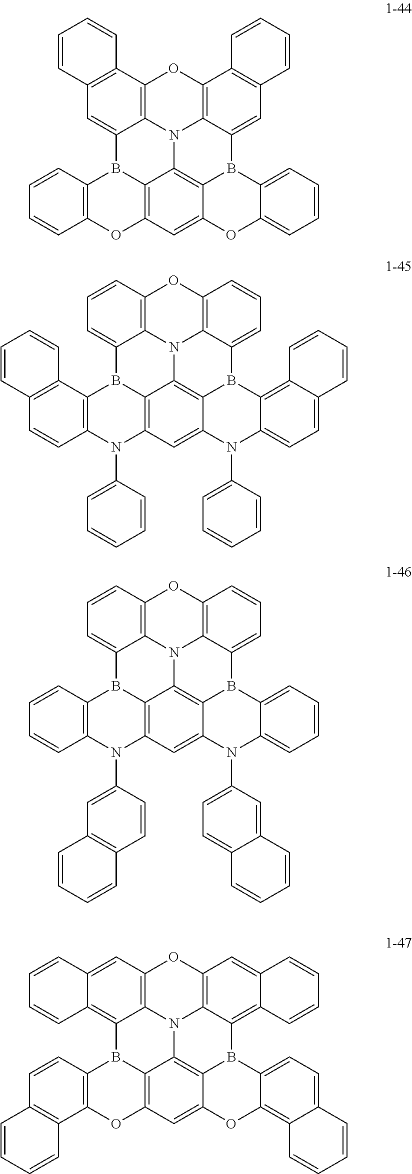

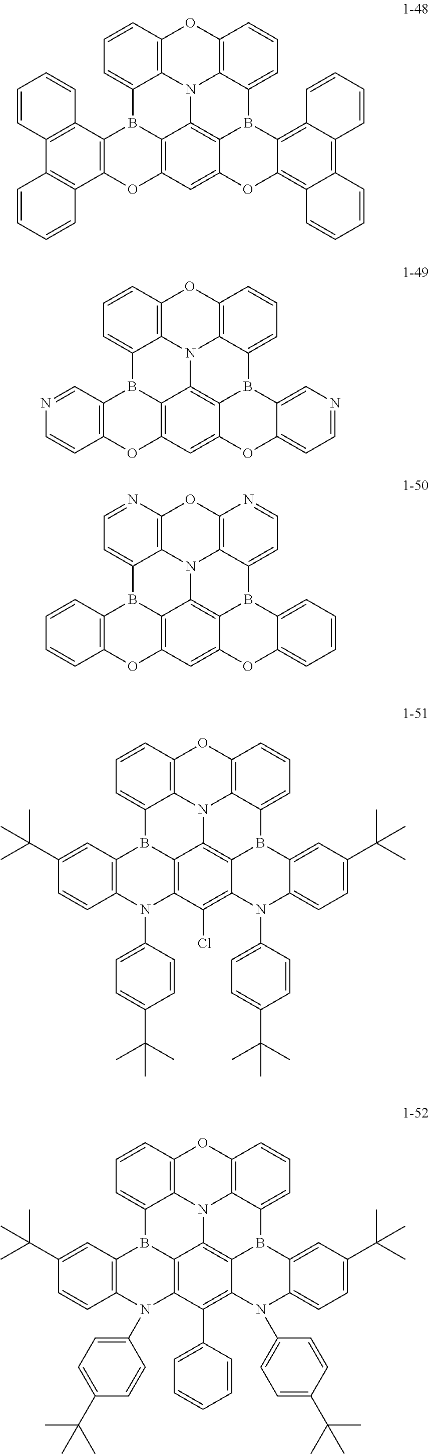

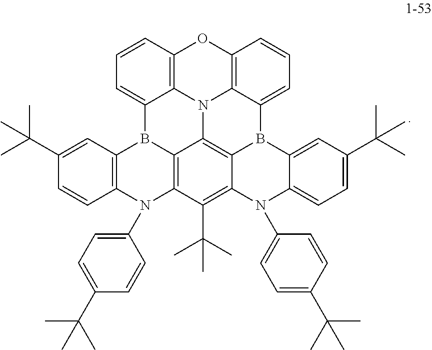 [SMILES: CC(C)(C)c1ccc(N2c3ccc(C(C)(C)C)cc3B3c4cccc5c4N4c6c(cccc6B6c7cc(C(C)(C)C)ccc7N(c7ccc(C(C)(C)C)cc7)c7c6c4c3c2c7C(C)(C)C)O5)cc1]

Among the above specific compounds, Compounds 1-1 to 1-29, for example, Compounds 1-6, 1-11, 1-12, 1-18, and 1-19, or for example, Compounds 1-12, 1-18, and 1-19, may be preferred. By having such a structure, the condensed cyclic compound may have a narrower blue emission spectrum and may exhibit higher color purity.

In an embodiment, the condensed cyclic compound represented by Formula 1 may be represented by Formula 3:

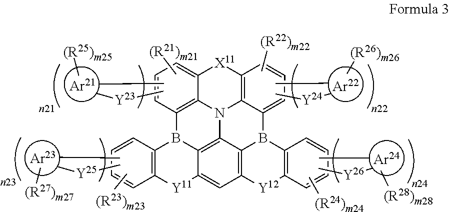

wherein, in Formula 3,

Ar²¹, Ar²², Ar²³, and Ar²⁴ may each independently be a group derived from an aromatic hydrocarbon ring having 6 to 18 ring-forming atoms or a group derived from a heteroaromatic ring having 5 to 18 ring-forming atoms.

The aromatic hydrocarbon ring of Ar²¹, Ar²², Ar²³, and Ar²⁴ may be a single ring or a condensed ring. The number of ring-forming atoms in the aromatic hydrocarbon ring may be 6 or more and 18 or less, for example, 6 or more and 14 or less, for example, 6 or more and 10 or less, or for example, about 6. Examples of the aromatic hydrocarbon ring having 6 to 18 ring-forming atoms may include, but are not particularly limited to, a benzene ring, a pentalene ring, an indene ring, a naphthalene ring, an anthracene ring, an azulene ring, a heptalene ring, an acenaphthalene ring, a phenalene ring, a fluorene ring, a phenanthrene ring, a biphenyl ring, a terphenyl ring, a triphenylene ring, a pyrene ring, a chrysene ring, a tetraphene ring, or the like. Among the above examples, a benzene ring may be preferred.

The heteroaromatic ring constituting each of Ar²¹, Ar²², Ar²³, and Ar²⁴ may be a single ring or a condensed ring. The number of ring-forming atoms in the heteroaromatic ring may be 5 or more and 18 or less, for example, 5 or more and 14 or less, for example, 5 or more and 10 or less, or for example, about 6.

The heteroaromatic ring may have one or more heteroatoms (e.g., nitrogen atoms (N), oxygen atoms (O), phosphorus atoms (P), sulfur atoms (S), silicon atoms (Si), or a combination thereof) as ring-forming atoms, and the remaining ring-forming atoms may be carbon atoms (C). Examples of the heteroaromatic ring having 5 to 18 ring-forming atoms may include, but are not particularly limited to, a pyridine ring, a pyrazine ring, a pyridazine ring, a pyrimidine ring, a triazine ring, a quinoline ring, an isoquinoline ring, a quinoxaline ring, a quinazoline ring, a naphthyridine ring, an acridine ring, a phenazine ring, a benzoquinoline ring, a benzoisoquinoline ring, a phenanthridine ring, a phenanthroline ring, a benzoquinone ring, a coumarin ring, an anthraquinone ring, a fluorenone ring, a furan ring, a thiophene ring, a benzofuran ring, a benzothiophene ring, a dibenzofuran ring, a dibenzothiophene ring, a pyrrole ring, an indole ring, a carbazole ring, an imidazole ring, a benzimidazole ring, a pyrazole ring, an indazole ring, an oxazole ring, an isoxazole ring, a benzoxazole ring, a benzoisoxide ring, a thiazole ring, an isothiazole ring, a benzothiazole ring, a benzoisothiazole ring, an imidazolinone ring, a benzimidazolinone ring, an imidazopyridine ring, an imidazopyrimidine ring, an imidazolephenanthridine ring, an azadibenzofuran ring, an azacarbazole ring, a diazadibenzofuran ring, a diazacarbazole ring, a diazadibenzothiophene ring, a xanthone ring, a thioxanthone ring, or the like.

According to an embodiment, a condensed cyclic compound represented by Formula 3,

X¹¹ may be the same as defined in Formula 1, and may be —O—, —S—, —NR^{X11}-(wherein R^{X11} is a phenyl group), or a single bond, for example, may be —O— or a single bond,

R^{X11} may be hydrogen, a substituted or unsubstituted alkyl group, a substituted or unsubstituted aryl group, a substituted or unsubstituted heteroaryl group, a substituted or unsubstituted alkylsilyl group, a substituted or unsubstituted arylsilyl group, a substituted or unsubstituted alkylamino group, a substituted or unsubstituted arylamino group, a substituted or unsubstituted alkenyl group, a substituted or unsubstituted alkynyl group, or a substituted or unsubstituted arylalkyl group, and Y¹¹, Y¹², Y²³, Y²⁴, Y²⁵, and Y²⁶ are each independently —O—, —S—, —Se—, —Te—, —NR^{Y11}—, —CR^{Y12}R^{Y13}— or —SiR^{Y14}R^{Y15}.

In an embodiment, Y¹¹, Y¹², Y²³, Y²⁴, Y²⁵, and Y²⁶ may each independently be —O—, —S—, or —NR^{Y21}— (wherein R^{Y21} is a phenyl group). For example, Y¹¹ and Y¹² may each independently be —O—, —S—, or —NR^{Y21}— (wherein R^{Y21} is a phenyl group), and Y²³, Y²⁴, Y²⁵, and Y²⁶ may each independently be —O—.

According to an embodiment, a condensed cyclic compound represented by Formula 3,

R^{Y11}, R^{Y12}, R^{Y13}, R^{Y14}, and R^{Y15} may each independently be hydrogen, a substituted or unsubstituted alkyl group, a substituted or unsubstituted aryl group, a substituted or unsubstituted heteroaryl group, a substituted or unsubstituted alkylsilyl group, a substituted or unsubstituted arylsilyl group, a substituted or unsubstituted alkylamino group, a substituted or unsubstituted arylamino group, a substituted or unsubstituted alkenyl group, a substituted or unsubstituted alkynyl group, or a substituted or unsubstituted arylalkyl group.

According to an embodiment, a condensed cyclic compound represented by Formula 3,

R²¹, R²², R²³, R²⁴, R²⁵, R²⁶, R²⁷, and R²⁸ may each independently be hydrogen, deuterium, a halogen, a cyano group, a substituted or unsubstituted alkyl group, a substituted or unsubstituted aryl group, a substituted or unsubstituted heteroaryl group, a substituted or unsubstituted alkylsilyl group, a substituted or unsubstituted arylsilyl group, a substituted or unsubstituted alkylamino group, a substituted or unsubstituted arylamino group, a substituted or unsubstituted alkenyl group, a substituted or unsubstituted alkynyl group, or a substituted or unsubstituted arylalkyl group,

R²¹, R²², R²³, R²⁴, R²⁵, R²⁶, R²⁷, and R²⁸ may each independently be a substituted or unsubstituted alkyl group, a substituted or unsubstituted aryl group, a substituted or unsubstituted heteroaryl group, or a substituted or unsubstituted arylamino group, for example, may each independently be a tert-butyl group, a phenyl group, a carbazole group, or a diphenylamino group, or for example, may each independently be a tert-butyl group or a phenyl group.

Examples of the halogen atom may include a fluorine (F), a chlorine (Cl), a bromine (Br), an iodine (I), and the like.

Examples of the substituted or unsubstituted alkyl group, the substituted or unsubstituted aryl group, the substituted or unsubstituted heteroaryl group, the substituted or unsubstituted alkylsilyl group, the substituted or unsubstituted arylsilyl group, the substituted or unsubstituted alkylamino group, the substituted or unsubstituted arylamino group, the substituted or unsubstituted alkenyl group, the substituted or unsubstituted alkynyl group, or the substituted or unsubstituted arylalkyl group may be the same as described in connection with R^{X11}.

According to an embodiment, a condensed cyclic compound represented by Formula 3,

n21, n22, n23, and n24 may each independently be 0 or 1, and the total sum of n21, n22, n23, and n24 may be 1 or more and 4 or less. In this regard, n21, n22, n23, and n24 may be identical to or different from each other. In an embodiment, n21 and n22 may be identical to each other, and n23 and n24 may be identical to each other. In an embodiment, n21 and n22 may each be 1, and n23 and n24 may each be 0. In one or more embodiments, n21 and n22 may each be 0, and n23 and n24 may each be 1.

According to an embodiment, a condensed cyclic compound represented by Formula 3, m21, m22, m23, and m24 may respectively indicate the number of substituents (R²¹, R²², R²³, and R²⁴) in a benzene ring, and may each independently be 0, 1, or 2. In this regard, m21, m22, m23, and m24 may be identical to or different from each other. In an embodiment, m21 and m22 may be identical to each other, and m23 and m24 may be identical to each other.

According to an embodiment, a condensed cyclic compound represented by Formula 3, m25, m26, m27, and m28 may respectively indicate the number of substituents (R²⁵, R²⁶, R²⁷, and R²⁸) present in Ar²¹, Ar²², Ar²³, and Ar²⁴, and may each independently be 0, 1, 2, 3, or 4. In this regard, m25, m26, m27, and m284 may be identical to or different from each other, for example, may be identical to each other. In an embodiment, m25, m26, m27, and m28 may each independently be 0 or 1.

In an embodiment, the condensed cyclic compound represented by Formula 1 may be represented by Formula 4:

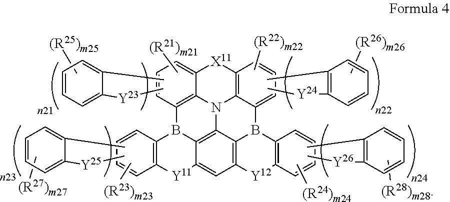

The condensed cyclic compound represented by Formula 4 may be a condensed cyclic compound in which Ar²¹, Ar²², Ar²³, and Ar²⁴ in Formula 3 are each a benzene ring.

According to an embodiment, a condensed cyclic compound represented by Formula 4,

X¹¹, Y¹¹, Y¹², Y²³, Y²⁴, Y²⁵, Y²⁶, R²¹, R²², R²³, R²⁴, R²⁵, R²⁶, R²⁷, R²⁸ n21 n22 n23 n24, m21, m22, m23, m24, m25, m25 m27, and m28 may be the same as defined in Formula 3.

In an embodiment, a specific compound of the condensed cyclic compound may be represented by one of Formulae 2-1 to 2-172:

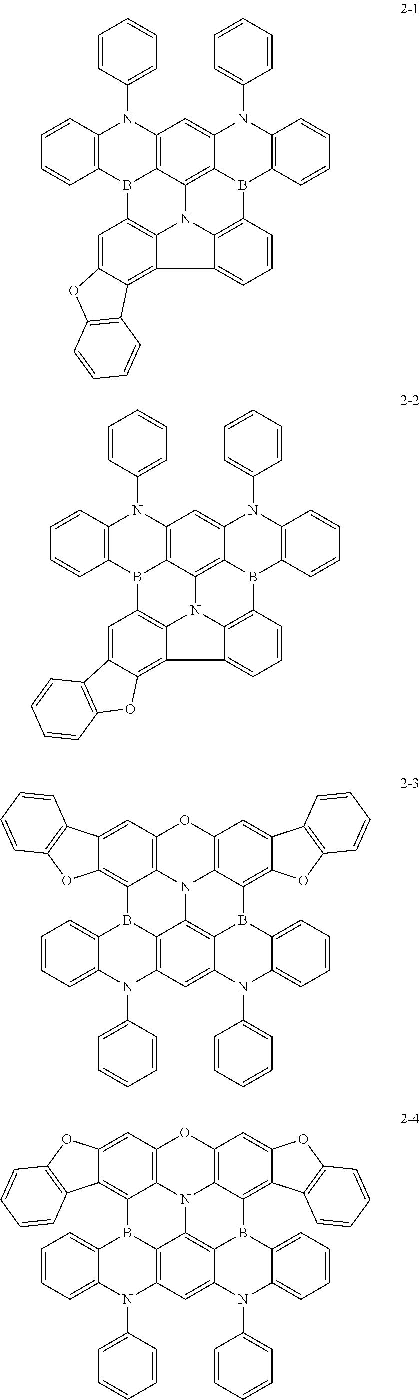

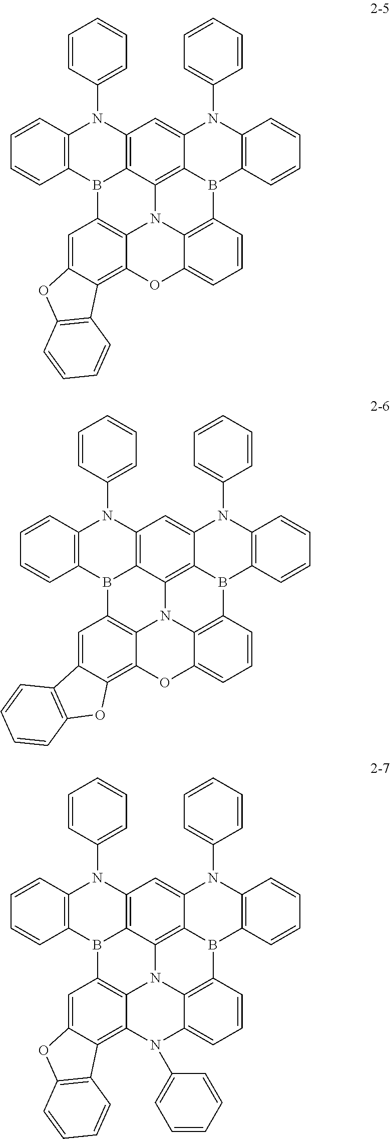

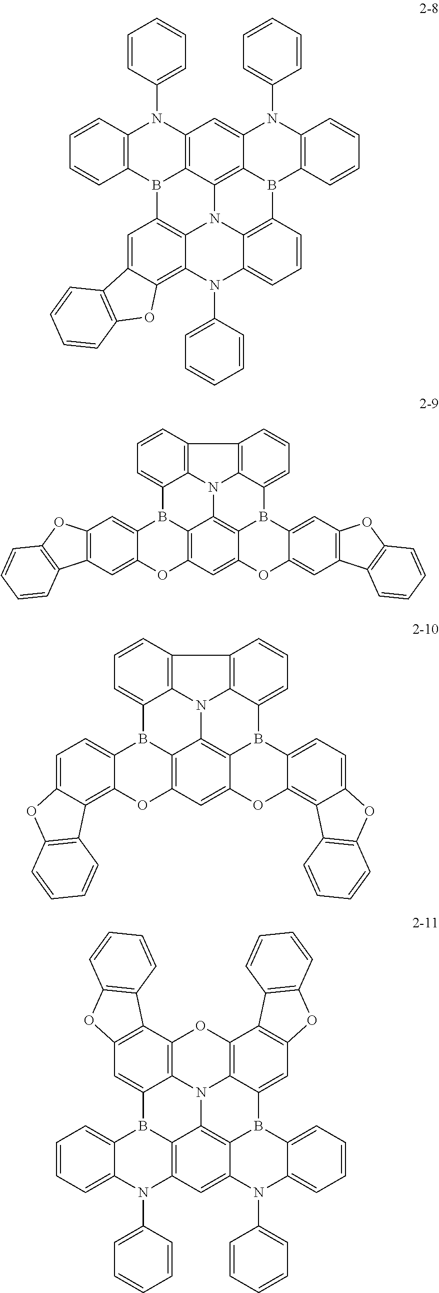

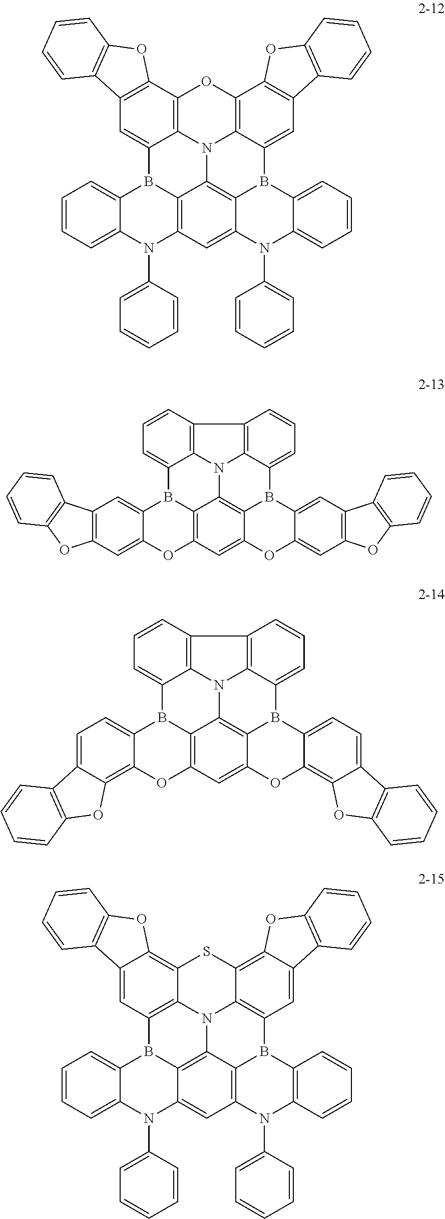 [SMILES: c1ccc(N2c3ccccc3B3c4cc5c(oc6ccccc65)c5c4N4c6c3c2cc2c6B(c3ccccc3N2c2ccccc2)c2cc3c(oc6ccccc63)c(c24)O5)cc1 ; c1ccc2c(c1)oc1cc3c(cc12)B1c2c(cc4c5c2-n2c6c1cccc6c1cccc(c12)B5c1cc2c(cc1O4)oc1ccccc12)O3 ; c1ccc2c(c1)oc1c3c(ccc12)B1c2c(cc4c5c2-n2c6c1cccc6c1cccc(c12)B5c1ccc2c(oc5ccccc52)c1O4)O3 ; c1ccc(N2c3ccccc3B3c4cc5c(oc6ccccc65)c5c4N4c6c3c2cc2c6B(c3ccccc3N2c2ccccc2)c2cc3c(oc6ccccc63)c(c24)S5)cc1]

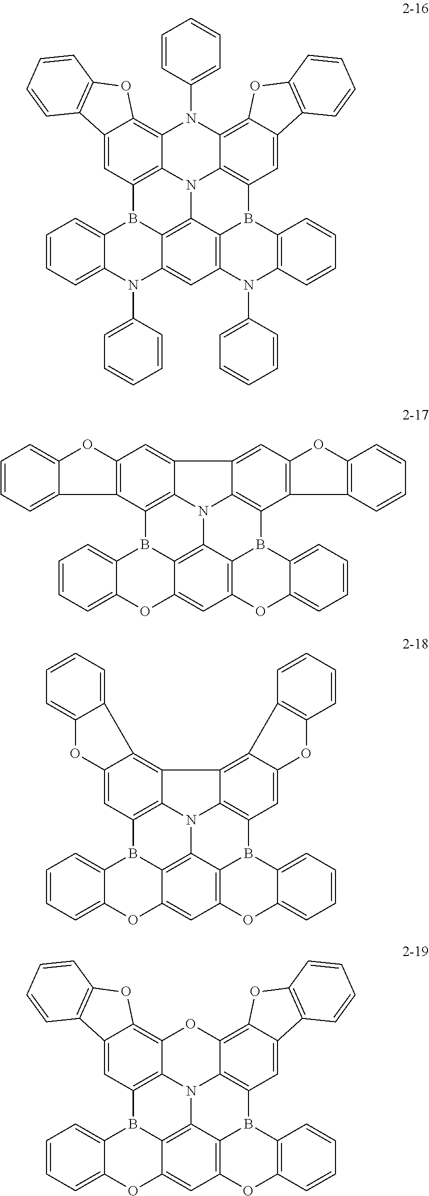

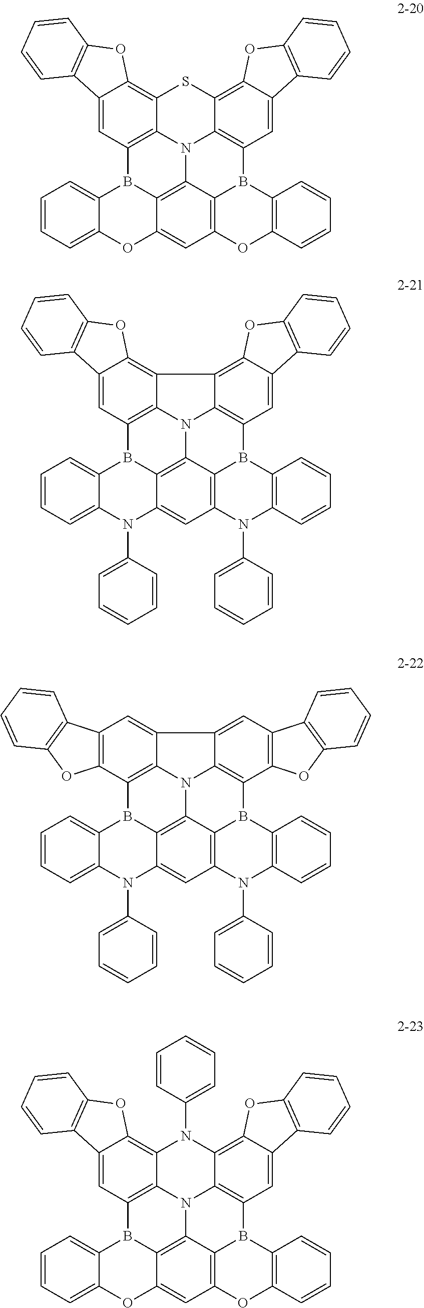

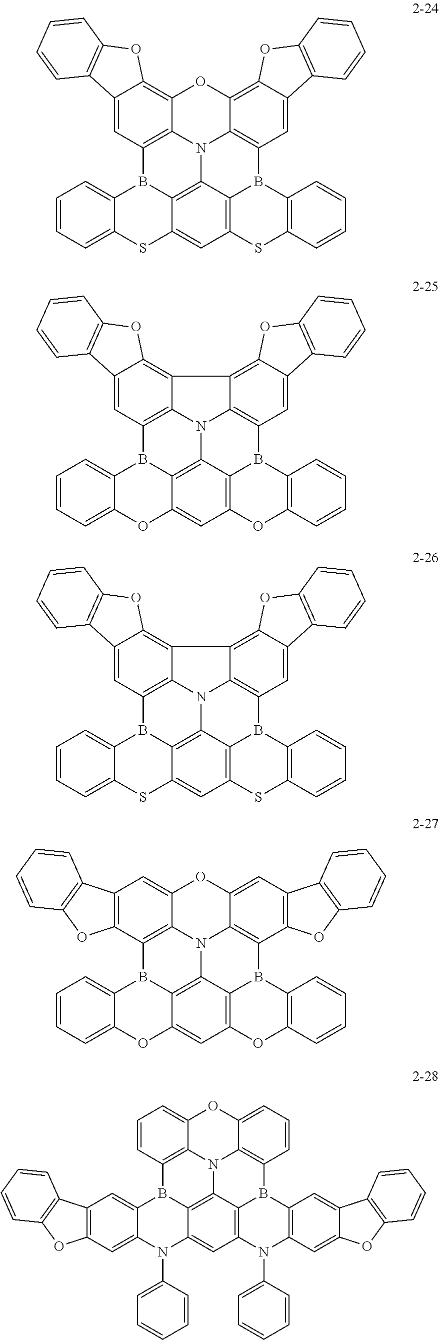

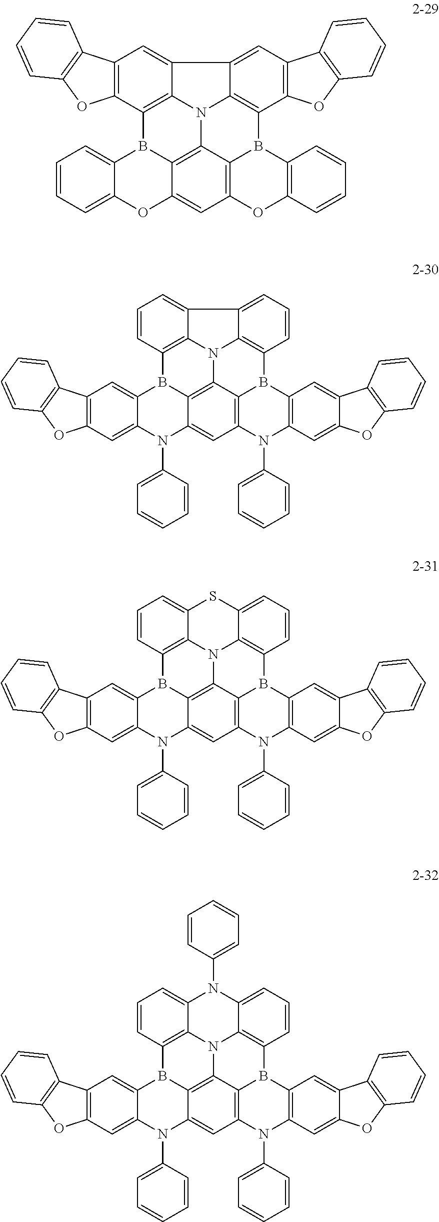 [SMILES: c1ccc2c(c1)Oc1cc3c4c5c1B2c1c2oc6ccccc6c2cc2c6cc7c(oc8ccccc87)c(c6n-5c12)B4c1ccccc1O3 ; c1ccc(N2c3cc4oc5ccccc5c4cc3B3c4c2cc2c5c4-n4c6c3cccc6c3cccc(c34)B5c3cc4c(cc3N2c2ccccc2)oc2ccccc24)cc1 ; c1ccc(N2c3cc4oc5ccccc5c4cc3B3c4cccc5c4N4c6c(cccc6B6c7cc8c(cc7N(c7ccccc7)c7cc2c3c4c76)oc2ccccc28)S5)cc1 ; c1ccc(N2c3cc4oc5ccccc5c4cc3B3c4cccc5c4N4c6c(cccc6N5c5ccccc5)B5c6cc7c(cc6N(c6ccccc6)c6cc2c3c4c65)oc2ccccc27)cc1]

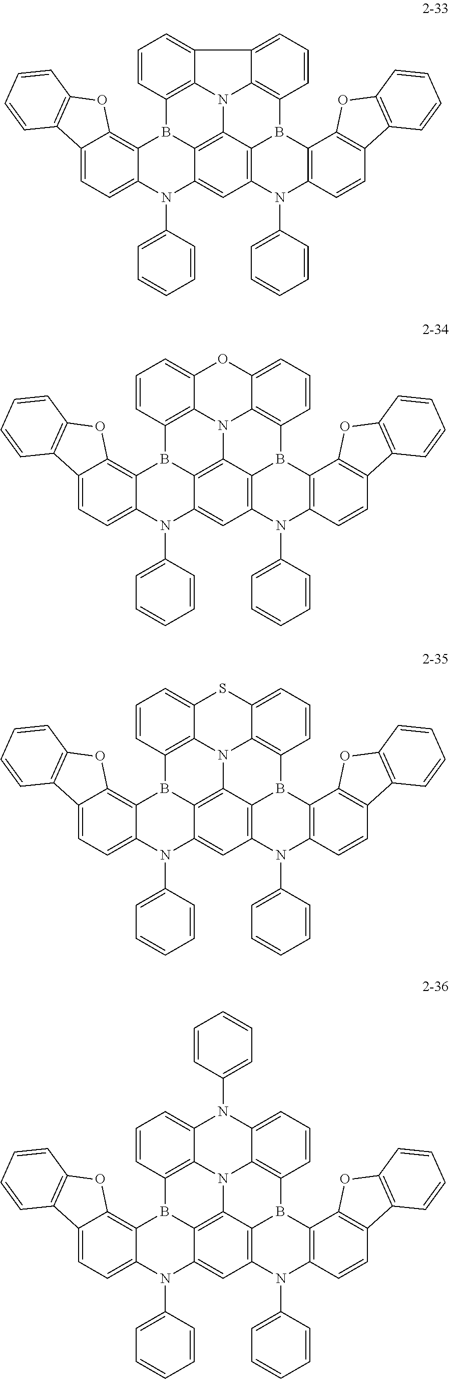 [SMILES: c1ccc(N2c3cc4c5c6c3B(c3c2ccc2c3oc3ccccc32)c2cccc3c7cccc(c7n-6c23)B5c2c(ccc3c2oc2ccccc23)N4c2ccccc2)cc1 ; c1ccc(N2c3cc4c5c6c3B(c3cccc7c3N6c3c(cccc3B5c3c(ccc5c3oc3ccccc35)N4c3ccccc3)O7)c3c2ccc2c3oc3ccccc32)cc1 ; c1ccc(N2c3cc4c5c6c3B(c3cccc7c3N6c3c(cccc3B5c3c(ccc5c3oc3ccccc35)N4c3ccccc3)S7)c3c2ccc2c3oc3ccccc32)cc1 ; c1ccc(N2c3cccc4c3N3c5c(cccc52)B2c5c(cc6c(c53)B4c3c(ccc4c3oc3ccccc34)N6c3ccccc3)N(c3ccccc3)c3ccc4c(oc5ccccc54)c32)cc1]

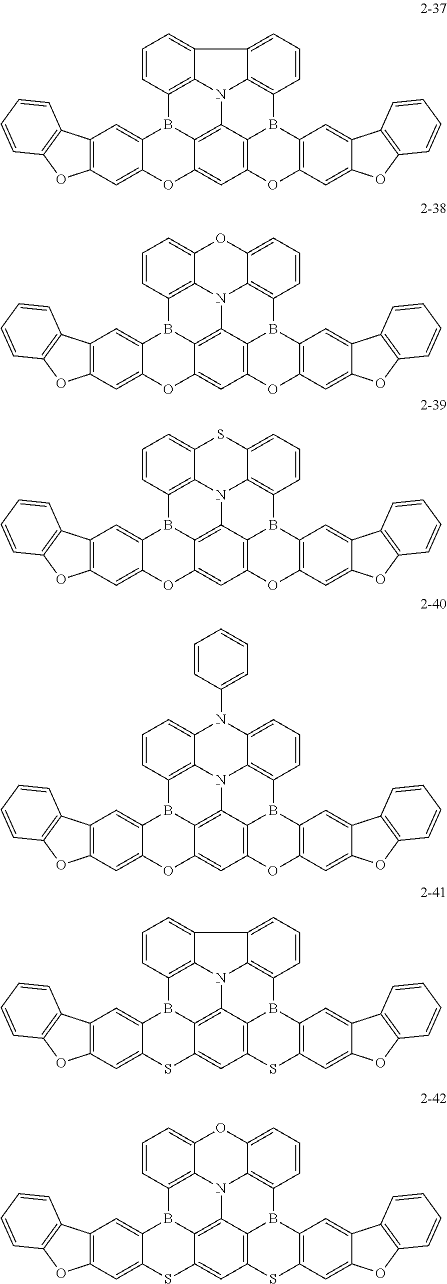

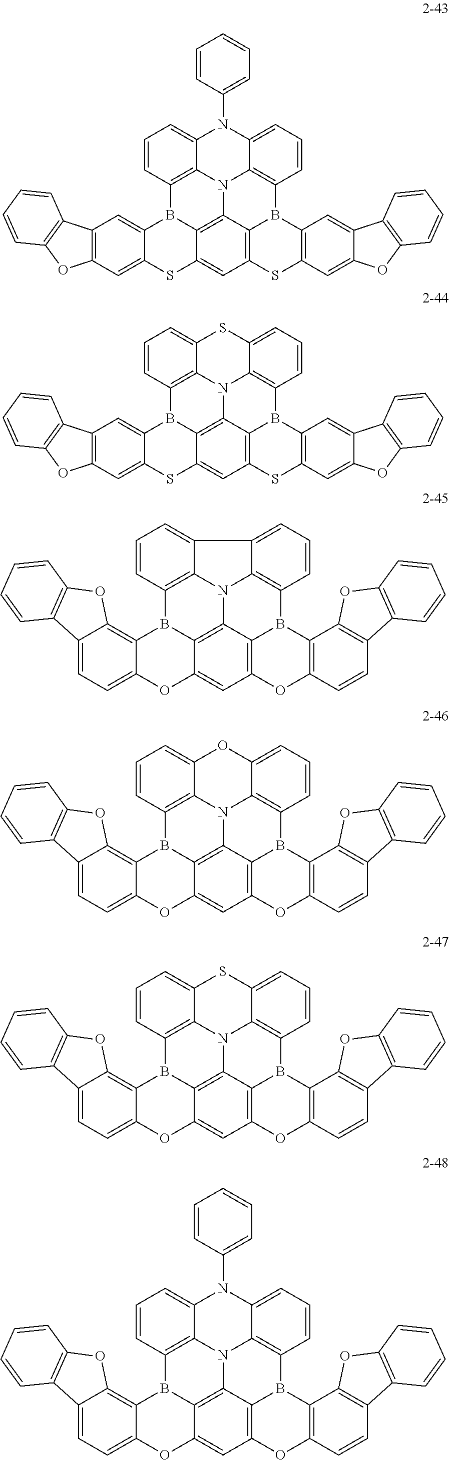

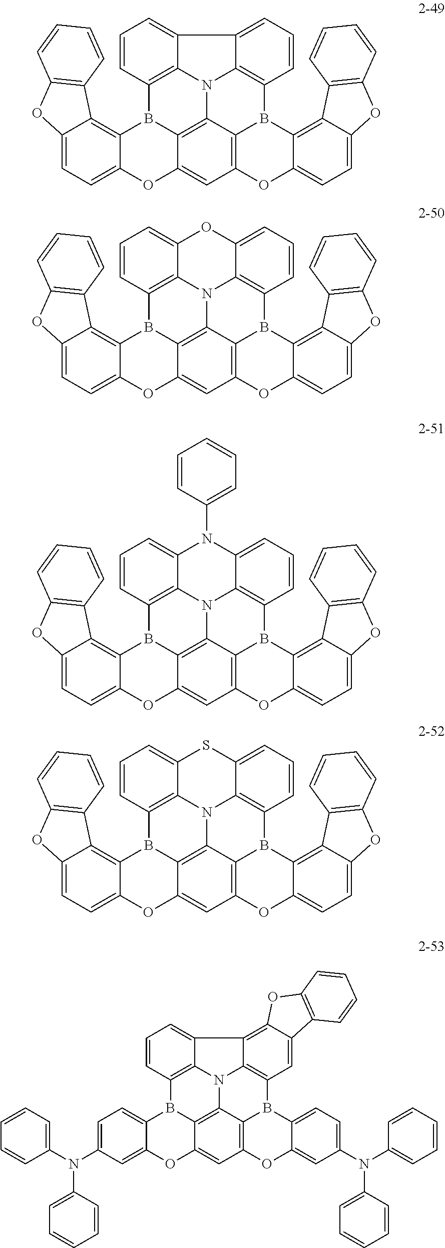

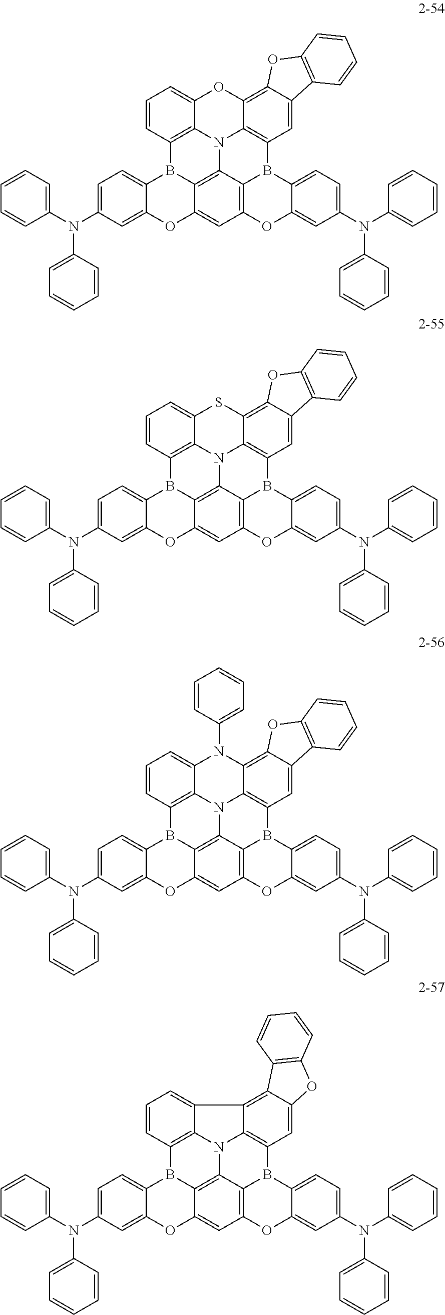 [SMILES: c1ccc(N(c2ccccc2)c2ccc3c(c2)Oc2cc4c5c6c2B3c2cccc3c2N6c2c(cc6c(oc7ccccc76)c2O3)B5c2ccc(N(c3ccccc3)c3ccccc3)cc2O4)cc1 ; c1ccc(N(c2ccccc2)c2ccc3c(c2)Oc2cc4c5c6c2B3c2cccc3c2N6c2c(cc6c(oc7ccccc76)c2S3)B5c2ccc(N(c3ccccc3)c3ccccc3)cc2O4)cc1 ; c1ccc(N(c2ccccc2)c2ccc3c(c2)Oc2cc4c5c6c2B3c2cccc3c2N6c2c(cc6c(oc7ccccc76)c2N3c2ccccc2)B5c2ccc(N(c3ccccc3)c3ccccc3)cc2O4)cc1 ; c1ccc(N(c2ccccc2)c2ccc3c(c2)Oc2cc4c5c6c2B3c2cccc3c7c8c(cc(c7n-6c23)B5c2ccc(N(c3ccccc3)c3ccccc3)cc2O4)oc2ccccc28)cc1]

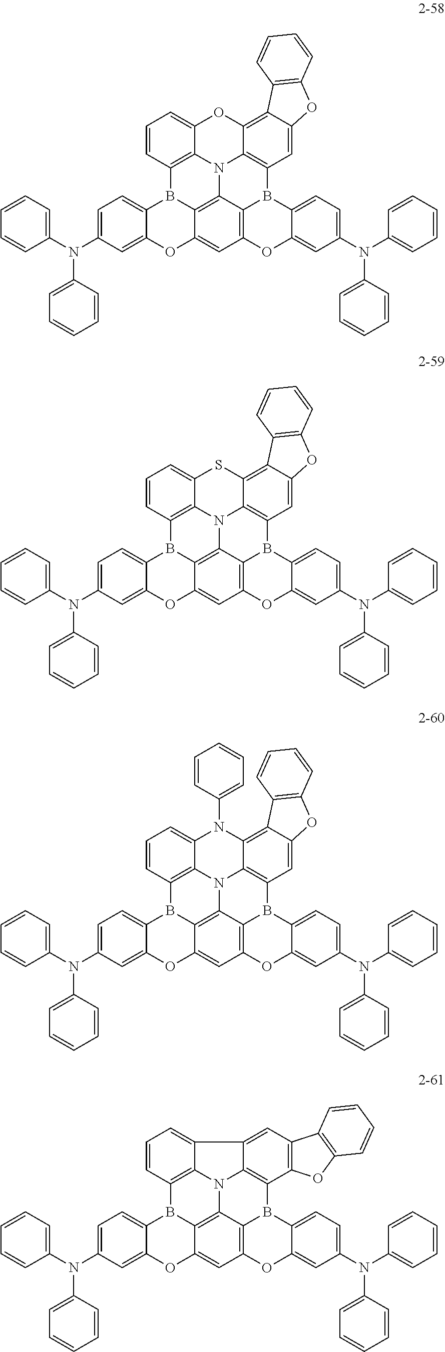 [SMILES: c1ccc(N(c2ccccc2)c2ccc3c(c2)Oc2cc4c5c6c2B3c2cccc3c2N6c2c(cc6oc7ccccc7c6c2O3)B5c2ccc(N(c3ccccc3)c3ccccc3)cc2O4)cc1 ; c1ccc(N(c2ccccc2)c2ccc3c(c2)Oc2cc4c5c6c2B3c2cccc3c2N6c2c(cc6oc7ccccc7c6c2S3)B5c2ccc(N(c3ccccc3)c3ccccc3)cc2O4)cc1 ; c1ccc(N(c2ccccc2)c2ccc3c(c2)Oc2cc4c5c6c2B3c2cccc3c2N6c2c(cc6oc7ccccc7c6c2N3c2ccccc2)B5c2ccc(N(c3ccccc3)c3ccccc3)cc2O4)cc1 ; c1ccc(N(c2ccccc2)c2ccc3c(c2)Oc2cc4c5c6c2B3c2cccc3c7cc8c(oc9ccccc98)c(c7n-6c23)B5c2ccc(N(c3ccccc3)c3ccccc3)cc2O4)cc1]

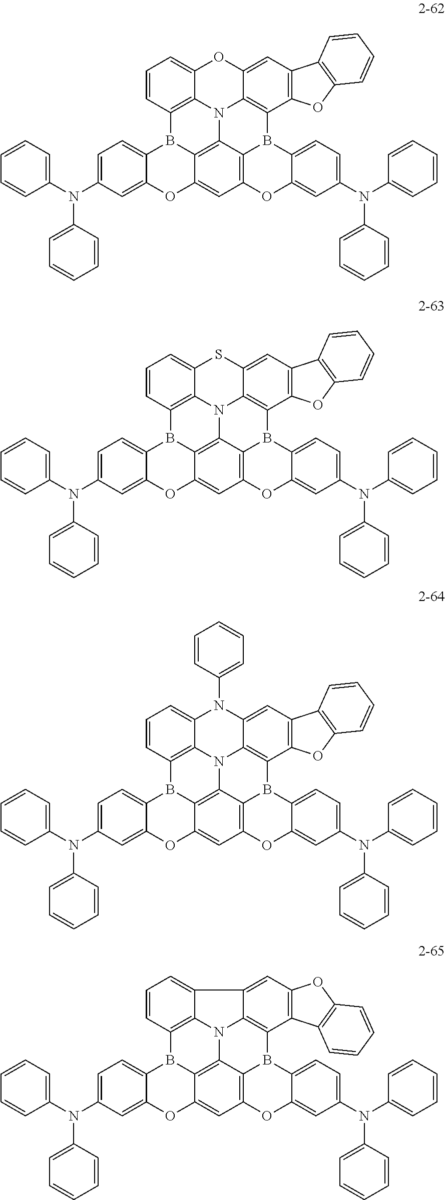 [SMILES: c1ccc(N(c2ccccc2)c2ccc3c(c2)Oc2cc4c5c6c2B3c2cccc3c2N6c2c(cc6c(oc7ccccc76)c2B5c2ccc(N(c5ccccc5)c5ccccc5)cc2O4)O3)cc1 ; c1ccc(N(c2ccccc2)c2ccc3c(c2)Oc2cc4c5c6c2B3c2cccc3c2N6c2c(cc6c(oc7ccccc76)c2B5c2ccc(N(c5ccccc5)c5ccccc5)cc2O4)S3)cc1 ; c1ccc(N(c2ccccc2)c2ccc3c(c2)Oc2cc4c5c6c2B3c2cccc3c2N6c2c(cc6c(oc7ccccc76)c2B5c2ccc(N(c5ccccc5)c5ccccc5)cc2O4)N3c2ccccc2)cc1 ; c1ccc(N(c2ccccc2)c2ccc3c(c2)Oc2cc4c5c6c2B3c2cccc3c7cc8oc9ccccc9c8c(c7n-6c23)B5c2ccc(N(c3ccccc3)c3ccccc3)cc2O4)cc1]

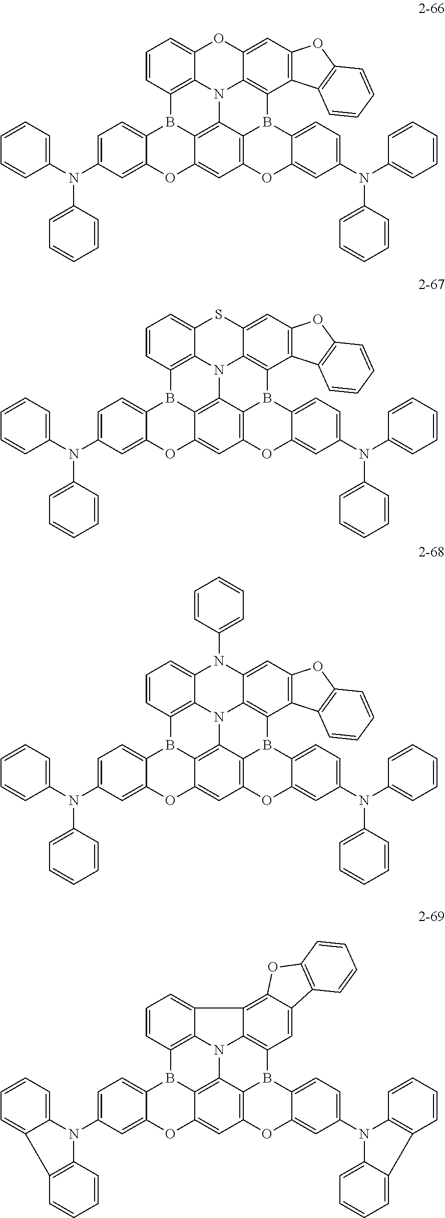 [SMILES: c1ccc(N(c2ccccc2)c2ccc3c(c2)Oc2cc4c5c6c2B3c2cccc3c2N6c2c(cc6oc7ccccc7c6c2B5c2ccc(N(c5ccccc5)c5ccccc5)cc2O4)O3)cc1 ; c1ccc(N(c2ccccc2)c2ccc3c(c2)Oc2cc4c5c6c2B3c2cccc3c2N6c2c(cc6oc7ccccc7c6c2B5c2ccc(N(c5ccccc5)c5ccccc5)cc2O4)S3)cc1 ; c1ccc(N(c2ccccc2)c2ccc3c(c2)Oc2cc4c5c6c2B3c2cccc3c2N6c2c(cc6oc7ccccc7c6c2B5c2ccc(N(c5ccccc5)c5ccccc5)cc2O4)N3c2ccccc2)cc1 ; c1ccc2c(c1)oc1c2cc2c3c1c1cccc4c1n3-c1c3c(cc5c1B2c1ccc(-n2c6ccccc6c6ccccc62)cc1O5)Oc1cc(-n2c5ccccc5c5ccccc52)ccc1B34]

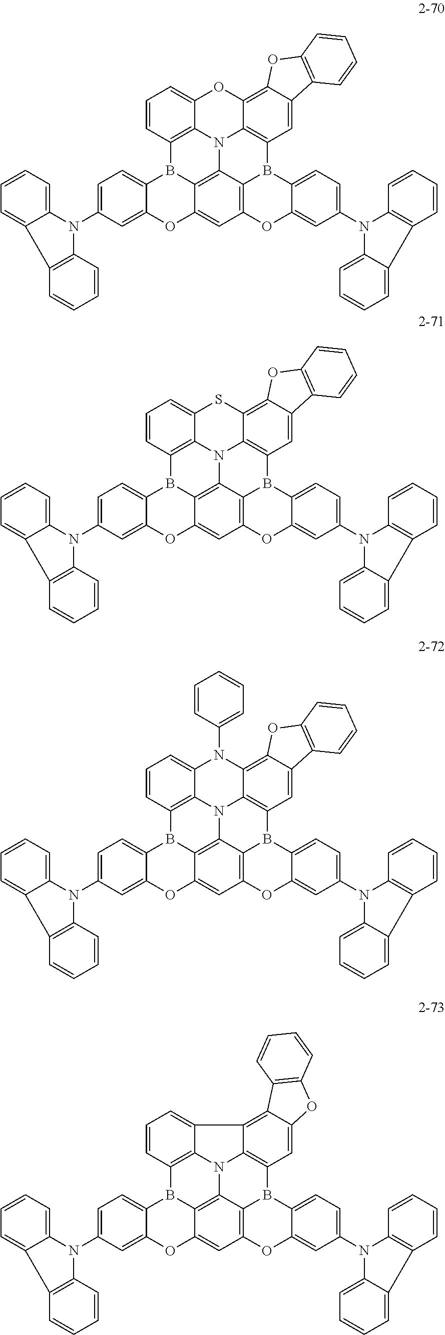 [SMILES: c1cc2c3c(c1)B1c4ccc(-n5c6ccccc6c6ccccc65)cc4Oc4cc5c6c(c41)N3c1c(cc3c(oc4ccccc43)c1O2)B6c1ccc(-n2c3ccccc3c3ccccc32)cc1O5 ; c1cc2c3c(c1)B1c4ccc(-n5c6ccccc6c6ccccc65)cc4Oc4cc5c6c(c41)N3c1c(cc3c(oc4ccccc43)c1S2)B6c1ccc(-n2c3ccccc3c3ccccc32)cc1O5 ; c1ccc(N2c3cccc4c3N3c5c6c(cc7c5B(c5ccc(-n8c9ccccc9c9ccccc98)cc5O7)c5cc7c(oc8ccccc87)c2c53)Oc2cc(-n3c5ccccc5c5ccccc53)ccc2B46)cc1 ; c1ccc2c(c1)oc1cc3c4c(c5cccc6c5n4-c4c5c(cc7c4B3c3ccc(-n4c8ccccc8c8ccccc84)cc3O7)Oc3cc(-n4c7ccccc7c7ccccc74)ccc3B56)c12]

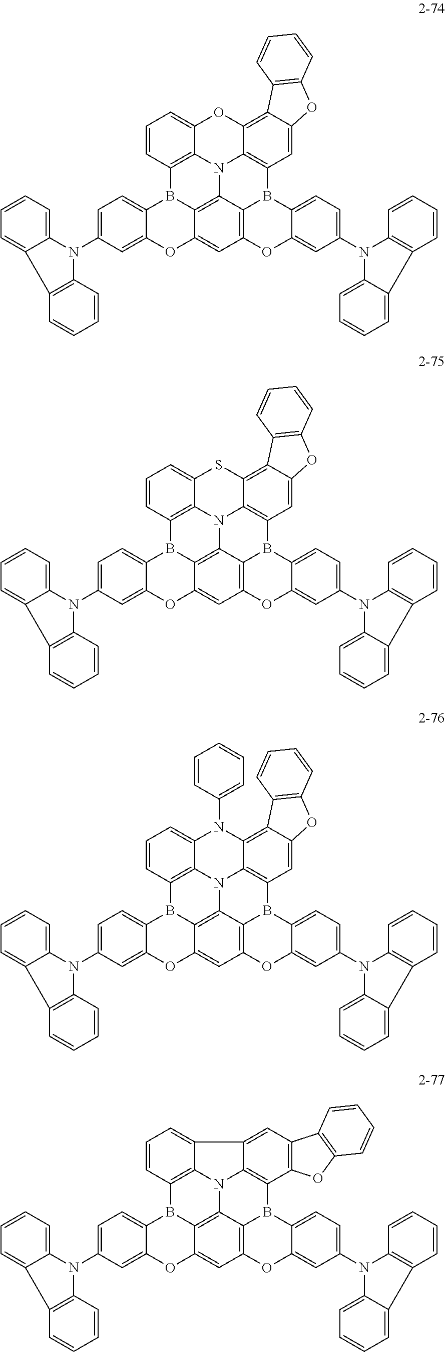 [SMILES: c1cc2c3c(c1)B1c4ccc(-n5c6ccccc6c6ccccc65)cc4Oc4cc5c6c(c41)N3c1c(cc3oc4ccccc4c3c1O2)B6c1ccc(-n2c3ccccc3c3ccccc32)cc1O5 ; c1cc2c3c(c1)B1c4ccc(-n5c6ccccc6c6ccccc65)cc4Oc4cc5c6c(c41)N3c1c(cc3oc4ccccc4c3c1S2)B6c1ccc(-n2c3ccccc3c3ccccc32)cc1O5 ; c1ccc(N2c3cccc4c3N3c5c6c(cc7c5B(c5ccc(-n8c9ccccc9c9ccccc98)cc5O7)c5cc7oc8ccccc8c7c2c53)Oc2cc(-n3c5ccccc5c5ccccc53)ccc2B46)cc1 ; c1ccc2c(c1)oc1c3c4c(cc12)c1cccc2c1n4-c1c4c(cc5c1B3c1ccc(-n3c6ccccc6c6ccccc63)cc1O5)Oc1cc(-n3c5ccccc5c5ccccc53)ccc1B42]

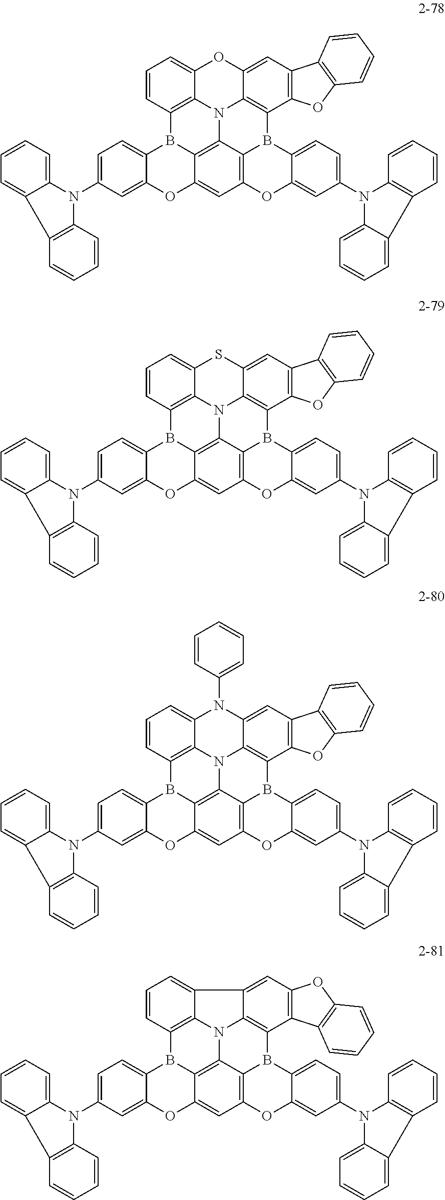 [SMILES: c1cc2c3c(c1)B1c4ccc(-n5c6ccccc6c6ccccc65)cc4Oc4cc5c6c(c41)N3c1c(cc3c(oc4ccccc43)c1B6c1ccc(-n3c4ccccc4c4ccccc43)cc1O5)O2 ; c1cc2c3c(c1)B1c4ccc(-n5c6ccccc6c6ccccc65)cc4Oc4cc5c6c(c41)N3c1c(cc3c(oc4ccccc43)c1B6c1ccc(-n3c4ccccc4c4ccccc43)cc1O5)S2 ; c1ccc(N2c3cccc4c3N3c5c6c(cc7c5B(c5ccc(-n8c9ccccc9c9ccccc98)cc5O7)c5c3c2cc2c5oc3ccccc32)Oc2cc(-n3c5ccccc5c5ccccc53)ccc2B46)cc1 ; c1ccc2c(c1)oc1cc3c4cccc5c4n4c3c(c12)B1c2ccc(-n3c6ccccc6c6ccccc63)cc2Oc2cc3c(c-4c21)B5c1ccc(-n2c4ccccc4c4ccccc42)cc1O3]

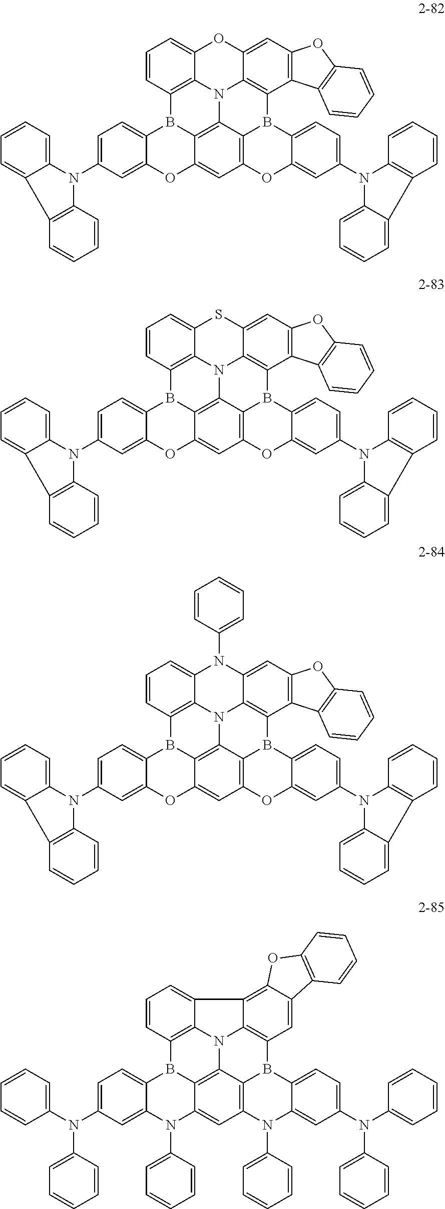 [SMILES: c1cc2c3c(c1)B1c4ccc(-n5c6ccccc6c6ccccc65)cc4Oc4cc5c6c(c41)N3c1c(cc3oc4ccccc4c3c1B6c1ccc(-n3c4ccccc4c4ccccc43)cc1O5)O2 ; c1cc2c3c(c1)B1c4ccc(-n5c6ccccc6c6ccccc65)cc4Oc4cc5c6c(c41)N3c1c(cc3oc4ccccc4c3c1B6c1ccc(-n3c4ccccc4c4ccccc43)cc1O5)S2 ; c1ccc(N2c3cccc4c3N3c5c6c(cc7c5B(c5ccc(-n8c9ccccc9c9ccccc98)cc5O7)c5c3c2cc2oc3ccccc3c52)Oc2cc(-n3c5ccccc5c5ccccc53)ccc2B46)cc1 ; c1ccc(N(c2ccccc2)c2ccc3c(c2)N(c2ccccc2)c2cc4c5c6c2B3c2cccc3c7c8oc9ccccc9c8cc(c7n-6c23)B5c2ccc(N(c3ccccc3)c3ccccc3)cc2N4c2ccccc2)cc1]

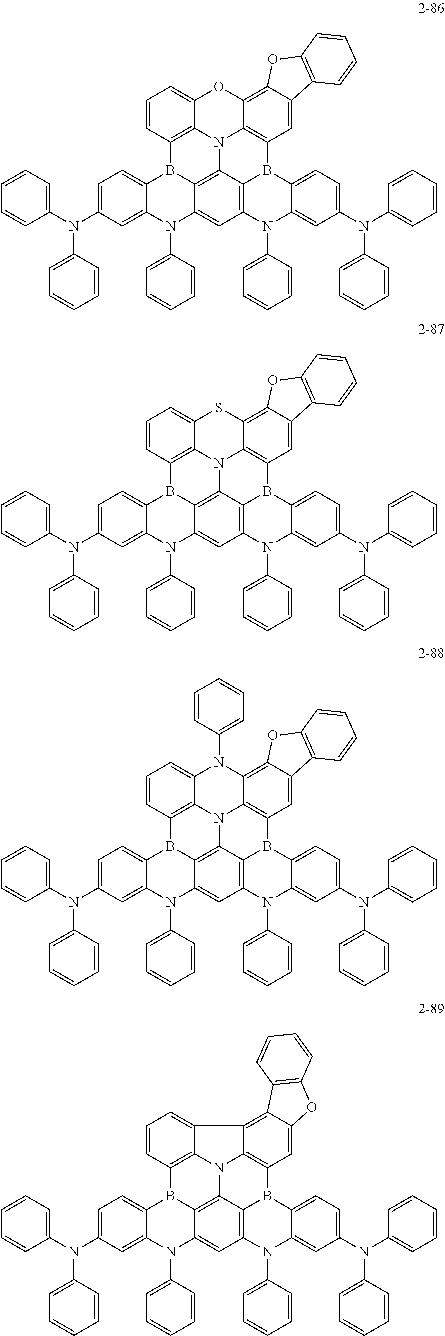

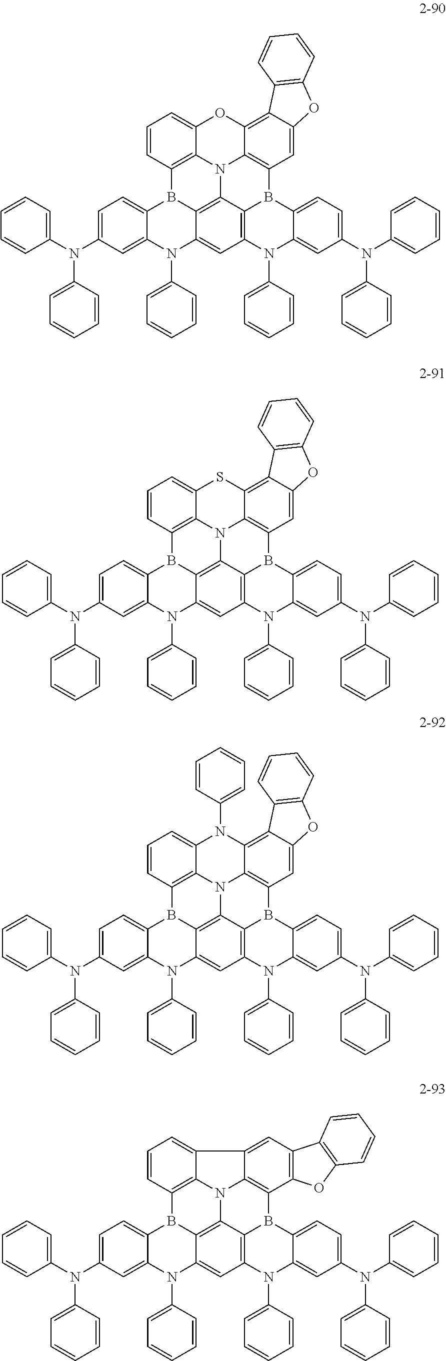

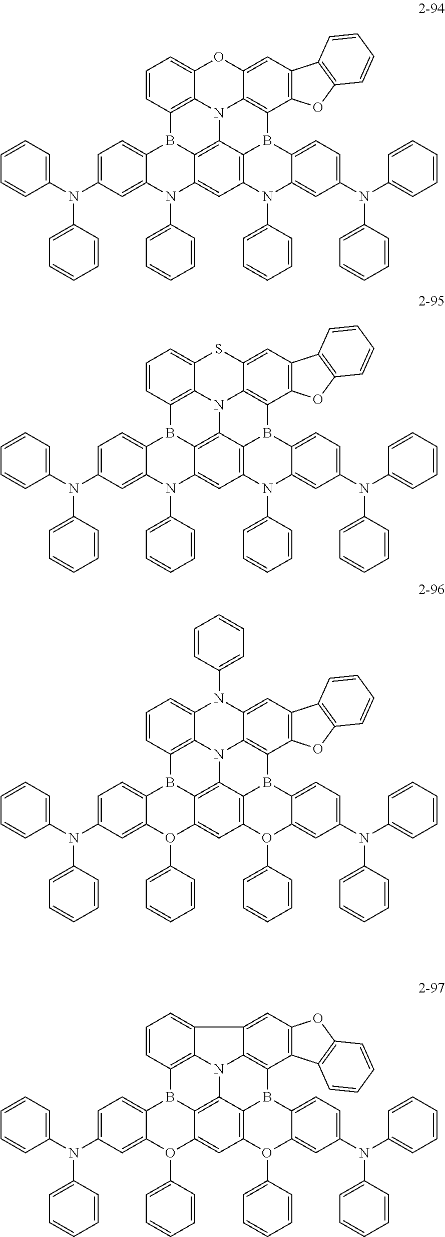

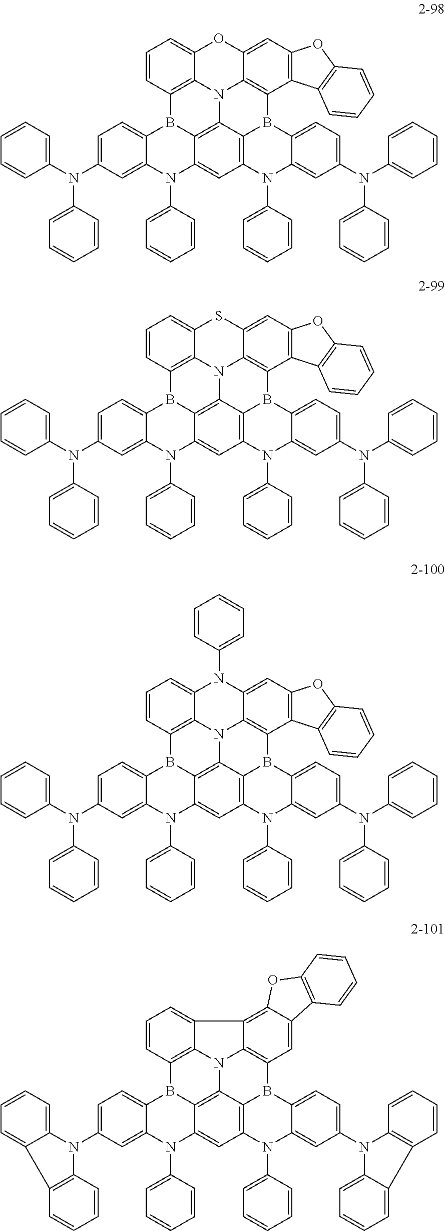

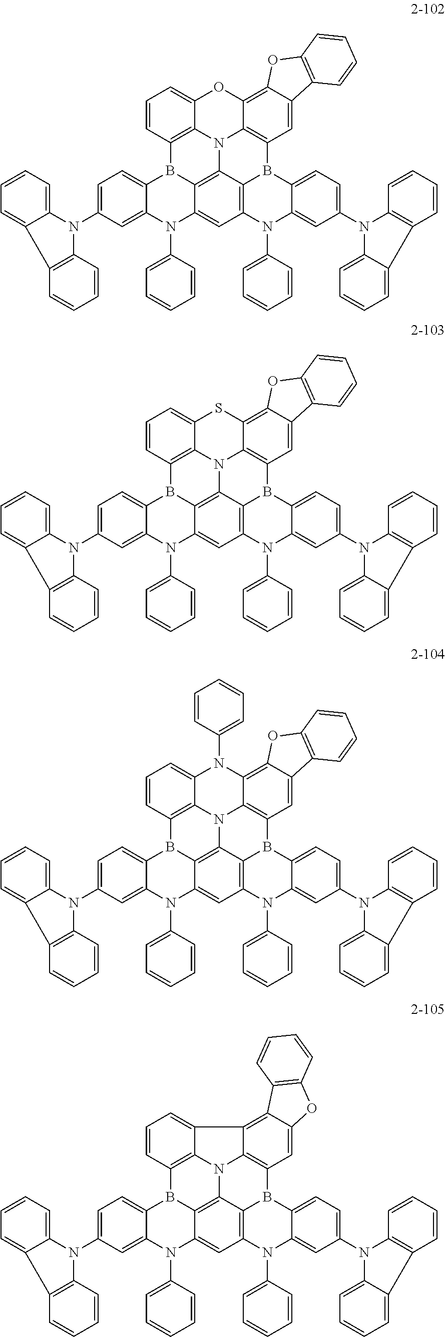

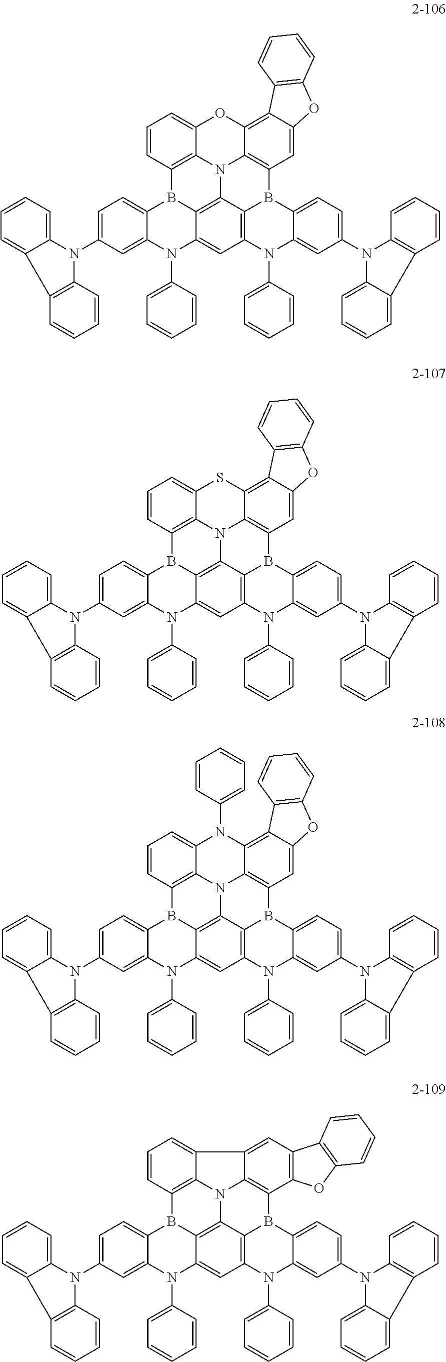

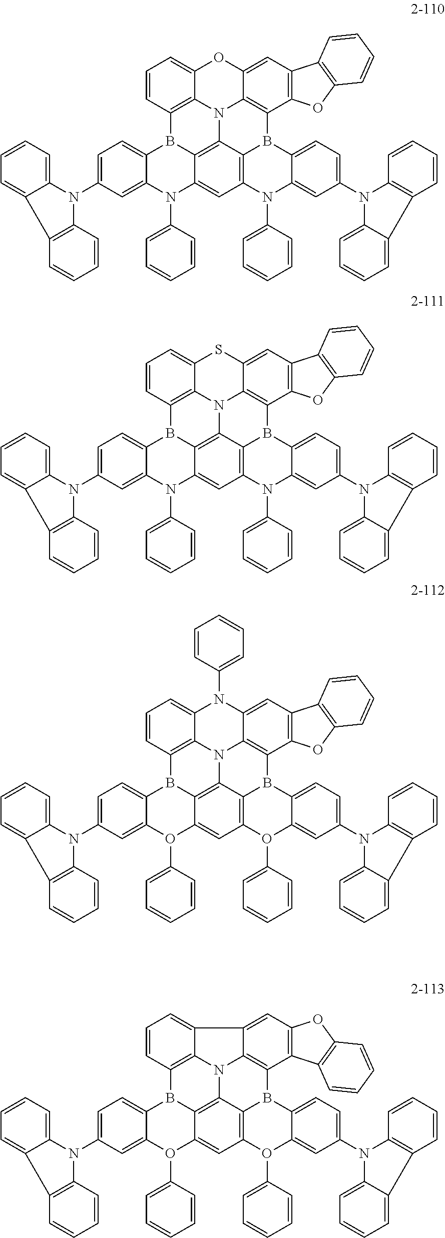

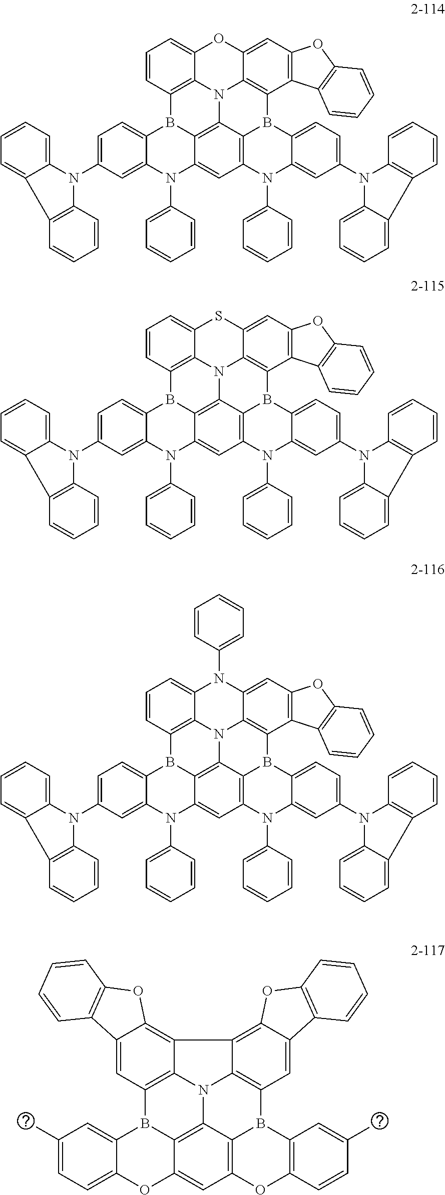

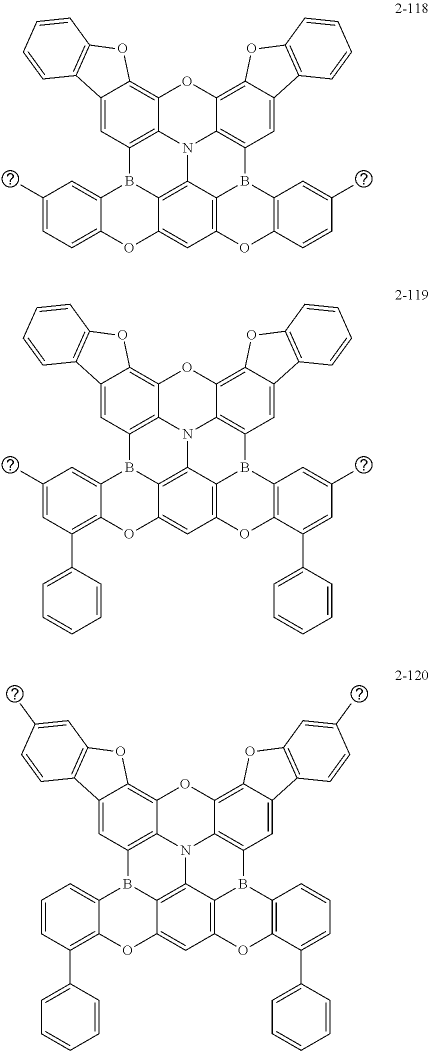

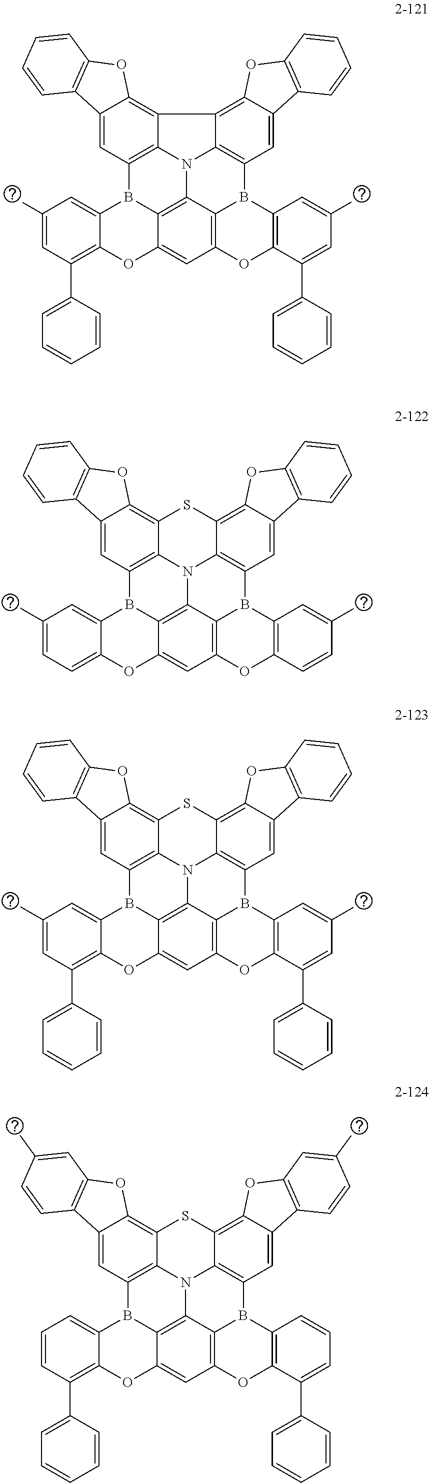

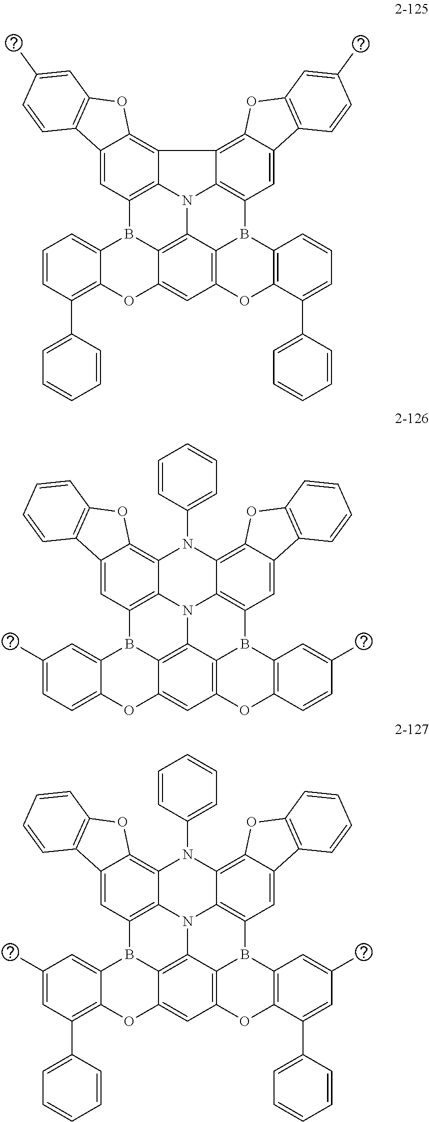

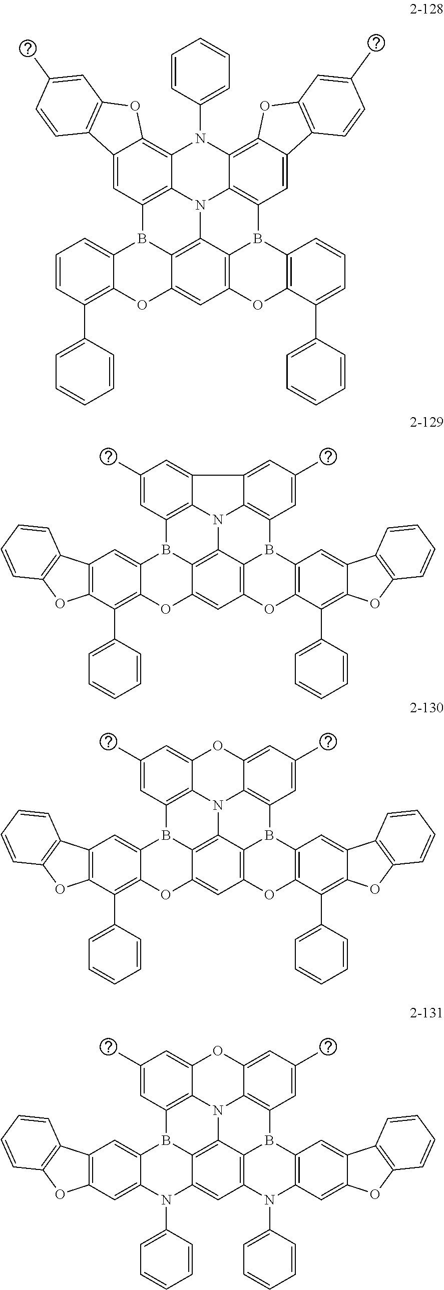

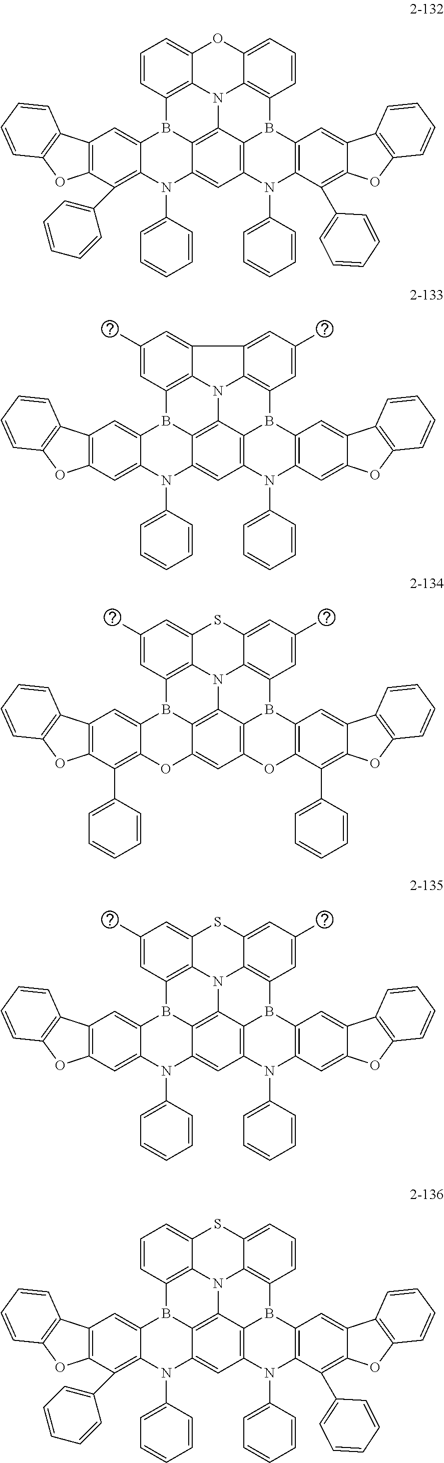

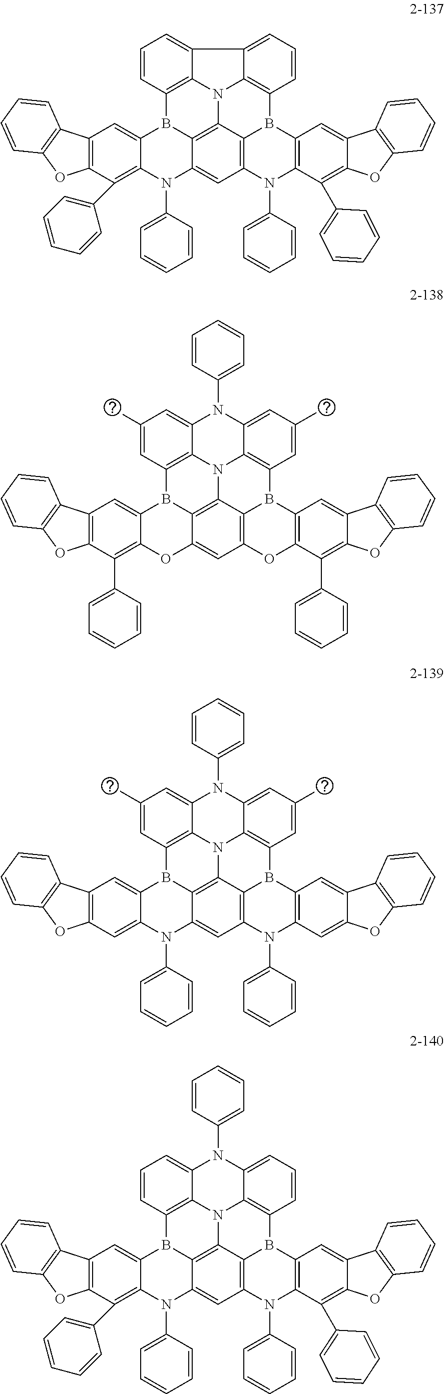

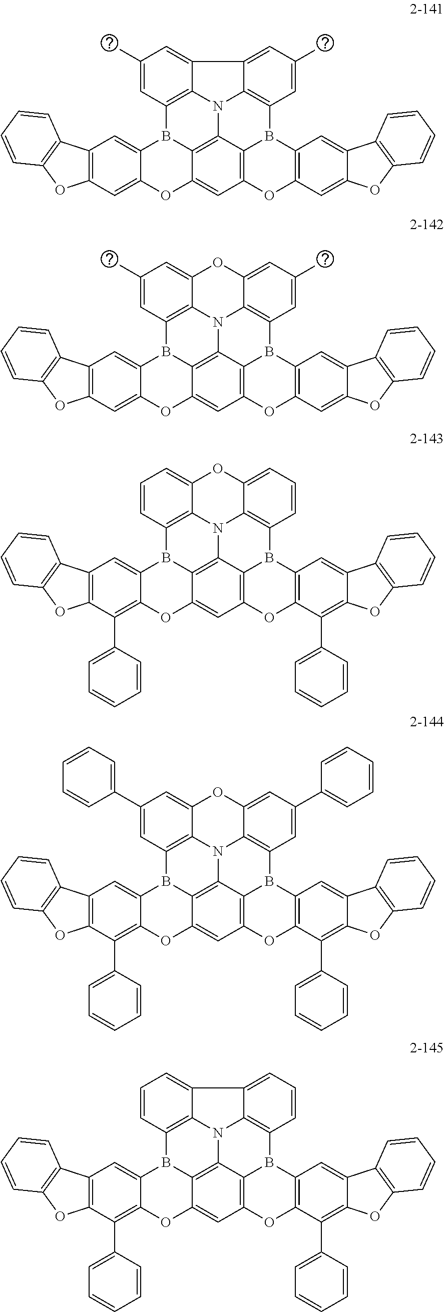

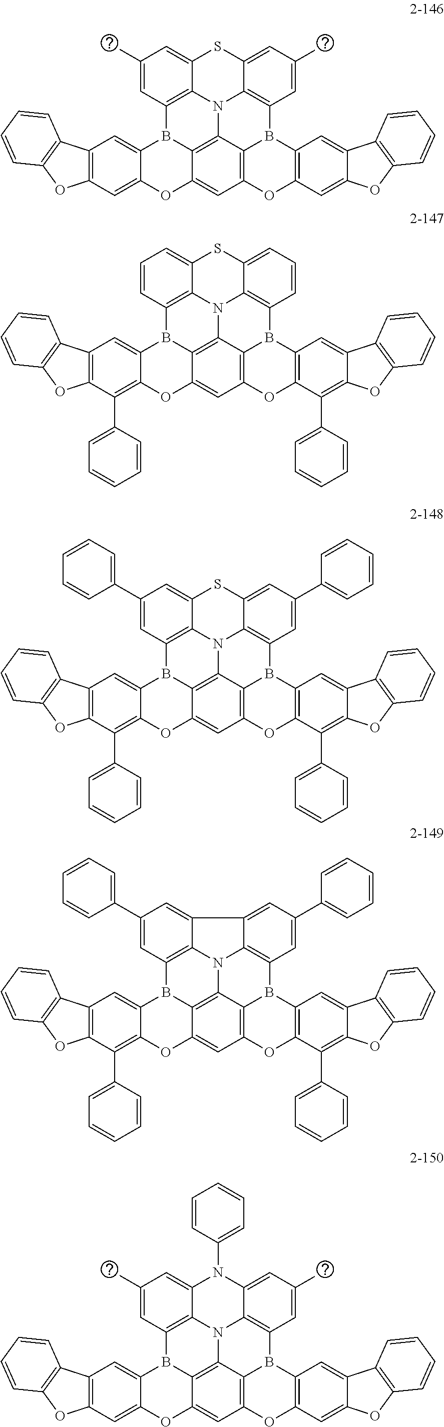

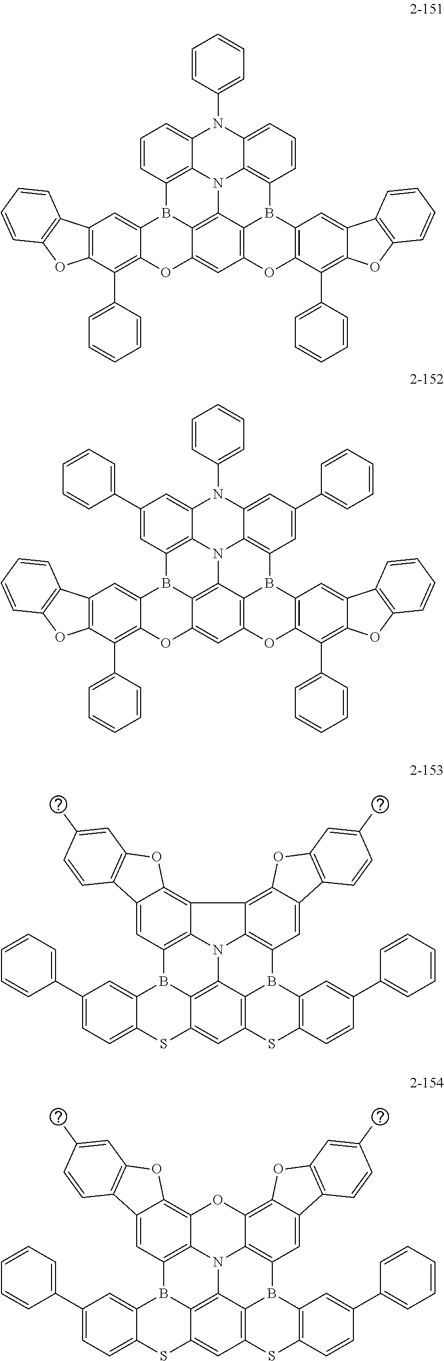 [SMILES: c1ccc(-c2c3c(cc4c2oc2ccccc24)B2c4cccc5c4N4c6c(cccc6N5c5ccccc5)B5c6cc7c(oc8ccccc87)c(-c7ccccc7)c6Oc6cc(c2c4c65)O3)cc1 ; c1ccc(-c2cc3c4c(c2)N(c2ccccc2)c2cc(-c5ccccc5)cc5c2N4c2c4c(cc6c2B5c2cc5c(oc7ccccc75)c(-c5ccccc5)c2O6)Oc2c(cc5c(oc6ccccc65)c2-c2ccccc2)B34)cc1 ; Cc1ccc2c(c1)oc1c2cc2c3c1c1c4oc5cc(C)ccc5c4cc4c1n3-c1c3c(cc5c1B4c1cc(-c4ccccc4)ccc1S5)Sc1ccc(-c4ccccc4)cc1B32 ; Cc1ccc2c(c1)oc1c3c4c(cc12)B1c2cc(-c5ccccc5)ccc2Sc2cc5c6c(c21)N4c1c(cc2c(oc4cc(C)ccc42)c1O3)B6c1cc(-c2ccccc2)ccc1S5]

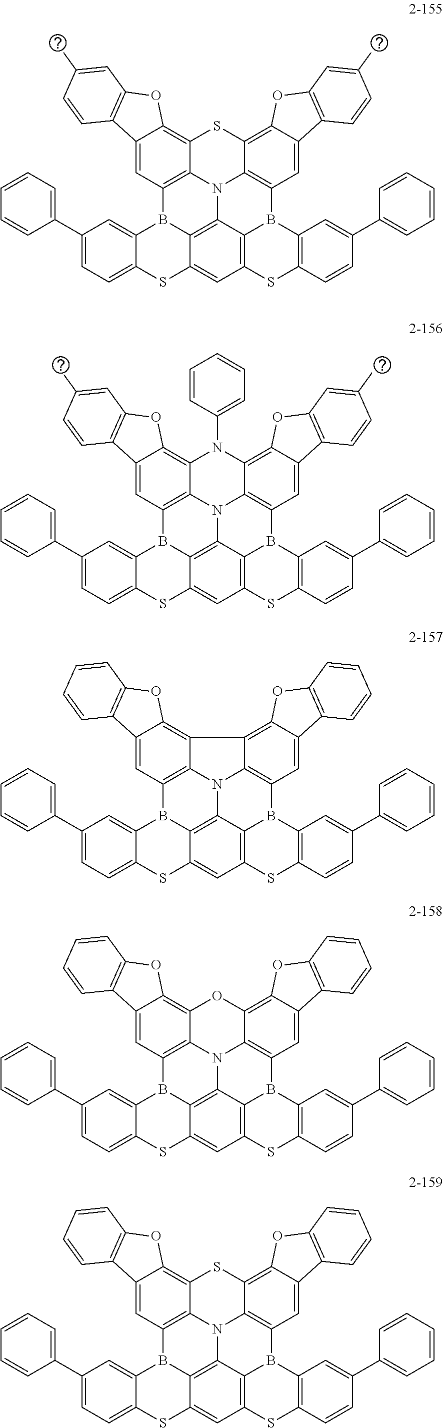

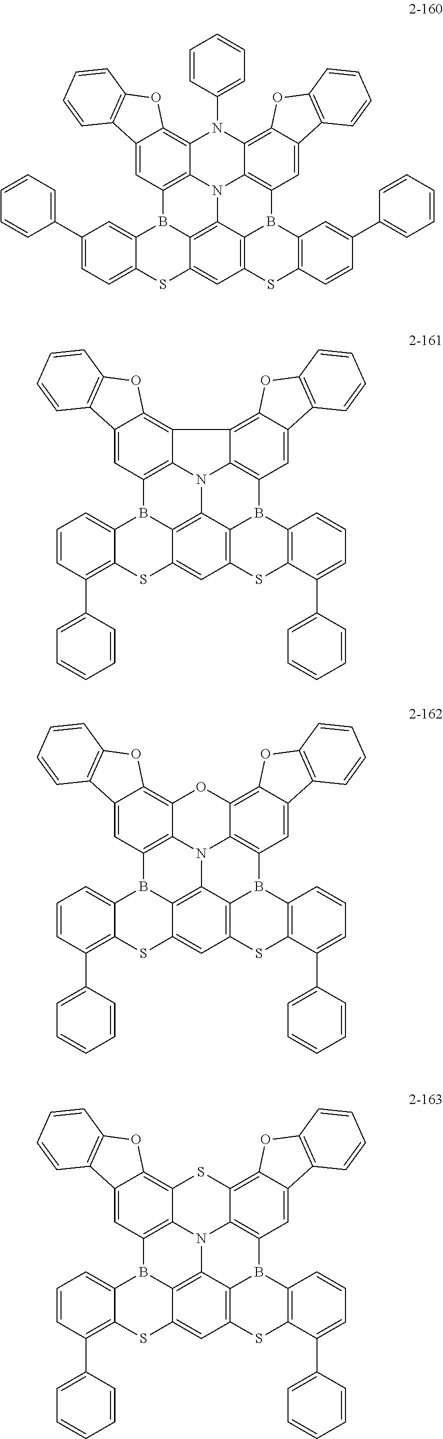

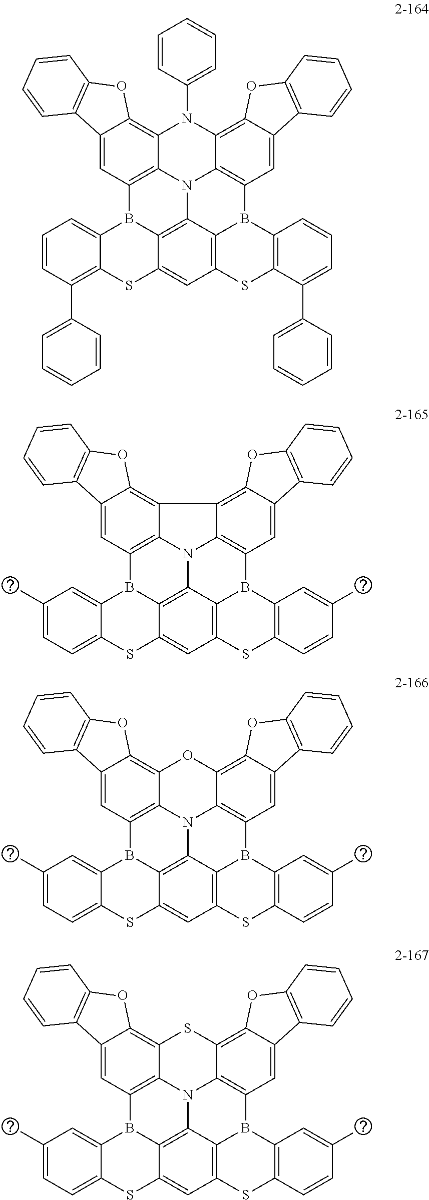

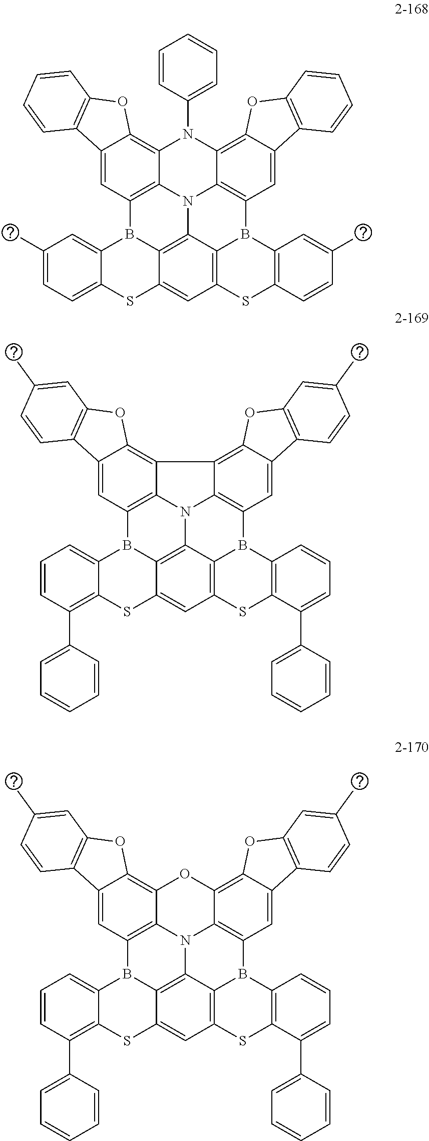

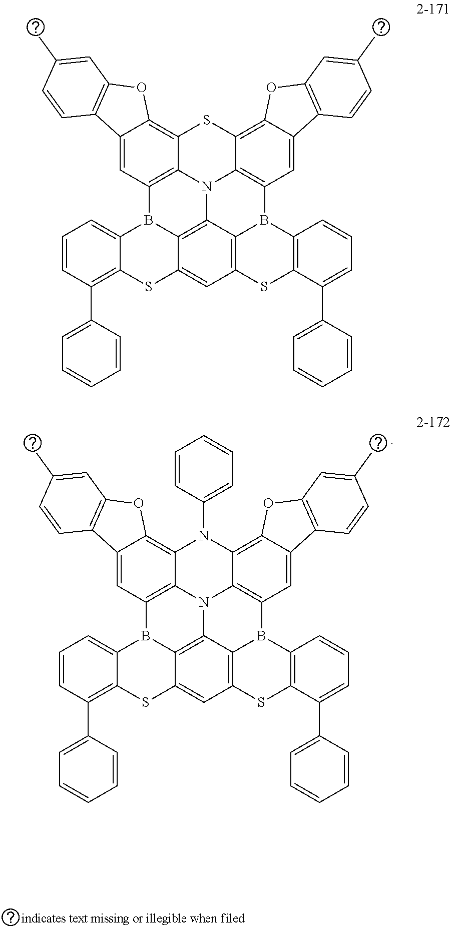

Among the above specific compounds, Compounds 2-22, 2-117, 2-120, 2-143, 2-161, 2-162, 2-165, and 2-169, for example, Compounds 2-22, 2-117, 2-120, 2-143, 2-161, and 2-169, or for example, Compounds 2-22, 2-143, 2-161, and 2-169, may be preferred. By having such a structure, the condensed cyclic compound may have a narrower blue emission spectrum, and thus, may exhibit higher color purity.

The condensed cyclic compound according to an embodiment may exhibit high color purity. In this regard, reorganization energy (g) or a spectrum width of fluorescence in photoluminescence (PL) (a full width at half maximum (FWHM) of the fluorescence spectrum peak) may be used as an index of color purity. The reorganization energy of the condensed cyclic compound may be as small as possible. In detail, the reorganization energy (g) of the condensed cyclic compound according to an embodiment may be 0.100 eV or less. In addition, the reorganization energy may be 0.080 eV or less, or for example, 0.070 eV or less. In addition, the reorganization energy may be 0.065 eV or less (with a lower limit: 0 eV). Within the above ranges, luminescence with a narrow emission spectrum width and high color purity may be obtained. As used herein, the “reorganization energy” adopts a value calculated by the method described later in Examples.

Alternatively, a spectrum width of fluorescence in PL (a FWHM of the fluorescence spectrum peak) of the condensed cyclic compound may be as narrow as possible. In detail, the spectrum width of fluorescence in PL of the condensed cyclic compound according to an embodiment may be 30 nanometers (nm) or less, for example, 25 nm or less, or for example, 20 nm or less (lower limit value: greater than 0 nm). Within the above ranges, luminescence with high color purity may be obtained. As used herein, the “spectrum width of fluorescence in PL” adopts a value calculated by the method described in Examples.

The condensed cyclic compound according to an embodiment may exhibit high fluorescence intensity. In this regard, oscillator strength f in a stable structure of an adiabatic first excited singlet state (S₁) may be used as an index of fluorescence intensity. The oscillator strength f affects light absorption and light emission of a molecule, and the higher the oscillator strength f, the higher the radiative transition speed and the higher the quantum yield of light emission. Accordingly, the oscillator strength f of the condensed cyclic compound may be as large as possible.

The oscillator strength f of the condensed cyclic compound according to an embodiment may be 0.100 or more, or for example, 0.250 or more. In addition, the oscillator strength f may be 0.300 or more. In addition, the oscillator strength f may be 0.330 or more, for example, 0.350 or more, or for example, 0.390 or more. In addition, the theoretical upper limit value of the oscillator strength f is the number of electrons included in the molecule. The upper limit value of the oscillator strength f may be, for example, 2 (2.000) or 3 (3.000), but the upper limit value of the oscillator strength f is not limited thereto. As used herein, the “oscillator strength f” adopts a value calculated by the method described later in Examples.

In the condensed cyclic compound according to an embodiment, the HOMO energy may be, but is not limited to, −5.80 electron Volts (eV) or more. In addition, the HOMO energy may be −5.60 eV or more, or for example, −5.35 eV or more. The HOMO energy may be −4.40 eV or less. In addition, the HOMO energy may be −4.50 eV or less, or for example, −4.60 eV or less. Within the above ranges, a difference between the HOMO energy of the condensed cyclic compound and the HOMO energy of a general host material that is used in an organic electroluminescent device may be reduced. Accordingly, an increase in driving voltage due to formation of hole traps may be suppressed. As used herein, the “HOMO energy” adopts a value calculated by the method described later in Examples.

In the condensed cyclic compound according to an embodiment, the LUMO energy may be, but is not limited to, −2.40 eV or more. In addition, the LUMO energy may be −2.20 eV or more, or for example, −2.10 eV or more. In addition, the LUMO energy may be −2.00 eV or more. The LUMO energy may be −0.80 eV or less. In addition, the LUMO energy may be −1.00 eV or less, or for example, −1.10 eV or less. In addition, the LUMO energy may be −1.30 eV or less. Within the above ranges, a difference between the LUMO energy of the condensed cyclic compound and the LUMO energy of a general host material that is used in an organic electroluminescent device may be reduced. Accordingly, an increase in driving voltage due to formation of electron traps may be suppressed. As used herein, the “LUMO energy” adopts a value calculated by the method described later in Examples.

In the condensed cyclic compound according to an embodiment, adiabatic first excited singlet state (S₁) energy (hereinafter, also referred to as “adiabatic S₁ excitation energy”) (eV) is obtained by converting the adiabatic first excited singlet state (S₁) into a light wavelength (nm). A given fluorescence wavelength peak is not particularly limited. In this regard, the fluorescence wavelength peak may be 360 nm or more and 515 nm or less. In addition, the fluorescence wavelength peak may be 380 nm or more and 505 nm or less, or for example, 400 nm or more and 500 nm or less. In addition, the fluorescence wavelength peak may be 420 nm or more and 490 nm or less. In addition, the fluorescence wavelength peak may be 430 nm or more and 480 nm or less. Within the above ranges, excellent luminescence, in particular, excellent blue luminescence may be obtained. As used herein, the term “fluorescence wavelength peak” refers to a “fluorescence wavelength (nm)” calculated by the method described later in Examples.

In addition, a peak wavelength of fluorescence in PL may have the same range as the fluorescence wavelength peak obtained by converting the adiabatic S₁ excitation energy into a light wavelength. As used herein, the “fluorescence wavelength peak in PL” adopts a value calculated by the method described later in Examples.

The HOMO, LUMO, peak oscillator strength f of the fluorescence wavelength obtained by converting the adiabatic S₁ excitation energy into a light wavelength, and reorganization energy may be calculated by the density functional theory (DFT) by using the calculation software Gaussian 16 (Gaussian Inc.). Each calculation method is described in detail later in Examples.

In addition, the peak wavelength of fluorescence and the spectrum width of fluorescence in PL may be measured using the spectrofluorophotometer F-7000 manufactured by Hitachi High-Tech Science Co., Ltd. In addition, the measurement method is described in detail later in Examples.

A method of synthesizing the condensed cyclic compound according to an embodiment is not particularly limited, and the condensed cyclic compound may be synthesized according to a known synthetic methods. In detail, the condensed cyclic compound may be synthesized according to or in view of the method described in Examples. For example, synthesis may be performed by changing raw materials or reaction conditions, by adding or excluding some sequences, or by appropriately combining known synthesis methods.

For example, the condensed cyclic compound according to an embodiment may be synthesized by the method described later in Examples.

A method of identifying the structure of the condensed cyclic compound according to an embodiment is not particularly limited. The structure of the condensed cyclic compound according to an embodiment may be identified by a known method (e.g., NMR, LC-MS, etc.).

### Material for Organic Electroluminescent Device

Another embodiment of the disclosure relates to a material for an organic electroluminescent device that includes the condensed cyclic compound of the disclosure.

The material for an organic electroluminescent device according to an embodiment (hereinafter, simply referred to as “material for an organic EL device”) may be different from the condensed cyclic compound and other materials used in the organic EL device.

The other materials used in an organic EL device may be, but are not particularly limited to, materials known in the art. For example, as the other materials used in an organic EL device, materials constituting each layer described in the below description of the organic EL device may be used. Among the materials constituting each layer, a dopant material or a host material described in the below description of an emission layer of the organic EL device may be used. In addition, a thermally activated delayed fluorescence (TADF) material (TADF compound), a phosphorescent material (phosphorescent compound), or a host material described in the below description of the emission layer of the organic EL device may be used. In addition, a host material, a TADF material, or a phosphorescent material and a host material may be used. In addition, a TADF material or a phosphorescent material and a host material may be used. In addition, a phosphorescent material and a host material may be used. In this regard, as the phosphorescent material, a phosphorescent complex described in the below description of the emission layer of the organic EL device may be used. In addition, as the phosphorescent material, a platinum complex described in the below description of the emission layer of the organic EL device may be used.

Accordingly, an embodiment of the disclosure may provide, in addition to the condensed cyclic compound of the disclosure, a material for an organic EL device that further includes a TADF material or a phosphorescent material to be described below. In this regard, the phosphorescent material may be a phosphorescent complex, or may be a platinum complex to be described below. When the material for an organic EL device, particularly a material for an emission layer, includes a TADF material or a phosphorescent material, in addition to the condensed cyclic compound of the disclosure, the luminescence efficiency and device lifespan of the organic EL device may be significantly improved. The reason for this may be the same as described in the below description of the emission layer of the organic EL device.

In an embodiment, the material for an organic EL device may be a liquid material further including a solvent. The solvent may be, but is not particularly limited to, a solvent having a boiling point of 100° C. or more and 350° C. or less at atmospheric pressure (101.3 kPa, 1 atm). The boiling point of the solvent at atmospheric pressure may be 150° C. or more and 320° C. or less, or for example, 180° C. or more and 300° C. or less. When the boiling point of the solvent at atmospheric pressure is within the above ranges, the processability or film-forming capability of a wet film forming method may be improved, especially in an inkjet method.

The solvent having a boiling point of 100° C. or more and 350° C. or less at atmospheric pressure is not particularly limited, and a known solvent may be appropriately used. Hereinafter, the solvent having a boiling point of 100° C. or more and 350° C. or less at atmospheric pressure will be described in detail, but the disclosure is not limited thereto.

Examples of a hydrocarbon-based solvent may include octane, nonane, decane, undecane, dodecane, and the like. Examples of an aromatic hydrocarbon-based solvent may include toluene, xylene, ethylbenzene, n-propyl benzene, iso-propyl benzene, mesitylene, n-butyl benzene, sec-butyl benzene, 1-phenyl pentane, 2-phenyl pentane, 3-phenyl pentane, phenyl cyclopentane, phenyl cyclohexane, 2-ethyl biphenyl, 3-ethyl biphenyl, and the like. Examples of an ether-based solvent may include 1,4-dioxane, 1,2-diethoxyethane, diethyleneglycol dimethyl ether, diethyleneglycol diethyl ether, anisole, ethoxybenzene, 3-methylanisole, m-dimethoxy benzene, and the like. Examples of a ketone-based solvent may include 2-hexanone, 3-hexanone, cyclohexanone, 2-heptanone, 3-heptanone, 4-heptanone, cycloheptanone, and the like. Examples of an ester-based solvent may include butyl acetate, butyl propionate, heptyl butyrate, propylene carbonate, methyl benzoate, ethyl benzoate, 1-propyl benzoate, 1-butyl benzoate, and the like. Examples of a nitrile-based solvent may include benzonitrile, 3-methyl benzonitrile, and the like. Examples of an amide-based solvent may include dimethyl formamide, dimethyl acetamide, N-methyl pyrrolidone, and the like. Such solvents may be used alone or in combination of two or more.

The material for an organic EL device according to an embodiment may be a material for an emission layer.

The material for an organic EL device according to an embodiment may not be a liquid composition. That is, the material for an organic EL device may be substantially free of a solvent.

In this regard, the term “material substantially free of a solvent” indicates that the amount of the solvent is less than 1 wt % based on the total weight of the composition. When the material for an organic EL device is not a liquid composition, the material for an organic EL device may be substantially free of a solvent and may not include a solvent (wherein the amount of the solvent is 0 wt % based on the total weight of the composition).

The amount of the condensed cyclic compound based on the total weight (in the case of a liquid composition, the total weight excluding the solvent) of the material for an organic EL device (in particular, the material for an emission layer) may be the same as the amount of the condensed cyclic compound based on the total weight of the emission layer of the organic EL device to be described below.

In addition, the amount of the TADF material or the phosphorescent material (in particular, the phosphorescent material) based on the total weight (in the case of a liquid composition, the total weight excluding the solvent) of the material for an organic EL device (in particular, the material for an emission layer) may be the same as the amount of the TADF material or the phosphorescent material (in particular, the phosphorescent material) based on the total weight of the emission layer of the organic EL device to be described below.

In addition, an amount (parts by weight) of the TADF material or the phosphorescent material (in particular, the phosphorescent material) based on 100 parts by weight of the condensed cyclic compound in the material for an organic EL device (in particular, the material for an emission layer) may be the same as an amount (parts by weight) of the TADF material or the phosphorescent material (in particular, the phosphorescent material) based on 100 parts by weight of the condensed cyclic compound in the emission layer of the organic EL device to be described below.

In addition, the amount of the host material based on the total weight (in the case of a liquid composition, the total weight excluding the solvent) of the material for an organic EL device (in particular, the material for an emission layer) may be the same as the amount of the host material based on the total weight of the emission layer of the organic EL device to be described below.

In addition, an amount (parts by weight) of the host material based on 100 parts by weight of the condensed cyclic compound in the material for an organic EL device (in particular, the material for an emission layer) may be the same as an amount (parts by weight) of the host material based on 100 parts by weight of the condensed cyclic compound in the emission layer of the organic EL device to be described below.

When the amounts of the condensed cyclic compound, the TADF material or the phosphorescent material, and the host material in the material for an organic EL device are within the above ranges, respectively, an organic EL device having improved luminescence efficiency and/or lifespan may be obtained according to the emission color purity.

### Organic Electroluminescent Device

Another embodiment of the present disclosure relates to an organic electroluminescent device having an organic layer including the condensed cyclic compound. The organic electroluminescent device may have a narrow emission spectrum, and may realize luminescence with high color purity. In addition, the organic electroluminescent device may realize improved luminescence efficiency.

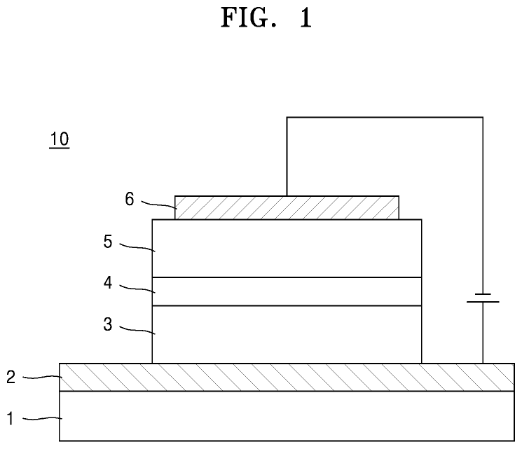

Hereinafter, an organic electroluminescent device 10 according to an embodiment will be described in detail with reference to FIGS. 1 to 3. FIGS. 1 to 3 are each a schematic view of an organic electroluminescent device 10 according to an embodiment. However, the structure of the organic electroluminescent device 10 according to the disclosure is not limited to the embodiments shown in FIGS. 1 to 3.

FIG. 1 is a schematic cross-sectional view of the organic electroluminescent device 10 according to an embodiment. The organic electroluminescent device 10 may include a substrate 1, a first electrode 2, a hole transport region 3, an emission layer 4, an electron transport region 5, and a second electrode 6, which are sequentially stacked in the stated order.

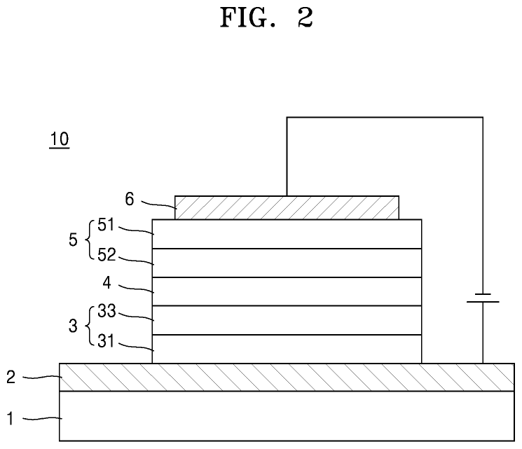

FIG. 2 is a schematic cross-sectional view of the organic electroluminescent device 10 according to another embodiment. The organic electroluminescent device 10 may include the substrate 1, the first electrode 2, the hole transport region 3, the emission layer 4, the electron transport region 5, and the second electrode 6. As shown in FIG. 2, the hole transport region 3 may include a hole injection layer 31 and a hole transport layer 32, which are sequentially layered in the stated order. In addition, as shown in FIG. 2, the electron transport region 5 may include an electron transport layer 52 and an electron injection layer 51, which are sequentially stacked in the stated order.

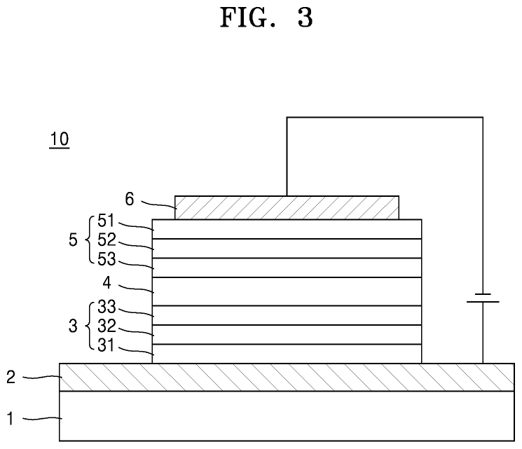

FIG. 3 is a schematic cross-sectional view of the organic electroluminescent device 10 according to another embodiment. The organic electroluminescent device 10 may include the substrate 1, the first electrode 2, the hole transport region 3, the emission layer 4, the electron transport region 5, and the second electrode 6. As shown in FIG. 3, the hole transport region 3 may include the hole injection layer 31, the hole transport layer 32, and an electron blocking layer 33, which are sequentially stacked in the stated order. In addition, as shown in FIG. 3, the electron transport region 5 may include a hole blocking layer 53, the electron transport layer 52, and the electron injection layer 51, which are sequentially stacked in the stated order.

The condensed cyclic compound according to the disclosure may be included, for example, in an organic layer arranged between the first electrode 2 and the second electrode 6. Examples of the organic layer may include the hole injection layer 31, the hole transport layer 32, the emission layer 4, the electron transport layer 52, the electron injection layer 51, and the like. The condensed cyclic compound according to the disclosure may be included in the emission layer 4. That is, in an embodiment, the organic layer may be the emission layer 4.

An embodiment may include, for example, an organic electroluminescent device including a first electrode, a second electrode, and a single or a plurality of emission layers. The second electrode may be arranged on the first electrode.

When a portion of a layer, film, region, plate, etc. is said to be “on” or “above” another portion in the present specification, this includes not only a case in which the portion is “directly on” another portion, but also a case in which an intervening layer is placed therebetween. Similarly, when a portion of a layer, film, region, plate, etc. is said to be “under” or “below” another portion in the present specification, this includes not only a case in which the portion is “directly under” another portion, but also a case in which an intervening layer is placed therebetween.

In the present specification, “arrangement” may include a case in which a portion is arranged not only on an upper part but also on a lower part.

The organic electroluminescent device 10 may include the condensed cyclic compound according to an embodiment. For example, the condensed cyclic compound according to an embodiment may be included in an organic layer arranged between the first electrode 2 and the second electrode 6. In an embodiment, the condensed cyclic compound may be included in the emission layer 4.

Hereinafter, an embodiment in which the emission layer 4 includes the condensed cyclic compound according to the disclosure will be described. In addition, the condensed cyclic compound according to the disclosure included in the emission layer 4 may be used alone or two or more condensed cyclic compounds may be combined, e.g., a mixture of two or more condensed cyclic compound in the emission layer 4.

The emission layer 4 may emit light by fluorescence or phosphorescence.

The emission layer 4 may be a single layer consisting of a single material or a single layer consisting of a plurality of different materials. In addition, the emission layer 4 may have a multi-layered structure having the same or different multiple layers including a plurality of different materials on one or more layers.

In the emission layer 4, the condensed cyclic compound may be used alone or two or more condensed cyclic compounds may be combined, e.g., as in a mixture in a single layer or as two or more separate layers.

The amount of the condensed cyclic compound may be, but is not particularly limited to, 0.05 weight percent (wt %) or more based on the total weight of the emission layer 4. In an embodiment, the amount of the condensed cyclic compound may be 0.1 wt % or more, 0.2 wt % or more, 1 wt % or more, or 5 wt % or more, based on the total weight of the emission layer 4. In an embodiment, the amount of the condensed cyclic compound may be 50 wt % or less, 30 wt % or less, or 25 wt % or less, based on the total weight of the emission layer 4. Within the above ranges, an organic electroluminescent device having improved color purity, luminescence efficiency, and/or lifespan may be obtained.

In an embodiment, the emission layer 4 may further include a host, the host and the condensed cyclic compound may be different from each other, and the emission layer 4 may consist of the host and the condensed cyclic compound. As such, the host does not emit light, and the condensed cyclic compound does emit light. That is, the condensed cyclic compound may be a dopant.

In an embodiment, the emission layer 4 may further include a host and a dopant. The host, the dopant, and the condensed cyclic compound may be different from one another, and the emission layer 4 may consist of the host, the dopant, and the condensed cyclic compound. As such, the host and the condensed cyclic compound do not each emit light, and the dopant emits light.

In the above embodiments, the host and the dopant may be the same as described below.

The emission layer 4 may include a known host material and a known dopant material.

For example, the emission layer 4 may include, in addition to the condensed cyclic compound, at least one of an anthracene derivative, a pyrene derivative, a fluoranthene derivative, a chrysene derivative, a dihydrobenzoanthracene derivative, or a triphenylene derivative.

For example, the emission layer 4 may include, as the host material, at least one of bis[2-(diphenylphosphino)phenyl]etheroxide (DPEPO), 4,4′-bis(carbazol-9-yl)biphenyl (CBP), 3,3′-bis(carbazol-9-yl)biphenyl (mCBP), 1,3-bis(carbazol-9-yl)benzene (mCP), 2,8-bis(diphenylphosphoryl)dibenzo[b,d]furan (PPF), 4,4′,4″-tris(carbazol-9-yl)triphenylamine (TcTa), and 1,3,5-tris(N-phenylbenzimidazole-2-yl)benzene (TPBi). However, the host material is not limited thereto, and the emission layer 4 may include, for example, tris(8-hydroxyquinolino)aluminum (Alq₃), 4,4′-bis(N-carbazolyl)-1,1′-biphenyl (CBP), poly(n-vinylcarbazole) (PVK), 9,10-di(naphthalene-2-yl)anthracene (ADN), 4,4′,4″-tris(carbazol-9-yl)-triphenylamine (TCTA), 1,3,5-tris(N-phenylbenzimidazol-2-yl)benzene (TPBi), 3-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalene-2-yl)anthracene (MADN), bis[2-(diphenylphosphino)phenyl]etheroxide (DPEPO), hexaphenylcyclotriphosphazene (CP1), 1,4-bis(triphenylsilyl)benzene (IGH2), hexaphenylcyclotrisiloxane (DPSiO₃), octaphenylcyclotetrasiloxane (DPSiO₄), or 2,8-bis(diphenylphosphoryl)dibenzofuran (PPF).

In addition, the emission layer 4 may include, as the host material, a material having a HOMO of −5.2 eV or less. In addition, the emission layer 4 may include, as the host material, a material having a LUMO of −1.4 eV or less. By using a host material having low HOMO and LUMO and high electron transport properties, the driving durability in an organic electroluminescent device, particularly in a blue organic electroluminescent device, may be improved. Such a material is not particularly limited, and an example thereof may include Compound A represented by the formula below, which is disclosed in “An Alternative Host Material for Long-Lifespan Blue Organic Light-Emitting Diodes Using Thermally Activated Delayed Fluorescence”, Soo-Ghang Ihn, Namheon Lee, Soon Ok Jeon, Myungsun Sim, Hosuk Kang, Yongsik Jung, Dal Ho Huh, Young Mok Son, Sae Youn Lee, Masaki Numata, Hiroshi Miyazaki, Rafael Gomez-Bombarelli, Jorge Aguilera-Iparraguirre, Timothy Hirzel, Alan Aspuru-Guzik, Sunghan Kim, and Sangyoon Lee, Advanced Science News 2017, 4, 1600502. When the emission layer 4 is formed in combination with such a host material, a blue luminescent material in the related art may become a deep hole trap, thereby causing undesirable effects such as an increase in driving voltage. The condensed cyclic compound has weak hole trapping properties, and thus is expected to suppress the increase in the driving voltage.

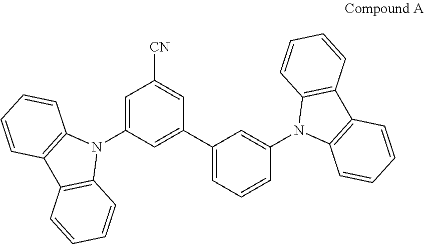 [SMILES: N#Cc1cc(-c2cccc(-n3c4ccccc4c4ccccc43)c2)cc(-n2c3ccccc3c3ccccc32)c1]

In addition, the emission layer may include, as the host material, the following compounds:

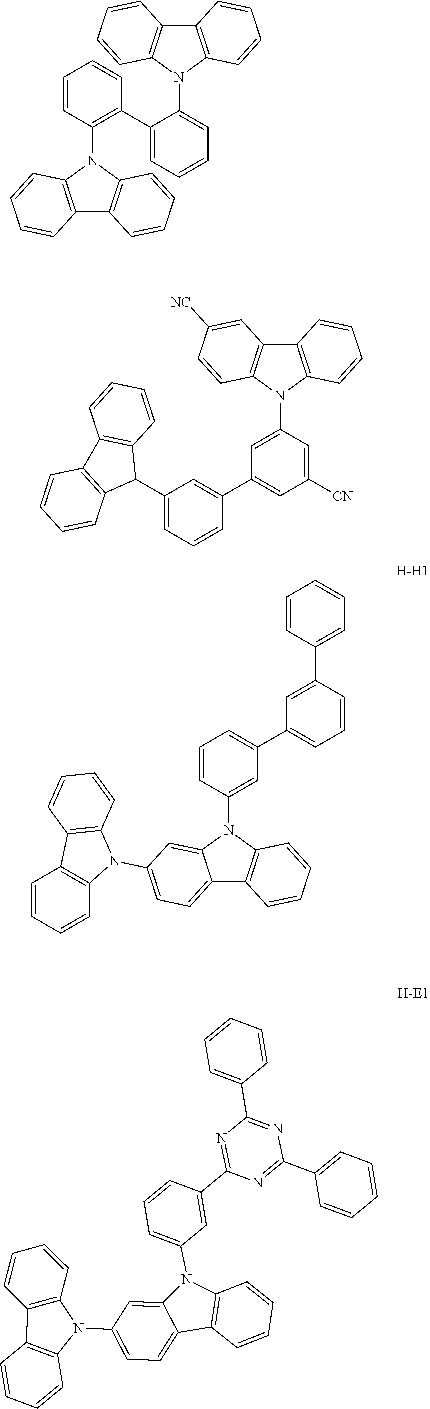 [SMILES: c1ccc(-n2c3ccccc3c3ccccc32)c(-c2ccccc2-n2c3ccccc3c3ccccc32)c1 ; N#Cc1cc(-c2cccc(C3c4ccccc4-c4ccccc43)c2)cc(-n2c3ccccc3c3cc(C#N)ccc32)c1 ; c1ccc(-c2cccc(-c3cccc(-n4c5ccccc5c5ccc(-n6c7ccccc7c7ccccc76)cc54)c3)c2)cc1 ; c1ccc(-c2nc(-c3ccccc3)nc(-c3cccc(-n4c5ccccc5c5ccc(-n6c7ccccc7c7ccccc76)cc54)c3)n2)cc1]

Among the above compounds, the emission layer 4 may include, as the host material, Compound H-H1 and/or Compound H-E1, and in particular, may include Compound H-H1 and Compound H-E1.

The amount of the host material based on the total weight of the emission layer 4 may be, but is not particularly limited to, 5 wt % or more. In an embodiment, the amount may be 10 wt % or more, or 20 wt % or more. In addition, the amount of the host material based on the total weight of the emission layer 4 may be 99 wt % or less. In addition, the amount of the host material based on the total weight of the emission layer 4 may be may be 95 wt % or less, or 90 wt % or less. Within the above ranges, an organic electroluminescent device having improved luminescence efficiency and/or lifespan may be obtained.

When the emission layer 4 includes a host material, the amount thereof may be, but is not particularly limited to, 1,000 parts by weight or more, or 200,000 parts by weight or less, based on 100 parts by weight of the condensed cyclic compound. In an embodiment, the amount of a host material may be 2,000 parts by weight or more, 3,000 parts by weight or more, 150,000 parts by weight or less, or 100,000 parts by weight or less, based on 100 parts by weight of the condensed cyclic compound. Within the above ranges, an organic electroluminescent device having improved luminescence efficiency and/or lifespan may be obtained.

The emission layer 4 is not particularly limited, and may include, for example, a known dopant material. For example, the emission layer 4 may include a styryl derivative (e.g., 1,4-bis[2-(3-N-ethylcarbazolyl)vinyl]benzene (BCzVB), 4-(di-p-trilamino)-4′-[(di-p)-trilamino)styryl]stylbene (DPAVB), or N-(4-((E)-2-(6-((E)-4-(diphenylamino)styryl)naphthalene-2-yl)vinyl)phenyl)-N-phenylbenzeneamine (N-BDAVBi)), perylene or a derivative thereof (e.g., 2,5,8,11-tetra-tert-butylperylene (TBP)), or pyrene or a derivative thereof e.g., 1, 1-dipyrene, 1,4-dipyrenylbenzene, or 1,4-bis(N,N-diphenylamino)pyrene).

In addition, the emission layer 4 may further include a known TADF material (TADF compound) or phosphorescent material, in addition to the condensed cyclic compound. The term “thermally activated delayed fluorescence” refers to a phenomenon in which reverse intersystem crossing occurs between triplet excitons and singlet excitons in a compound with a small energy difference (ΔEst) between the singlet level and the triplet level, and the term “TADF material” refers to a material in which such a phenomenon occurs.

As is known in the related art, in an emission layer of an organic electroluminescent device, singlet excitons and triplet excitons are generated at a ratio of 1:3 by recombination of holes and electrons. In a device including only a fluorescent material as a luminescent material, only singlet excitons are involved in light emission, whereas in a device including a TADF material or a phosphorescent material as a luminescent material, both singlet excitons and triplet excitons may contribute to light emission. Accordingly, the luminescence efficiency of the device including the TADF material or the phosphorescent material as a luminescent material may be significantly improved. Excitons generated on the TADF material or the phosphorescent material generally have a long lifespan of 1 microsecond (μs) or more. The excitons are in an unstable state with high energy, and thus, material degradation may occur while the excitons are present, leading to a reduction in device lifespan. When the TADF material or the phosphorescent material is present in the emission layer, in addition to the condensed cyclic compound, excitons are generated with high efficiency on the TADF material or the phosphorescent material, and energy is transferred to the condensed cyclic compound through a Förster resonance energy transfer (FRET) mechanism. As a result, highly efficient fluorescence may be obtained from the condensed cyclic compound, and the time for which excitons are present on the TADF material or the phosphorescent material may be shortened. Thus, the possibility of material deterioration may be significantly reduced, and the device lifespan may be significantly improved.

The amount of the TADF material or the phosphorescent material (in particular, the phosphorescent material) based on the total weight of the emission layer 4 may be, but is not particularly limited to, 0.1 wt % or more. In an embodiment, the amount of the TADF material or the phosphorescent material may be 0.5 wt % or more, 1 wt % or more, 3 wt % or more, or 5 wt % or more. In addition, the amount of the TADF material or the phosphorescent material (in particular, the phosphorescent material) based on the total weight of the emission layer 4 may be 50 wt % or less. In an embodiment, the amount of the TADF material or the phosphorescent material may be 40 wt % or less, or 30 wt % or less. In addition, when the emission layer 4 includes both the TADF material and the phosphorescent material, the total amount thereof may be within the above ranges. Within the above ranges, an organic electroluminescent device having improved luminescence efficiency and/or lifespan may be obtained.

When the emission layer 4 includes the TADF material or the phosphorescent material (in particular, the phosphorescent material), the amount of the TADF material or the phosphorescent material may be, but is not particularly limited to, 100 parts by mass or more based on 100 parts by mass of the condensed cyclic compound. In an embodiment, the amount of the TADF material or the phosphorescent material may be 150 parts by mass or more, or 200 parts by mass or more, based on 100 parts by mass of the condensed cyclic compound. In addition, the amount of the TADF material or the phosphorescent material (in particular, the phosphorescent material) may be 10,000 parts by mass or less based on 100 parts by mass of the condensed cyclic compound. In an embodiment, the amount of the TADF material or the phosphorescent material may be 7,500 parts by mass or less, or 5,000 parts by mass or less, based on 100 parts by mass of the condensed cyclic compound. In addition, when the emission layer 4 includes both the TADF material and the phosphorescent material, the total amount thereof may be within the above ranges. Within the above ranges, an organic electroluminescent device having improved luminescence efficiency and/or lifespan may be obtained.

Examples of the TADF material may include the following compounds:

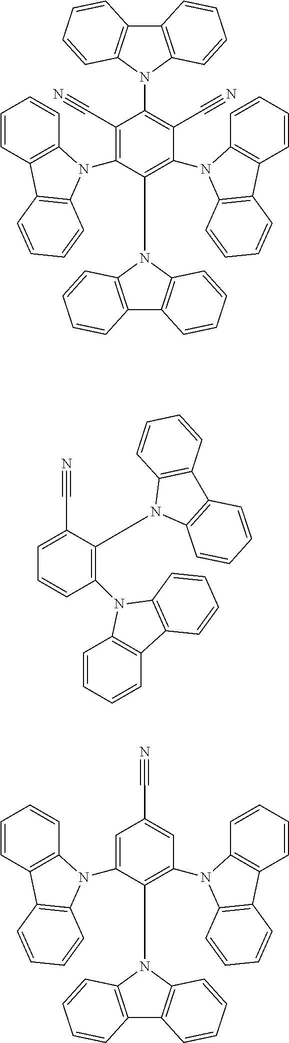 [SMILES: N#Cc1c(-n2c3ccccc3c3ccccc32)c(C#N)c(-n2c3ccccc3c3ccccc32)c(-n2c3ccccc3c3ccccc32)c1-n1c2ccccc2c2ccccc21 ; N#Cc1cccc(-n2c3ccccc3c3ccccc32)c1-n1c2ccccc2c2ccccc21 ; N#Cc1cc(-n2c3ccccc3c3ccccc32)c(-n2c3ccccc3c3ccccc32)c(-n2c3ccccc3c3ccccc32)c1]

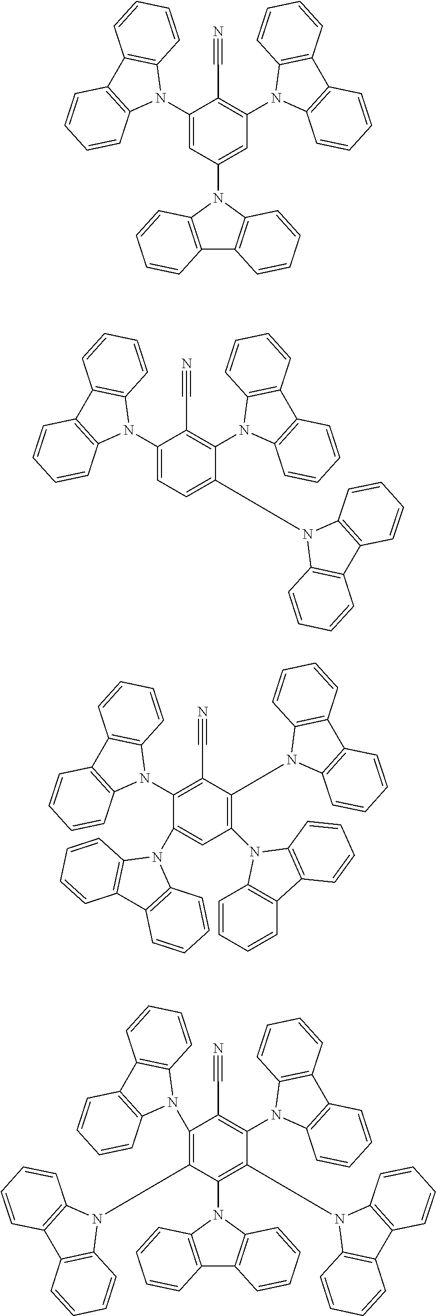

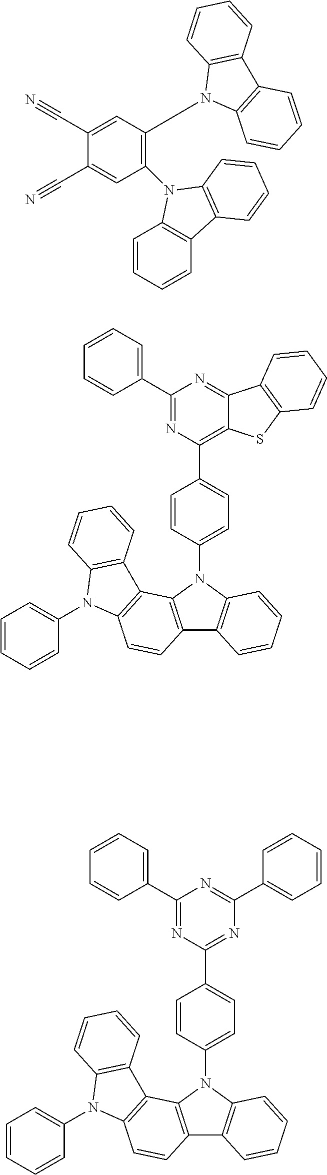 [SMILES: N#Cc1cc(-n2c3ccccc3c3ccccc32)c(-n2c3ccccc3c3ccccc32)cc1C#N ; c1ccc(-c2nc(-c3ccc(-n4c5ccccc5c5ccc6c(c7ccccc7n6-c6ccccc6)c54)cc3)c3sc4ccccc4c3n2)cc1 ; c1ccc(-c2nc(-c3ccccc3)nc(-c3ccc(-n4c5ccccc5c5ccc6c(c7ccccc7n6-c6ccccc6)c54)cc3)n2)cc1]

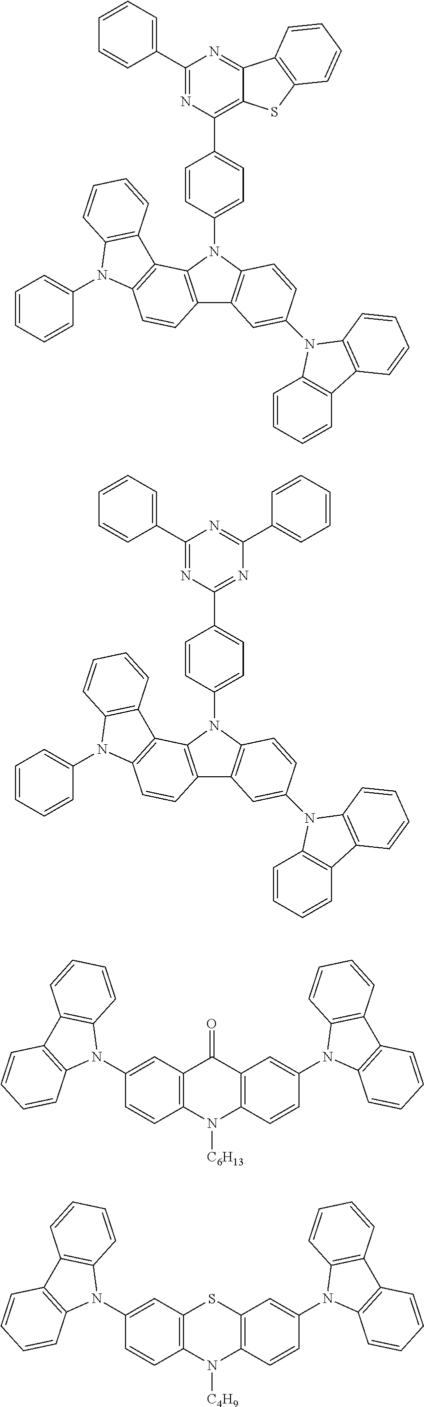

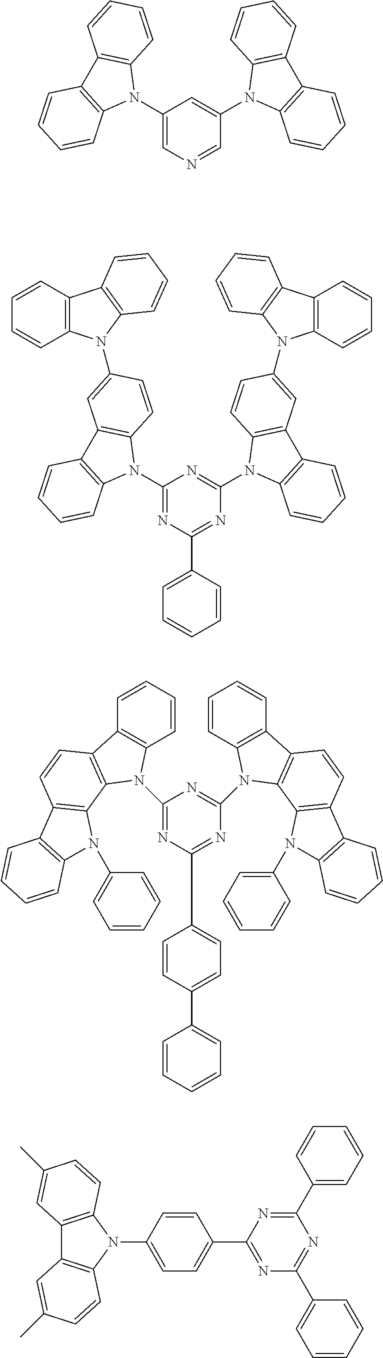 [SMILES: c1ccc2c(c1)c1ccccc1n2-c1cncc(-n2c3ccccc3c3ccccc32)c1 ; c1ccc(-c2nc(-n3c4ccccc4c4cc(-n5c6ccccc6c6ccccc65)ccc43)nc(-n3c4ccccc4c4cc(-n5c6ccccc6c6ccccc65)ccc43)n2)cc1 ; c1ccc(-c2ccc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1 ; Cc1ccc2c(c1)c1cc(C)ccc1n2-c1ccc(-c2nc(-c3ccccc3)nc(-c3ccccc3)n2)cc1]

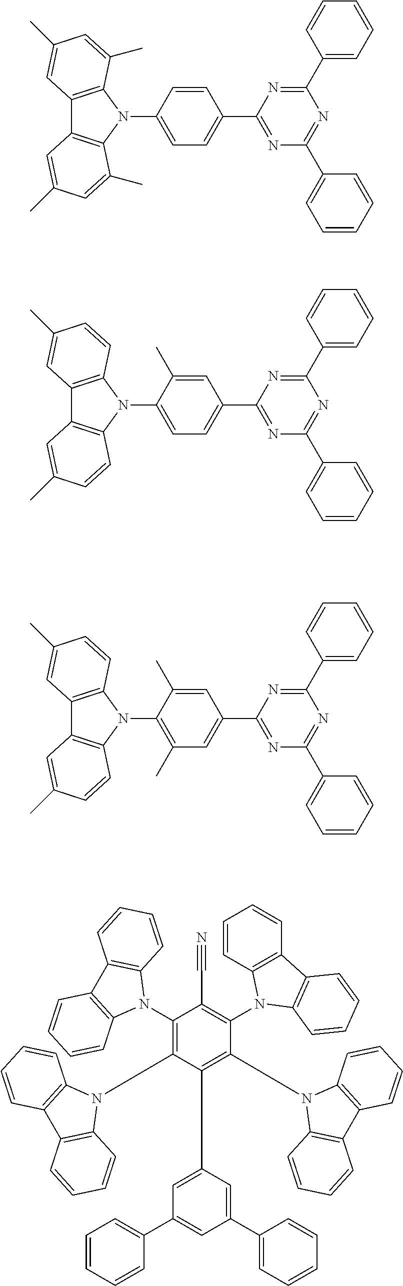 [SMILES: Cc1cc(C)c2c(c1)c1cc(C)cc(C)c1n2-c1ccc(-c2nc(-c3ccccc3)nc(-c3ccccc3)n2)cc1 ; Cc1ccc2c(c1)c1cc(C)ccc1n2-c1ccc(-c2nc(-c3ccccc3)nc(-c3ccccc3)n2)cc1C ; Cc1ccc2c(c1)c1cc(C)ccc1n2-c1c(C)cc(-c2nc(-c3ccccc3)nc(-c3ccccc3)n2)cc1C ; N#Cc1c(-n2c3ccccc3c3ccccc32)c(-n2c3ccccc3c3ccccc32)c(-c2cc(-c3ccccc3)cc(-c3ccccc3)c2)c(-n2c3ccccc3c3ccccc32)c1-n1c2ccccc2c2ccccc21]

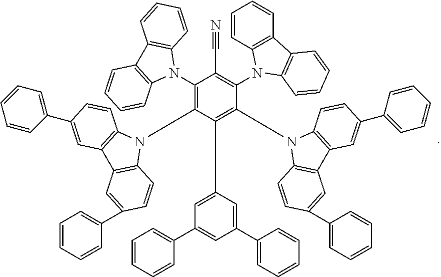 [SMILES: N#Cc1c(-n2c3ccccc3c3ccccc32)c(-n2c3ccc(-c4ccccc4)cc3c3cc(-c4ccccc4)ccc32)c(-c2cc(-c3ccccc3)cc(-c3ccccc3)c2)c(-n2c3ccc(-c4ccccc4)cc3c3cc(-c4ccccc4)ccc32)c1-n1c2ccccc2c2ccccc21]

The TADF material may be used alone or in combination of two or more material (compounds).

As stated, the emission layer 4 may include a phosphorescent material (phosphorescent compound), in addition to the condensed cyclic compound. The phosphorescent material (phosphorescent compound) is not particularly limited, and a known phosphorescent compound may be used. Among known phosphorescent compounds, a phosphorescent complex may be used, and in particular, an iridium complex, a platinum complex, or palladium complex may be used. Among known phosphorescent compounds, a platinum phosphorescent complex may be used.

Examples of the phosphorescent material (phosphorescent compound) may include the following compounds:

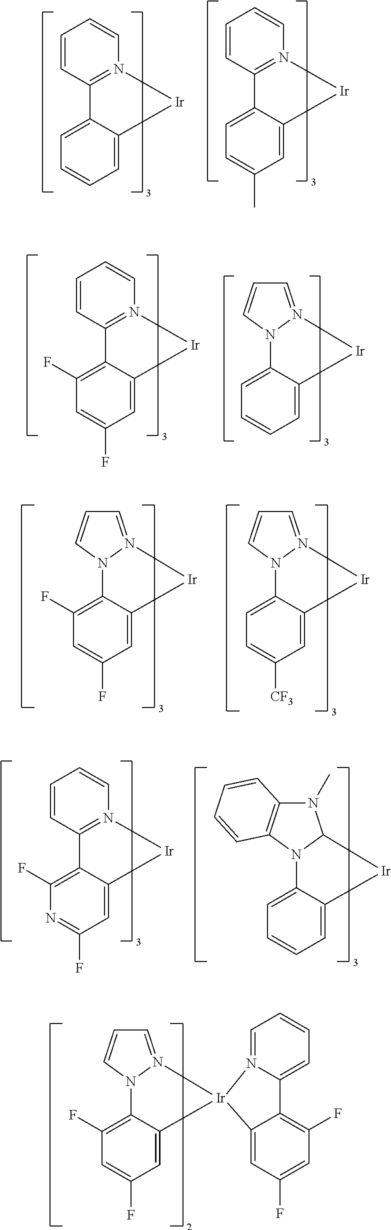

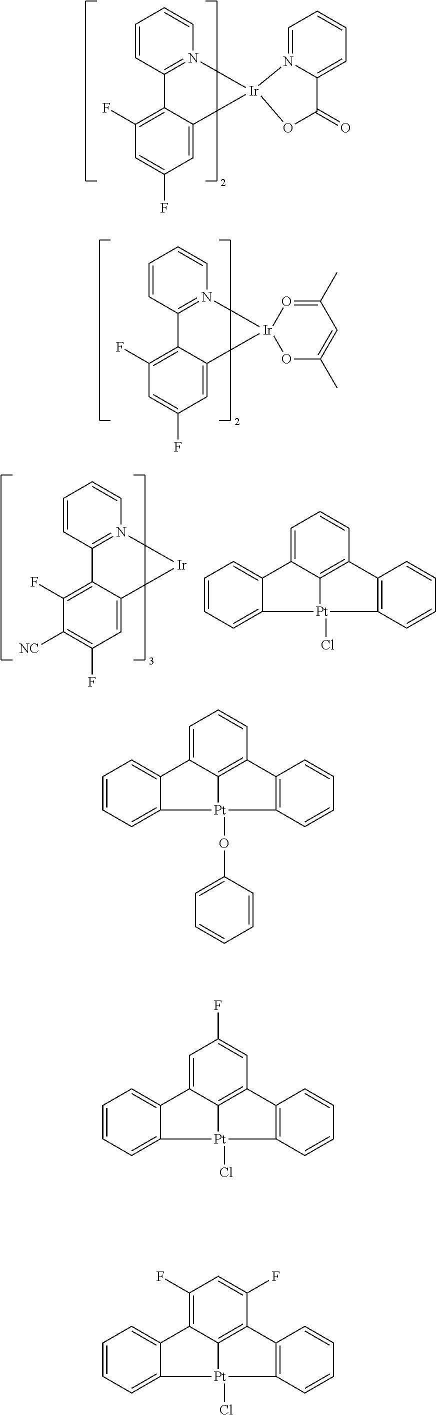

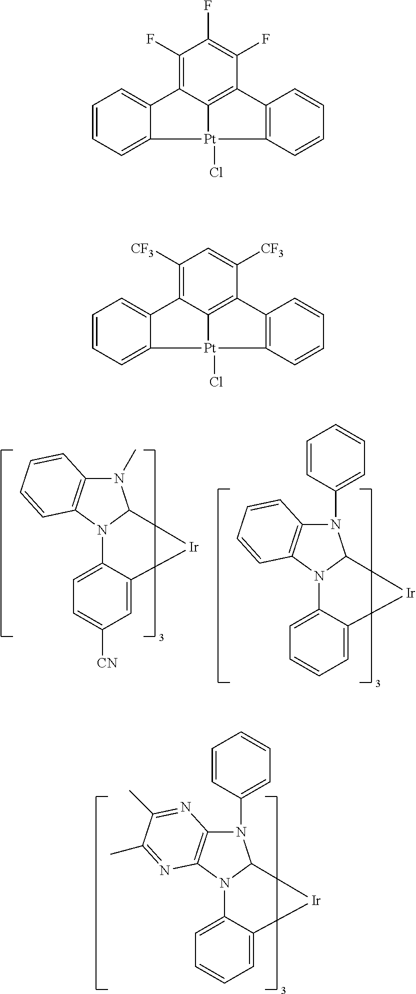

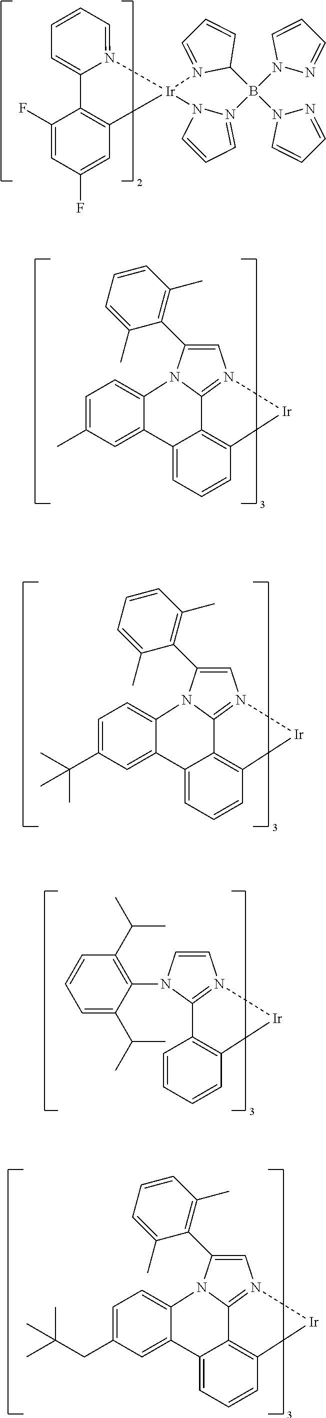

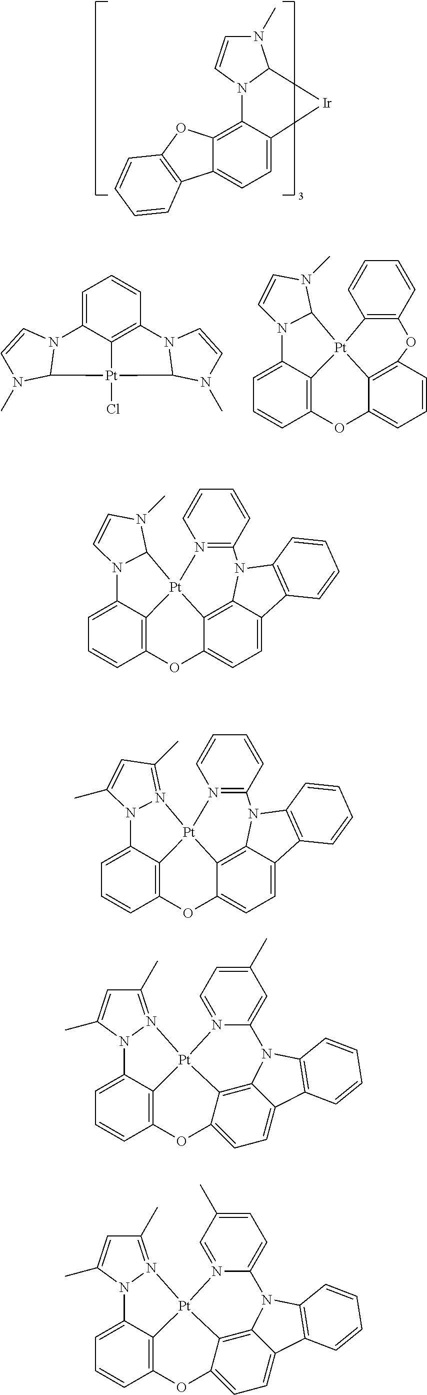

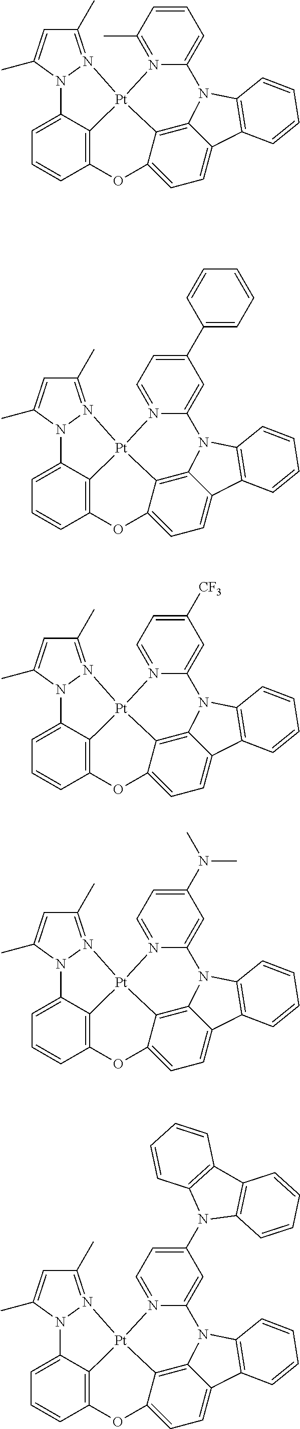

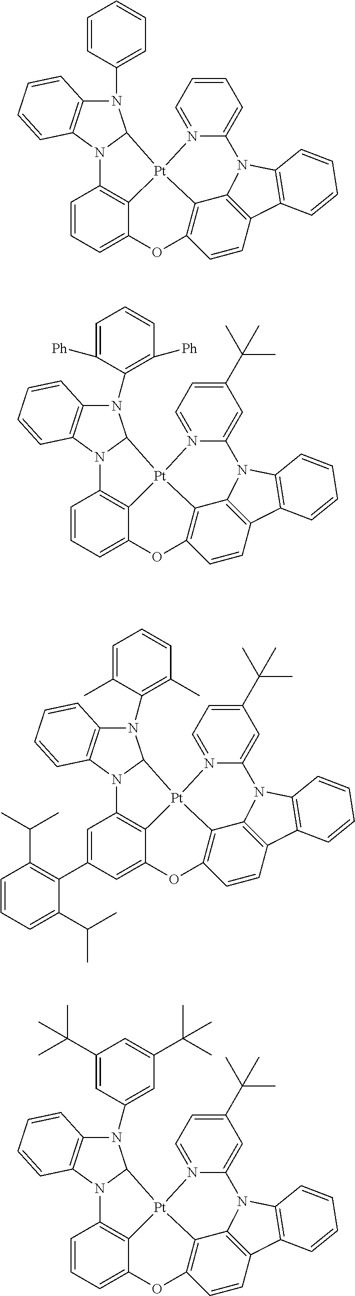

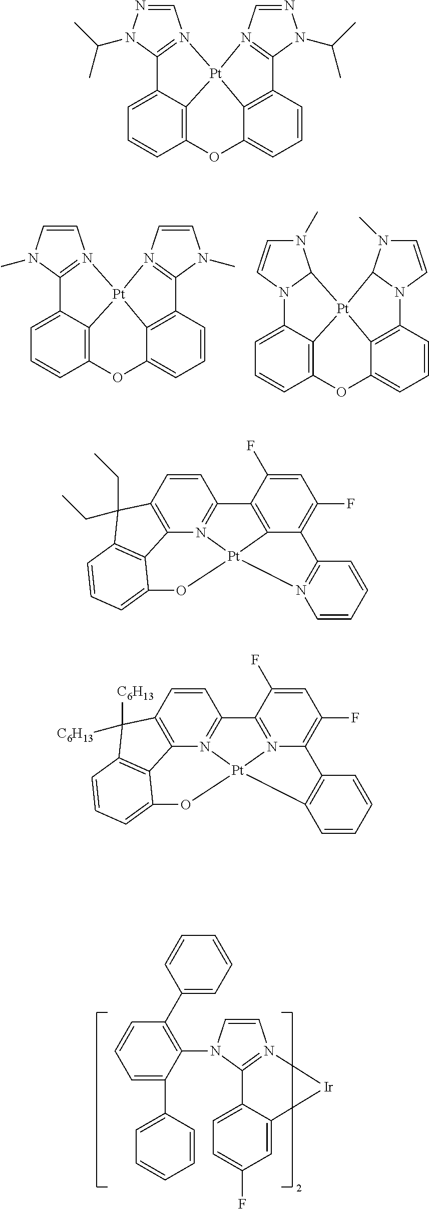

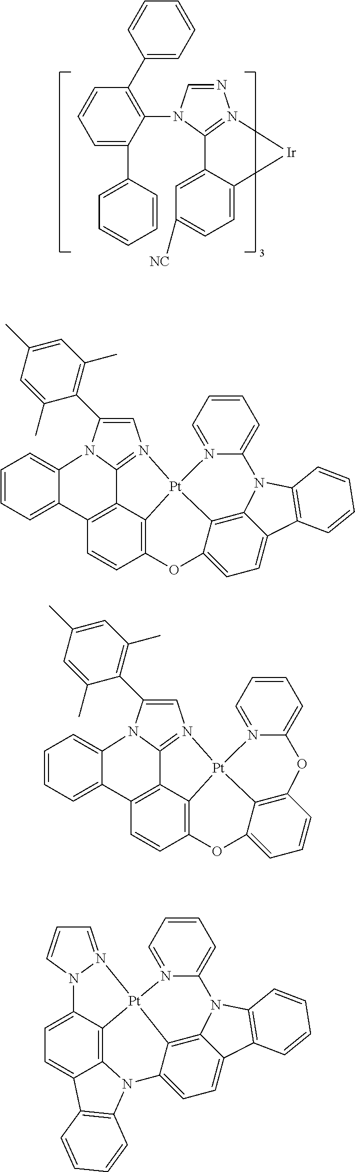

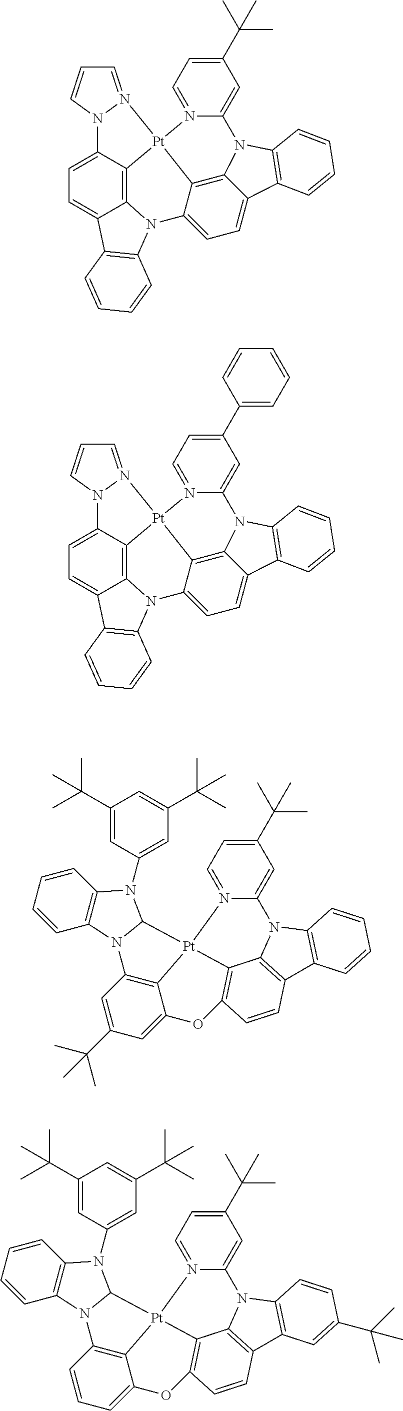

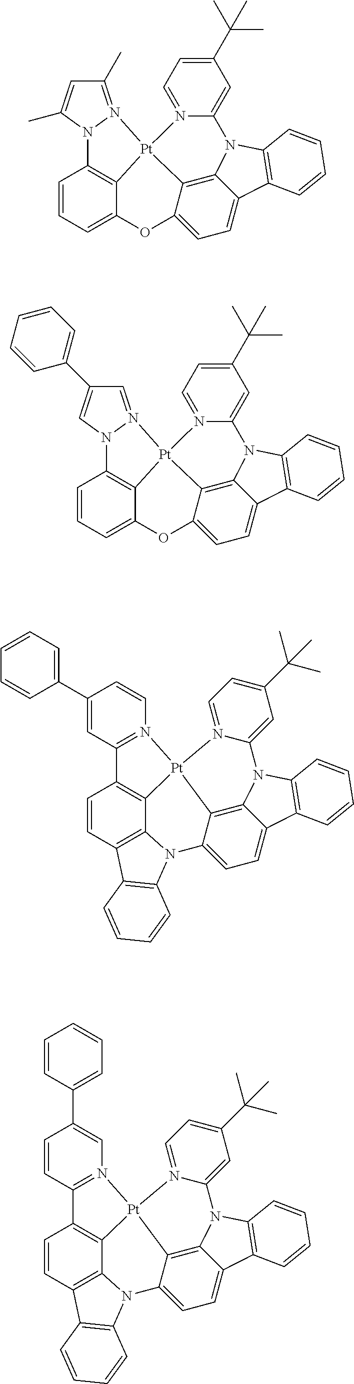

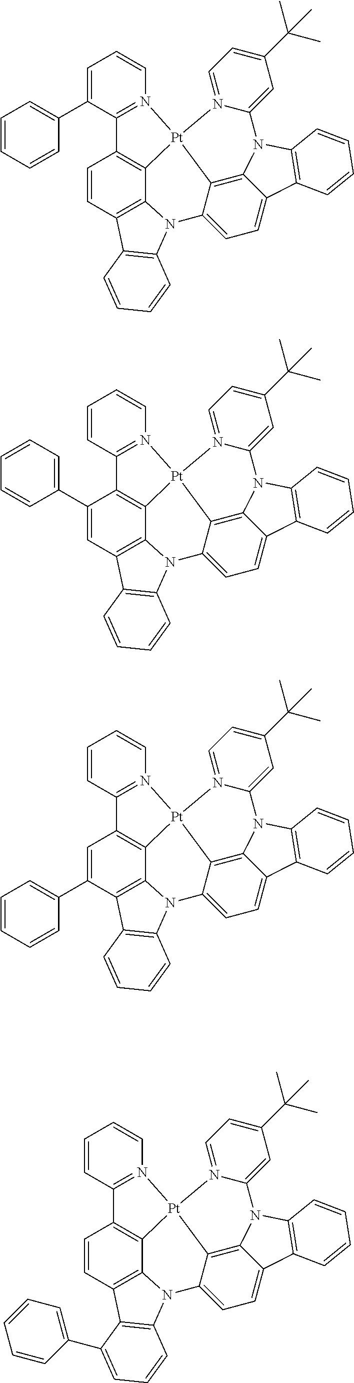

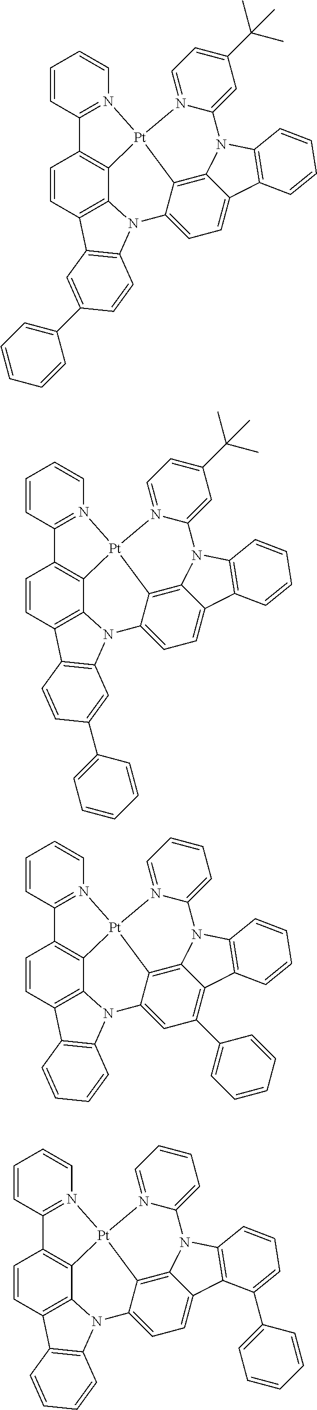

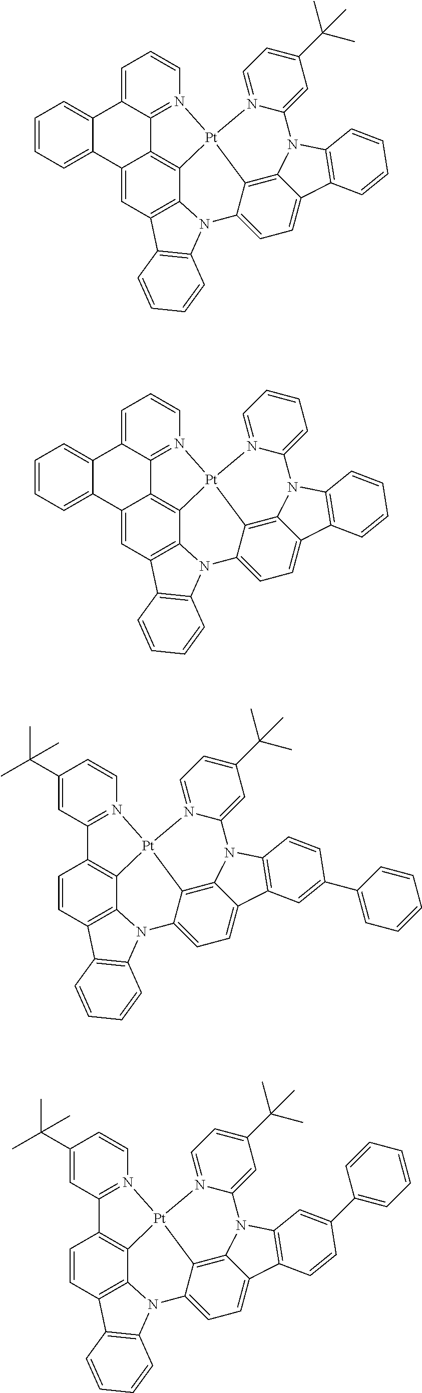

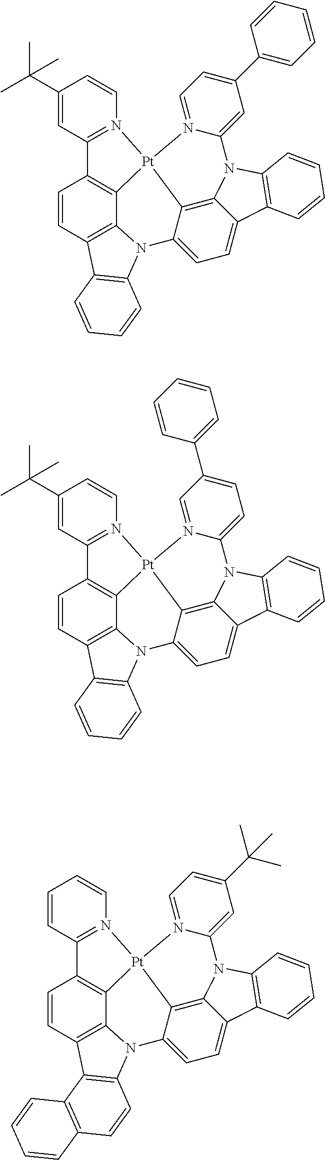

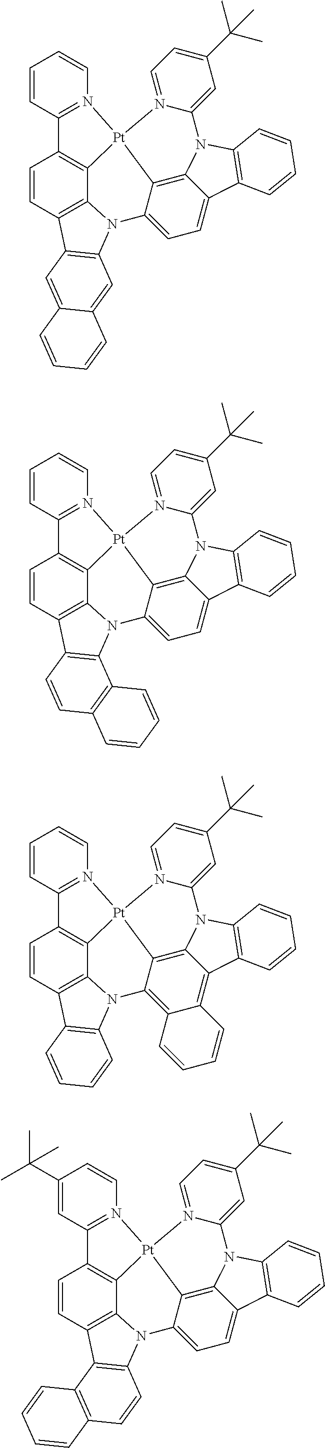

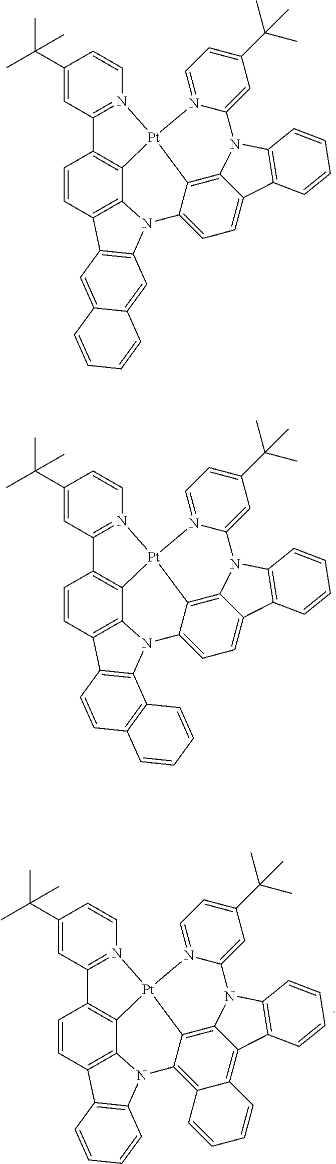

The phosphorescent material (phosphorescent compound) may be used alone or in combination of two or more.

The emission layer 4 may be a single layer consisting of a single material or a single layer consisting of a plurality of different materials. In addition, the emission layer 4 may have a multi-layered structure with multiple layers with the layers having same or different materials or a plurality of different materials.

The thickness of the emission layer 4 may be, but is not particularly limited to, in a range about 1 nm to about 100 nm, or for example, about 10 nm to about 30 nm.

The emission wavelength of the organic electroluminescent device 10 is not particularly limited. However, the organic electroluminescent device 10 may emit light having a peak in a wavelength range of 360 nm or more to 515 nm or less, 380 nm or more to 505 nm or less, 400 nm or more to 500 nm or less, 420 nm or more to 490 nm or less, or 430 nm or more to 480 nm or less. When the above ranges are satisfied, excellent luminescence, in particular, excellent blue luminescence may be obtained.

In addition, the FWHM of an emission spectrum of the organic electroluminescent device 10 may be about 30 nm or less, about 25 nm or less, about 20 nm or less, or about 10 nm, about 5 nm or more, or 0 nm or more. When the above ranges are satisfied, light emission with higher color purity may be obtained.

Examples of the film forming method of the emission layer 4 may include, but are not particularly limited to, known film forming methods such as vacuum deposition, spin coating, Langmuir-Blodgett (LB) deposition, ink-jet printing, laser printing, and laser-induced thermal imaging (LITI).

Hereinafter, each region and each layer other than the emission layer 4 will be described in detail.

The organic electroluminescent device 10 may include the substrate 1. A substrate that is used in a general organic electroluminescent device may be used as the substrate 1. For example, the substrate 1 may be a glass substrate, a silicon substrate, or a transparent plastic substrate having excellent mechanical strength, thermal stability, transparency, surface smoothness, ease of handling, and water repellency, but embodiments are not limited thereto.

The first electrode 2 may be arranged on the substrate 1. The first electrode 2 may be an anode and be formed of a material with a relatively high work function selected from a metal, an alloy, a conductive compound, and a combination thereof, for facilitating hole injection. The first electrode 2 may be a pixel electrode. The first electrode 2 may be a reflective electrode, a semi-transmissive electrode, or a transmissive electrode.

Materials for forming the first electrode 2 are not particularly limited. For example, when the first electrode 2 is a transparent electrode, the first electrode 2 may include indium tin oxide (ITO), indium zinc oxide (IZO), tin oxide (SnO₂), zinc oxide (ZnO), or indium tin zinc oxide (ITZO), each having excellent transparency and conductivity. When the first electrode 2 is a semi-transmissive or reflective electrode, the first electrode 2 may include Ag, Mg, Cu, Al, Pt, Pd, Au, Ni, Nd, Ir, Cr, Li, Ca, In, LiF/Ca, LiF/AI, Mo, Ti, or a mixture thereof (e.g., a mixture of Ag and Mg or a mixture of Mg and In).

The first electrode 2 may be a single layer consisting of a single material or a single layer consisting of a plurality of different materials. In one or more embodiments, the first electrode 2 may have a multi-layered structure having multiple layers consisting of various same or different materials.

The thickness of the first electrode 2 may be, but is not particularly limited to, about 10 nm or more and about 1,000 nm or less, or about 100 nm or more and about 300 nm or less.

The hole transport region 3 may be arranged on the first electrode 2.

The hole transport region 3 may include at least one of the hole injection layer 31, the hole transport layer 32, the electron blocking layer 33, and a hole buffer layer (not shown).

The hole transport region 3 may be a single layer consisting of a single material or a single layer consisting of a plurality of different materials. In one or more embodiments, the hole transport region 3 may have a multi-layered structure having multiple layers consisting of various same or different materials.

The hole transport region 3 may include the hole injection layer 31 only or the hole transport layer 32 only. In one or more embodiments, the hole transport region 3 may be a single layer including a hole injection material and a hole transport material. The hole transport region 3 may have a hole injection layer/hole transport layer structure, a hole injection layer/hole buffer layer structure, a hole injection layer/hole transport layer/hole buffer layer structure, or a hole injection layer/hole transport layer/electron blocking layer structure, wherein layers of each structure are sequentially stacked in the stated order from the first electrode 2.

Layers forming the hole injection layer 31 and other layers included in the hole transport region 3 are not particularly limited, and a known hole injection material and/or a hole transport material may be included.

Examples of the hole injection material may include a phthalocyanin compound such as copper phthalocyanin, N,N′-diphenyl-N,N′-bis-[4-phenyl-m-tril-amino)-phenyl]-biphenyl-4,4′-diamine (DNTPD), (4,4′,4″-tris(3-methylphenylphenylamino)triphenylamine) (m-MTDATA), 4,4′,4″-tris(N,N-diphenylamino)triphenylamine (TDATA), 4,4′,4″-tris{N,-(2-naphthyl)-N-phenyl amino}-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidin (NPB), polyetherketone including triphenylamine (TPAPEK), 4-isopropyl-4′-methyldiphenyliodonium tetrakis(pentafluorophenyl)borate, dipyrazino[2,3-f:2′,3′-h]quinoxaline-2,3,6,7,10,11-hexacarbonitrile (HAT-CN), 1,3,4,5,7,8-hexafluorotetracyano-2,6-naphthoquinodimethane (F6-TCNNQ), and the like.

Examples of the hole transport material may include N-phenylcarbazole, a carbazole-based derivative such as polyvinyl carbazole, a fluorene-based derivative, N,N′-bis(3-methylphenyl)-N,N′-diphenyl-[1,1-biphenyl]-4,4′-diamine (TPD), a triphenylamine-based derivative such as 4,4′,4″-tris(N-carbazolyl)triphenylamine (TCTA), N,N′-di(naphthalene-1-yl)-N,N′-diphenylbenzidine (NPB), 4,4′-cyclohexylidenbis[N,N-bis(4-methylphenyl)benzenamine] (TAPC), 4,4′-bis[N,N′-(3-tril)amino]-3,3′-dimethylbiphenyl (HMTPD), 1,3-bis(N-carbazolyl)benzene (mCP), Compound H1, Compound H2, Compound HT01, and the like:

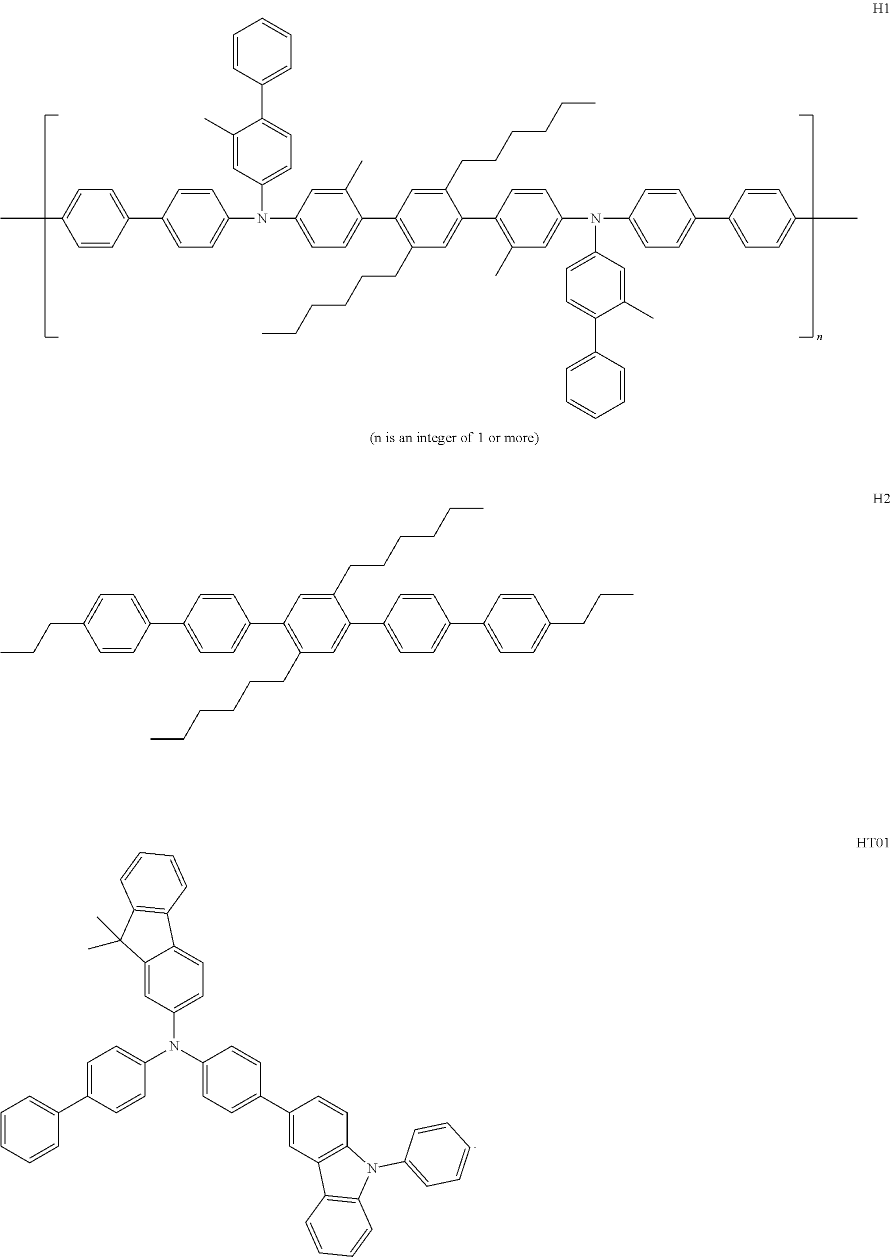

The hole transport region 3 may include, in addition to the materials described above, a charge generating material for improving conductive properties. The charge generating material may be homogeneously or non-homogeneously dispersed in the hole transport region 3.

The charge generating material is not particularly limited and may be, for example, a p-dopant. Examples of the p-dopant may include: a quinone derivative, such as tetracyanoquinodimethane (TCNQ) or 2,3,5,6-tetrafluoro-tetracyano-1,4-benzoquinonedimethane (F4-TCNQ); a metal oxide, such as a tungsten oxide or a molybdenum oxide; and a compound containing a cyano group, but are not limited thereto.

The hole buffer layer (not shown) may increase luminescence efficiency by compensating for an optical resonance distance according to the wavelength of light emitted by the emission layer 4. Materials included in the hole buffer layer (not shown) are not particularly limited, and a known hole buffer layer material may be used. For example, the compounds that may be included in the hole transport region 3 may be used.

The electron blocking layer 33 may prevent electron injection from the electron transport region 5 to the hole transport region 3. Materials included in the electron blocking layer 33 are not particularly limited, and a known electron blocking layer material may be used. For example, the host materials that may be included in the emission layer and Compound H-H1 as a host material may be included.

The thickness of the hole transport region 3 may be, but is not particularly limited to, about 1 nm or more and about 1,000 nm or less, or for example, about 10 nm or more and about 500 nm or less. In addition, the thickness of the hole injection layer 31 may be, but is not particularly limited to, about 3 nm or more and about 100 nm or less. The thickness of the hole transport layer 32 may be, but is not particularly limited to, about 3 nm or more and about 100 nm or less. The thickness of the electron blocking layer 33 may be, but is not particularly limited to, about 1 nm or more and about 100 nm or less. In addition, the thickness of the hole buffer layer (not shown) is not particularly limited, as long as the hole buffer layer may not adversely effect on functions of an organic electroluminescent device. When the thickness of the hole transport region 3, the hole injection layer 31, the hole transport layer 32, or the electron blocking layer 33 is within the above ranges, excellent hole transport characteristics may be obtained without a substantial increase in driving voltage.

Examples of the film forming method of the hole transport region 3 or each layer thereof may include, but are not particularly limited to, known film forming methods such as vacuum deposition, spin coating, LB deposition, ink-jet printing, laser printing, and LITI.

The emission layer 4 may be arranged on the hole transport region 3. The emission layer 4 may be the same as described above.

The electron transport region 5 may be arranged on the emission layer 4. The electron transport region 5 may include at least one of the hole blocking layer 53, the electron transport layer 52, and the electron injection layer 51.

The electron transport region 5 may be a single layer consisting of a single material or a single layer consisting of a plurality of different materials. In one or more embodiments, the electron transport region 5 may have a multi-layered structure having multiple layers consisting of various same or different materials.

The electron transport region 5 may include the electron transport layer 52 only or the electron injection layer 51 only. In one or more embodiments, the electron transport region 5 may be a single layer including an electron injection material and an electron transport material. The electron transport region 5 may have an electron transport layer/electron injection layer structure or a hole blocking layer/electron transport layer/electron injection layer structure, wherein layers of each structure are sequentially stacked in the stated order from the emission layer 4.

The electron injection layer 51 is not particularly limited and may include, for example, a known electron injection material. Examples of the electron injection layer material may include Yb, a lithium compound such as (8-hydroxyquinolinato)lithium (Liq) and lithium fluoride (LiF), sodium chloride (NaCl), cesium fluoride (CsF), rubidium fluoride (RbCl), lithium oxide (Li₂O), or barium oxide (BaO).

In one or more embodiments, the electron injection layer 51 may include an electron transport material and an insulating organic metal salt to be described below. The organic metal salt is not particularly limited and may be, for example, a material having an energy band gap of 4 eV or more. The organic metal salt may include, for example, an acetate metal salt, a benzoate metal salt, an acetate metal salt, an acetyl acetonate metal salt, a stearate metal salt, or the like.

The electron transport layer 52 is not particularly limited and may include, for example, a known electron transport material. Examples of the electron transport material may include an anthracene-based compound, tris(8-hydroxyquinolinolate)aluminum) (Alq₃), 1,3,5-tri[(3-pyridyl)-pen-3-yl]benzene, 2,4,6-tris(3′-pyridine-3-yl)biphenyl-3-yl)-1,3,5-triazine, 2-(4-(N-phenylbenzimidazolyl-1-ylphenyl)-9,10-dinaphthylanthracene, 1,3,5-tri(1-phenyl-1H-benzo[d]imidazole-2-yl)phenyl (TPBi), 2,9-dimethyl-4,7-diphenyl-1,10-phenanthroline (BCP), 4,7-diphenyl-1, 10-phenanthroline (Bphen), 3-(4-biphenyl)-4-phenyl-5-tert-butylphenyl-1,2,4-triazole (TAZ), 4-(naphthalene-1-yl)-3,5-diphenyl-4H-1,2,4-triazole (NTAZ), 2-(4-biphenyl)-5-(4-tert-butylphenyl)-1,3,4-oxadiazole (tBu-PBD), bis(2-methyl-8-quinolinolate-N1,O8)-(1,1′-biphenyl-4-orato)aluminum (BAIq), berylliumbis(benzoquinoline-10-orato) (Bebq2), 9,10-di(naphthalene-2-yl)anthracene (ADN), Iithum quinolate (LiQ), Compound ET1, and the like:

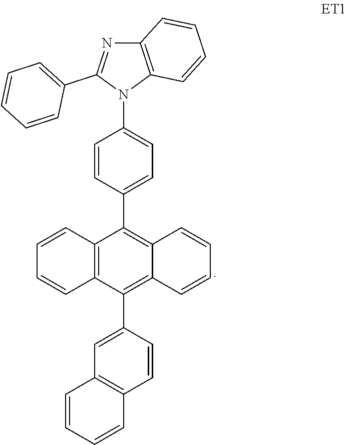 [SMILES: c1ccc(-c2nc3ccccc3n2-c2ccc(-c3c4ccccc4c(-c4ccc5ccccc5c4)c4ccccc34)cc2)cc1]

The hole blocking layer 53 may prevent hole injection from the hole transport region 3 to the electron transport region 5. Materials included in the hole blocking layer 53 are not particularly limited, and a known hole blocking material may be used. The hole blocking layer 53 may include, for example, 2,9-dimethyl-4,7-diphenyl-1,10-phenanthroline (BCP), 4,7-diphenyl-1,10-phenanthroline (Bphen), and the like. In addition, examples of the hole blocking material may include the host materials that may be included in the emission layer, and Compound H-E1 as a host material.

The thickness of the electron transport region 5 may be, but is not particularly limited to, about 0.1 nm or more and about 210 nm or less, or for example, about 100 nm or more and about 150 nm or less. The thickness of the electron transport layer 52 may be, but is not particularly limited to, about 10 nm or more and about 100 nm or less, or for example, about 15 nm or more and about 50 nm or less. The thickness of the hole blocking layer 53 may be, but is not particularly limited to, about 10 nm or more and about 100 nm or less, or for example, about 15 nm or more and about 50 nm or less. The thickness of the electron injection layer 51 may be, but is not particularly limited to, about 0.1 nm or more and about 10 nm or less, or for example, about 0.3 nm or more and about 9 nm or less. When the thickness of the electron injection layer 51 is within the above ranges, excellent electron injection characteristics may be obtained without a substantial increase in driving voltage. In addition, when the thickness of the electron transport region 5, the electron injection layer 51, the electron transport layer 52, or the hole blocking layer 53 is within the above ranges, excellent hole transport characteristics may be obtained without a substantial increase in driving voltage.

Examples of the film forming method of the electron transport region 5 and each layer thereof may include, but are not particularly limited to, known film forming methods such as vacuum deposition, spin coating, LB deposition, ink-jet printing, laser printing, and LITI.

The second electrode 6 may be arranged on the electron transport region 5. The second electrode 6 may be a cathode and be formed of a material with a relatively low work function selected from a metal, an alloy, or a conductive compound, for facilitating electron injection. The second electrode 6 may be a common electrode. The second electrode 6 may be a reflective electrode, a semi-transmissive electrode, or a transmissive electrode. The second electrode 6 may have a single-layered structure or a multi-layered structure including two or more layers.

Materials for forming the second electrode 6 are not particularly limited. For example, when the second electrode 6 is a transparent electrode, the second electrode 6 may include a transparent metal oxide, for example, ITO, IZO, ZnO, or ITZO. When the second electrode 6 is a semi-transmissive or reflective electrode, the second electrode 6 may include Ag, Mg, Cu, Al, Pt, Pd, Au, Ni, Nd, Ir, Cr, Li, Ca, In, LiF/Ca, LiF/, Mo, Ti, or a mixture thereof (e.g., a mixture of Ag and Mg or a mixture of Mg and In).

The second electrode 6 may be a single layer consisting of a single material or a single layer consisting of a plurality of different materials. In one or more embodiments, the second electrode 6 may have a multi-layered structure having multiple layers consisting of various or same different materials.

The thickness of the second electrode 6 may be, but is not particularly limited to, about 10 nm or more and about 1,000 nm or less.

The second electrode 6 may be further connected to an auxiliary electrode (not shown). When the second electrode 6 is connected to the auxiliary electrode, the resistance of the second electrode 6 may be further reduced.

A capping layer (not shown) may be further arranged on the second electrode 6. The capping layer (not shown) is not particularly limited and may include, for example, α-NPD, NPB, TPD, m-MTDATA, Alq₃, CuPc, N4,N4,N4′,N4′-tetra(phenyl-4-yl)biphenyl-4,4′-diamine (TPD15), TCTA, N,N′-bis(naphthalene-1-yl), and the like.

In addition, a stacking structure of the organic electroluminescent device 10 according to an embodiment is not limited to the above descriptions. The organic electroluminescent device 10 according to an embodiment may have a different stacking structure known in the art. For example, the organic electroluminescent device 10 may not include at least one selected from the hole injection layer 31, the hole transport layer 32, the electron transport layer 52, and the electron injection layer 51, or may further include another layer. In addition, each layer of the organic electroluminescent device 10 may be formed as a single layer or as multiple layers.

Methods of forming each layer of the organic electroluminescent device 10 according to an embodiment are not particularly limited. For example, various methods such as vacuum deposition, solution coating, laser printing, LB deposition, and LITI may be used in forming each layer thereof.

The solution coating may include spin coating, casting, micro-gravure coating, gravure coating, bar coating, roll coating, wire bar coating, dip coating, spray coating, screen printing, flexographic printing, offset printing, ink-jet printing, and the like.

The vacuum deposition may be performed at a deposition temperature in a range of about 100° C. to about 500° C., at a vacuum degree in a range of about 10⁻⁸ torr to about 10⁻³ torr, and at a deposition rate in a range of about 0.01 nm per second (nm/sec) to about 10 nm/sec, though the conditions may vary depending on a compound that is used and a structure and thermal properties of a desired layer.

In an embodiment, the first electrode 2 may be an anode, and the second electrode 6 may be a cathode.

For example, as indicated in FIG. 3, the first electrode 2 may be an anode, the second electrode 6 may be a cathode, and an organic layer may include the emission layer 4 between the first electrode 2 and the second electrode 6 and may further include a hole transport region 3 between the first electrode 2 and the emission layer 4 and an electron transport region 5 between the emission layer 4 and the second electrode 6, wherein the hole transport region 3 may include at least one selected from the hole injection layer 31, the hole transport layer 32, a hole buffer layer, and an electron blocking layer, and the electron transport region 5 may include at least one selected from a hole blocking layer, the electron transport layer 52, and the electron injection layer 51.

In one or more embodiments, the first electrode 2 may be a cathode, and the second electrode 6 may be an anode.

The material constituting each layer and each electrode may be used alone or in combination of two or more.

In the organic electroluminescent device 10, the condensed cyclic compound or the material for an organic electroluminescent device may be included in the emission layer 4, but may also be included in organic layers other than the emission layer 4. In addition, the condensed cyclic compound or the material for an organic electroluminescent device may be included in the emission layer 4 and in organic layers other than the emission layer 4.

In the organic electroluminescent device 10 of, when a voltage is applied across the first electrode 2 and the second electrode 6, holes provided from the first electrode 2 may move toward the emission layer 4 through the hole transport region 3, and electrons provided from the second electrode 6 may move toward the emission layer 4 through the electron transport region 5. The holes and the electrons may recombine in the emission layer 4 to produce excitons, and these excitons may transition from an excited state to a ground state to thereby generate light.

In addition, the following embodiments are also included in the scope of the disclosure:

1. a condensed cyclic compound represented by Formula 1;

2. a condensed cyclic compound represented by Formula 2;

3. a condensed cyclic compound represented by one of Formulae 1-1 to 1-53;

4. a condensed cyclic compound represented by Formula 3;

5. a condensed cyclic compound represented by Formula 4;

6. a condensed cyclic compound represented by one of Formulae 2-1 to 2-172;

7. a material for an organic electroluminescent device including the condensed cyclic compound described in one of Embodiments 1 to 6;

8. an organic electroluminescent device including the condensed cyclic compound described in one of Embodiments 1 to 6;

9. the organic electroluminescent device described in Embodiment 8, wherein the organic layer further includes a TADF material or a phosphorescent material;

10. the organic electroluminescent device described in Embodiment 9, wherein the phosphorescent material is a platinum complex; and

11. the organic electroluminescent device described in one of Embodiments 8 to 10, wherein the organic layer is an emission layer.

Hereinbefore, the organic electroluminescent device 10 has been described with reference to FIGS. 1 to 3, but embodiments are not limited thereto. In addition, the disclosure will be described in more detail by using the following Examples and Comparative Examples, but the technical scope of the disclosure is not limited thereto.

### SYNTHESIS EXAMPLES

Compound 1-19 was synthesized as follows.

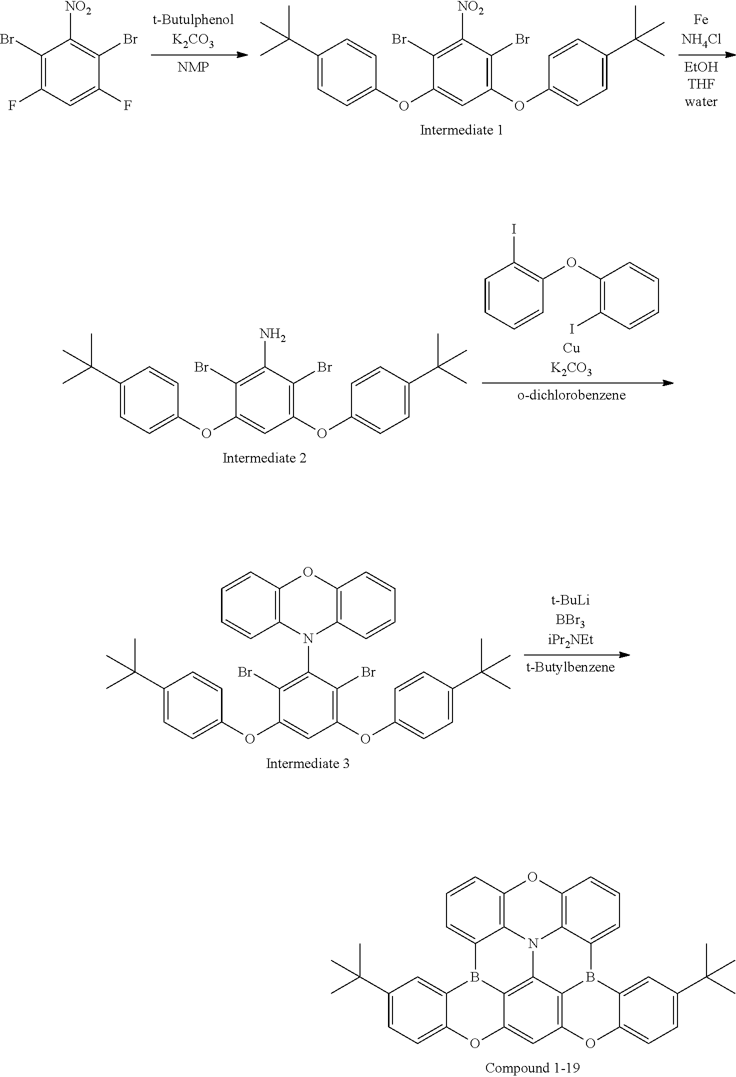

### (1) Synthesis of Intermediate 1

2,4-dibromo-1,5-difluoro-3-nitrobenzene (10.0 g, 31.6 mmol), 4-tert-butylphenol (10.0 g, 66.6 mmol), and potassium carbonate (18.4 g, 1 33 mmol) were added to a 300 mL branched flask and dissolved in N-methyl-2-pyrrolidone (NMP) (130 mL). The reaction solution was heated and stirred at 100° C. for 6 hours and then cooled to room temperature. The reaction solution was added to water (200 mL), and the precipitated solid was extracted by filtration. The product was subjected to silica gel column chromatography to obtain Intermediate 1.

### (2) Synthesis of Intermediate 2

Intermediate 1 (15.0 g, 17.3 mmol) was added to a 300 mL branched flask and dissolved in ethanol (35 mL), tetrahydrofuran (THF) (17 mL), and water (8 mL). Reduced iron (4.83 g, 86.6 mmol) and ammonium chloride (4.63 g, 86.6 mmol) were added thereto, and the reaction solution was heated and stirred at 100° C. for 5 hours and then cooled to room temperature. After removing the solvent from the reaction solution by distillation, water and ethyl acetate were added thereto. Then, an aqueous layer was separated therefrom, and an extraction process was performed on the aqueous layer by using ethyl acetate. After drying the extracted organic layer with anhydrous magnesium sulfate, the solvent was removed therefrom by distillation to obtain Intermediate 2.

### (3) Synthesis of Intermediate 3

Intermediate 2 (1.00 g, 1.83 mmol), 1,1′-oxybis[2-iodobenzene] (0.81 g, 1.92 mmol), copper (0.232 g, 3.65 mmol) and potassium carbonate (0.56 g, 4.02 mmol) were added to a 100 mL branched flask and dissolved in orthodichlorobenzene (10 mL). The reaction solution was heated and stirred at 190° C. for 20 hours and then cooled to room temperature. After filtering out the insolubles, the solvent was removed from the filtrate solution by distillation. The resulting product was filtered by silica gel column chromatography to obtain Intermediate 3.

### (4) Synthesis of Compound 1-19

Intermediate 3 (0.80 g, 1.12 mmol) was added to a 100 mL branched flask and dissolved in t-butylbenzene (50 mL). After cooling the reaction solution to −30° C., n-butyllithium (2.6 M hexane solution, 0.94 mL, 2.47 mmol) was added dropwise to the flask, followed by stirring at room temperature for 1 hour. After cooling the reaction solution to −30° C., boron tribromide (0.61 g, 2.47 mmol) was added to the flask, followed by stirring at room temperature for 1 hour. After adding diisopropylethylamine (0.97 mL, 5.61 mmol), the reaction solution was heated under reflux for 12 hours. After cooling to room temperature and filtering out the precipitated solid, the product solution was purified by silica gel column chromatography to obtain 0.03 g of Compound 1-19.

The structure of Compound 1-19 may be identified by a known method (e.g., NMR, LC-MS, etc.). As a specific example, the results of identifying the structure of Compound 1-19 by LC-MS measurement are as follows: MS (APCI): 572 ([M+H]+).

### Synthesis Example of Compound 2-143

Compound 2-143 was synthesized as follows.

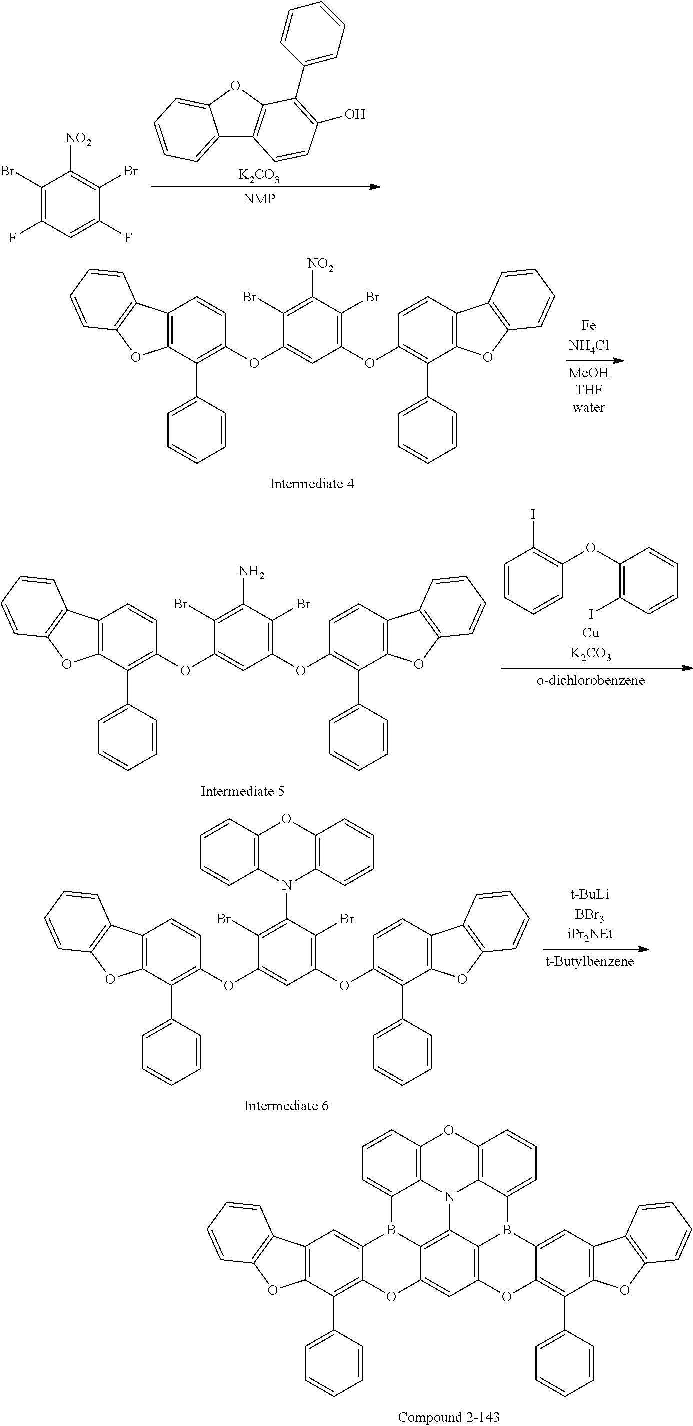

### (1) Synthesis of Intermediate 4

Intermediate 4 was obtained in the same manner as used to synthesize Intermediate 1, except that 4-tert-butylphenol was changed to 4-phenyl-3-dibenzofuranol.

### (2) Synthesis of Intermediate 5

Intermediate 5 was obtained in the same manner as used to synthesize Intermediate 2, except that Intermediate 1 was changed to Intermediate 4.

### (3) Synthesis of Intermediate 6

Intermediate 6 was obtained in the same manner as used to synthesize Intermediate 3, except that Intermediate 2 was changed to Intermediate 5.

### (4) Synthesis of Compound 2-143

0.10 g of Compound 2-143 was obtained in the same manner as used to synthesize Compound 1-19, except that Intermediate 3 was changed to Intermediate 6.

### Other Condensed Cyclic Compounds According to Disclosure

In addition, condensed cyclic compounds according to the disclosure other than the above compounds have the same or similar skeletal structure as each of the above compounds, and thus may be synthesized by appropriately changing raw materials or reaction conditions used in each synthesis method described above, or by appropriately combining the above synthesis methods and known synthesis methods.

### Simulation Evaluation of Condensed Cyclic Compound

According to “High-Performance Dibenzoheteraborin-Based Thermally Activated Delayed Fluorescence Emitters: Molecular Architectonics for Concurrently Achieving Narrowband Emission and Efficient Triplet-Singlet Spin Conversion,” In Seob Park, Kyohei Matsuo, Naoya Aizawa, and Takuma Yasuda, Advanced Functional Materials 2018, 28, 1802 031, the spectrum width of fluorescence (the FWHM of the fluorescence spectrum peak) has a close relationship with the reorganization energy [E(S₀@S₁)−E(S₀@S₀)] that is expressed by the difference between the ground state (S₀) energy of the stable structure in the first excited singlet state (S₁) [E(S₀@S₁)] and the ground state (S₀) energy of the stable structure in the ground state (S₀) [E(S₀@S₀)].

### Identification of Relationship Between Reorganization Energy and Spectrum Width of Fluorescence

First, the relationship between the reorganization energy [E(S₀@S₁)−E(S₀@S₀)] and the spectrum width (FWHM) of fluorescence was identified as follows.

### Calculation by DFT

For Condensed Cyclic Compounds R1 to R3 known in the art, the following calculations were performed by the DFT.

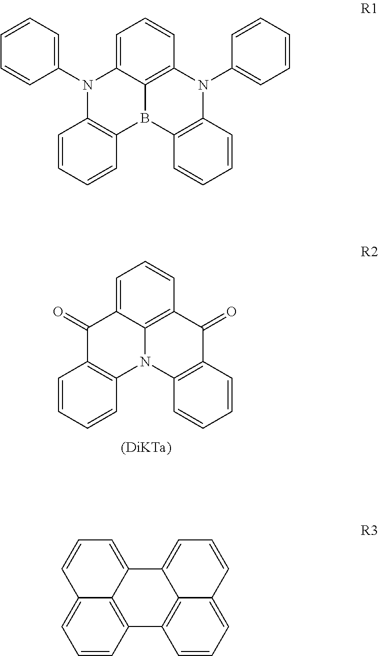

The ground state (S₀) energy of the stable structure in the first excited singlet state (S₁) [E(S₀@S₁)] and the ground state (S₀) energy of the stable structure in the ground state (S₀) [E(S₀@S₀)] were calculated, and from the difference therebetween, the reorganization energy [E(S₀@S₁)]−[E(S₀@S₀)] (eV) was calculated.

In addition, the first excited singlet state (S₁) energy of the stable structure in the first excited singlet state (S₁) [E(S₁@S₁)] was calculated, and from the difference between this value and the ground state (S₀) energy of the stable structure in the ground state (S₀) [E(S₀@S₀)], the adiabatic first excited singlet state (S₁) energy [E(S₁@S₁)]-[E(S₀@S₀)](eV) was calculated.

Then, the fluorescence wavelength (nm) obtained by converting the adiabatic first excited singlet state (S₁) energy into a light wavelength (nm) was calculated.

In addition, the oscillator strength f of the stable structure in the first excited singlet state (S₁) was calculated.

In addition, the HOMO energy and the LUMO energy were calculated.

In this regard, the calculation by the DFT was performed according to the following calculation methods (I), (II), and (III) by using Gaussian 16 (Gaussian Inc.) as calculation software:

(I) S₀ calculation method: structural optimization calculation by DFT including functional B3LYP, basis function 6-31 G(d, p), and toluene solvent effect (PCM);

(II) S₁ calculation method: structural optimization calculation by time-dependent DFT (TDDFT) including functional B3LYP, basis function 6-31 G(d, p), and toluene solvent effect (PCM); and

(III) S₀ calculation method: calculation on input structure by DFT including functional B3LYP, basis function 6-31 G(d, p), and toluene solvent effect (PCM).

In detail, the calculation of each item was performed using the following calculation methods:
Ground state (S₀) energy of stable structure in ground state (S₀) [E(S₀@S₀)]: Calculation method (I);
First excited singlet state (S₁) energy of stable structure in first excited singlet state (S₁) [E(S₁@S₁)]: Calculation method (II);
Ground state (S₀) energy of stable structure in first excited singlet state (S₁) [E(S₀@S₁)]: Calculation methods (II) and (III);
Reorganization energy [E(S₀@S₁)]−[E(S₀@S₀)]: Calculation methods (I), (II), and (III);
Adiabatic first excited singlet state (S₁) energy [E(S₁@S₁)]−[E(S₀@S₀)]: Calculation methods (I) and (II);
Fluorescence wavelength (nm): Calculation methods (I) and (II);
Oscillator strength f of stable structure in first excited singlet state (S₁): Calculation method (II); and
HOMO and LUMO: Calculation method (I).

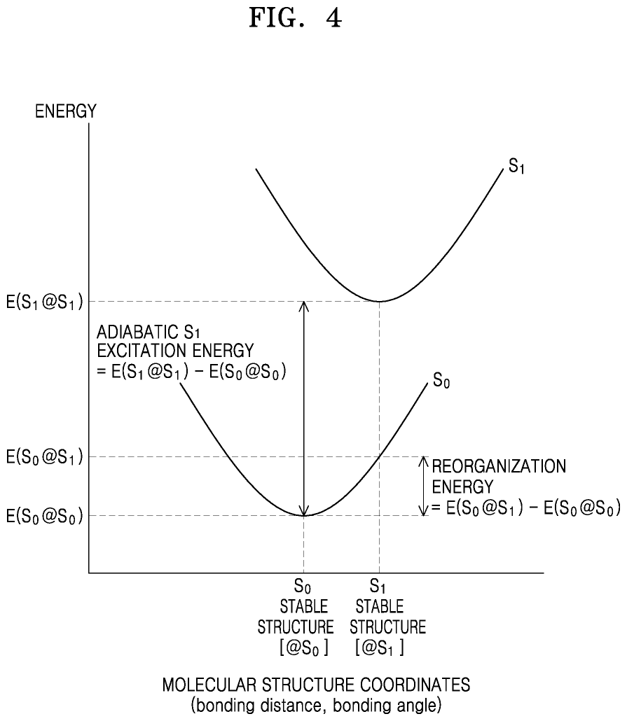

FIG. 4 is an explanatory diagram qualitatively illustrating each energy relationship. The results are shown in Table 1.

### Measurement of Spectrum Width (FWHM) of Fluorescence

For each of toluene solutions respectively including Condensed Cyclic Compounds R¹ to R³ at a concentration of 1×10⁻⁵M (=mol/dm³, mol/L), the peak wavelength (nm) of fluorescence in PL and the spectrum width of fluorescence (the FWHM of the fluorescence spectrum peak) were evaluated by measuring at room temperature with an excitation wavelength of 320 nm using the spectrofluorophotometer F-7000 manufactured by Hitachi High-Tech Co., Ltd. The results are shown in Table 1.

TABLE 1

| | Calculation by DFT | | | | | | | |
|---|---|---|---|---|---|---|---|---|
| | | | Adiabatic | | | | | |
| | | | first | | | | | |
| | | | excited | | | | | |
| | | | singlet | | Reorgani- | | Found | |
| | | | state (S₁) | Oscillator | zation | Fluorescence | PL peak | PL |
| | HOMO | LUMO | energy | strength | energy | wavelength | wavelength | FWHM |
| Comp. | (eV) | (eV) | (eV) | f | (eV) | (nm) | (nm) | (nm) |
| R1 | −4.88 | −1.23 | 2.99 | 0.214 | 0.109 | 415 | 453 | 22 |
| R2 | −5.94 | −2.36 | 2.96 | 0.161 | 0.132 | 419 | 451 | 26 |
| R3 | −5.02 | −1.96 | 2.62 | 0.491 | 0.164 | 474 | 445 | 42 |

From the results of Table 1, it was confirmed that the color of the fluorescence wavelength (nm) calculated by the DFT and the measured peak wavelength showed values close to each other to a certain extent. From these results, it was confirmed that the color estimated by the calculation by the DFT and the color measured were colors of the same kind.

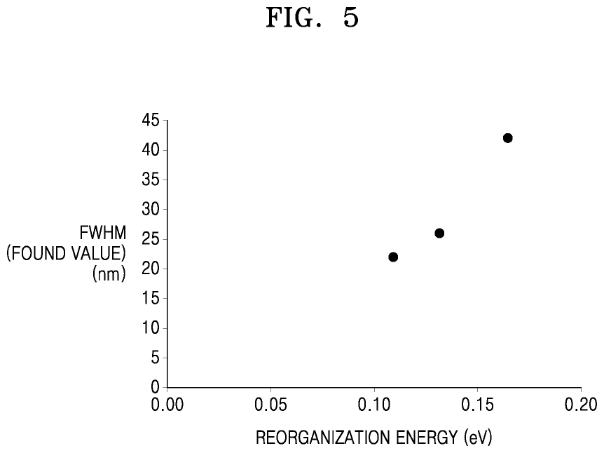

In this regard, a graph of the FWHM of fluorescence in PL measured in Condensed Cyclic Compounds R¹ to R³ versus the reorganization energy (eV) calculated by the DFT is shown in FIG. 5. From the results of FIG. 5, it was confirmed that there was a relationship between the reorganization energy (eV) calculated by the DFT and the FWHM of fluorescence, wherein the smaller the reorganization energy (eV), the narrower the FWHM of fluorescence, that is, the narrower the spectrum width of fluorescence.

### Calculation of Oscillator Strength f, Reorganization Energy, and Fluorescence Wavelength of Compounds of Disclosure and Comparative Compound R1

For each of Compounds 1-6, 1-11, 1-12, 1-18, and 1-19 of the disclosure and Comparative Compound R1, the HOMO (eV), LUMO (eV), adiabatic first excited singlet state (S₁) energy (eV), fluorescence wavelength (nm), oscillator intensity f, and reorganization energy (eV) were calculated, as described above in the section [Identification of relationship between reorganization energy and spectrum width of fluorescence]. The results are shown in Table 2.

TABLE 2

| | | | | Adiabatic | | | |
|---|---|---|---|---|---|---|---|
| | | | | first | | | |
| | | | | excited | | | |
| | | | | singlet | | | Fluores- |
| | | | | state | Oscil- | Reorgani- | cence |
| | | | | (S₁) | lator | zation | wave- |
| | | HOMO | LUMO | energy | strength | energy | length |
| Comp. | Structure | (eV) | (eV) | (eV) | f | (eV) | (nm) |
| 1-6 | 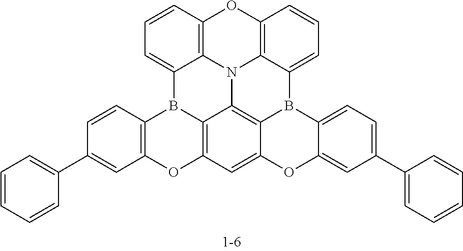 [SMILES: c1ccc(-c2ccc3c(c2)Oc2cc4c5c6c2B3c2cccc3c2N6c2c(cccc2B5c2ccc(-c5ccccc5)cc2O4)O3)cc1] | −5.12 | −1.76 | 2.73 | 0.464 | 0.077 | 454 |
| 1-11 | 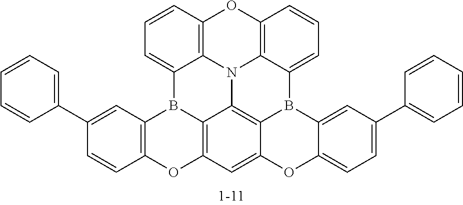 [SMILES: c1ccc(-c2ccc3c(c2)B2c4cccc5c4N4c6c(cccc6B6c7cc(-c8ccccc8)ccc7Oc7cc(c2c4c76)O3)O5)cc1] | −5.16 | −1.77 | 2.76 | 0.455 | 0.071 | 449 |
| 1-12 | 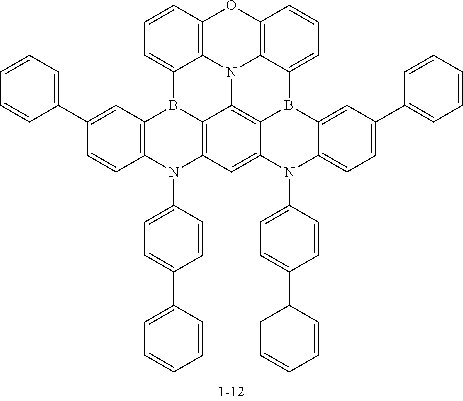 [SMILES: C1=CCC(c2ccc(N3c4ccc(-c5ccccc5)cc4B4c5cccc6c5N5c7c(cccc7B7c8cc(-c9ccccc9)ccc8N(c8ccc(-c9ccccc9)cc8)c8cc3c4c5c87)O6)cc2)C=C1] | −4.76 | −1.36 | 2.80 | 0.602 | 0.052 | 442 |
| 1-18 | 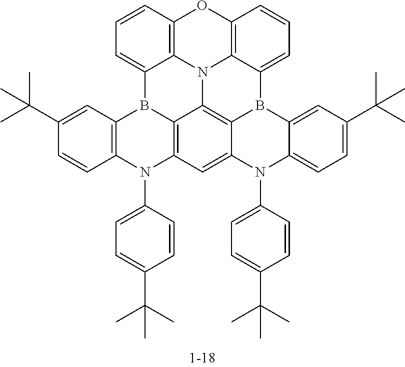 [SMILES: CC(C)(C)c1ccc(N2c3ccc(C(C)(C)C)cc3B3c4cccc5c4N4c6c(cccc6B6c7cc(C(C)(C)C)ccc7N(c7ccc(C(C)(C)C)cc7)c7cc2c3c4c76)O5)cc1] | −4.66 | −1.20 | 2.85 | 0.404 | 0.065 | 435 |
| 1-19 | 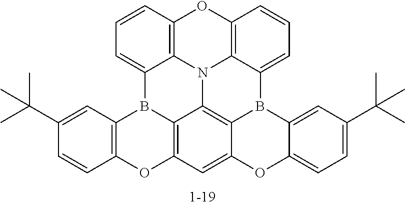 [SMILES: CC(C)(C)c1ccc2c(c1)B1c3cccc4c3N3c5c(cccc5B5c6cc(C(C)(C)C)ccc6Oc6cc(c1c3c65)O2)O4] | −5.08 | −1.66 | 2.80 | 0.394 | 0.075 | 443 |
| R1 | 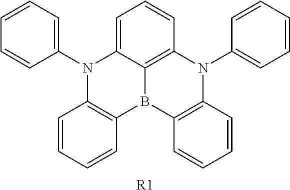 | −4.88 | −1.23 | 2.99 | 0.214 | 0.109 | 415 |

For each of Compounds 2-117, 2-143, 2-161, 2-169, 2-120, and 2-22 of the disclosure and Comparative Compound R1, the HOMO (eV), LUMO (eV), adiabatic first excited singlet state (S₁) energy (eV), fluorescence wavelength (nm), oscillator intensity f, and reorganization energy (eV) were calculated, as described above in the section [identification of relationship between reorganization energy and spectrum width of fluorescence]. The results are shown in Table 3.

TABLE 3

| | | | | Adiabatic | | | |
|---|---|---|---|---|---|---|---|
| | | | | first | | | |
| | | | | excited | | | Fluores- |
| | | | | singlet | Oscil- | Reorgani- | cence |
| | | | | state (S₁) | lator | zation | wave- |
| | | HOMO | LUMO | energy | strength | energy | length |
| Comp. | Structure | (eV) | (eV) | (eV) | f | (eV) | (nm) |
| 2-117 | 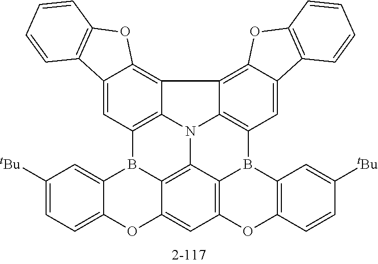 [SMILES: CC(C)(C)c1ccc2c(c1)B1c3c(cc4c5c3-n3c6c1cc1c7ccccc7oc1c6c1c6oc7ccccc7c6cc(c13)B5c1cc(C(C)(C)C)ccc1O4)O2] | −5.00 | −1.59 | 2.79 | 0.288 | 0.084 | 444 |
| 2-143 | 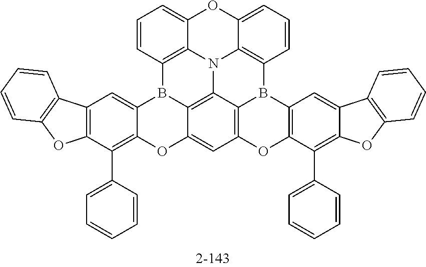 [SMILES: c1ccc(-c2c3c(cc4c2oc2ccccc24)B2c4cccc5c4N4c6c(cccc6B6c7cc8c(oc9ccccc98)c(-c8ccccc8)c7Oc7cc(c2c4c76)O3)O5)cc1] | −5.15 | −1.81 | 2.72 | 0.550 | 0.069 | 455 |
| 2-161 | 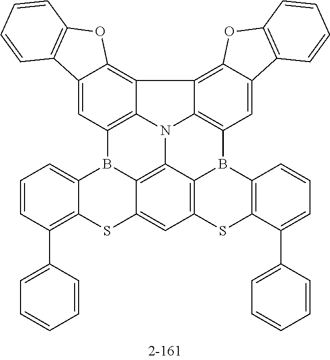 [SMILES: c1ccc(-c2cccc3c2Sc2cc4c5c6c2B3c2cc3c7ccccc7oc3c3c7c8oc9ccccc9c8cc(c7n-6c23)B5c2cccc(-c3ccccc3)c2S4)cc1] | −5.32 | −1.96 | 2.73 | 0.251 | 0.068 | 454 |
| 2-169 | 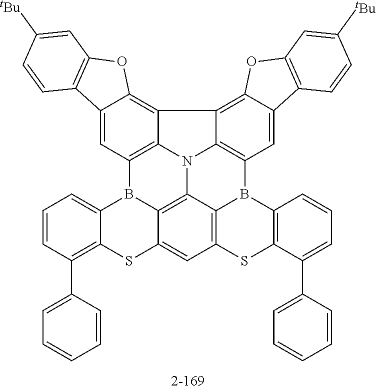 [SMILES: CC(C)(C)c1ccc2c(c1)oc1c2cc2c3c1c1c4oc5cc(C(C)(C)C)ccc5c4cc4c1n3-c1c3c(cc5c1B4c1cccc(-c4ccccc4)c1S5)Sc1c(cccc1-c1ccccc1)B32] | −5.26 | −1.90 | 2.73 | 0.317 | 0.062 | 454 |
| 2-120 | 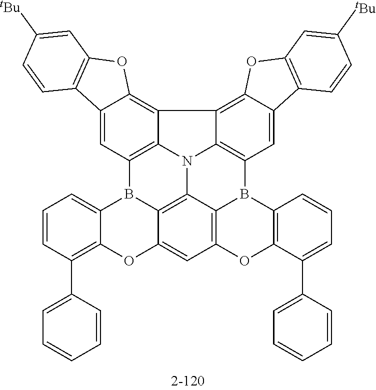 [SMILES: CC(C)(C)c1ccc2c(c1)oc1c2cc2c3c1c1c4oc5cc(C(C)(C)C)ccc5c4cc4c1n3-c1c3c(cc5c1B4c1cccc(-c4ccccc4)c1O5)Oc1c(cccc1-c1ccccc1)B32] | −4.99 | −1.62 | 2.74 | 0.341 | 0.079 | 452 |
| 2-22 | 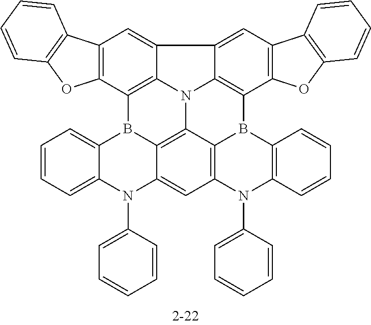 [SMILES: c1ccc(N2c3ccccc3B3c4c2cc2c5c4-n4c6c3c3oc7ccccc7c3cc6c3cc6c(oc7ccccc76)c(c34)B5c3ccccc3N2c2ccccc2)cc1] | −4.91 | −1.53 | 2.72 | 0.107 | 0.067 | 455 |
| R1 | 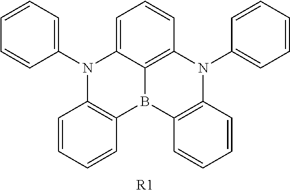 | −4.88 | −1.23 | 2.99 | 0.214 | 0.109 | 415 |

As shown in Tables 2 and 3, the compounds of the disclosure each have reorganization energy of 0.100 eV or less, which is smaller than that of Comparative Compound R1 as a TADF material. Accordingly, referring to FIG. 5, it is assumed that the compounds of the disclosure each have a smaller FWHM than Comparative Compound R1 known in the art. Accordingly, it is expected that the compounds of the disclosure each exhibit significantly higher color purity than Comparative Compound R1.

It was confirmed that the compounds of the disclosure each had oscillator strength f of sufficient magnitude and excellent fluorescence efficiency.

It was confirmed that the compounds of the disclosure each had a fluorescence wavelength of 430 nm or more and 480 nm or less and an appropriate blue fluorescence wavelength.

From the above results, it can be seen that the compounds of the disclosure each have small reorganization energy and large oscillator strength f. Accordingly, it was confirmed that the compounds of the disclosure each had a narrow emission spectrum width, and thus may each serve as a blue luminescent material capable of realizing high color purity and improving the luminescence efficiency of an organic EL device.

### Evaluation of Condensed Cyclic Compound

### Measurement of Spectrum Width (FWHM) of Fluorescence

For a toluene solution including Compound 1-19 of the disclosure at a concentration of 1×10⁻⁵M (=mol/dm³, mol/L), the peak wavelength (nm) of fluorescence in PL and the spectrum width of fluorescence (the FWHM of the fluorescence spectrum peak) were evaluated by measuring at room temperature with an excitation wavelength of 320 nm using the spectrofluorophotometer F-7000 manufactured by Hitachi High-Tech Co., Ltd.

In this evaluation, the peak wavelength of fluorescence is not particularly limited, but may be within the blue emission region, and may be 440 nm or more and 470 nm or less.

In this evaluation, the spectrum width (FWHM) of fluorescence may be as small as possible, and it is considered that the smaller the spectrum width is, the better the color purity is.

The results are shown in Table 4. In addition, Table 4 also shows the results of Condensed Cyclic Compounds R1 to R3 measured in the same manner as described above.

TABLE 4

| | PL peak | PL | |
|---|---|---|---|
| | wavelength | FWHM | |
| Compound | (nm) | (nm) | |
| Compound 1-19 | 453 | 21 | Compound of disclosure |
| Comparative | 453 | 22 | Known condensed |
| Compound R1 | | | cyclic compound |
| Comparative | 451 | 26 | Known condensed |
| Compound R2 | | | cyclic compound |
| Comparative | 445 | 42 | Known condensed |
| Compound R3 | | | cyclic compound |

As shown in Table 4, it was confirmed that Compound 1-19 of the disclosure had a smaller FWHM and superior color purity than Comparative Compounds R¹, R², and R³, which are TADF materials known in the art.

### Manufacture of Organic EL Device

### Device Manufacturing Example 1

An ITO glass substrate on which an electrode pattern was formed was cut to a size of 50 mm×50 mm×0.5 mm, sonicated in acetone, isopropyl, alcohol, and pure water, in this stated order, each for 15 minutes, and then cleaned by exposure to UV ozone for 30 minutes. The following layers were deposited on the ITO electrode (anode) of the glass substrate by using a vacuum deposition apparatus.

First, F6-TCNNQ (see the formula below) was deposited on the ITO electrode to form a hole injection layer having a thickness of 10 nm. Subsequently, Compound HT1 (see the formula below) was deposited on the hole injection layer to form a hole transport layer having a thickness of 140 nm. Subsequently, Compound H-H1 (see the formula below) was deposited on the hole transport layer to form an electron blocking layer having a thickness of 5 nm. As a result, a hole transport region was formed.

Compound H-H1, Compound H-E1 (see the formula below), and Compound 1-19 were co-deposited on the hole transport region to form an emission layer having a thickness of 40 nm. In this regard, the formation of the emission layer was performed such that the mass ratio of Compound H-H1 and Compound H-E1 in the emission layer was Compound H-H1:Compound H-E1=60:40. In addition, the formation of the emission layer was performed such that the concentration of Compound 1-19 in the emission layer was 1.5 wt % based on the total mass of Compound H-H1, Compound H-E1, and Compound 1-19 (i.e., the total mass of the emission layer). Compound H-H1 and Compound H-E1 are host materials.

Compound H-E1 was vacuum-deposited on the emission layer to form a hole blocking layer having a thickness of 5 nm. Subsequently, Compound ET1 (see the formula below) and LiQ were co-deposited on the hole blocking layer at a mass ratio of Compound ET1:LiQ=5:5 (unit: parts by mass) to form an electron transport layer having a thickness of 30 nm. Subsequently, LiQ was deposited on the electron transport layer to form an electron injection layer having a thickness of 1 nm. As a result, an electron transport region was formed.

Al (cathode) was deposited on the electron injection layer to a thickness of 100 nm to thereby manufacture an organic EL device. Then, in a glove box of a nitrogen atmosphere with water concentration of 1 ppm or less and oxygen concentration of 1 ppm or less, a glass sealing tube with a desiccating agent and an ultraviolet curing resin (manufactured by MORESCO Co., Ltd., product name WB90US) were used to seal the organic EL device manufactured by the above process. As a result, the manufacture of Organic EL Device 1 was completed.

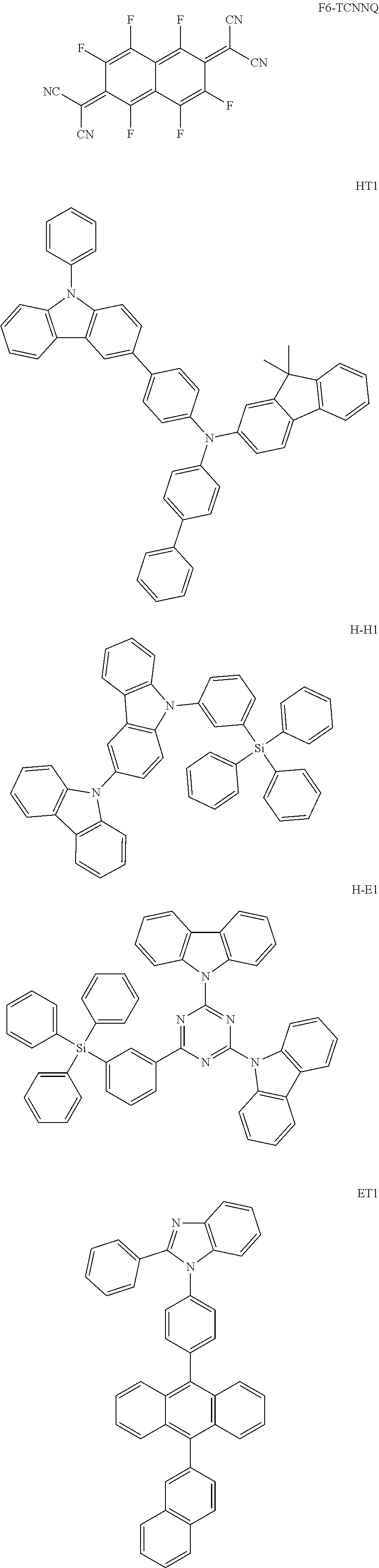 [SMILES: N#CC(C#N)=c1c(F)c(F)c2c(F)c(=C(C#N)C#N)c(F)c(F)c2c1F ; CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc([Si](c2ccccc2)(c2ccccc2)c2cccc(-n3c4ccccc4c4cc(-n5c6ccccc6c6ccccc65)ccc43)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc(-c2nc3ccccc3n2-c2ccc(-c3c4ccccc4c(-c4ccc5ccccc5c4)c4ccccc34)cc2)cc1]

### Comparative Device Manufacturing Example 1

In the formation of the emission layer, Compound 1-19 in emission layer was changed to Comparative Compound R1. Except for the above, a comparative organic EL device was manufactured in the same manner as in Device Manufacturing Example 1. Then, the device was sealed to complete the manufacture of Comparative Organic EL Device 1.

### Device Manufacturing Example 2

An organic EL device was manufactured in the same manner as in Device Manufacturing Example 1, except that the formation of the emission layer was changed as follows. Then, the device was sealed to complete the manufacture of Organic EL Device 2.

### Formation of Emission Layer in Device Manufacturing Example 2

Compound H-H1, Compound H-E1, Phosphorescent Complex Pt1 (see the formula below), and Compound 1-19 were co-deposited on the hole transport region to form an emission layer having a thickness of 40 nm. In this regard, the formation of the emission layer was performed such that the mass ratio of Compound H-H1, Compound H-E1, and Phosphorescent Complex Pt1 in the emission layer was Compound H-H1:Compound H-E1:Phosphorescent Complex Pt1=60:40:13. In addition, the formation of the emission layer was performed such that the concentration of Compound 1-19 in the emission layer was 0.4 wt % based on the total mass of Compound H-H1, Compound H-E1, Phosphorescent Complex Pt1, and Compound 1-19 (i.e., the total mass of the emission layer). Compound H-H1 and Compound H-E1 are host materials.

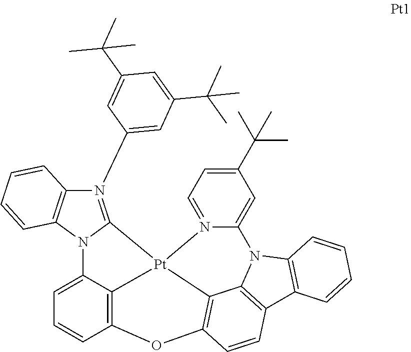

### Comparative Device Manufacturing Example 2

An organic EL device was manufactured in the same manner as in Device Manufacturing Example 2, except that, in the formation of the emission layer, Compound 1-19 was changed to Comparative Compound R1. Then, the device was sealed to complete the manufacture of Comparative Organic EL Device 2.

### Evaluation of Organic EL Device

### (1) Luminance, External Quantum Efficiency, and Device Lifespan

The emission peak wavelength at the luminance of 1,000 cd/m², emission spectrum width, external quantum efficiency, and device lifespan were evaluated according to the following methods.

The organic EL device was allowed to emit light by continuously changing the voltage applied to the organic EL device using a DC constant voltage power supply (2400 source meter manufactured by Keithley Instruments), and the luminance, emission spectrum, and luminescence amount at this time were measured with a luminance meter (SR-3 manufactured by Topcon).

In this regard, the external quantum efficiency was calculated from the emission spectrum, luminance, and current value at the time of measurement. The external quantum efficiency at the luminance of 1,000 cd/m² was defined as EQE [%]. In addition, the EQE in Table 5 is a relative value when the EQE of Comparative Organic EL Device 1 is set to 1, and similarly, the EQE in Table 6 is a relative value when the EQE of Comparative Organic EL Device 2 is set to 1.

In addition, the lifespan (durability) of the device was defined as LT95 [hr] by measuring the amount of time taken when the emission luminance, which decays as time lapses, becomes 95% of the initial luminance when the device is continuously driven on a current value having an initial luminance of 1,000 cd/m². In addition, the LT95 in Table 5 is a relative value when the LT95 of Comparative Organic EL Device 1 is set to 1, and similarly, the LT95 in Table 6 is a relative value when the LT95 of Comparative Organic EL Device 2 is set to 1.

TABLE 5
Evaluation result of organic EL device

| | Compound | EQE | LT95 |
|---|---|---|---|
| Organic EL Device 1 | Compound 1-19 | 1.3 | 3.7 |
| Comparative Organic | Comparative | 1 | 1 |
| EL Device 1 | Compound R1 | | |

TABLE 6
Evaluation result of organic EL device including
Phosphorescent Complex Pt1 in emission layer

| | Compound | EQE | LT95 |
|---|---|---|---|
| Organic EL Device 2 | Compound 1-19 | 1 | 1.8 |
| Comparative Organic | Comparative | 1 | 1 |
| EL Device 2 | Compound R1 | | |

From the evaluation results of the organic EL devices shown in Table 5, it was confirmed that Organic EL Device 1 using Compound 1-19 of the disclosure had superior luminescence efficiency and device lifespan than Comparative Organic EL Device 1 using Comparative Compound R1.

From the evaluation results of the organic EL devices including Phosphorescent Complex Pt1 in the emission layer thereof shown in Table 6, it was confirmed that Organic EL Device 2 using Compound 1-19 of the disclosure had superior luminescence efficiency and device lifespan than Comparative Organic EL Device 2 using Comparative Compound R1.

### (2) Emission Peak Wavelength and Emission Spectrum Width (FWHM)

The emission peak wavelength and the emission spectrum width were read from the result of measuring the emission spectrum. The wavelength representing the maximum value of the emission spectrum was defined as the emission peak wavelength, and the wavelength width corresponding to half of the maximum value was defined as the FWHM.

In this evaluation, it was confirmed that the emission peakwavelengths of Organic EL Device 1 and Organic EL Device 2 were within a range of a blue emission region, i.e., 455 nm or more and 475 nm or less. In addition, it was confirmed that Organic EL Device 1 and Organic EL Device 2 each had a sufficiently small emission spectrum width (FWHM) and excellent color purity.

From the above, it was confirmed that the condensed cyclic compound of the disclosure had excellent color purity as a luminescent material. In addition, it was confirmed that the condensed cyclic compound of the disclosure may contribute to achieving long lifespan and high efficiency in an organic EL device. In addition, it was confirmed that an organic EL device using the condensed cyclic compound in combination with Phosphorescent Complex Pt1, which is one of embodiments the disclosure, exhibited superiority over an organic EL device using Comparative Compound R1. That is, when a combination of the condensed cyclic compound and Phosphorescent Complex Pt1 was used, significant effectiveness of the disclosure was exhibited.

As described above, an organic electroluminescent device including the condensed cyclic compound may have high color purity.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A condensed cyclic compound represented by Formula 1: 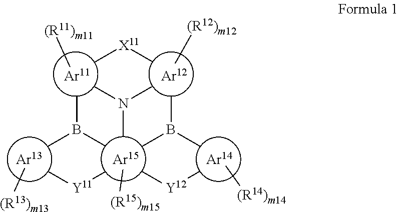
wherein, in Formula 1,
Ar¹¹, Ar¹², Ar¹³, and Ar¹⁴ are each independently a group derived from an aromatic hydrocarbon ring having 6 to 18 ring-forming atoms or a group derived from a heteroaromatic ring having 5 to 18 ring-forming atoms,
Ar¹⁵ is a group derived from a benzene ring or a group derived from a heteroaromatic ring having 5 or 6 ring-forming atoms,
X¹¹ is —O—, —S—, —Se—, —Te—, —NR^{X11}—, or a single bond,
R^{X11} is a hydrogen atom, a substituted or unsubstituted alkyl group, a substituted or unsubstituted aryl group, a substituted or unsubstituted heteroaryl group, a substituted or unsubstituted alkylsilyl group, a substituted or unsubstituted arylsilyl group, a substituted or unsubstituted alkylamino group, a substituted or unsubstituted arylamino group, a substituted or unsubstituted alkenyl group, a substituted or unsubstituted alkynyl group, or a substituted or unsubstituted arylalkyl group, wherein R^{X11} is optionally bonded to at least one of adjacent rings Ar¹¹ or Ar¹² via a linking group,
Y¹¹ and Y¹² are each independently —O—, —S—, —Se—, —Te—, —NR^{Y11}—, —CR^{Y12}R^{Y13}—, or —R^{Y11}, R^{Y12}, R^{Y13}, R^{Y14}, and R^{Y15} are each independently hydrogen, a substituted or unsubstituted alkyl group, a substituted or unsubstituted aryl group, a substituted or unsubstituted heteroaryl group, a substituted or unsubstituted alkylsilyl group, a substituted or unsubstituted arylsilyl group, a substituted or unsubstituted alkylamino group, a substituted or unsubstituted arylamino group, a substituted or unsubstituted alkenyl group, a substituted or unsubstituted alkynyl group, or a substituted or unsubstituted arylalkyl group, wherein at least one of R^{Y11}, R^{Y12}, R^{Y13}, R^{Y14}, or R^{Y15} are independently optionally bonded to adjacent ring Ar¹⁵ via a linking group, at least one of R^{Y11}, R^{Y13} or R^{Y15} are independently optionally bonded to adjacent ring Ar¹³ via a single bond, and/or at least one of R^{Y11}, R^{Y12} or R^{Y4} are independently optionally bonded to adjacent ring Ar¹⁴ via a single bond,
R¹¹, R¹², R¹³, R¹⁴, and R¹⁵ are each independently a hydrogen atom, deuterium atom, a halogen atom, a cyano group, a substituted or unsubstituted alkyl group, a substituted or unsubstituted aryl group, a substituted or unsubstituted heteroaryl group, a substituted or unsubstituted diarylamino group, a substituted or unsubstituted diheteroarylamino group, a substituted or unsubstituted arylheteroarylamino group, a substituted or unsubstituted alkylsilyl group, a substituted or unsubstituted arylsilyl group, a substituted or unsubstituted alkylamino group, a substituted or unsubstituted arylamino group, a substituted or unsubstituted aryloxy group, a substituted or unsubstituted heteroaryloxy group, a substituted or unsubstituted arylthio group, a substituted or unsubstituted heteroarylthio group, a substituted or unsubstituted alkenyl group, a substituted or unsubstituted alkynyl group, or a substituted or unsubstituted arylalkyl group,
m11 and m12 are each independently 0, 1, 2, or 3,
m13 and m14 are each independently 0, 1, 2, 3, or 4, and
m15 is 0 or 1.

2. The condensed cyclic compound of claim 1, wherein Ar¹¹, Ar¹², Ar¹³, and Ar¹⁴ are each independently:
a benzene ring, a pentalene ring, an indene ring, a naphthalene ring, an anthracene ring, an azulene ring, a heptalene ring, an acenaphthylene ring, a phenalene ring, a fluorene ring, a phenanthrene ring, a biphenyl ring, a terphenyl ring, a triphenylene ring, a pyrene ring, a chrysene ring, or a tetraphene ring; or
a pyridine ring, a pyrazine ring, a pyridazine ring, a pyrimidine ring, a triazine ring, a quinoline ring, an isoquinoline ring, a quinoxaline ring, a quinazoline ring, a naphthyridine ring, an acridine ring, phenazine ring, a benzoquinoline ring, a benzoisoquinoline ring, a phenanthridine ring, a phenanthroline ring, a benzoquinone ring, a coumarin ring, an anthraquinone ring, a fluorenone ring, a furan ring, a thiophene ring, a benzofuran ring, a benzothiophene ring, a dibenzofuran ring, a dibenzothiophene ring, a pyrrole ring, an indole ring, a carbazole ring, an imidazole ring, a benzimidazole ring, a pyrazole ring, an indazole ring, an oxazole ring, an isoxazole ring, a benzoxazole ring, a benzoisoxide ring, a thiazole ring, an isothiazole ring, a benzothiazole ring, a benzoisothiazole ring, an imidazolinone ring, a benzimidazolinone ring, an imidazopyridine ring, an imidazopyrimidine ring, an imidazolephenanthridine ring, an azadibenzofuran ring, an azacarbazole ring, a diazadibenzofuran ring, a diazacarbazole ring, a diazadibenzothiophene ring, a xanthone ring, or a thioxanthone ring.

3. The condensed cyclic compound of claim 1, wherein the condensed cyclic compound is represented by Formula 2: 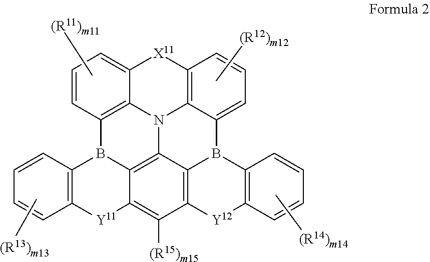
wherein, in Formula 2,
X¹¹ is —O—, —S—, —Se—, or —Te—,
Y¹¹ and Y¹² are as defined in Formula 1, and
R¹¹, R¹², R¹³, R¹⁴, R¹⁵, m11, m12, m13, m14, and m15 are as defined in Formula 1.

4. The condensed cyclic compound of claim 1, wherein R¹¹, R¹², R¹³, R¹⁴, and R¹⁵ are each independently a hydrogen atom, a chlorine atom (Cl), a tert-butyl group, a phenyl group, or a diphenylamino group.

5. The condensed cyclic compound of claim 1, wherein m11 and m12 are each independently 0 or 1.

6. The condensed cyclic compound of claim 1, wherein the condensed cyclic compound is represented by Formulae 1-1 to 1-53:

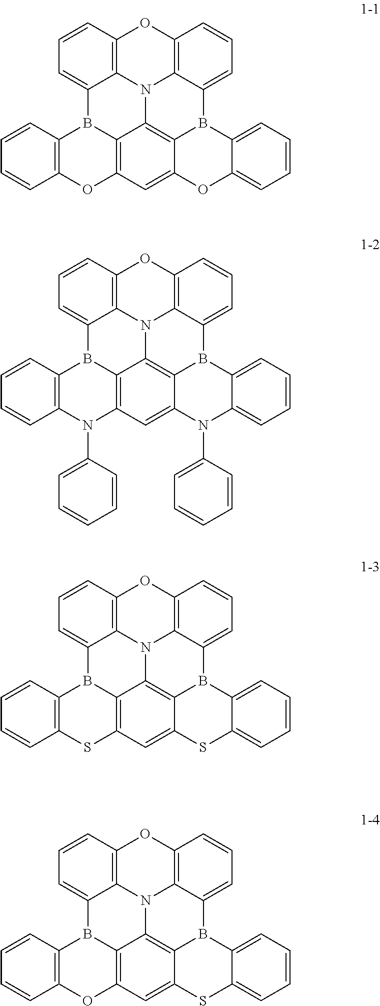 [SMILES: c1ccc2c(c1)Oc1cc3c4c5c1B2c1cccc2c1N5c1c(cccc1B4c1ccccc1O3)O2 ; c1ccc(N2c3ccccc3B3c4cccc5c4N4c6c(cccc6B6c7ccccc7N(c7ccccc7)c7cc2c3c4c76)O5)cc1 ; c1ccc2c(c1)Sc1cc3c4c5c1B2c1cccc2c1N5c1c(cccc1B4c1ccccc1S3)O2 ; c1ccc2c(c1)Oc1cc3c4c5c1B2c1cccc2c1N5c1c(cccc1B4c1ccccc1S3)O2]

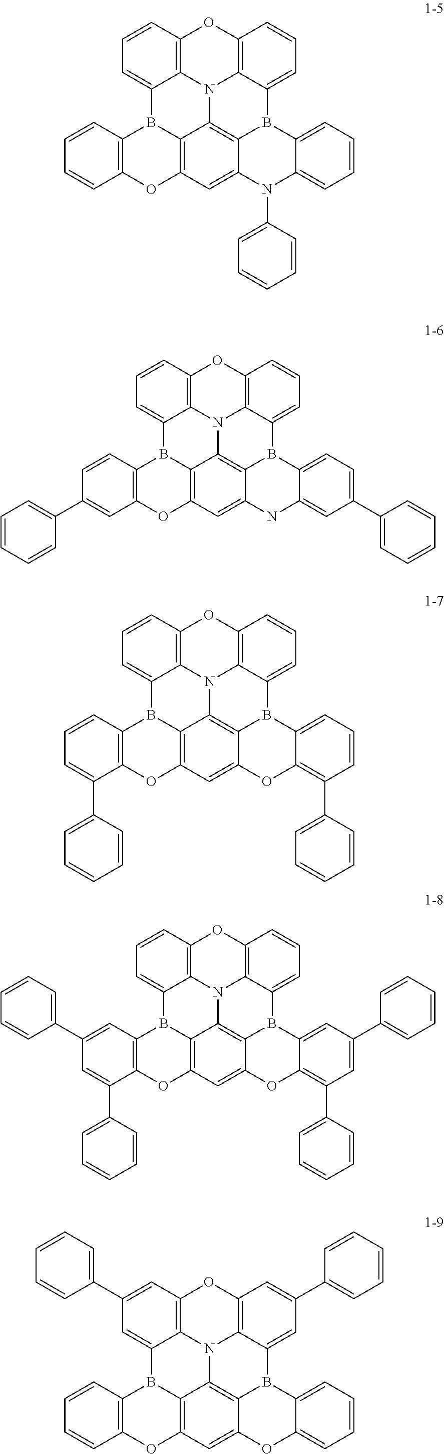 [SMILES: c1ccc(N2c3ccccc3B3c4cccc5c4N4c6c(cccc6B6c7ccccc7Oc7cc2c3c4c76)O5)cc1 ; c1ccc(-c2ccc3c(c2)Nc2cc4c5c6c2B3c2cccc3c2N6c2c(cccc2B5c2ccc(-c5ccccc5)cc2O4)O3)cc1 ; c1ccc(-c2cccc3c2Oc2cc4c5c6c2B3c2cccc3c2N6c2c(cccc2B5c2cccc(-c5ccccc5)c2O4)O3)cc1 ; c1ccc(-c2cc3c(c(-c4ccccc4)c2)Oc2cc4c5c6c2B3c2cccc3c2N6c2c(cccc2B5c2cc(-c5ccccc5)cc(-c5ccccc5)c2O4)O3)cc1 ; c1ccc(-c2cc3c4c(c2)B2c5ccccc5Oc5cc6c7c(c52)N4c2c(cc(-c4ccccc4)cc2B7c2ccccc2O6)O3)cc1]

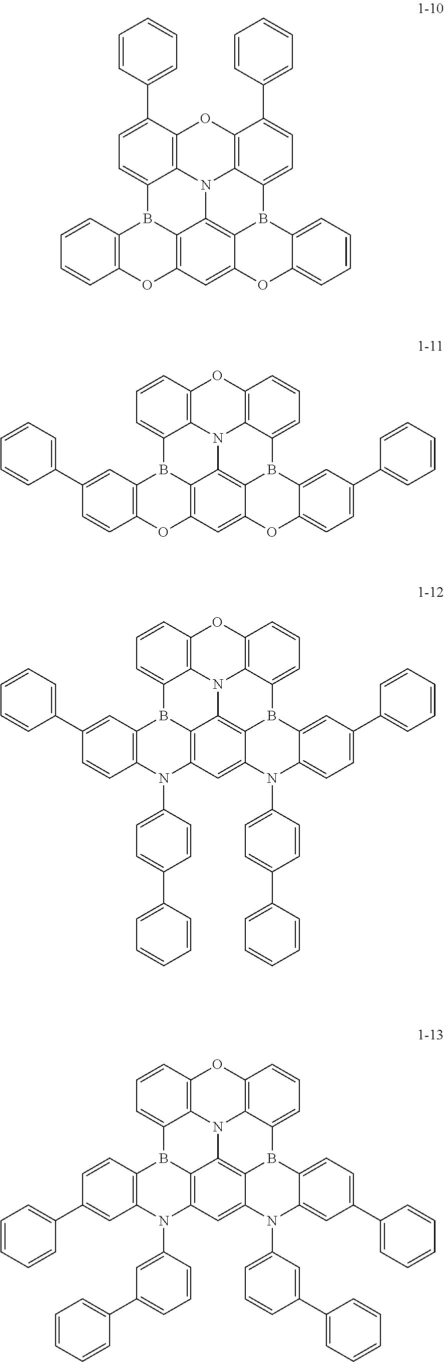 [SMILES: c1ccc(-c2ccc3c4c2Oc2c(-c5ccccc5)ccc5c2N4c2c4c(cc6c2B5c2ccccc2O6)Oc2ccccc2B34)cc1 ; c1ccc(-c2ccc3c(c2)B2c4cccc5c4N4c6c(cccc6B6c7cc(-c8ccccc8)ccc7Oc7cc(c2c4c76)O3)O5)cc1 ; c1ccc(-c2ccc(N3c4ccc(-c5ccccc5)cc4B4c5cccc6c5N5c7c(cccc7B7c8cc(-c9ccccc9)ccc8N(c8ccc(-c9ccccc9)cc8)c8cc3c4c5c87)O6)cc2)cc1 ; c1ccc(-c2cccc(N3c4cc(-c5ccccc5)ccc4B4c5cccc6c5N5c7c(cccc7B7c8ccc(-c9ccccc9)cc8N(c8cccc(-c9ccccc9)c8)c8cc3c4c5c87)O6)c2)cc1]

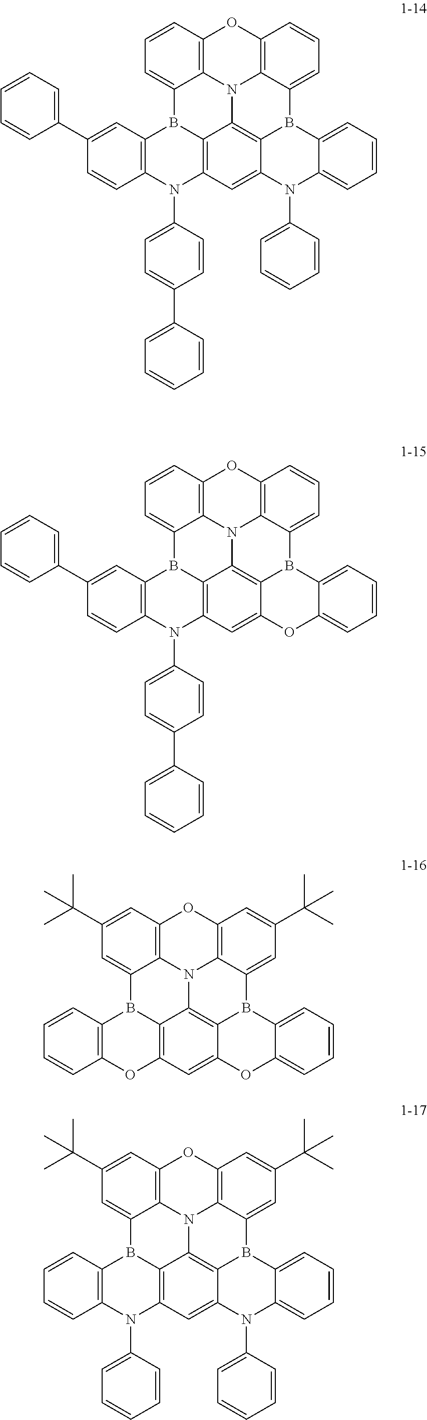

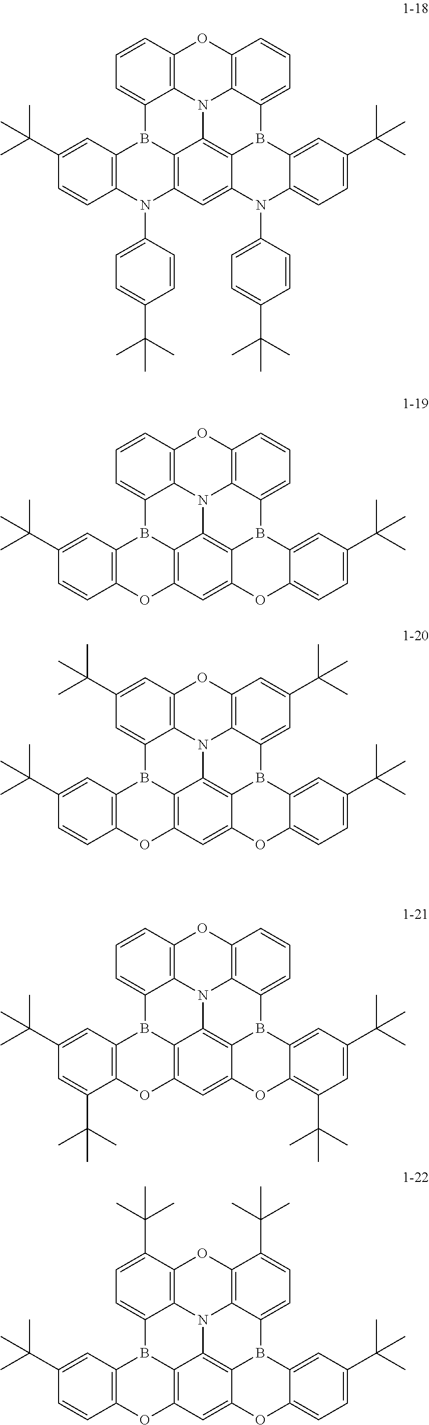

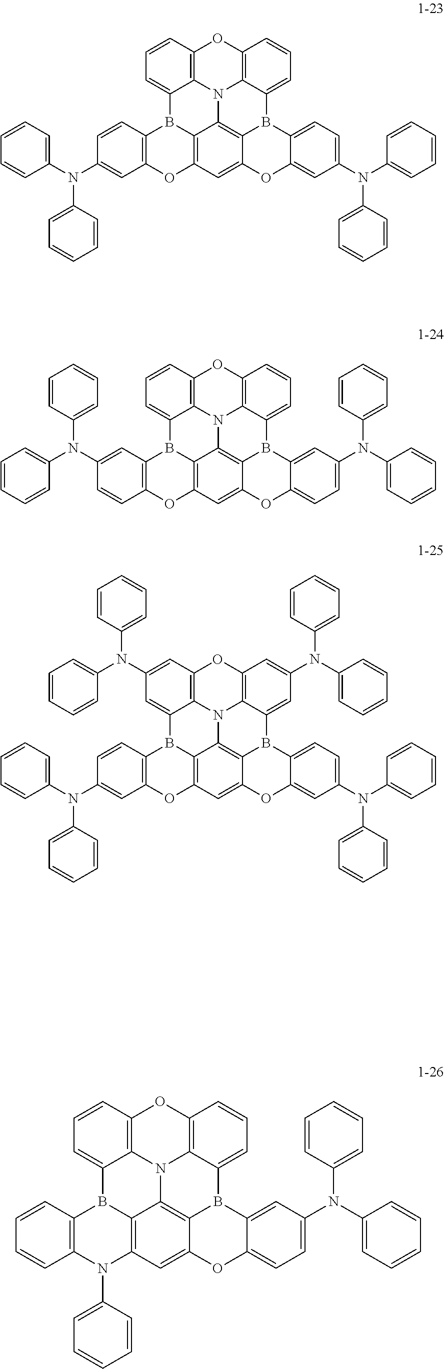 [SMILES: c1ccc(N(c2ccccc2)c2ccc3c(c2)Oc2cc4c5c6c2B3c2cccc3c2N6c2c(cccc2B5c2ccc(N(c5ccccc5)c5ccccc5)cc2O4)O3)cc1 ; c1ccc(N(c2ccccc2)c2ccc3c(c2)B2c4cccc5c4N4c6c(cccc6B6c7cc(N(c8ccccc8)c8ccccc8)ccc7Oc7cc(c2c4c76)O3)O5)cc1 ; c1ccc(N(c2ccccc2)c2ccc3c(c2)Oc2cc4c5c6c2B3c2cc(N(c3ccccc3)c3ccccc3)cc3c2N6c2c(cc(N(c6ccccc6)c6ccccc6)cc2B5c2ccc(N(c5ccccc5)c5ccccc5)cc2O4)O3)cc1 ; c1ccc(N(c2ccccc2)c2ccc3c(c2)B2c4cccc5c4N4c6c(cccc6B6c7ccccc7N(c7ccccc7)c7cc(c2c4c76)O3)O5)cc1]

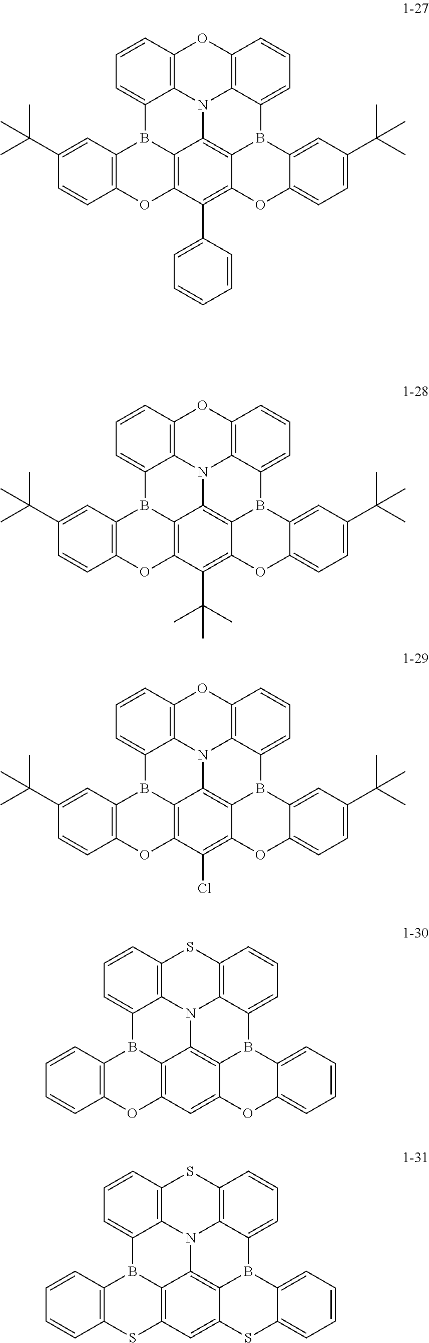

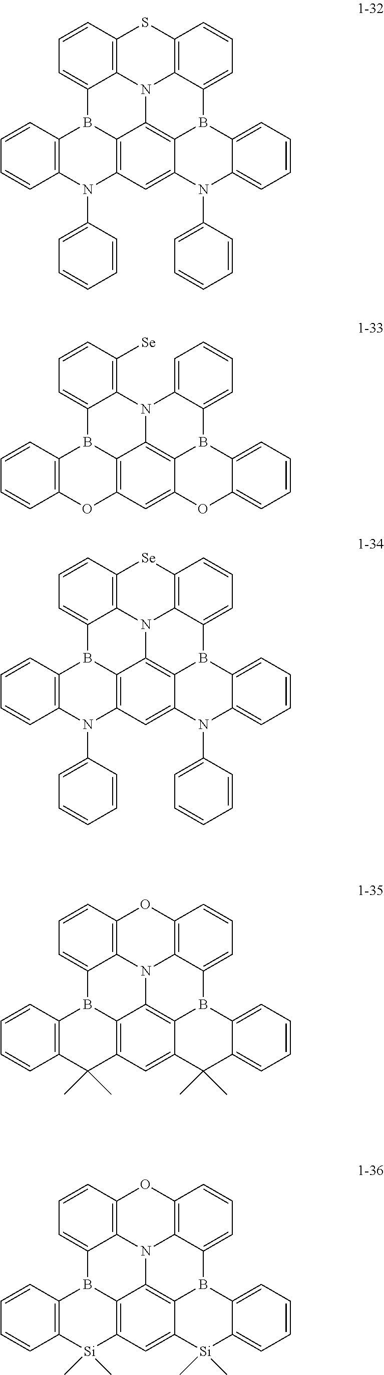

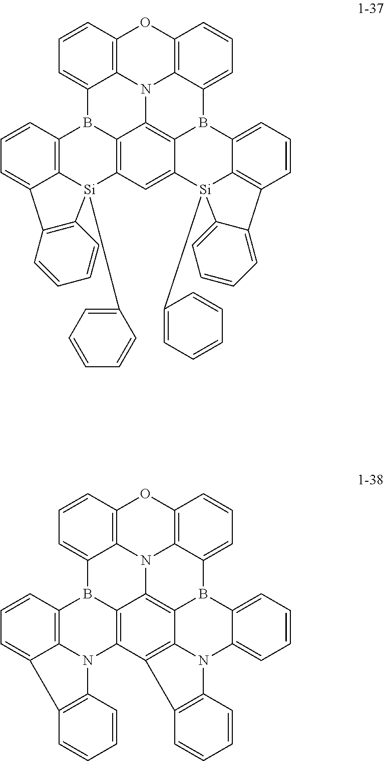 [SMILES: c1ccc([Si]23c4ccccc4-c4cccc(c42)B2c4cccc5c4N4c6c(cccc6B6c7cccc8c7[Si](c7ccccc7)(c7ccccc7-8)c7cc3c2c4c76)O5)cc1 ; c1ccc2c(c1)B1c3cccc4c3N3c5c(cccc5B5c6c3c1c1c(c6-n3c6ccccc6c6cccc5c63)c3ccccc3n1-2)O4]

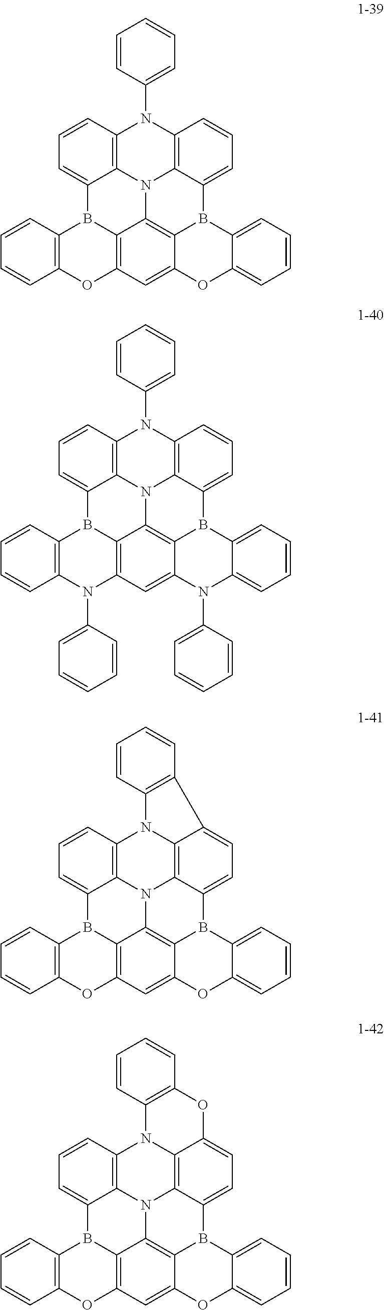

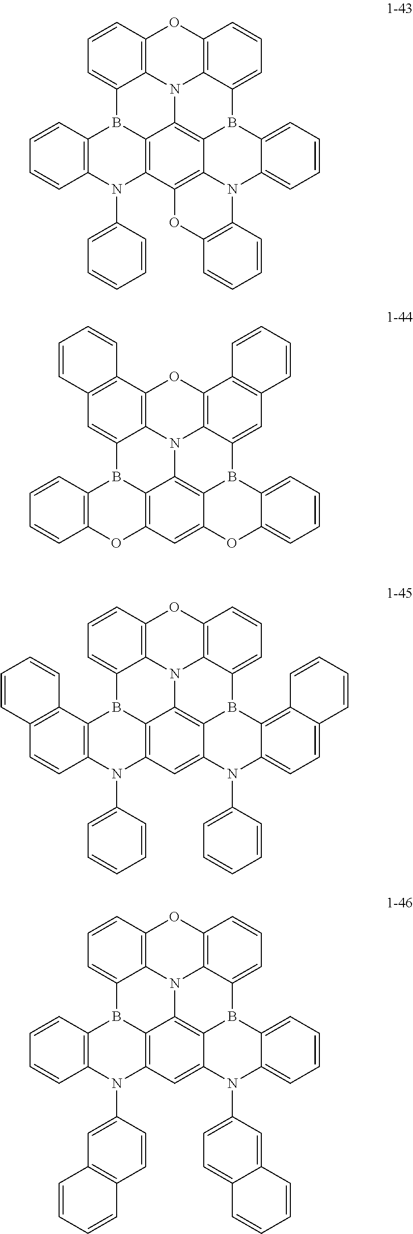

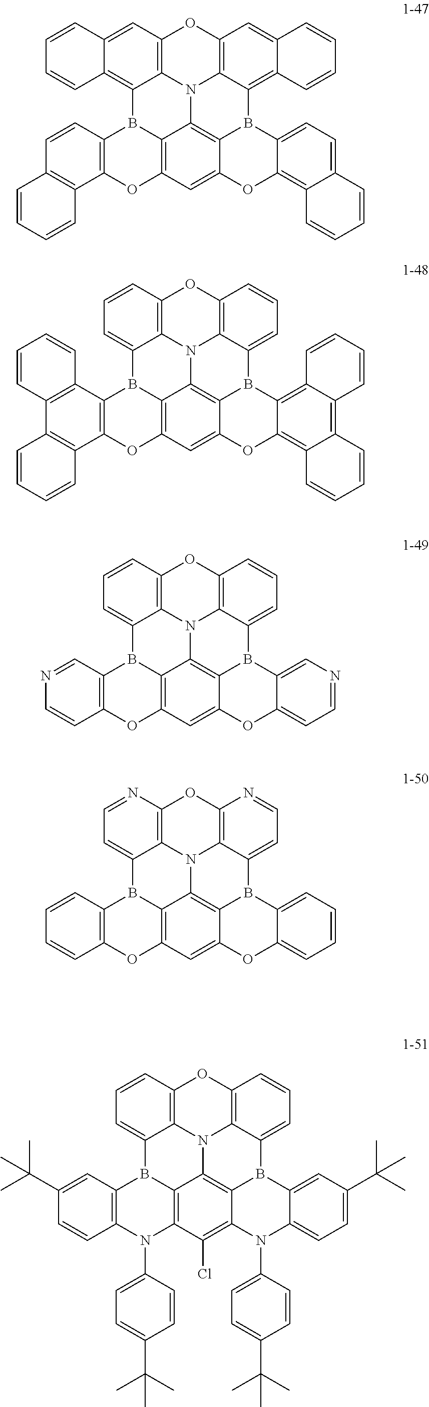 [SMILES: c1ccc2c3c(ccc2c1)B1c2c(cc4c5c2N2c6c(cc7ccccc7c61)Oc1cc6ccccc6c(c12)B5c1ccc2ccccc2c1O4)O3 ; c1cc2c3c(c1)B1c4c(cc5c6c4N3c3c(cccc3B6c3c(c4ccccc4c4ccccc34)O5)O2)Oc2c1c1ccccc1c1ccccc21 ; c1cc2c3c(c1)B1c4cnccc4Oc4cc5c6c(c41)N3c1c(cccc1B6c1cnccc1O5)O2 ; c1ccc2c(c1)Oc1cc3c4c5c1B2c1ccnc2c1N5c1c(ccnc1O2)B4c1ccccc1O3 ; CC(C)(C)c1ccc(N2c3ccc(C(C)(C)C)cc3B3c4cccc5c4N4c6c(cccc6B6c7cc(C(C)(C)C)ccc7N(c7ccc(C(C)(C)C)cc7)c7c(Cl)c2c3c4c76)O5)cc1]

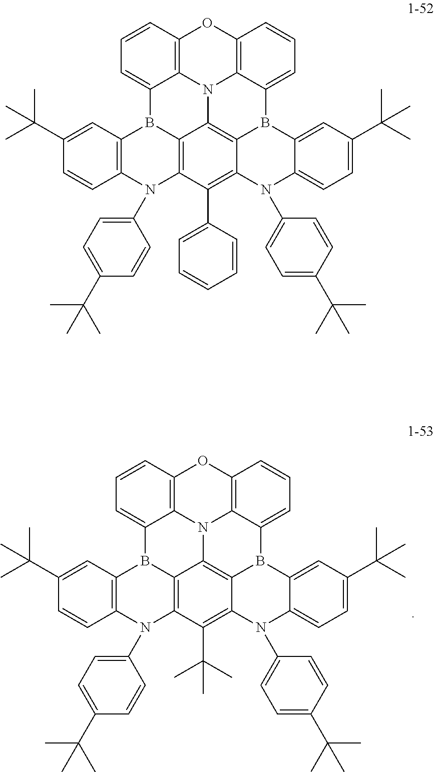

7. The condensed cyclic compound of claim 1, wherein the condensed cyclic compound is represented by Formula 3: 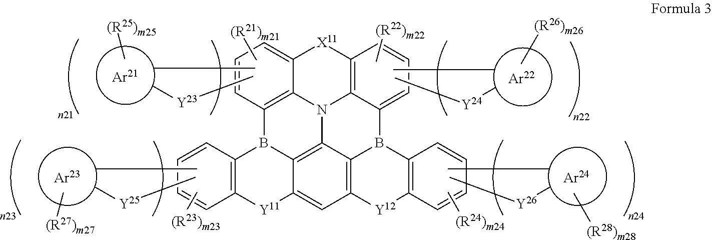
wherein, in Formula 3,
Ar²¹, Ar²², Ar²³, and Ar²⁴ are each independently a group derived from an aromatic hydrocarbon ring having 6 to 18 ring-forming atoms or a group derived from a heteroaromatic ring having 5 to 18 ring-forming atoms,
X¹¹ is —O—, —S—, —Se—, —Te—, —NR^{X11}—, or a single bond,
R^{X11} is a hydrogen atom, a substituted or unsubstituted alkyl group, a substituted or unsubstituted aryl group, a substituted or unsubstituted heteroaryl group, a substituted or unsubstituted alkylsilyl group, a substituted or unsubstituted arylsilyl group, a substituted or unsubstituted alkylamino group, a substituted or unsubstituted arylamino group, a substituted or unsubstituted alkenyl group, a substituted or unsubstituted alkynyl group, or a substituted or unsubstituted arylalkyl group,
Y¹¹, Y¹², Y²³, Y²⁴, Y²⁵, and Y²⁶ are each independently —O—, —S—, —Se—, —Te—, —NR^{Y11}—, —CR^{Y12}R^{Y13}—, or —SiR^{Y4}R^{Y15}—,
R^{Y11}, R^{Y12}, R^{Y13}, R^{Y14}, and R^{Y15} are each independently hydrogen, a substituted or unsubstituted alkyl group, a substituted or unsubstituted aryl group, a substituted or unsubstituted heteroaryl group, a substituted or unsubstituted alkylsilyl group, a substituted or unsubstituted arylsilyl group, a substituted or unsubstituted alkylamino group, a substituted or unsubstituted arylamino group, a substituted or unsubstituted alkenyl group, a substituted or unsubstituted alkynyl group, or a substituted or unsubstituted arylalkyl group,
R²¹, R²², R²³, R²⁴, R²⁵, R²⁶, R²⁷, and R²⁸ are each independently a hydrogen atom, a deuterium atom, a halogen atom, a cyano group, a substituted or unsubstituted alkyl group, a substituted or unsubstituted aryl group, a substituted or unsubstituted heteroaryl group, a substituted or unsubstituted alkylsilyl group, a substituted or unsubstituted arylsilyl group, a substituted or unsubstituted alkylamino group, a substituted or unsubstituted arylamino group, a substituted or unsubstituted alkenyl group, a substituted or unsubstituted alkynyl group, or a substituted or unsubstituted arylalkyl group,
n21, n22, n23, and n24 are each independently 0 or 1, and a total sum of n21, n22, n23, and n24 is 1 or more and 4 or less,
m21, m22, m23, and m24 are each independently 0, 1, or 2, and
m25, m26, m27, and m28 are each independently 0, 1, 2, 3, or 4.

8. The condensed cyclic compound of claim 7, wherein Ar²¹, Ar²², Ar²³, and Ar²⁴ are each independently:
a benzene ring, a pentalene ring, an indene ring, a naphthalene ring, an anthracene ring, an azulene ring, a heptalene ring, an acenaphthalene ring, a phenalene ring, a fluorene ring, a phenanthrene ring, a biphenyl ring, a terphenyl ring, a triphenylene ring, a pyrene ring, a chrysene ring, or a tetraphene ring; or
a pyridine ring, a pyrazine ring, a pyridazine ring, a pyrimidine ring, a triazine ring, a quinoline ring, an isoquinoline ring, a quinoxaline ring, a quinazoline ring, a naphthyridine ring, an acridine ring, phenazine ring, a benzoquinoline ring, a benzoisoquinoline ring, a phenanthridine ring, a phenanthroline ring, a benzoquinone ring, a coumarin ring, an anthraquinone ring, a fluorenone ring, a furan ring, a thiophene ring, a benzofuran ring, a benzothiophene ring, a dibenzofuran ring, a dibenzothiophene ring, a pyrrole ring, an indole ring, a carbazole ring, an imidazole ring, a benzimidazole ring, a pyrazole ring, an indazole ring, an oxazole ring, an isoxazole ring, a benzoxazole ring, a benzoisoxide ring, a thiazole ring, an isothiazole ring, a benzothiazole ring, a benzoisothiazole ring, an imidazolinone ring, a benzimidazolinone ring, an imidazopyridine ring, an imidazopyrimidine ring, an imidazolephenanthridine ring, an azadibenzofuran ring, an azacarbazole ring, a diazadibenzofuran ring, a diazacarbazole ring, a diazadibenzothiophene ring, a xanthone ring, or a thioxanthone ring.

9. The condensed cyclic compound of claim 7, wherein the condensed cyclic compound is represented by Formula 4: 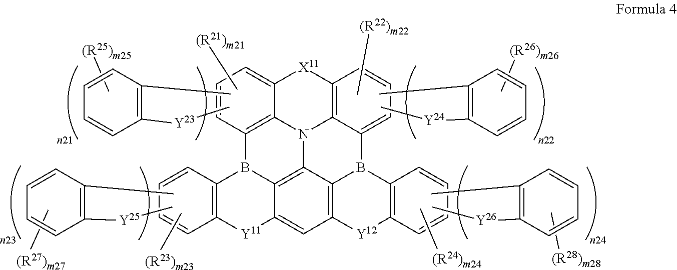
wherein, in Formula 4,
X¹¹, Y¹¹, Y¹², Y²³, Y²⁴, Y²⁵, Y²⁶, R²¹, R²², R²³, R²⁴, R²⁵, R²⁶, R²⁷, R²⁸, n21, n22, n23, n24, m21, m22, m23, m24, m25, m25 m27, and m28 are as defined in Formula 3.

10. The condensed cyclic compound of claim 7, wherein R²¹, R²², R²³, R²⁴, R²⁵, R²⁶, R²⁷, and R²⁸ are each independently a tert-butyl group, a phenyl group, a carbazole group, or a diphenylamino group.

11. The condensed cyclic compound of claim 7, wherein m25, m26, m27, and m28 are each independently 0 or 1.

12. The condensed cyclic compound of claim 7, wherein the condensed cyclic compound is represented by Formulae 2-1 to 2-172:

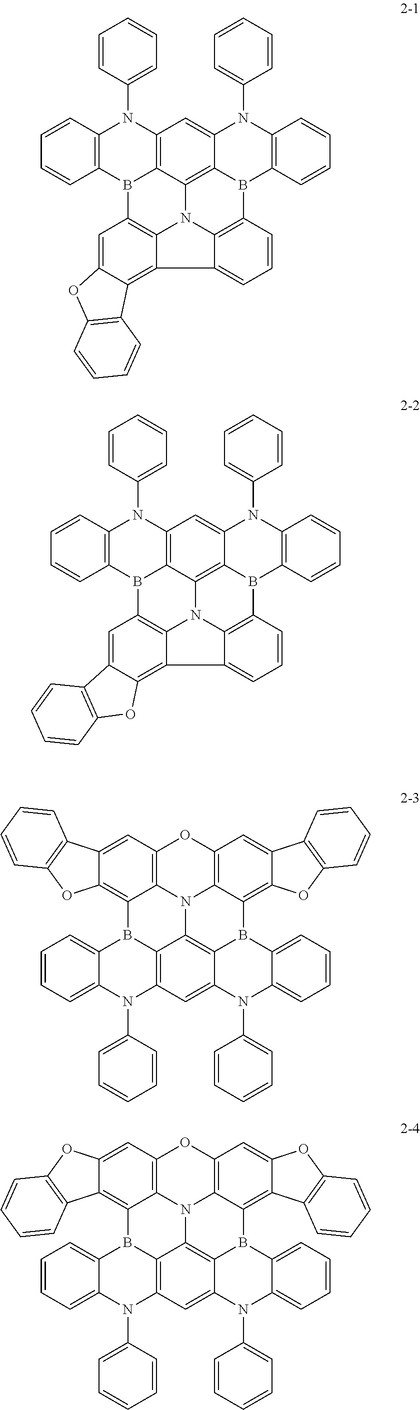

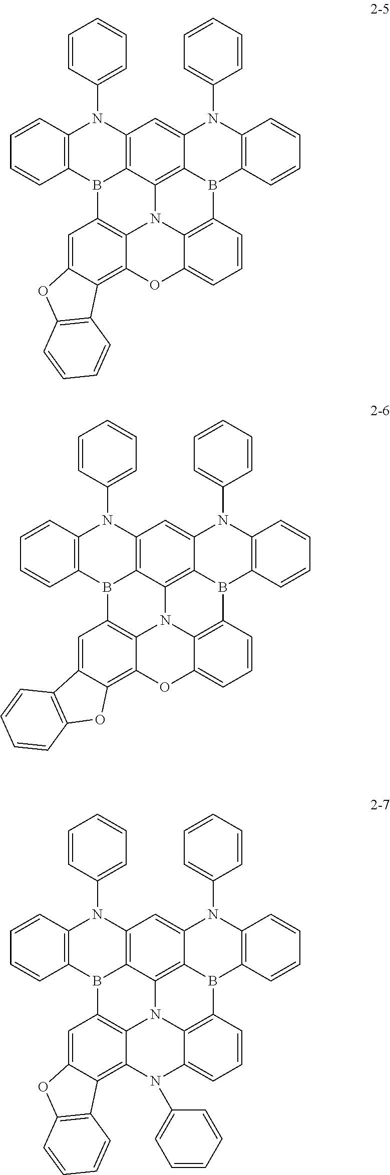

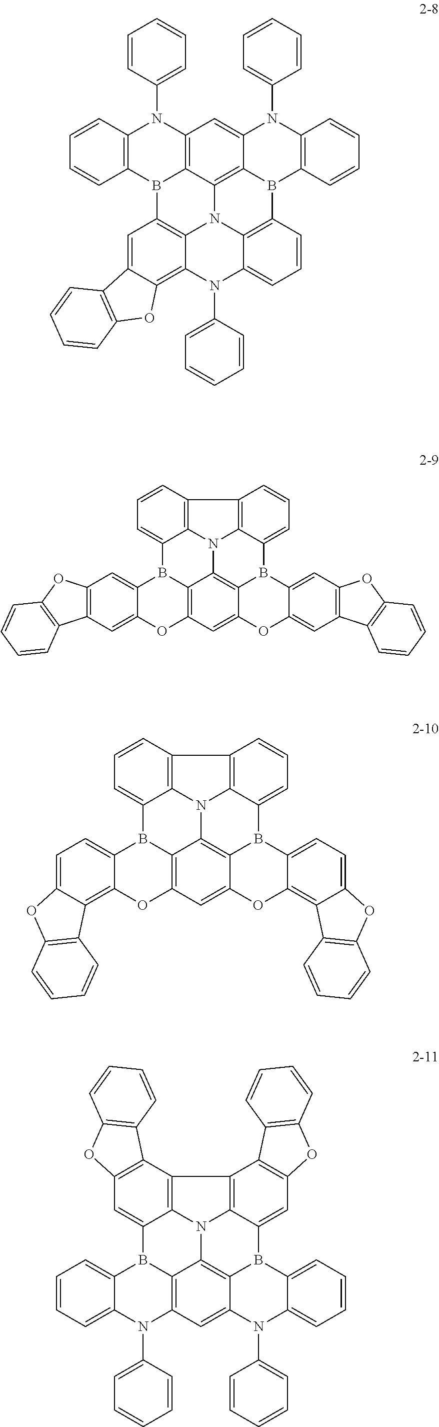 [SMILES: c1ccc(N2c3ccccc3B3c4cccc5c4N4c6c3c2cc2c6B(c3ccccc3N2c2ccccc2)c2cc3c(oc6ccccc63)c(c24)N5c2ccccc2)cc1 ; c1ccc2c(c1)oc1cc3c(cc12)Oc1cc2c4c5c1B3c1cccc3c6cccc(c6n-5c13)B4c1cc3oc4ccccc4c3cc1O2 ; c1ccc2c(c1)oc1ccc3c(c12)Oc1cc2c4c5c1B3c1cccc3c6cccc(c6n-5c13)B4c1ccc3oc4ccccc4c3c1O2 ; c1ccc(N2c3ccccc3B3c4c2cc2c5c4-n4c6c3cc3oc7ccccc7c3c6c3c6c(cc(c34)B5c3ccccc3N2c2ccccc2)oc2ccccc26)cc1]

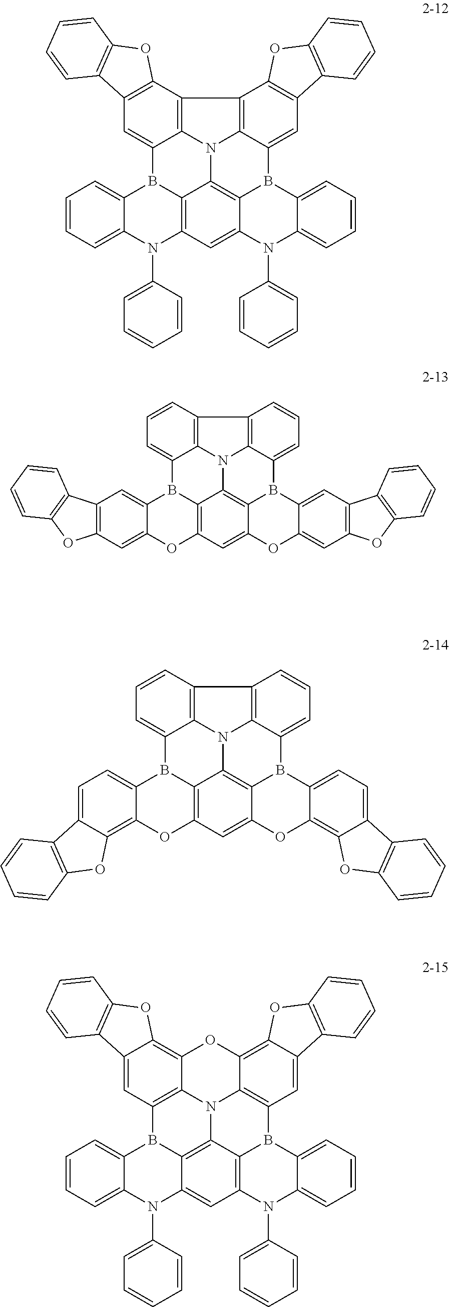 [SMILES: c1ccc(N2c3ccccc3B3c4c2cc2c5c4-n4c6c3cc3c7ccccc7oc3c6c3c6oc7ccccc7c6cc(c34)B5c3ccccc3N2c2ccccc2)cc1 ; c1ccc2c(c1)oc1cc3c(cc12)B1c2c(cc4c5c2-n2c6c1cccc6c1cccc(c12)B5c1cc2c(cc1O4)oc1ccccc12)O3 ; c1ccc2c(c1)oc1c3c(ccc12)B1c2c(cc4c5c2-n2c6c1cccc6c1cccc(c12)B5c1ccc2c(oc5ccccc52)c1O4)O3 ; c1ccc(N2c3ccccc3B3c4cc5c(oc6ccccc65)c5c4N4c6c3c2cc2c6B(c3ccccc3N2c2ccccc2)c2cc3c(oc6ccccc63)c(c24)O5)cc1]

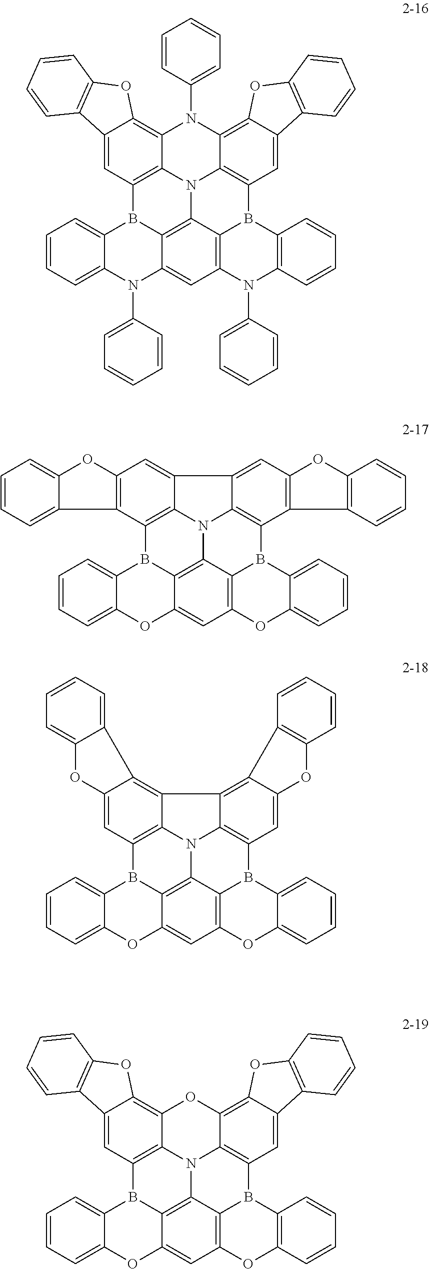 [SMILES: c1ccc(N2c3ccccc3B3c4cc5c(oc6ccccc65)c5c4N4c6c3c2cc2c6B(c3ccccc3N2c2ccccc2)c2cc3c(oc6ccccc63)c(c24)N5c2ccccc2)cc1 ; c1ccc2c(c1)Oc1cc3c4c5c1B2c1c2c(cc6c7cc8oc9ccccc9c8c(c7n-5c16)B4c1ccccc1O3)oc1ccccc12 ; c1ccc2c(c1)Oc1cc3c4c5c1B2c1cc2oc6ccccc6c2c2c6c7c(cc(c6n-5c12)B4c1ccccc1O3)oc1ccccc17 ; c1ccc2c(c1)Oc1cc3c4c5c1B2c1cc2c(oc6ccccc62)c2c1N5c1c(cc5c(oc6ccccc65)c1O2)B4c1ccccc1O3]

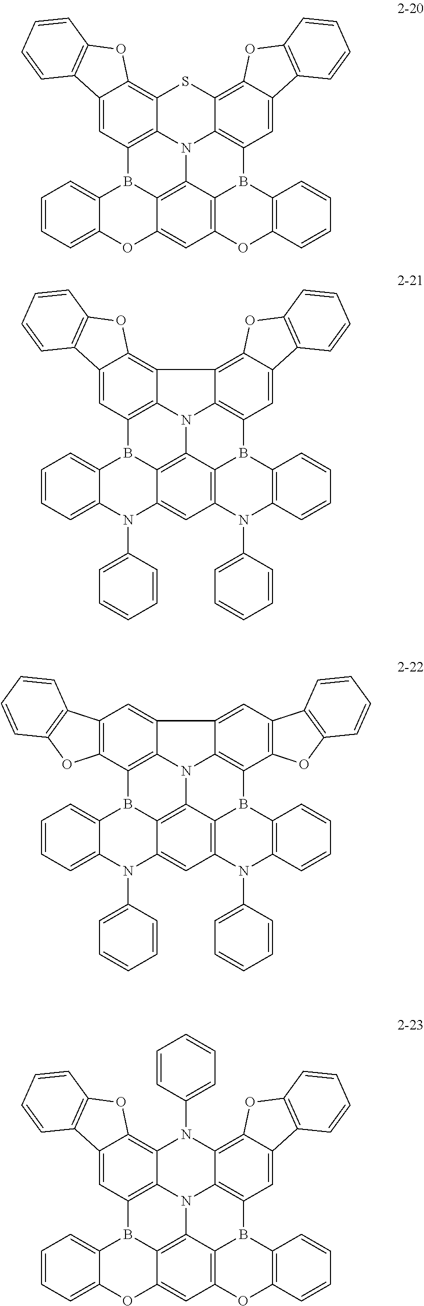

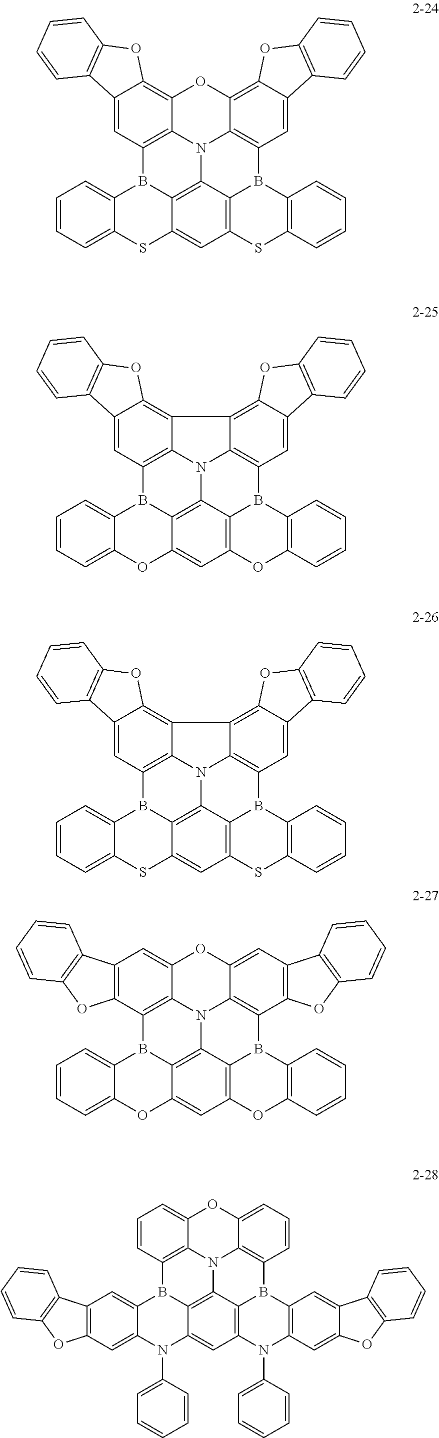 [SMILES: c1ccc2c(c1)Sc1cc3c4c5c1B2c1cc2c(oc6ccccc62)c2c1N5c1c(cc5c(oc6ccccc65)c1O2)B4c1ccccc1S3 ; c1ccc2c(c1)Oc1cc3c4c5c1B2c1cc2c6ccccc6oc2c2c6c7oc8ccccc8c7cc(c6n-5c12)B4c1ccccc1O3 ; c1ccc2c(c1)Sc1cc3c4c5c1B2c1cc2c6ccccc6oc2c2c6c7oc8ccccc8c7cc(c6n-5c12)B4c1ccccc1S3 ; c1ccc2c(c1)Oc1cc3c4c5c1B2c1c2c(cc6c1oc1ccccc16)Oc1cc6c(oc7ccccc76)c(c1N52)B4c1ccccc1O3 ; c1ccc(N2c3cc4oc5ccccc5c4cc3B3c4cccc5c4N4c6c(cccc6B6c7cc8c(cc7N(c7ccccc7)c7cc2c3c4c76)oc2ccccc28)O5)cc1]

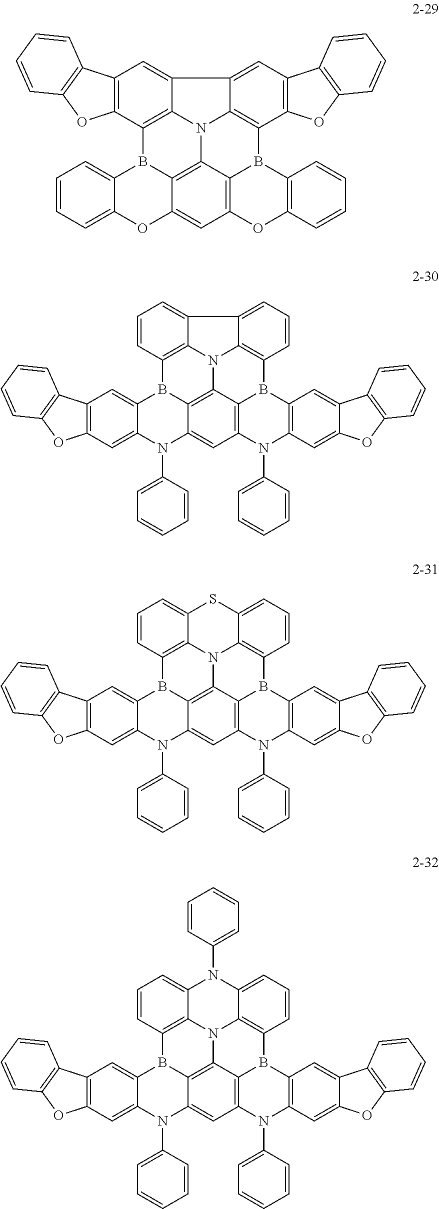 [SMILES: c1ccc2c(c1)Oc1cc3c4c5c1B2c1c2oc6ccccc6c2cc2c6cc7c(oc8ccccc87)c(c6n-5c12)B4c1ccccc1O3 ; c1ccc(N2c3cc4oc5ccccc5c4cc3B3c4c2cc2c5c4-n4c6c3cccc6c3cccc(c34)B5c3cc4c(cc3N2c2ccccc2)oc2ccccc24)cc1 ; c1ccc(N2c3cc4oc5ccccc5c4cc3B3c4cccc5c4N4c6c(cccc6B6c7cc8c(cc7N(c7ccccc7)c7cc2c3c4c76)oc2ccccc28)S5)cc1 ; c1ccc(N2c3cc4oc5ccccc5c4cc3B3c4cccc5c4N4c6c(cccc6N5c5ccccc5)B5c6cc7c(cc6N(c6ccccc6)c6cc2c3c4c65)oc2ccccc27)cc1]

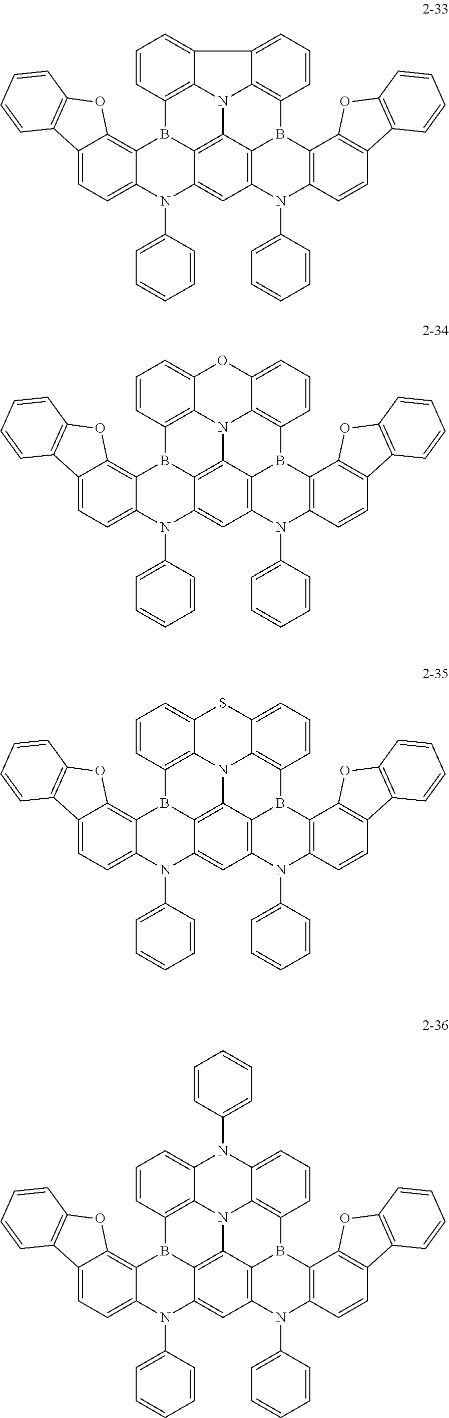 [SMILES: c1ccc(N2c3cc4c5c6c3B(c3c2ccc2c3oc3ccccc32)c2cccc3c7cccc(c7n-6c23)B5c2c(ccc3c2oc2ccccc23)N4c2ccccc2)cc1 ; c1ccc(N2c3cc4c5c6c3B(c3cccc7c3N6c3c(cccc3B5c3c(ccc5c3oc3ccccc35)N4c3ccccc3)O7)c3c2ccc2c3oc3ccccc32)cc1 ; c1ccc(N2c3cc4c5c6c3B(c3cccc7c3N6c3c(cccc3B5c3c(ccc5c3oc3ccccc35)N4c3ccccc3)S7)c3c2ccc2c3oc3ccccc32)cc1 ; c1ccc(N2c3cccc4c3N3c5c(cccc52)B2c5c(cc6c(c53)B4c3c(ccc4c3oc3ccccc34)N6c3ccccc3)N(c3ccccc3)c3ccc4c(oc5ccccc54)c32)cc1]

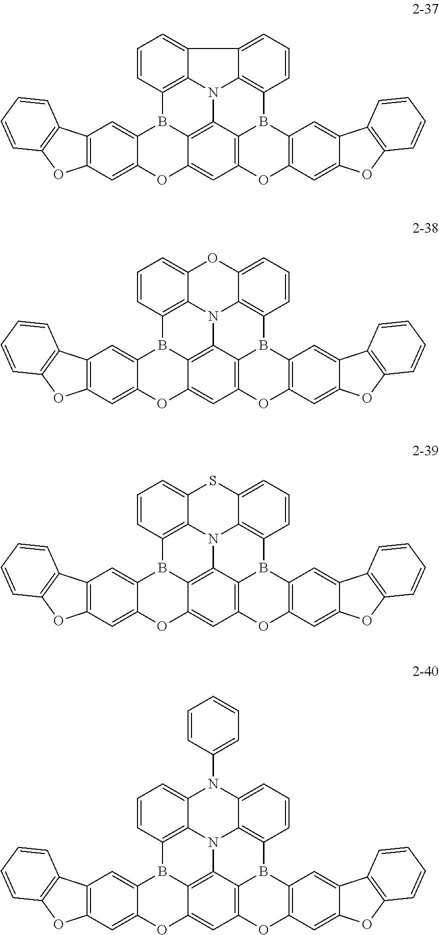 [SMILES: c1ccc2c(c1)oc1cc3c(cc12)B1c2c(cc4c5c2-n2c6c1cccc6c1cccc(c12)B5c1cc2c(cc1O4)oc1ccccc12)O3 ; c1cc2c3c(c1)B1c4cc5c(cc4Oc4cc6c7c(c41)N3c1c(cccc1B7c1cc3c(cc1O6)oc1ccccc13)O2)oc1ccccc15 ; c1cc2c3c(c1)B1c4cc5c(cc4Oc4cc6c7c(c41)N3c1c(cccc1B7c1cc3c(cc1O6)oc1ccccc13)S2)oc1ccccc15 ; c1ccc(N2c3cccc4c3N3c5c(cccc52)B2c5cc6c(cc5Oc5cc7c(c3c52)B4c2cc3c(cc2O7)oc2ccccc23)oc2ccccc26)cc1]

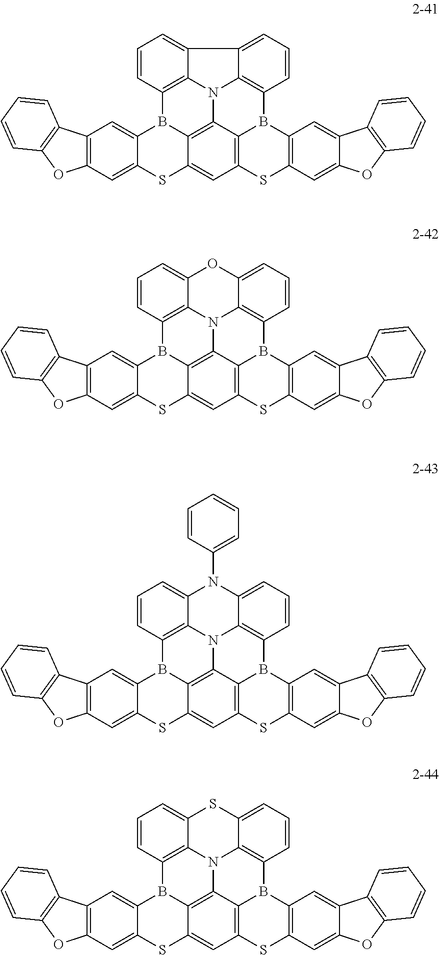 [SMILES: c1ccc2c(c1)oc1cc3c(cc12)B1c2c(cc4c5c2-n2c6c1cccc6c1cccc(c12)B5c1cc2c(cc1S4)oc1ccccc12)S3 ; c1cc2c3c(c1)B1c4cc5c(cc4Sc4cc6c7c(c41)N3c1c(cccc1B7c1cc3c(cc1S6)oc1ccccc13)O2)oc1ccccc15 ; c1ccc(N2c3cccc4c3N3c5c(cccc52)B2c5cc6c(cc5Sc5cc7c(c3c52)B4c2cc3c(cc2S7)oc2ccccc23)oc2ccccc26)cc1 ; c1cc2c3c(c1)B1c4cc5c(cc4Sc4cc6c7c(c41)N3c1c(cccc1B7c1cc3c(cc1S6)oc1ccccc13)S2)oc1ccccc15]

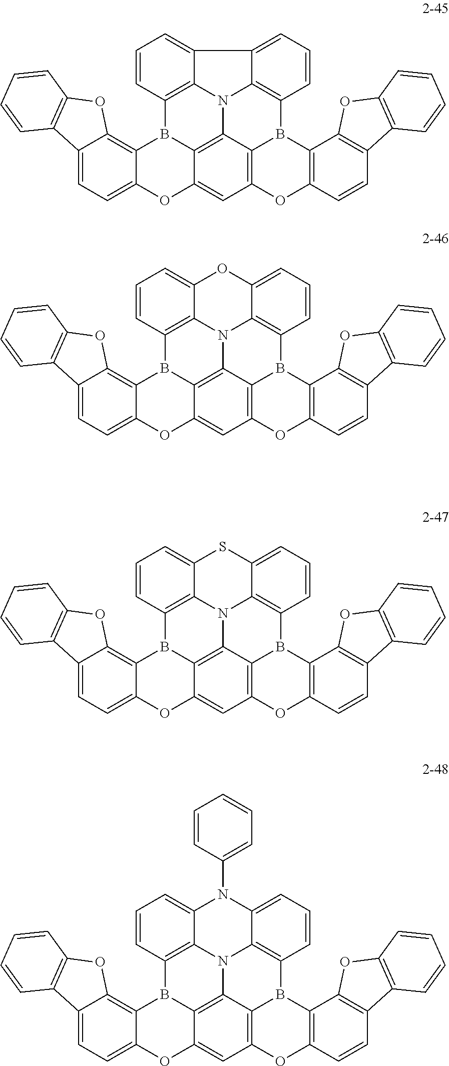 [SMILES: c1ccc2c(c1)oc1c3c(ccc12)Oc1cc2c4c5c1B3c1cccc3c6cccc(c6n-5c13)B4c1c(ccc3c1oc1ccccc13)O2 ; c1cc2c3c(c1)B1c4c(cc5c6c4N3c3c(cccc3B6c3c(ccc4c3oc3ccccc34)O5)O2)Oc2ccc3c(oc4ccccc43)c21 ; c1cc2c3c(c1)B1c4c(cc5c6c4N3c3c(cccc3B6c3c(ccc4c3oc3ccccc34)O5)S2)Oc2ccc3c(oc4ccccc43)c21 ; c1ccc(N2c3cccc4c3N3c5c(cccc52)B2c5c(cc6c(c53)B4c3c(ccc4c3oc3ccccc34)O6)Oc3ccc4c(oc5ccccc54)c32)cc1]

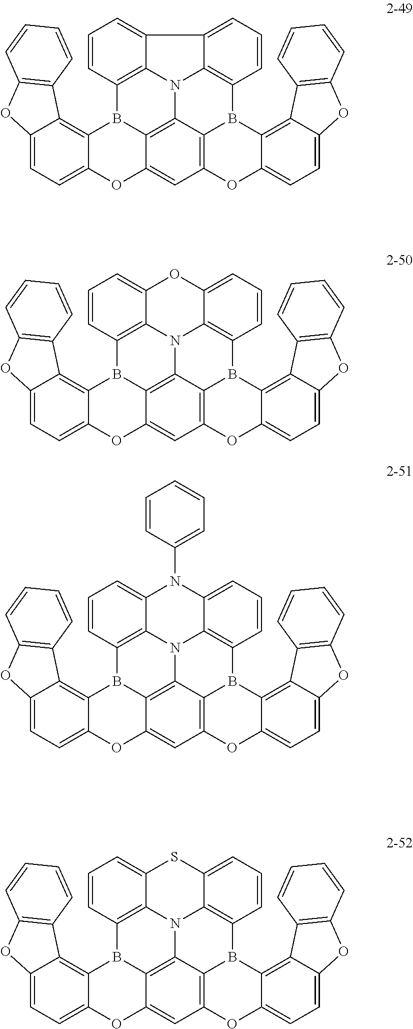

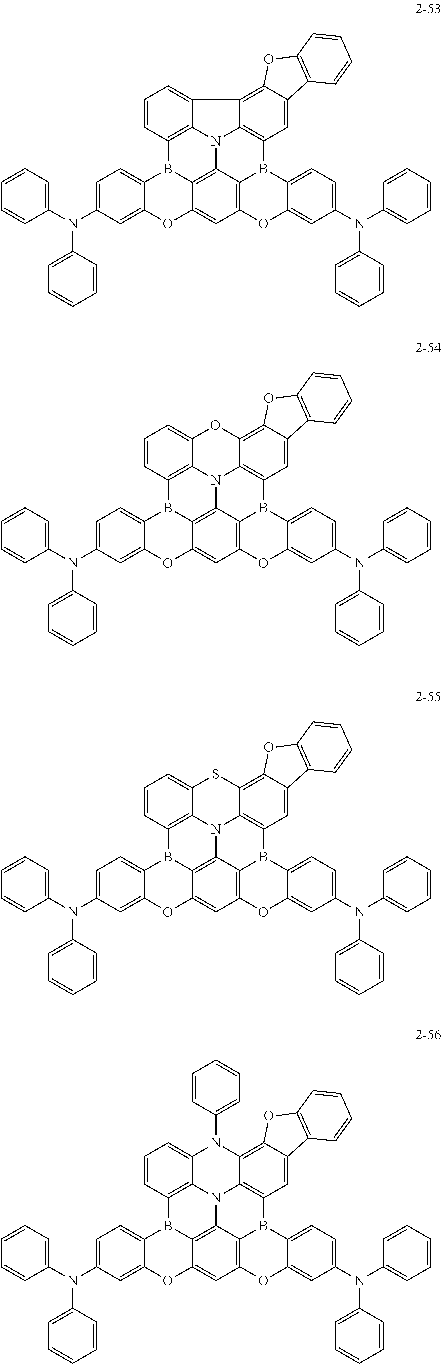 [SMILES: c1ccc(N(c2ccccc2)c2ccc3c(c2)Oc2cc4c5c6c2B3c2cccc3c7c8oc9ccccc9c8cc(c7n-6c23)B5c2ccc(N(c3ccccc3)c3ccccc3)cc2O4)cc1 ; c1ccc(N(c2ccccc2)c2ccc3c(c2)Oc2cc4c5c6c2B3c2cccc3c2N6c2c(cc6c(oc7ccccc76)c2O3)B5c2ccc(N(c3ccccc3)c3ccccc3)cc2O4)cc1 ; c1ccc(N(c2ccccc2)c2ccc3c(c2)Oc2cc4c5c6c2B3c2cccc3c2N6c2c(cc6c(oc7ccccc76)c2S3)B5c2ccc(N(c3ccccc3)c3ccccc3)cc2O4)cc1 ; c1ccc(N(c2ccccc2)c2ccc3c(c2)Oc2cc4c5c6c2B3c2cccc3c2N6c2c(cc6c(oc7ccccc76)c2N3c2ccccc2)B5c2ccc(N(c3ccccc3)c3ccccc3)cc2O4)cc1]

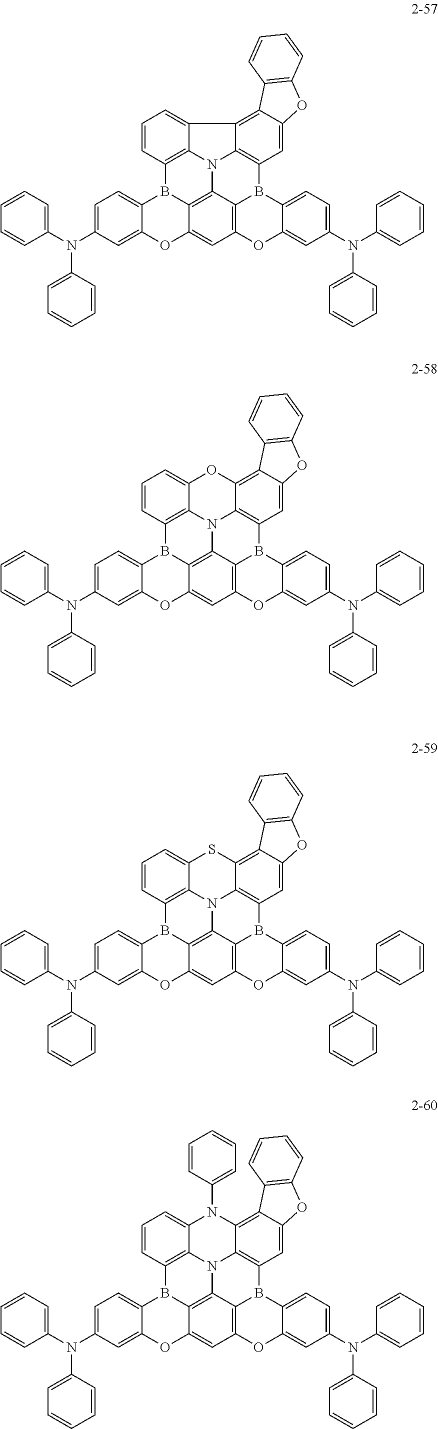 [SMILES: c1ccc(N(c2ccccc2)c2ccc3c(c2)Oc2cc4c5c6c2B3c2cccc3c7c8c(cc(c7n-6c23)B5c2ccc(N(c3ccccc3)c3ccccc3)cc2O4)oc2ccccc28)cc1 ; c1ccc(N(c2ccccc2)c2ccc3c(c2)Oc2cc4c5c6c2B3c2cccc3c2N6c2c(cc6oc7ccccc7c6c2O3)B5c2ccc(N(c3ccccc3)c3ccccc3)cc2O4)cc1 ; c1ccc(N(c2ccccc2)c2ccc3c(c2)Oc2cc4c5c6c2B3c2cccc3c2N6c2c(cc6oc7ccccc7c6c2S3)B5c2ccc(N(c3ccccc3)c3ccccc3)cc2O4)cc1 ; c1ccc(N(c2ccccc2)c2ccc3c(c2)Oc2cc4c5c6c2B3c2cccc3c2N6c2c(cc6oc7ccccc7c6c2N3c2ccccc2)B5c2ccc(N(c3ccccc3)c3ccccc3)cc2O4)cc1]

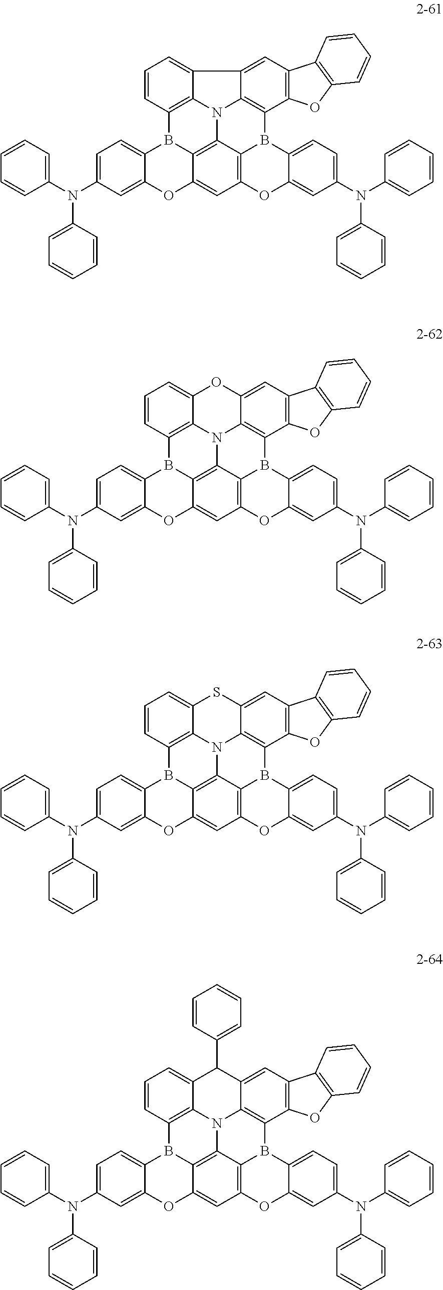 [SMILES: c1ccc(N(c2ccccc2)c2ccc3c(c2)Oc2cc4c5c6c2B3c2cccc3c7cc8c(oc9ccccc98)c(c7n-6c23)B5c2ccc(N(c3ccccc3)c3ccccc3)cc2O4)cc1 ; c1ccc(N(c2ccccc2)c2ccc3c(c2)Oc2cc4c5c6c2B3c2cccc3c2N6c2c(cc6c(oc7ccccc76)c2B5c2ccc(N(c5ccccc5)c5ccccc5)cc2O4)O3)cc1 ; c1ccc(N(c2ccccc2)c2ccc3c(c2)Oc2cc4c5c6c2B3c2cccc3c2N6c2c(cc6c(oc7ccccc76)c2B5c2ccc(N(c5ccccc5)c5ccccc5)cc2O4)S3)cc1 ; c1ccc(C2c3cccc4c3N3c5c6c(cc7c5B(c5ccc(N(c8ccccc8)c8ccccc8)cc5O7)c5c3c2cc2c5oc3ccccc32)Oc2cc(N(c3ccccc3)c3ccccc3)ccc2B46)cc1]

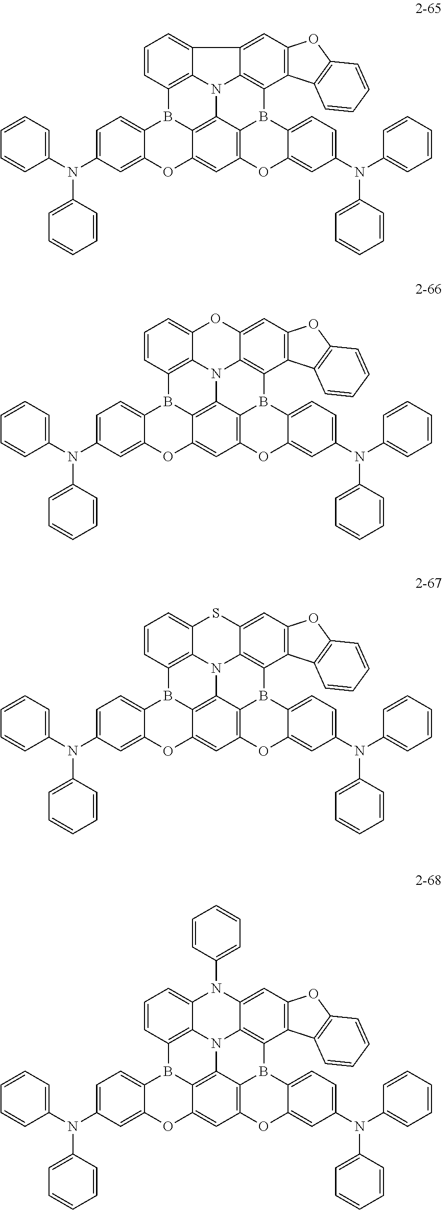 [SMILES: c1ccc(N(c2ccccc2)c2ccc3c(c2)Oc2cc4c5c6c2B3c2cccc3c7cc8oc9ccccc9c8c(c7n-6c23)B5c2ccc(N(c3ccccc3)c3ccccc3)cc2O4)cc1 ; c1ccc(N(c2ccccc2)c2ccc3c(c2)Oc2cc4c5c6c2B3c2cccc3c2N6c2c(cc6oc7ccccc7c6c2B5c2ccc(N(c5ccccc5)c5ccccc5)cc2O4)O3)cc1 ; c1ccc(N(c2ccccc2)c2ccc3c(c2)Oc2cc4c5c6c2B3c2cccc3c2N6c2c(cc6oc7ccccc7c6c2B5c2ccc(N(c5ccccc5)c5ccccc5)cc2O4)S3)cc1 ; c1ccc(N(c2ccccc2)c2ccc3c(c2)Oc2cc4c5c6c2B3c2cccc3c2N6c2c(cc6oc7ccccc7c6c2B5c2ccc(N(c5ccccc5)c5ccccc5)cc2O4)N3c2ccccc2)cc1]

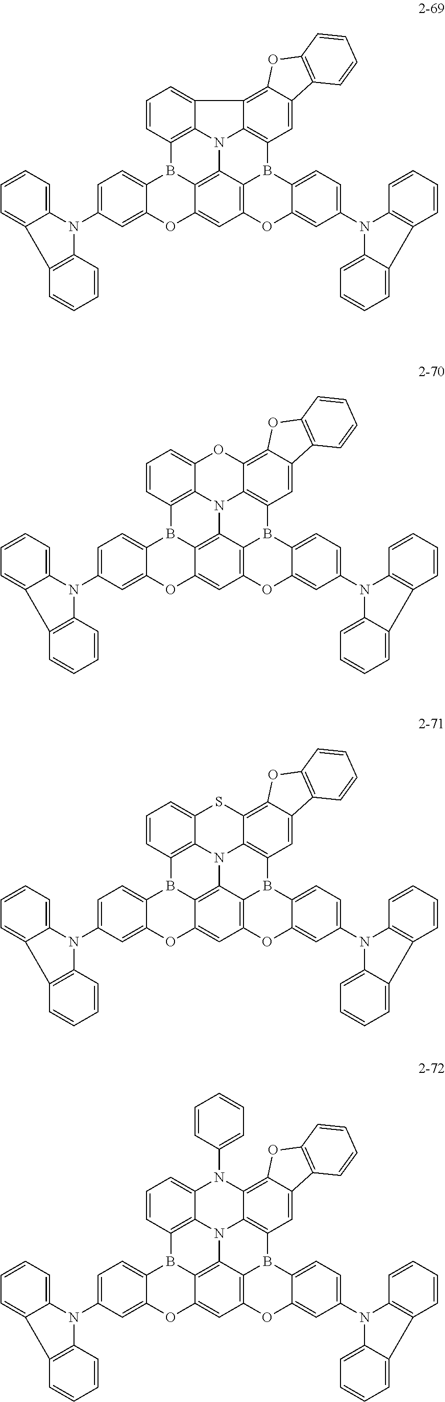 [SMILES: c1ccc2c(c1)oc1c2cc2c3c1c1cccc4c1n3-c1c3c(cc5c1B2c1ccc(-n2c6ccccc6c6ccccc62)cc1O5)Oc1cc(-n2c5ccccc5c5ccccc52)ccc1B34 ; c1cc2c3c(c1)B1c4ccc(-n5c6ccccc6c6ccccc65)cc4Oc4cc5c6c(c41)N3c1c(cc3c(oc4ccccc43)c1O2)B6c1ccc(-n2c3ccccc3c3ccccc32)cc1O5 ; c1cc2c3c(c1)B1c4ccc(-n5c6ccccc6c6ccccc65)cc4Oc4cc5c6c(c41)N3c1c(cc3c(oc4ccccc43)c1S2)B6c1ccc(-n2c3ccccc3c3ccccc32)cc1O5 ; c1ccc(N2c3cccc4c3N3c5c6c(cc7c5B(c5ccc(-n8c9ccccc9c9ccccc98)cc5O7)c5cc7c(oc8ccccc87)c2c53)Oc2cc(-n3c5ccccc5c5ccccc53)ccc2B46)cc1]

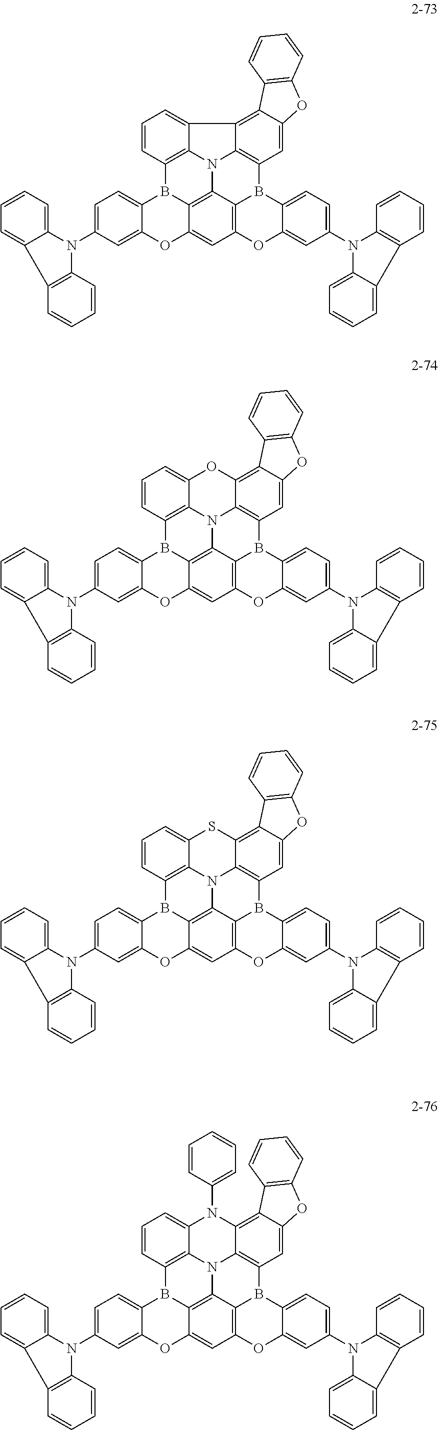 [SMILES: c1ccc2c(c1)oc1cc3c4c(c5cccc6c5n4-c4c5c(cc7c4B3c3ccc(-n4c8ccccc8c8ccccc84)cc3O7)Oc3cc(-n4c7ccccc7c7ccccc74)ccc3B56)c12 ; c1cc2c3c(c1)B1c4ccc(-n5c6ccccc6c6ccccc65)cc4Oc4cc5c6c(c41)N3c1c(cc3oc4ccccc4c3c1O2)B6c1ccc(-n2c3ccccc3c3ccccc32)cc1O5 ; c1cc2c3c(c1)B1c4ccc(-n5c6ccccc6c6ccccc65)cc4Oc4cc5c6c(c41)N3c1c(cc3oc4ccccc4c3c1S2)B6c1ccc(-n2c3ccccc3c3ccccc32)cc1O5 ; c1ccc(N2c3cccc4c3N3c5c6c(cc7c5B(c5ccc(-n8c9ccccc9c9ccccc98)cc5O7)c5cc7oc8ccccc8c7c2c53)Oc2cc(-n3c5ccccc5c5ccccc53)ccc2B46)cc1]

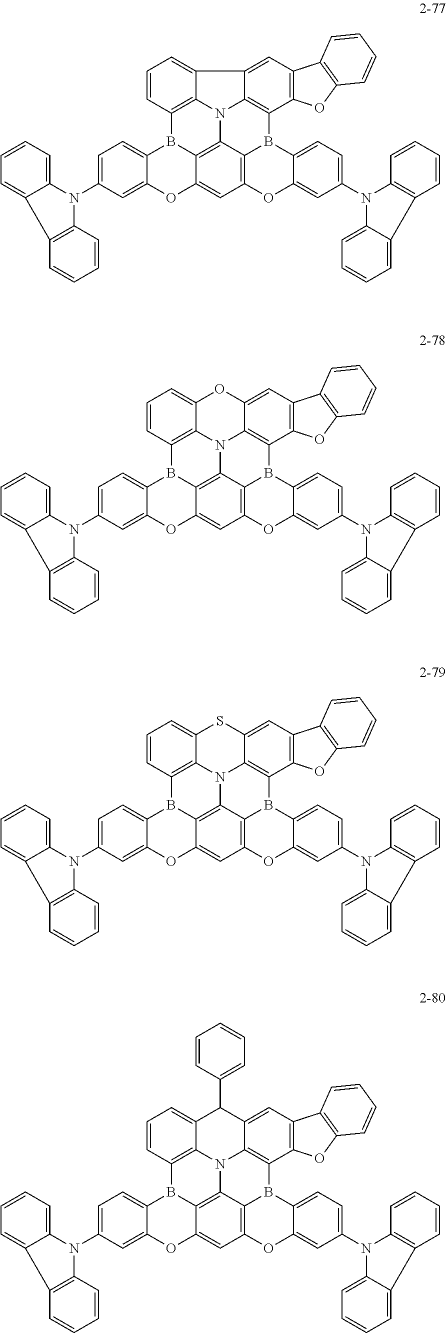 [SMILES: c1ccc2c(c1)oc1c3c4c(cc12)c1cccc2c1n4-c1c4c(cc5c1B3c1ccc(-n3c6ccccc6c6ccccc63)cc1O5)Oc1cc(-n3c5ccccc5c5ccccc53)ccc1B42 ; c1cc2c3c(c1)B1c4ccc(-n5c6ccccc6c6ccccc65)cc4Oc4cc5c6c(c41)N3c1c(cc3c(oc4ccccc43)c1B6c1ccc(-n3c4ccccc4c4ccccc43)cc1O5)O2 ; c1cc2c3c(c1)B1c4ccc(-n5c6ccccc6c6ccccc65)cc4Oc4cc5c6c(c41)N3c1c(cc3c(oc4ccccc43)c1B6c1ccc(-n3c4ccccc4c4ccccc43)cc1O5)S2 ; c1ccc(C2c3cccc4c3N3c5c6c(cc7c5B(c5ccc(-n8c9ccccc9c9ccccc98)cc5O7)c5c3c2cc2c5oc3ccccc32)Oc2cc(-n3c5ccccc5c5ccccc53)ccc2B46)cc1]

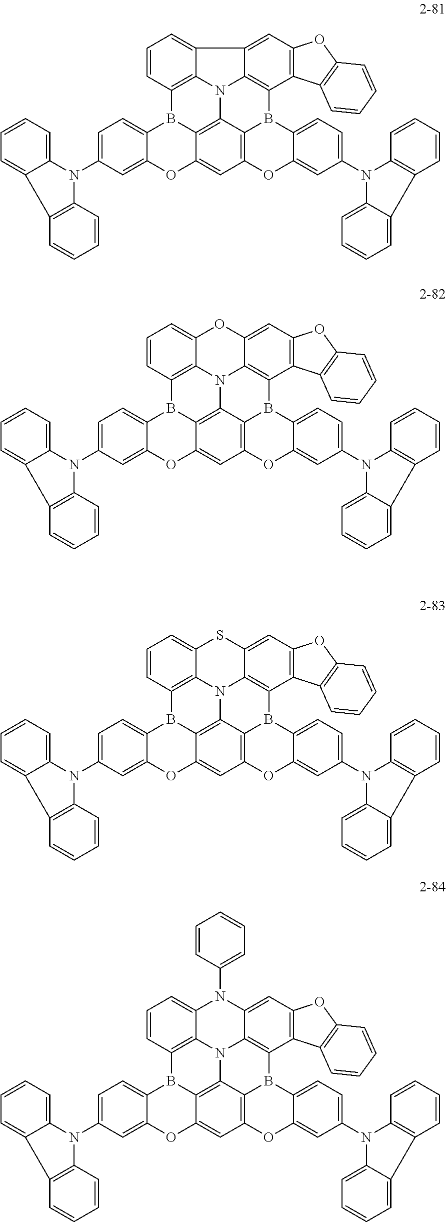 [SMILES: c1ccc2c(c1)oc1cc3c4cccc5c4n4c3c(c12)B1c2ccc(-n3c6ccccc6c6ccccc63)cc2Oc2cc3c(c-4c21)B5c1ccc(-n2c4ccccc4c4ccccc42)cc1O3 ; c1cc2c3c(c1)B1c4ccc(-n5c6ccccc6c6ccccc65)cc4Oc4cc5c6c(c41)N3c1c(cc3oc4ccccc4c3c1B6c1ccc(-n3c4ccccc4c4ccccc43)cc1O5)O2 ; c1cc2c3c(c1)B1c4ccc(-n5c6ccccc6c6ccccc65)cc4Oc4cc5c6c(c41)N3c1c(cc3oc4ccccc4c3c1B6c1ccc(-n3c4ccccc4c4ccccc43)cc1O5)S2 ; c1ccc(N2c3cccc4c3N3c5c6c(cc7c5B(c5ccc(-n8c9ccccc9c9ccccc98)cc5O7)c5c3c2cc2oc3ccccc3c52)Oc2cc(-n3c5ccccc5c5ccccc53)ccc2B46)cc1]

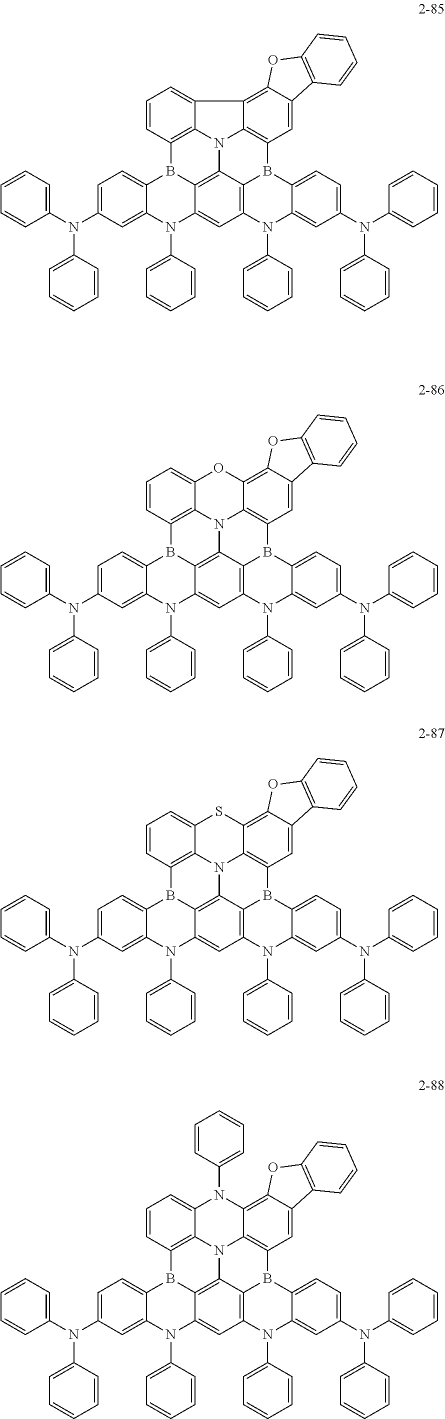

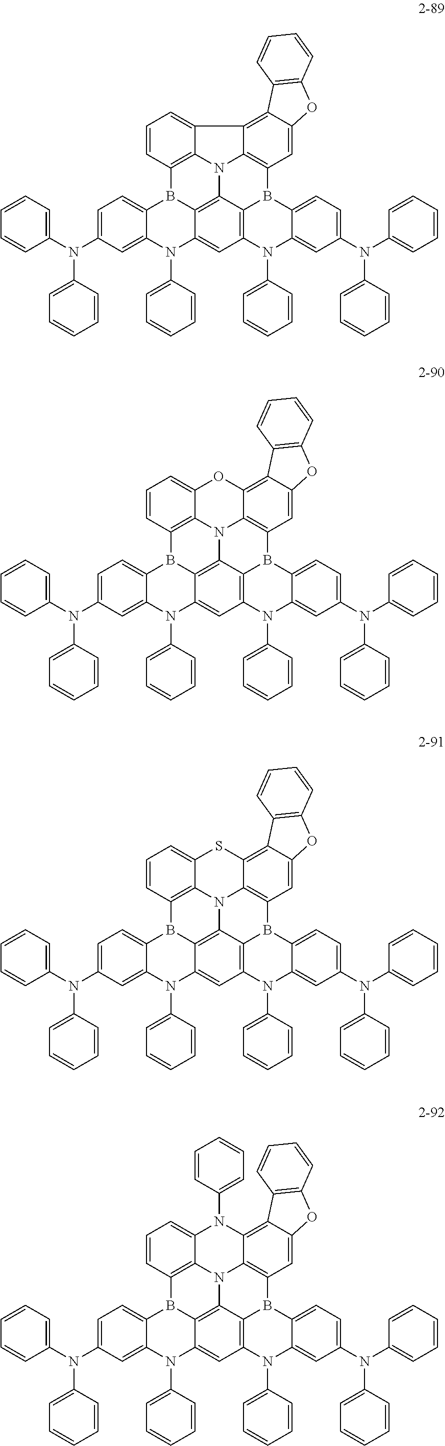

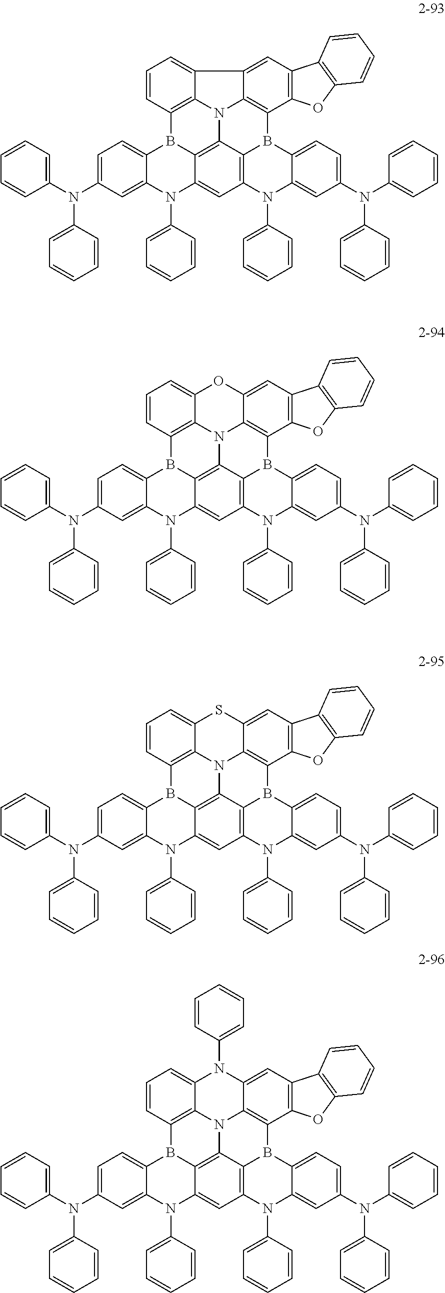

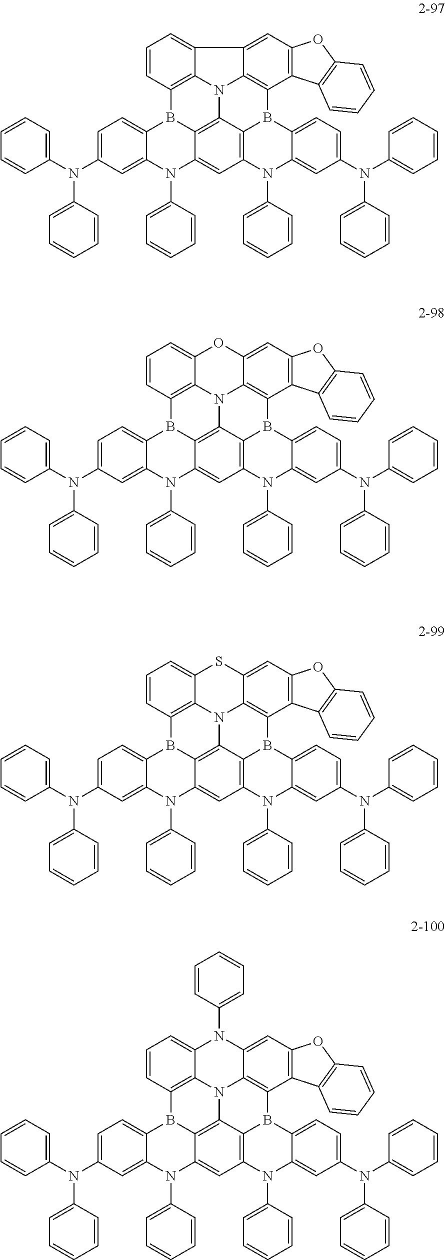

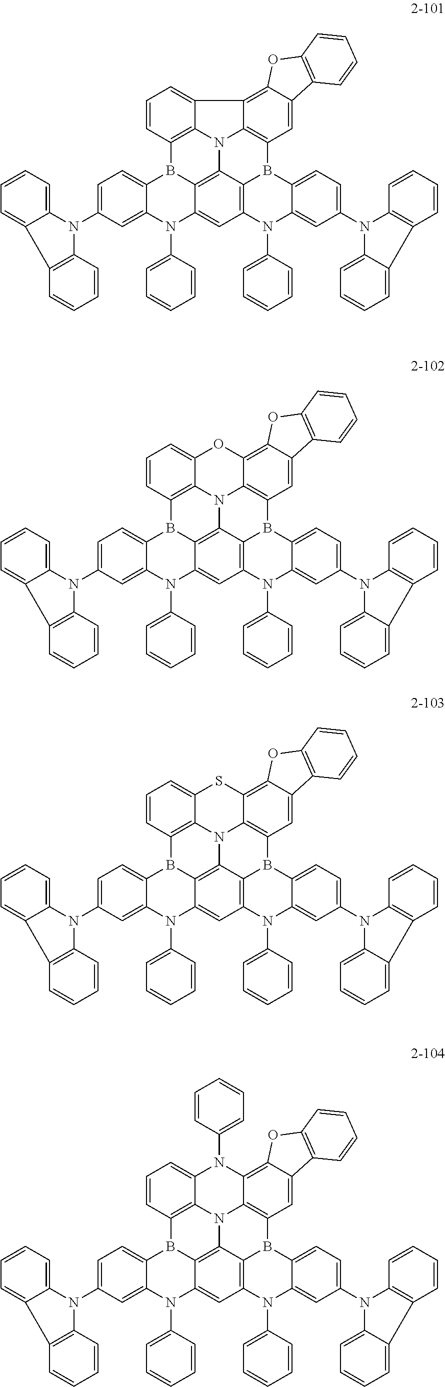

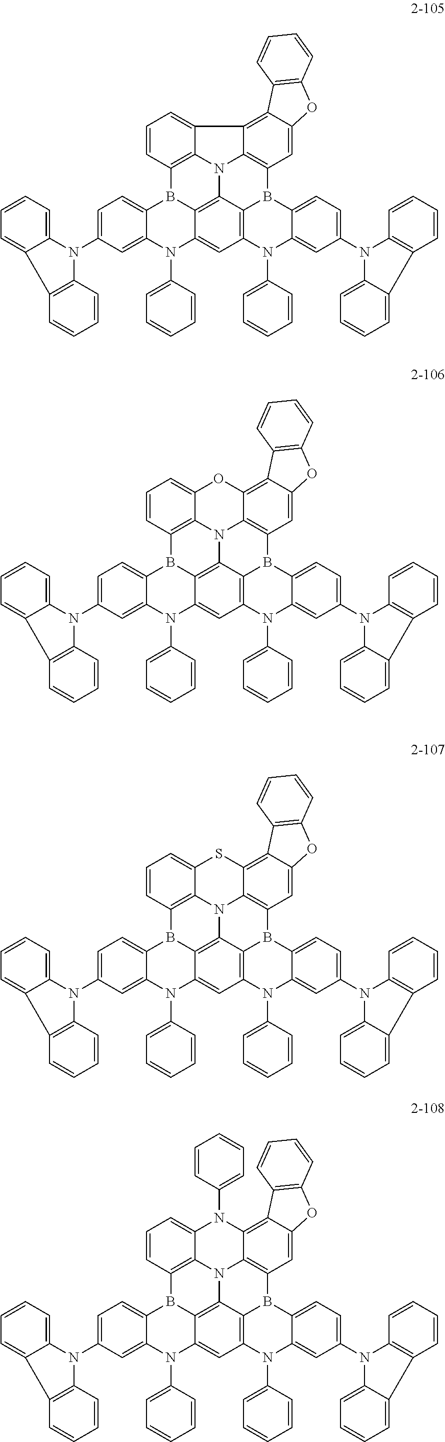

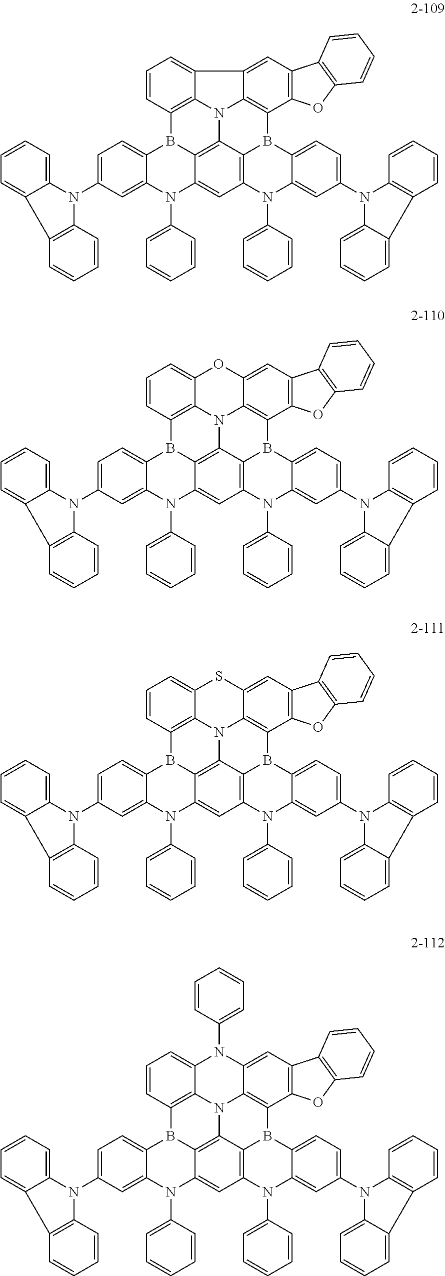

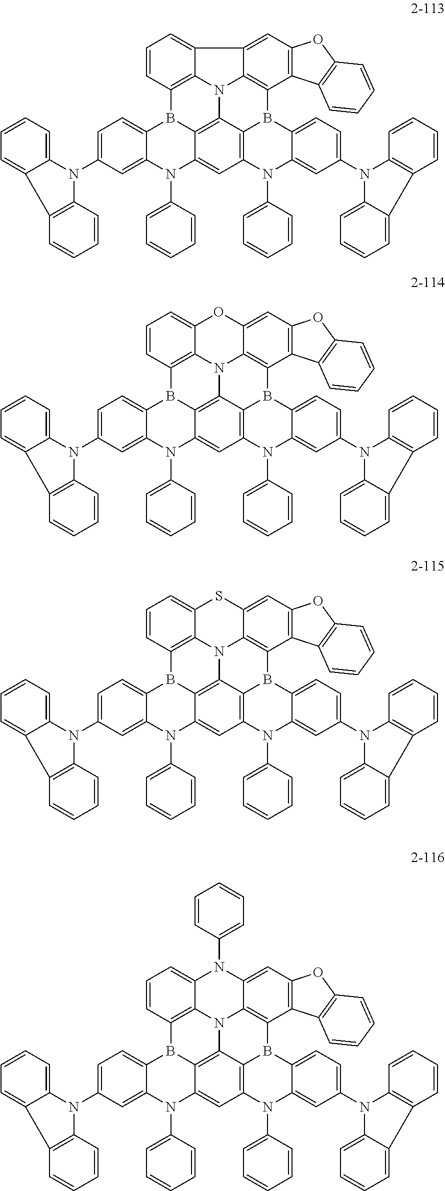

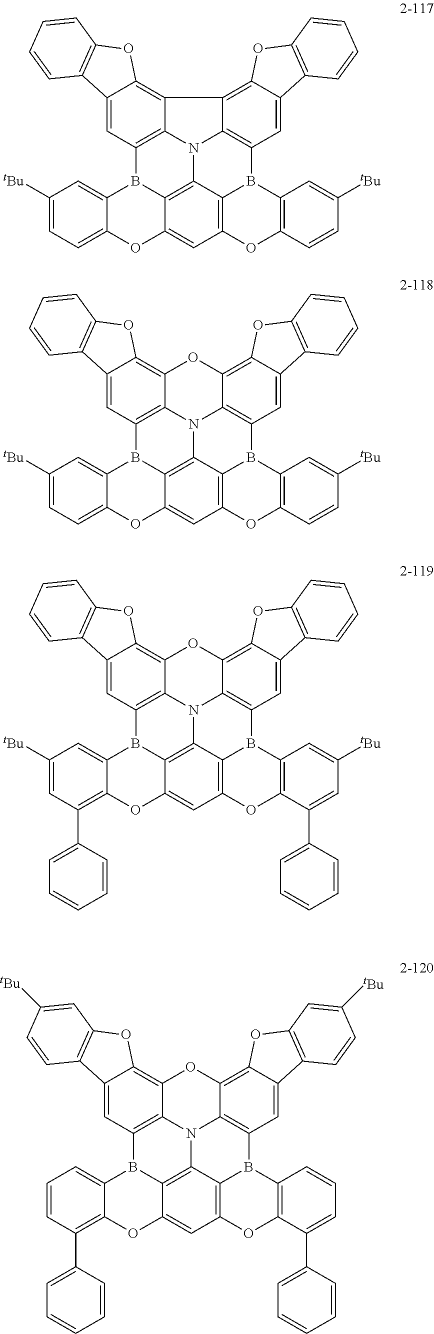

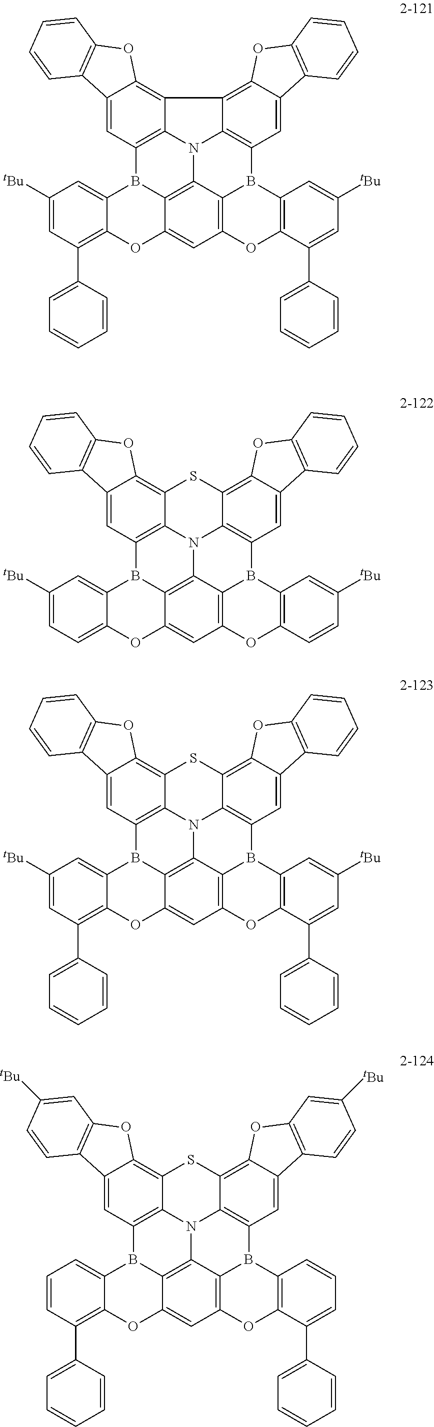 [SMILES: CC(C)(C)c1cc2c(c(-c3ccccc3)c1)Oc1cc3c4c5c1B2c1cc2c6ccccc6oc2c2c6c7oc8ccccc8c7cc(c6n-5c12)B4c1cc(C(C)(C)C)cc(-c2ccccc2)c1O3 ; CC(C)(C)c1ccc2c(c1)B1c3cc4c(oc5ccccc54)c4c3N3c5c1c(cc1c5B(c5cc(C(C)(C)C)ccc5O1)c1cc5c(oc6ccccc65)c(c13)S4)O2 ; CC(C)(C)c1cc2c(c(-c3ccccc3)c1)Oc1cc3c4c5c1B2c1cc2c(oc6ccccc62)c2c1N5c1c(cc5c(oc6ccccc65)c1S2)B4c1cc(C(C)(C)C)cc(-c2ccccc2)c1O3 ; CC(C)(C)c1ccc2c(c1)oc1c3c4c(cc12)B1c2cccc(-c5ccccc5)c2Oc2cc5c6c(c21)N4c1c(cc2c(oc4cc(C(C)(C)C)ccc42)c1S3)B6c1cccc(-c2ccccc2)c1O5]

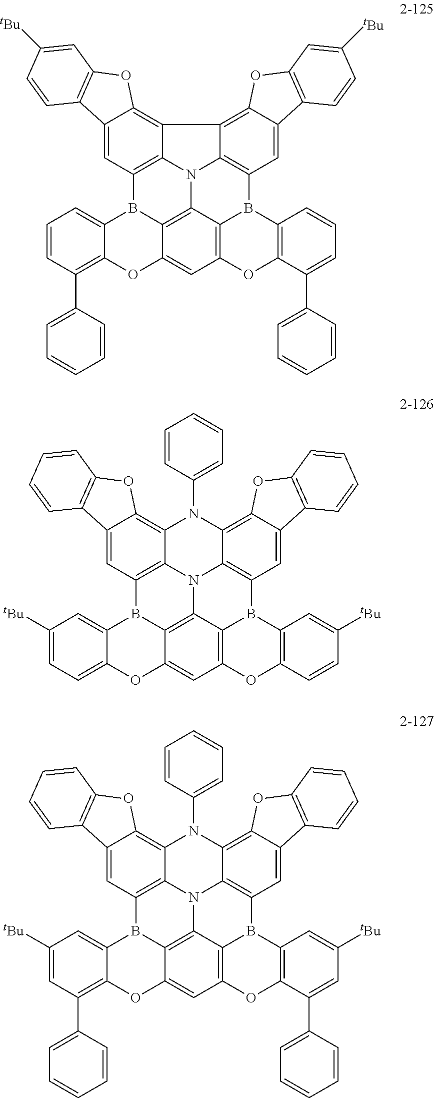 [SMILES: CC(C)(C)c1ccc2c(c1)oc1c2cc2c3c1c1c4oc5cc(C(C)(C)C)ccc5c4cc4c1n3-c1c3c(cc5c1B4c1cccc(-c4ccccc4)c1O5)Oc1c(cccc1-c1ccccc1)B32 ; CC(C)(C)c1ccc2c(c1)B1c3cc4c(oc5ccccc54)c4c3N3c5c1c(cc1c5B(c5cc(C(C)(C)C)ccc5O1)c1cc5c(oc6ccccc65)c(c13)N4c1ccccc1)O2 ; CC(C)(C)c1cc2c(c(-c3ccccc3)c1)Oc1cc3c4c5c1B2c1cc2c(oc6ccccc62)c2c1N5c1c(cc5c(oc6ccccc65)c1N2c1ccccc1)B4c1cc(C(C)(C)C)cc(-c2ccccc2)c1O3]

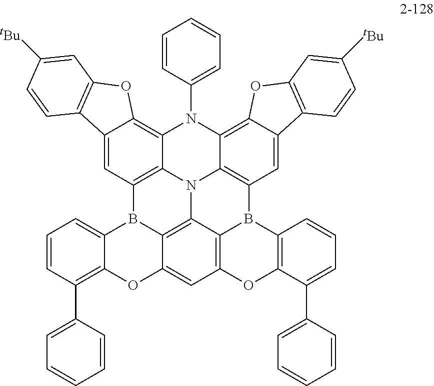 [SMILES: CC(C)(C)c1ccc2c(c1)oc1c3c4c(cc12)B1c2cccc(-c5ccccc5)c2Oc2cc5c6c(c21)N4c1c(cc2c(oc4cc(C(C)(C)C)ccc42)c1N3c1ccccc1)B6c1cccc(-c2ccccc2)c1O5]

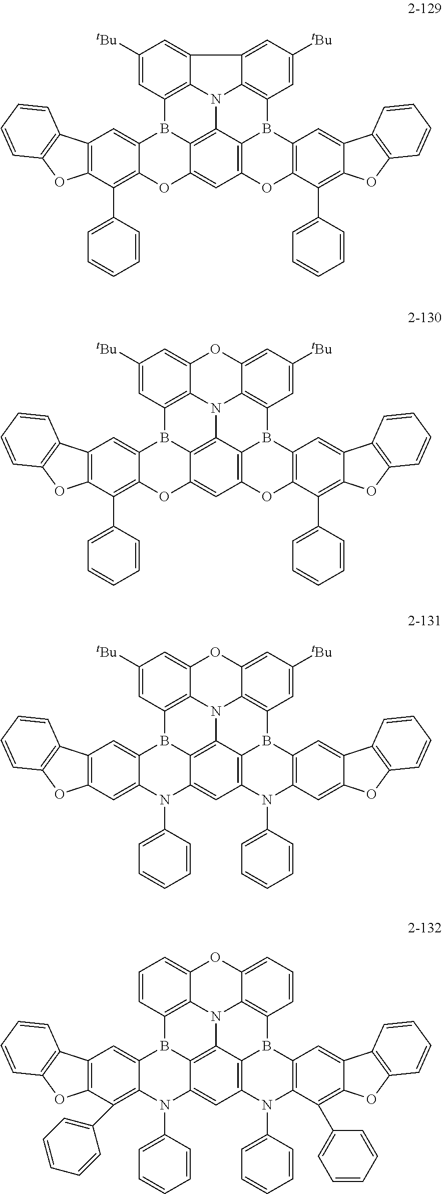

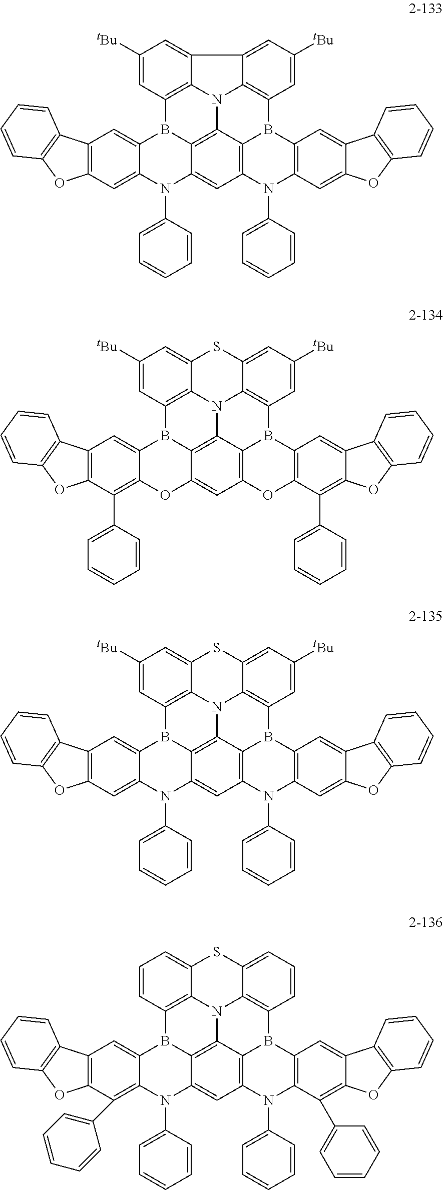

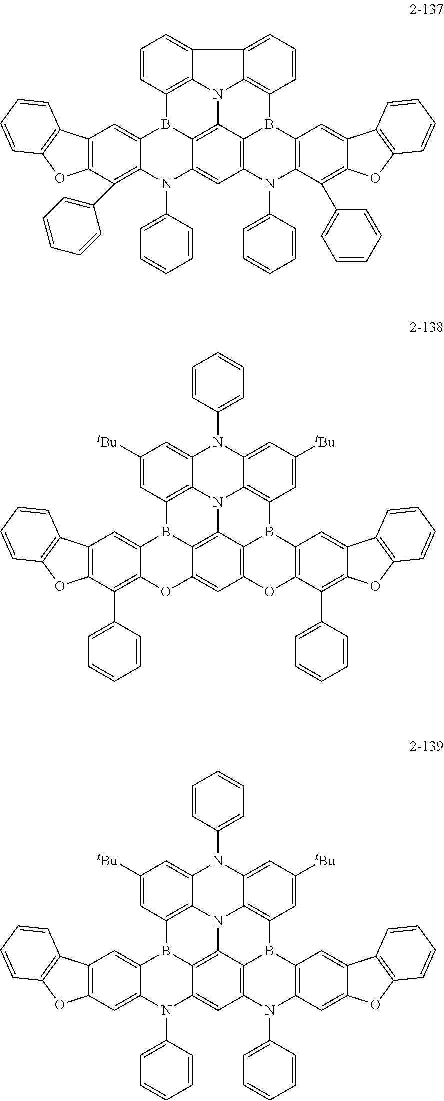 [SMILES: c1ccc(-c2c3c(cc4c2oc2ccccc24)B2c4c(cc5c6c4-n4c7c2cccc7c2cccc(c24)B6c2cc4c(oc6ccccc64)c(-c4ccccc4)c2N5c2ccccc2)N3c2ccccc2)cc1 ; CC(C)(C)c1cc2c3c(c1)N(c1ccccc1)c1cc(C(C)(C)C)cc4c1N3c1c3c(cc5c1B4c1cc4c(oc6ccccc64)c(-c4ccccc4)c1O5)Oc1c(cc4c(oc5ccccc54)c1-c1ccccc1)B23 ; CC(C)(C)c1cc2c3c(c1)N(c1ccccc1)c1cc(C(C)(C)C)cc4c1N3c1c3c(cc5c1B4c1cc4c(cc1N5c1ccccc1)oc1ccccc14)N(c1ccccc1)c1cc4oc5ccccc5c4cc1B23]

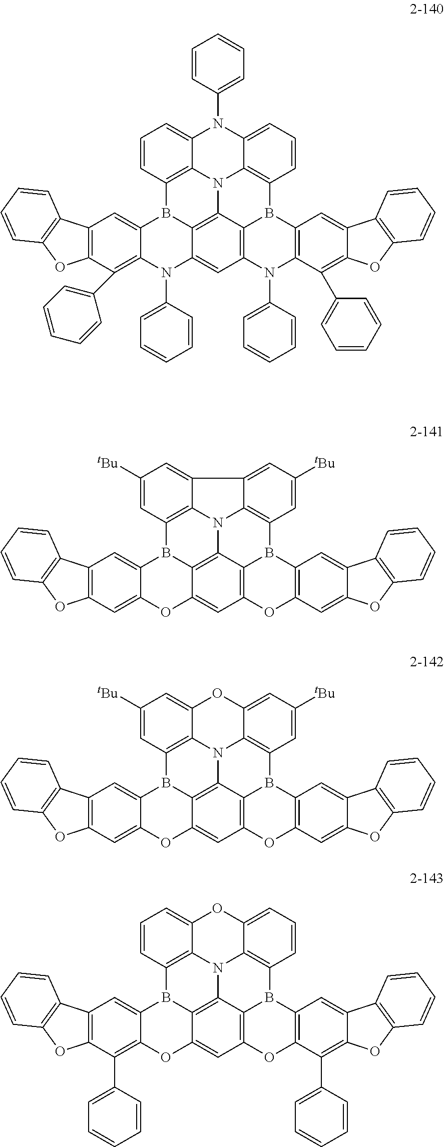 [SMILES: c1ccc(-c2c3c(cc4c2oc2ccccc24)B2c4cccc5c4N4c6c(cccc6N5c5ccccc5)B5c6cc7c(oc8ccccc87)c(-c7ccccc7)c6N(c6ccccc6)c6cc(c2c4c65)N3c2ccccc2)cc1 ; CC(C)(C)c1cc2c3c(c1)c1cc(C(C)(C)C)cc4c1n3-c1c3c(cc5c1B4c1cc4c(cc1O5)oc1ccccc14)Oc1cc4oc5ccccc5c4cc1B32 ; CC(C)(C)c1cc2c3c(c1)B1c4cc5c(cc4Oc4cc6c7c(c41)N3c1c(cc(C(C)(C)C)cc1B7c1cc3c(cc1O6)oc1ccccc13)O2)oc1ccccc15 ; c1ccc(-c2c3c(cc4c2oc2ccccc24)B2c4cccc5c4N4c6c(cccc6B6c7cc8c(oc9ccccc98)c(-c8ccccc8)c7Oc7cc(c2c4c76)O3)O5)cc1]

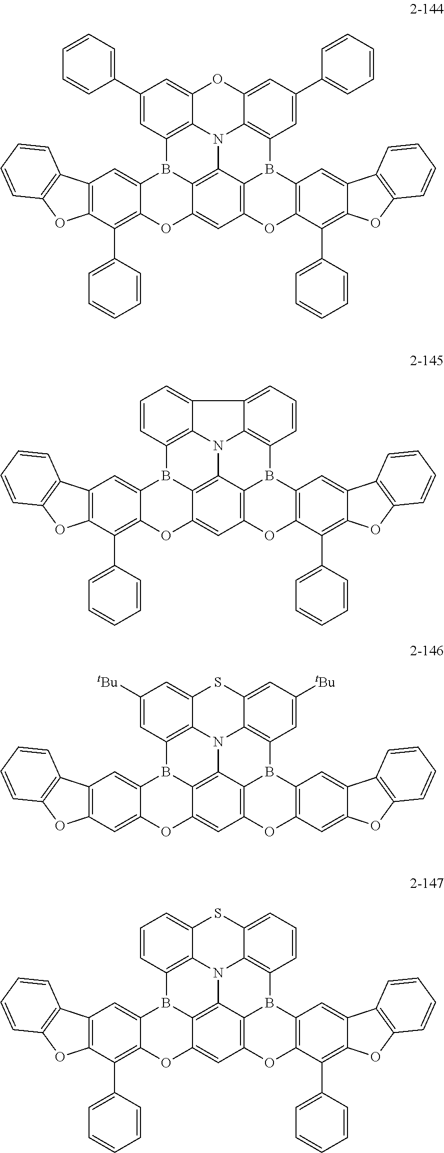 [SMILES: c1ccc(-c2cc3c4c(c2)B2c5cc6c(oc7ccccc76)c(-c6ccccc6)c5Oc5cc6c7c(c52)N4c2c(cc(-c4ccccc4)cc2B7c2cc4c(oc5ccccc54)c(-c4ccccc4)c2O6)O3)cc1 ; c1ccc(-c2c3c(cc4c2oc2ccccc24)B2c4c(cc5c6c4-n4c7c2cccc7c2cccc(c24)B6c2cc4c(oc6ccccc64)c(-c4ccccc4)c2O5)O3)cc1 ; CC(C)(C)c1cc2c3c(c1)B1c4cc5c(cc4Oc4cc6c7c(c41)N3c1c(cc(C(C)(C)C)cc1B7c1cc3c(cc1O6)oc1ccccc13)S2)oc1ccccc15 ; c1ccc(-c2c3c(cc4c2oc2ccccc24)B2c4cccc5c4N4c6c(cccc6B6c7cc8c(oc9ccccc98)c(-c8ccccc8)c7Oc7cc(c2c4c76)O3)S5)cc1]

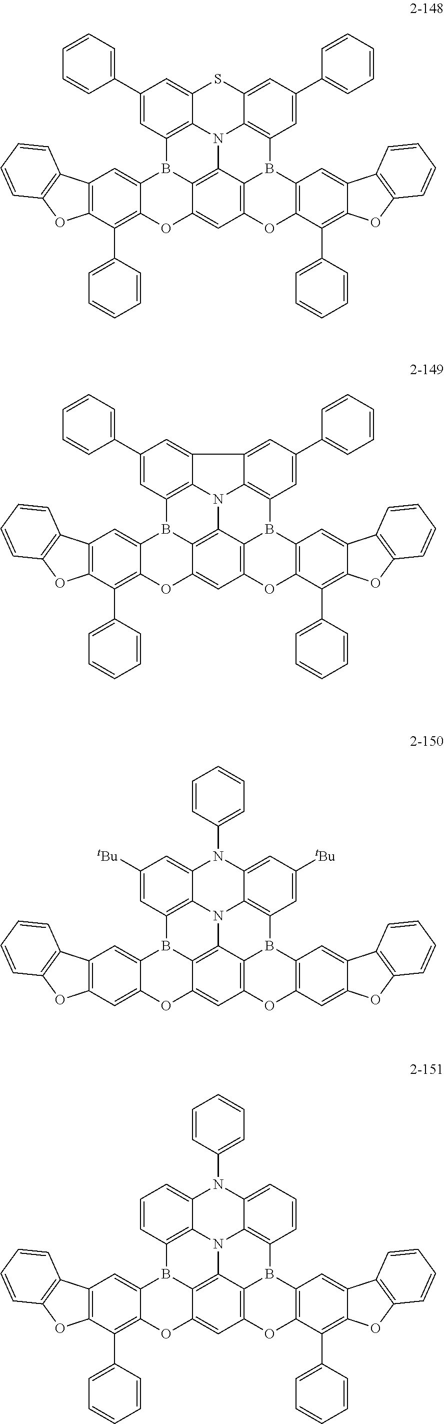 [SMILES: c1ccc(-c2cc3c4c(c2)B2c5cc6c(oc7ccccc76)c(-c6ccccc6)c5Oc5cc6c7c(c52)N4c2c(cc(-c4ccccc4)cc2B7c2cc4c(oc5ccccc54)c(-c4ccccc4)c2O6)S3)cc1 ; c1ccc(-c2cc3c4c(c2)c2cc(-c5ccccc5)cc5c2n4-c2c4c(cc6c2B5c2cc5c(oc7ccccc75)c(-c5ccccc5)c2O6)Oc2c(cc5c(oc6ccccc65)c2-c2ccccc2)B43)cc1 ; CC(C)(C)c1cc2c3c(c1)N(c1ccccc1)c1cc(C(C)(C)C)cc4c1N3c1c3c(cc5c1B4c1cc4c(cc1O5)oc1ccccc14)Oc1cc4oc5ccccc5c4cc1B23 ; c1ccc(-c2c3c(cc4c2oc2ccccc24)B2c4cccc5c4N4c6c(cccc6N5c5ccccc5)B5c6cc7c(oc8ccccc87)c(-c7ccccc7)c6Oc6cc(c2c4c65)O3)cc1]

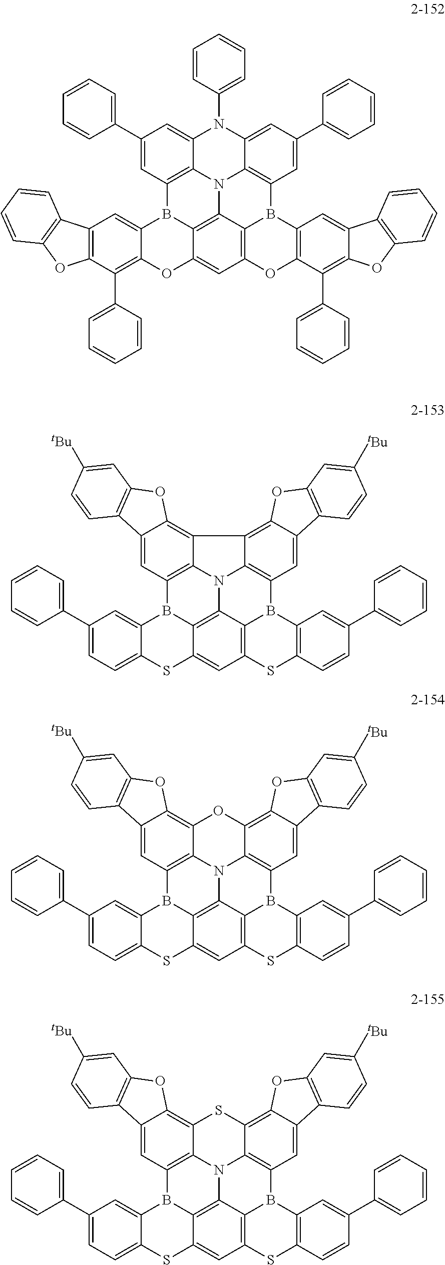

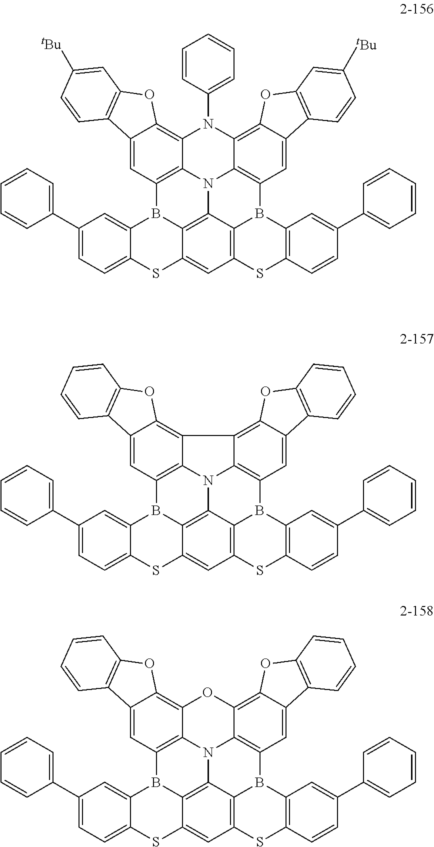 [SMILES: CC(C)(C)c1ccc2c(c1)oc1c3c4c(cc12)B1c2cc(-c5ccccc5)ccc2Sc2cc5c6c(c21)N4c1c(cc2c(oc4cc(C(C)(C)C)ccc42)c1N3c1ccccc1)B6c1cc(-c2ccccc2)ccc1S5 ; c1ccc(-c2ccc3c(c2)B2c4c(cc5c6c4-n4c7c2cc2c8ccccc8oc2c7c2c7oc8ccccc8c7cc(c24)B6c2cc(-c4ccccc4)ccc2S5)S3)cc1 ; c1ccc(-c2ccc3c(c2)B2c4cc5c(oc6ccccc65)c5c4N4c6c2c(cc2c6B(c6cc(-c7ccccc7)ccc6S2)c2cc6c(oc7ccccc76)c(c24)O5)S3)cc1]

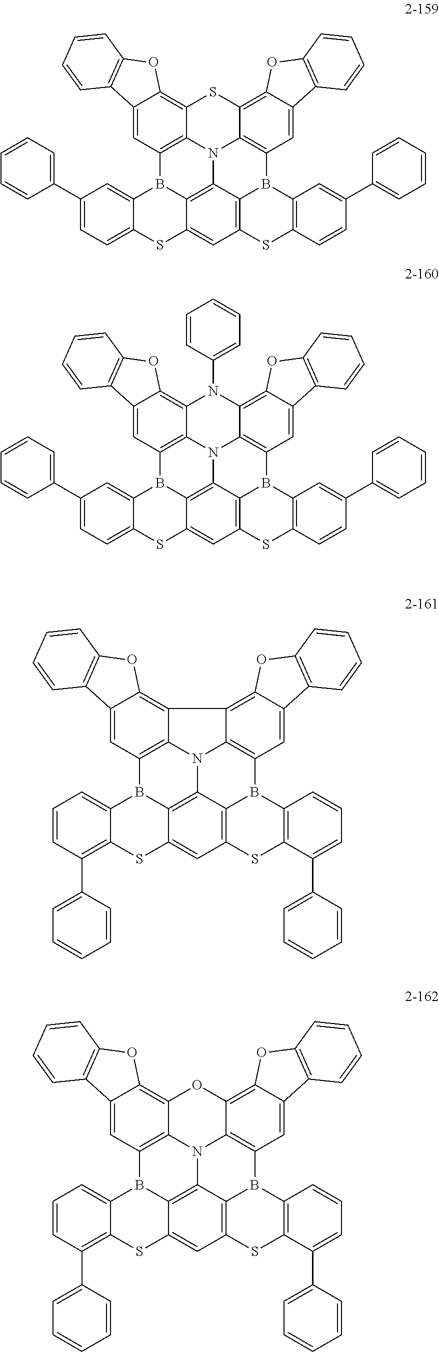 [SMILES: c1ccc(-c2ccc3c(c2)B2c4cc5c(oc6ccccc65)c5c4N4c6c2c(cc2c6B(c6cc(-c7ccccc7)ccc6S2)c2cc6c(oc7ccccc76)c(c24)S5)S3)cc1 ; c1ccc(-c2ccc3c(c2)B2c4cc5c(oc6ccccc65)c5c4N4c6c2c(cc2c6B(c6cc(-c7ccccc7)ccc6S2)c2cc6c(oc7ccccc76)c(c24)N5c2ccccc2)S3)cc1 ; c1ccc(-c2cccc3c2Sc2cc4c5c6c2B3c2cc3c7ccccc7oc3c3c7c8oc9ccccc9c8cc(c7n-6c23)B5c2cccc(-c3ccccc3)c2S4)cc1 ; c1ccc(-c2cccc3c2Sc2cc4c5c6c2B3c2cc3c(oc7ccccc73)c3c2N6c2c(cc6c(oc7ccccc76)c2O3)B5c2cccc(-c3ccccc3)c2S4)cc1]

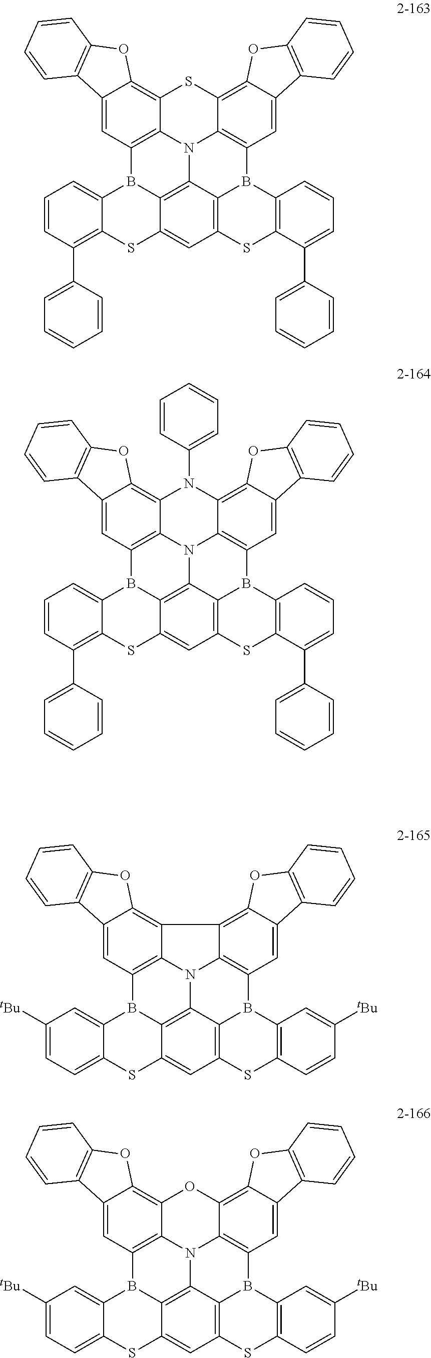 [SMILES: c1ccc(-c2cccc3c2Sc2cc4c5c6c2B3c2cc3c(oc7ccccc73)c3c2N6c2c(cc6c(oc7ccccc76)c2S3)B5c2cccc(-c3ccccc3)c2S4)cc1 ; c1ccc(-c2cccc3c2Sc2cc4c5c6c2B3c2cc3c(oc7ccccc73)c3c2N6c2c(cc6c(oc7ccccc76)c2N3c2ccccc2)B5c2cccc(-c3ccccc3)c2S4)cc1 ; CC(C)(C)c1ccc2c(c1)B1c3c(cc4c5c3-n3c6c1cc1c7ccccc7oc1c6c1c6oc7ccccc7c6cc(c13)B5c1cc(C(C)(C)C)ccc1S4)S2 ; CC(C)(C)c1ccc2c(c1)B1c3cc4c(oc5ccccc54)c4c3N3c5c1c(cc1c5B(c5cc(C(C)(C)C)ccc5S1)c1cc5c(oc6ccccc65)c(c13)O4)S2]

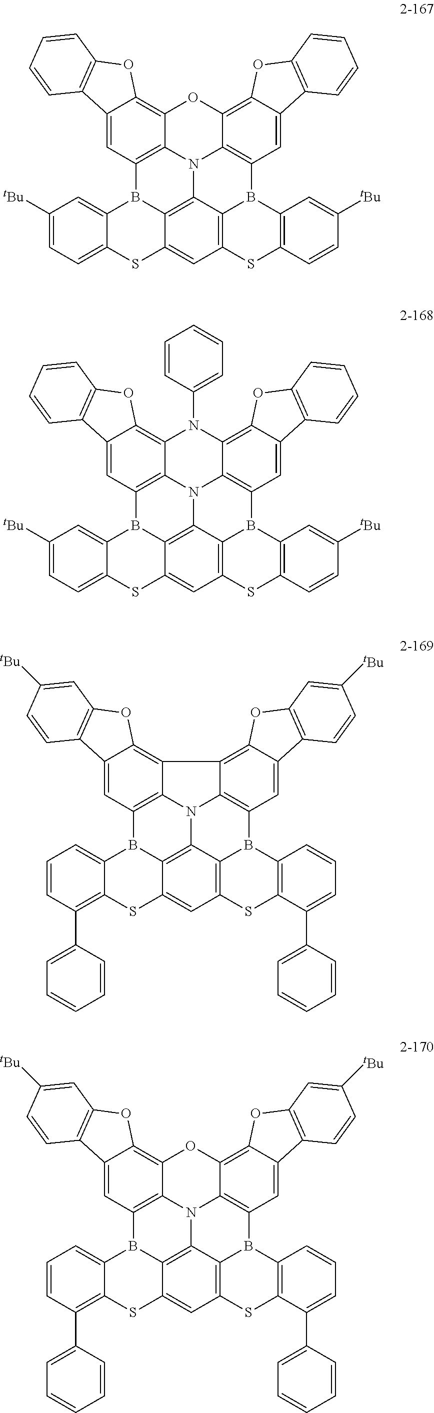 [SMILES: CC(C)(C)c1ccc2c(c1)B1c3cc4c(oc5ccccc54)c4c3N3c5c1c(cc1c5B(c5cc(C(C)(C)C)ccc5S1)c1cc5c(oc6ccccc65)c(c13)O4)S2 ; CC(C)(C)c1ccc2c(c1)B1c3cc4c(oc5ccccc54)c4c3N3c5c1c(cc1c5B(c5cc(C(C)(C)C)ccc5S1)c1cc5c(oc6ccccc65)c(c13)N4c1ccccc1)S2 ; CC(C)(C)c1ccc2c(c1)oc1c2cc2c3c1c1c4oc5cc(C(C)(C)C)ccc5c4cc4c1n3-c1c3c(cc5c1B4c1cccc(-c4ccccc4)c1S5)Sc1c(cccc1-c1ccccc1)B32 ; CC(C)(C)c1ccc2c(c1)oc1c3c4c(cc12)B1c2cccc(-c5ccccc5)c2Sc2cc5c6c(c21)N4c1c(cc2c(oc4cc(C(C)(C)C)ccc42)c1O3)B6c1cccc(-c2ccccc2)c1S5]

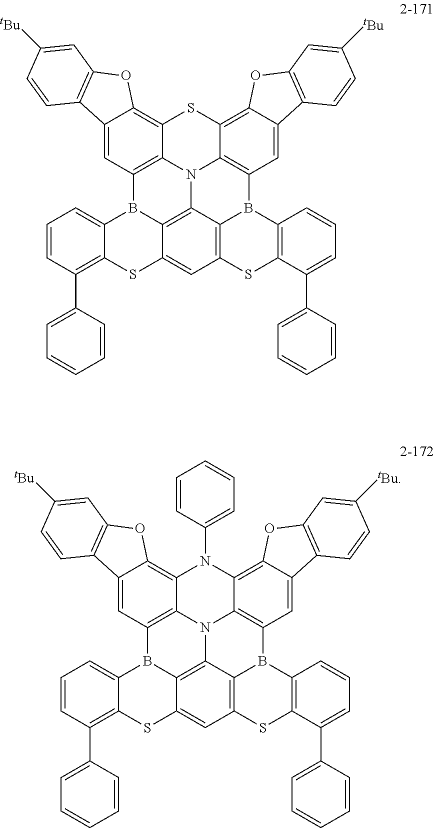 [SMILES: CC(C)(C)c1ccc2c(c1)oc1c3c4c(cc12)B1c2cccc(-c5ccccc5)c2Sc2cc5c6c(c21)N4c1c(cc2c(oc4cc(C(C)(C)C)ccc42)c1S3)B6c1cccc(-c2ccccc2)c1S5 ; CC(C)(C)c1ccc2c(c1)oc1c3c4c(cc12)B1c2cccc(-c5ccccc5)c2Sc2cc5c6c(c21)N4c1c(cc2c(oc4cc(C(C)(C)C)ccc42)c1N3c1ccccc1)B6c1cccc(-c2ccccc2)c1S5]

13. The condensed cyclic compound of claim 1, wherein a reorganization energy of the condensed cyclic compound is 0 eV or more and 0.100 eV or less.

14. The condensed cyclic compound of claim 1, wherein an oscillator strength of the condensed cyclic compound is 0.100 or more.

15. An organic electroluminescent device comprising:
a first electrode; a second electrode; and an organic layer comprising an emission layer and arranged between the first electrode and the second electrode,
wherein the organic layer comprises the condensed cyclic compound of claim 1.

16. The organic electroluminescent device of claim 15, wherein the emission layer comprises the condensed cyclic compound.

17. The organic electroluminescent device of claim 16, wherein the emission layer further comprises a host material.

18. The organic electroluminescent device of claim 16, wherein the emission layer further comprises a thermally activated delayed fluorescence material.

19. The organic electroluminescent device of claim 16, wherein the emission layer further comprises a phosphorescent material.

20. The organic electroluminescent device of claim 19, wherein the phosphorescent material is a platinum complex.
